(19) United States
(12) Patent Application Publication
(10) Pub. No.: US 2025/0275182 A1
(43) Pub. Date: Aug. 28, 2025

(54) SEMICONDUCTOR DEVICE AND DISPLAY APPARATUS

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Shunpei YAMAZAKI, Setagaya, Tokyo (JP)

(21) Appl. No.: 18/858,107

(22) PCT Filed: Apr. 10, 2023
(86) PCT No.: PCT/IB2023/053621

§ 371 Date: Oct. 18, 2024

(30) Foreign Application Priority Data
Apr. 22, 2022 (JP) 2022-070711
May 20, 2022 (JP) 2022-082945

(51) Int. Cl. H10D 30/67; H10D 30/01; H10D 86/60

(52) U.S. Cl. CPC H10D 30/6731; H10D 30/6736; H10D 30/6755; H10D 30/6757; H10D 86/60; H10D 30/0314

(57) ABSTRACT

A high-resolution display apparatus is provided. The display apparatus includes a transistor, and a semiconductor layer of the transistor is provided in an opening formed in an interlayer insulating layer over a substrate. A conductive layer in a floating state is provided below the opening. A source electrode and a drain electrode are provided over the interlayer insulating layer so as to face each other with the opening therebetween in a plan view. A gate insulating layer and a gate electrode are provided over the semiconductor layer. In the semiconductor layer, a region along a side surface of the opening can be a channel formation region.

### TECHNICAL FIELD

One embodiment of the present invention relates to a semiconductor device, a display apparatus, a display module, and an electronic device. One embodiment of the present invention relates to a manufacturing method of a semiconductor device and a manufacturing method of a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

In recent years, there has been a need for display apparatuses applicable to virtual reality (VR), augmented reality (AR), substitutional reality (SR), or mixed reality (MR). VR, AR, SR, and MR are collectively referred to as extended reality (XR). Display apparatuses for XR have been desired to have high resolution and high color reproducibility so that realistic feeling and the sense of immersion can be enhanced. Examples of apparatuses applicable to such display apparatuses include a liquid crystal display apparatus and a light-emitting apparatus including a light-emitting element such as organic EL (Electro Luminescence) element or a light-emitting diode (LED).

Patent Document 1 discloses a display apparatus using an organic EL element (also referred to as an organic EL device) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a high-resolution display apparatus and a manufacturing method thereof. Another object of one embodiment of the present invention is to provide a small display apparatus and a manufacturing method thereof. Another object of one embodiment of the present invention is to provide a display apparatus with a narrow bezel and a manufacturing method thereof. Another object of one embodiment of the present invention is to provide a display apparatus including a transistor with high on-state current and a manufacturing method of the display apparatus. Another object of one embodiment of the present invention is to provide a display apparatus having favorable electrical characteristics and a manufacturing method thereof. Another object of one embodiment of the present invention is to provide a display apparatus with high display quality and a manufacturing method thereof. Another object of one embodiment of the present invention is to provide a novel display apparatus and a manufacturing method thereof. Another object of one embodiment of the present invention is to provide a semiconductor device applicable to the above display apparatus. Another object of one embodiment of the present invention is to provide a novel semiconductor device and a manufacturing method thereof.

Note that the description of these objects does not preclude the existence of other objects. One embodiment of the present invention does not need to achieve all of these objects. Note that objects other than these can be derived from the descriptions of the specification, the drawings, the claims, and the like.

### Means for Solving the Problems

One embodiment of the present inventio is a semiconductor device including a transistor and a first insulating layer. The transistor includes a first conductive layer, a second conductive layer, a third conductive layer, a fourth conductive layer, a semiconductor layer, and a second insulating layer. The first insulating layer is provided over the first conductive layer. The second conductive layer and the third conductive layer are provided over the first insulating layer. The first insulating layer includes an opening reaching the first conductive layer. The second conductive layer and the third conductive layer are provided to face each other with the opening therebetween in a plan view. The semiconductor layer is provided to include a region in contact with the first conductive layer, a region in contact with the second conductive layer, and a region in contact with the third conductive layer and to include a region positioned in the opening. The second insulating layer is provided over the semiconductor layer to include a region positioned in the opening. The fourth conductive layer is provided over the second insulating layer to include a region positioned in the opening.

In the above embodiment, the first conductive layer may be in a floating state. The second conductive layer may serve as one of a source electrode and a drain electrode of the transistor. The third conductive layer may serve as the other of the source electrode and the drain electrode of the transistor. The fourth conductive layer may serve as a gate electrode of the transistor.

In the above embodiment, an end portion of the semiconductor layer may include a region overlapping with the second conductive layer and a region overlapping with the third conductive layer.

In the above embodiment, the first conductive layer may include a region overlapping with the second conductive layer and a region overlapping with the third conductive layer.

Another embodiment of the present invention is a display apparatus including a signal line driver circuit, a transistor, a first insulating layer, and a pixel. The transistor includes a first conductive layer, a second conductive layer, a third conductive layer, a fourth conductive layer, a semiconductor layer, and a second insulating layer. The first insulating layer is provided over the first conductive layer. The second conductive layer and the third conductive layer are provided over the first insulating layer. The first insulating layer includes an opening reaching the first conductive layer. The second conductive layer and the third conductive layer are provided to face each other with the opening therebetween in a plan view. The semiconductor layer is provided to include a region in contact with the first conductive layer, a region in contact with the second conductive layer, and a region in contact with the third conductive layer and to include a region positioned in the opening. The second insulating layer is provided over the semiconductor layer to include a region positioned in the opening. The fourth conductive layer is provided over the second insulating layer to include a region positioned in the opening. The second conductive layer is electrically connected to the signal line driver circuit. The third conductive layer is electrically connected to the pixel.

In the above embodiment, the first conductive layer may be in a floating state, and the fourth conductive layer may serve as a gate electrode of the transistor.

In the above embodiment, an end portion of the semiconductor layer may include a region overlapping with the second conductive layer and a region overlapping with the third conductive layer.

In the above embodiment, the first conductive layer may include a region overlapping with the second conductive layer and a region overlapping with the third conductive layer.

Another embodiment of the present invention is a display apparatus including a signal line driver circuit, a first transistor, a second transistor, a first insulating layer, a first pixel, and a second pixel. The first transistor includes a first conductive layer, a second conductive layer, a third conductive layer, a fourth conductive layer, a first semiconductor layer, and a second insulating layer. The second transistor includes the second conductive layer, a fifth conductive layer, a sixth conductive layer, a seventh conductive layer, a second semiconductor layer, and the second insulating layer. The first insulating layer is provided over the first conductive layer and the fifth conductive layer. The second conductive layer, the third conductive layer, and the sixth conductive layer are provided over the first insulating layer. The first insulating layer includes a first opening reaching the first conductive layer and a second opening reaching the fifth conductive layer. The second conductive layer and the third conductive layer are provided to face each other with the first opening therebetween in a plan view. The second conductive layer and the sixth conductive layer are provided to face each other with the second opening therebetween in the plan view. The first semiconductor layer is provided to include a region in contact with the first conductive layer, a region in contact with the second conductive layer, and a region in contact with the third conductive layer and to include a region positioned in the first opening. The second semiconductor layer is provided to include a region in contact with the second conductive layer, a region in contact with the fifth conductive layer, and a region in contact with the sixth conductive layer and to include a region positioned in the second opening. The second insulating layer is provided over the first semiconductor layer and the second semiconductor layer to include a region positioned in the first opening and a region positioned in the second opening. The fourth conductive layer is provided over the second insulating layer to include a region positioned in the first opening. The seventh conductive layer is provided over the second insulating layer to include a region positioned in the second opening. The second conductive layer is electrically connected to the signal line driver circuit. The third conductive layer is electrically connected to the first pixel. The sixth conductive layer is electrically connected to the second pixel.

In the above embodiment, the first conductive layer and the fifth conductive layer may each be in a floating state. The fourth conductive layer may serve as a gate electrode of the first transistor. The seventh conductive layer may serve as a gate electrode of the second transistor.

In the above embodiment, an end portion of the first semiconductor layer may include a region overlapping with the second conductive layer and a region overlapping with the third conductive layer. An end portion of the second semiconductor layer may include a region overlapping with the second conductive layer and a region overlapping with the sixth conductive layer.

In the above embodiment, the first conductive layer may include a region overlapping with the second conductive layer and a region overlapping with the third conductive layer. The fifth conductive layer may include a region overlapping with the second conductive layer and a region overlapping with the sixth conductive layer.

In the above embodiment, the first semiconductor layer and the second semiconductor layer may each include a metal oxide. The metal oxide may contain indium, zinc, and M (M is one or more kinds selected from aluminum, titanium, gallium, germanium, tin, yttrium, zirconium, lanthanum, cerium, neodymium, and hafnium).

In the above embodiment, the display apparatus may include a control circuit. The control circuit may have a function of generating a first signal and outputting the first signal to the fourth conductive layer. The control circuit may have a function of generating a second signal and outputting the second signal to the seventh conductive layer. The first signal and the second signal may be complementary signals.

Another embodiment of the present invention is a semiconductor device including a transistor, and a first insulating layer. The transistor includes a first conductive layer, a second conductive layer, a third conductive layer, a semiconductor layer, and a second insulating layer. The first insulating layer includes an opening. The semiconductor layer is provided to include a region positioned in the opening. A top surface of the semiconductor layer includes a region in contact with the first conductive layer and a region in contact with the second conductive layer. The first conductive layer and the second conductive layer are provided to face each other with the opening therebetween in a plan view. The second insulating layer is provided over the semiconductor layer to include a region positioned in the opening. The third conductive layer is provided over the second insulating layer to include a region positioned in the opening.

Another embodiment of the present invention is a semiconductor device including a transistor and a first insulating layer. The transistor includes a first conductive layer, a second conductive layer, a third conductive layer, a fourth conductive layer, a semiconductor layer, and a second insulating layer. The first insulating layer includes a first opening and a second opening. The semiconductor layer is provided to include a region positioned in the first opening and a region positioned in the second opening. The semiconductor layer is provided to include a region in contact with the first conductive layer, a region in contact with the second conductive layer, and a region in contact with the third conductive layer. The first conductive layer and the second conductive layer are provided to face each other with the first opening therebetween in a plan view. The second conductive layer and the third conductive layer are provided to face each other with the second opening therebetween in the plan view. The second insulating layer is provided over the semiconductor layer to include a region positioned in the first opening and a region positioned in the second opening. The fourth conductive layer is provided over the second insulating layer to include a region positioned in the first opening and a region positioned in the second opening.

Another embodiment of the present invention is a semiconductor device including a transistor and a first insulating layer. The transistor includes a first conductive layer, a second conductive layer, a third conductive layer, a semiconductor layer, and a second insulating layer. The first insulating layer includes a first opening and a second opening. The semiconductor layer is provided to include a region positioned in the first opening and a region positioned in the second opening. The semiconductor layer is provided to include a region in contact with the first conductive layer and a region in contact with the second conductive layer. The first conductive layer and the second conductive layer are provided to face each other with the first opening and the second opening therebetween in a plan view. The second insulating layer is provided over the semiconductor layer to include a region positioned in the first opening and a region positioned in the second opening. The third conductive layer is provided over the second insulating layer to include a region positioned in the first opening and a region positioned in the second opening.

In the above embodiment, the semiconductor layer may include a region in contact with a top surface of the first insulating layer in a region between the first opening and the second opening in the plan view.

### Effect of the Invention

One embodiment of the present invention can provide a high-resolution display apparatus and a manufacturing method thereof. Another embodiment of the present invention can provide a small display apparatus and a manufacturing method thereof. Another embodiment of the present invention can provide a display apparatus with a narrow bezel and a manufacturing method thereof. Another embodiment of the present invention can provide a display apparatus including a transistor with high on-state current and a manufacturing method of the display apparatus. Another embodiment of the present invention can provide a display apparatus having favorable electrical characteristics and a manufacturing method thereof. Another embodiment of the present invention can provide a display apparatus with high display quality and a manufacturing method thereof. Another embodiment of the present invention can provide a novel display apparatus and a manufacturing method thereof. Another embodiment of the present invention can provide a semiconductor device applicable to the display apparatus. Another embodiment of the present invention can provide a novel semiconductor device and a manufacturing method thereof.

Note that the description of these effects does not preclude the existence of other effects. One embodiment of the present invention does not necessarily have all of these effects. Other effects can be derived from the descriptions of the specification, the drawings, and the claims.

### BRIEF DESCRIPTION OF THE DRAWINGS

FIG. 1 is a block diagram illustrating a structure example of a display apparatus.

FIG. 2A1 and FIG. 2A2 are plan views illustrating a structure example of a display apparatus.

FIG. 2B is a cross-sectional view illustrating the structure example of the display apparatus.

FIG. 3A is a cross-sectional view illustrating a structure example of a display apparatus. FIG. 3B and FIG. 3C are circuit diagrams illustrating transistors.

FIG. 4A is a plan view illustrating a structure example of a display apparatus. FIG. 4B is a cross-sectional view illustrating the structure example of the display apparatus.

FIG. 5 is a plan view illustrating a structure example of a display apparatus.

FIG. 6A is a plan view illustrating a structure example of a display apparatus. FIG. 6B is a cross-sectional view illustrating the structure example of the display apparatus.

FIG. 7A1 and FIG. 7A2 are plan views illustrating a structure example of a display apparatus.

FIG. 7B is a cross-sectional view illustrating the structure example of the display apparatus.

FIG. 8A1 and FIG. 8A2 are plan views illustrating a structure example of a display apparatus.

FIG. 8B is a cross-sectional view illustrating the structure example of the display apparatus.

FIG. 9A1 and FIG. 9A2 are plan views illustrating a structure example of a display apparatus.

FIG. 9B is a cross-sectional view illustrating the structure example of the display apparatus.

FIG. 10A1, FIG. 10A2, and FIG. 10B are plan views illustrating structure examples of a display apparatus. FIG. 10C is a cross-sectional view illustrating the structure example of the display apparatus.

FIG. 11A1 and FIG. 11A2 are plan views illustrating a structure example of a display apparatus.

FIG. 11B is a cross-sectional view illustrating the structure example of the display apparatus.

FIG. 12A is a cross-sectional view illustrating a structure example of a display apparatus. FIG. 12B and FIG. 12C are circuit diagrams illustrating transistors.

FIG. 13A1 and FIG. 13A2 are plan views illustrating a structure example of a display apparatus.

FIG. 13B is a cross-sectional view illustrating the structure example of the display apparatus.

FIG. 14A to FIG. 14C are plan views illustrating structure examples of a display apparatus.

FIG. 15A and FIG. 15B are plan views illustrating structure examples of a display apparatus.

FIG. 16A and FIG. 16B are plan views illustrating structure examples of a display apparatus.

FIG. 17A1, FIG. 17A2, and FIG. 17B are plan views illustrating structure examples of a display apparatus. FIG. 17C is a cross-sectional view illustrating the structure example of the display apparatus.

FIG. 18A and FIG. 18B are cross-sectional views illustrating structure examples of a display apparatus.

FIG. 19A1 and FIG. 19A2 are plan views illustrating a structure example of a display apparatus.

FIG. 19B is a circuit diagram illustrating transistors.

FIG. 20A and FIG. 20B are plan views illustrating a structure example of a display apparatus.

FIG. 21A1 and FIG. 21A2 are plan views illustrating a structure example of a display apparatus.

FIG. 21B is a circuit diagram illustrating transistors.

FIG. 22A and FIG. 22B are plan views illustrating a structure example of a display apparatus.

FIG. 23A and FIG. 23B are plan views illustrating structure examples of a display apparatus.

FIG. 24A1 and FIG. 24A2 are plan views illustrating a structure example of a display apparatus.

FIG. 24B is a cross-sectional view illustrating the structure example of the display apparatus.

FIG. 25A is a cross-sectional view illustrating a structure example of a display apparatus. FIG. 25B is a circuit diagram illustrating transistors.

FIG. 26A1 and FIG. 26A2 are plan views illustrating a structure example of a display apparatus.

FIG. 26B is a cross-sectional view illustrating the structure example of the display apparatus.

FIG. 27A1 and FIG. 27A2 are plan views illustrating a structure example of a display apparatus.

FIG. 27B is a cross-sectional view illustrating the structure example of the display apparatus.

FIG. 28A1 and FIG. 28A2 are plan views illustrating a structure example of a display apparatus.

FIG. 28B is a cross-sectional view illustrating the structure example of the display apparatus.

FIG. 29A1 and FIG. 29A2 are plan views illustrating a structure example of a display apparatus.

FIG. 29B is a cross-sectional view illustrating the structure example of the display apparatus.

FIG. 30A is a cross-sectional view illustrating a structure example of a display apparatus. FIG. 30B is a circuit diagram illustrating transistors.

FIG. 31A1 and FIG. 31A2 are plan views illustrating a structure example of a display apparatus.

FIG. 31B is a cross-sectional view illustrating the structure example of the display apparatus.

FIG. 32A1, FIG. 32A2, and FIG. 32B are plan views illustrating structure examples of a display apparatus.

FIG. 33A and FIG. 33B are plan views illustrating structure examples of a display apparatus.

FIG. 34A and FIG. 34B are plan views illustrating structure examples of a display apparatus.

FIG. 35A is a plan view illustrating a structure example of a display apparatus. FIG. 35B is a cross-sectional view illustrating the structure example of the display apparatus.

FIG. 36A is a plan view illustrating a structure example of a display apparatus. FIG. 36B is a cross-sectional view illustrating the structure example of the display apparatus.

FIG. 37A is a plan view illustrating a structure example of a display apparatus. FIG. 37B is a cross-sectional view illustrating the structure example of the display apparatus.

FIG. 38A is a plan view illustrating a structure example of a display apparatus. FIG. 38B is a cross-sectional view illustrating the structure example of the display apparatus.

FIG. 39A to FIG. 39C are plan views illustrating structure examples of a display apparatus.

FIG. 40A to FIG. 40C are plan views illustrating structure examples of a display apparatus.

FIG. 41A to FIG. 41C are plan views illustrating structure examples of a display apparatus.

FIG. 42A and FIG. 42B are plan views illustrating structure examples of a display apparatus.

FIG. 43A and FIG. 43B are plan views illustrating structure examples of a display apparatus.

FIG. 44A and FIG. 44C are plan views illustrating structure examples of a display apparatus.

FIG. 45A1 and FIG. 45A2 are plan views illustrating a structure example of a display apparatus.

FIG. 45B1 and FIG. 45B2 are cross-sectional views illustrating structure examples of the display apparatus.

FIG. 46A and FIG. 46B are cross-sectional views illustrating structure examples of a display apparatus.

FIG. 47A and FIG. 47B are cross-sectional views illustrating structure examples of a display apparatus.

FIG. 48A and FIG. 48B are cross-sectional views illustrating structure examples of a display apparatus.

FIG. 49A1 and FIG. 49A2 are plan views illustrating structure examples of a display apparatus.

FIG. 49B1 and FIG. 49B2 are cross-sectional views illustrating structure examples of a display apparatus.

FIG. 50A1 and FIG. 50B1 are plan views illustrating an example of a method for manufacturing a display apparatus. FIG. 50A2 and FIG. 50B2 are cross-sectional views illustrating the example of the method for manufacturing the display apparatus.

FIG. 51A1 and FIG. 51B1 are plan views illustrating the example of the method for manufacturing the display apparatus. FIG. 51A2 and FIG. 51B2 are cross-sectional views illustrating the example of the method for manufacturing the display apparatus.

FIG. 52A1 and FIG. 52B1 are plan views illustrating the example of the method for manufacturing the display apparatus. FIG. 52A2 and FIG. 52B2 are cross-sectional views illustrating the example of the method for manufacturing the display apparatus.

FIG. 53A1 and FIG. 53B1 are plan views illustrating the example of the method for manufacturing the display apparatus. FIG. 53A2 and FIG. 53B2 are cross-sectional views illustrating the example of the method for manufacturing the display apparatus.

FIG. 54A1 and FIG. 54B1 are plan views illustrating the example of the method for manufacturing the display apparatus. FIG. 54A2 and FIG. 54B2 are cross-sectional views illustrating the example of the method for manufacturing the display apparatus.

FIG. 55 is a block diagram illustrating a structure example of a display apparatus.

FIG. 56A and FIG. 56B are circuit diagrams illustrating a structure example of a display apparatus.

FIG. 57A is a plan view illustrating a structure example of a display apparatus. FIG. 57B is a cross-sectional view illustrating the structure example of the display apparatus.

FIG. 58 is a plan view illustrating a structure example of a display apparatus.

FIG. 59 is a block diagram illustrating a structure example of a display apparatus.

FIG. 60 is a plan view illustrating a structure example of a display apparatus.

FIG. 61A to FIG. 61E are circuit diagrams illustrating structure examples of a pixel.

FIG. 62A is a plan view illustrating a structure example of a display apparatus. FIG. 62B is a cross-sectional view illustrating the structure example of the display apparatus.

FIG. 63 is a plan view illustrating a structure example of a display apparatus.

FIG. 64A is a plan view illustrating a structure example of a display apparatus. FIG. 64B is a cross-sectional view illustrating the structure example of the display apparatus.

FIG. 65A is a block diagram illustrating a structure example of a memory device. FIG. 65B to FIG. 65F are circuit diagrams illustrating structure examples of a memory cell.

FIG. 66A to FIG. 66G are plan views illustrating structure examples of a pixel.

FIG. 67A to FIG. 67K are plan views illustrating structure examples of a pixel.

FIG. 68 is a perspective view illustrating a structure example of a display apparatus.

FIG. 69 is a cross-sectional view illustrating a structure example of a display apparatus.

FIG. 70A is a cross-sectional view illustrating a structure example of a display apparatus. FIG. 70B and FIG. 70C are cross-sectional views illustrating structure examples of transistors.

FIG. 71 is a cross-sectional view illustrating a structure example of a display apparatus.

FIG. 72 is a cross-sectional view illustrating a structure example of a display apparatus.

FIG. 73 is a cross-sectional view illustrating a structure example of a display apparatus.

FIG. 74 is a cross-sectional view illustrating a structure example of a display apparatus.

FIG. 75 is a cross-sectional view illustrating a structure example of a display apparatus.

FIG. 76A to FIG. 76F are cross-sectional views illustrating structure examples of a light-emitting element.

FIG. 77A to FIG. 77C are cross-sectional views illustrating structure examples of a light-emitting element.

FIG. 78A to FIG. 78D are diagrams illustrating examples of electronic devices.

FIG. 79A to FIG. 79F are diagrams illustrating examples of electronic devices.

FIG. 80A to FIG. 80G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases. Furthermore, a plurality of layers that can be formed in the same step are shown with the same hatching pattern in some cases.

The position, size, range, or the like of each component illustrated in drawings does not represent the actual position, size, range, or the like in some cases for easy understanding. Therefore, the disclosed invention is not necessarily limited to the position, size, range, and the like disclosed in drawings.

Note that the term “film” and the term “layer” can be interchanged with each other depending on the case or the situation. For example, the term “conductive layer” can be changed into the term “conductive film” in some cases. For another example, the term “insulating film” can be changed into the term “insulating layer” in some cases.

In this specification and the like, the terms such as “electrode” and “wiring” do not limit the functions of the components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, a structure where at least light-emitting layers are separately formed for light-emitting elements with different emission wavelengths is referred to as a side-by-side (SBS) structure in some cases. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases depending on the cross-sectional shape, the characteristics, or the like. One layer may have two or three functions of the carrier-injection layer, the carrier-transport layer, and the carrier-blocking layer in some cases.

In this specification and the like, a light-emitting element (also referred to as a light-emitting device) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving element (also referred to as a light-receiving device) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to a shape such that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, when a side surface of a layer has a tapered shape, an outermost portion of the side surface of the layer is referred to as an end portion of the layer unless otherwise specified. For example, in the case where an end portion of a bottom surface of a layer is positioned outward from an end portion of a top surface, the end portion of the bottom surface is simply referred to as an end portion unless otherwise specified.

In this specification and the like, a mask layer (also referred to as a sacrificial layer) refers to a layer that is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, the expression “having substantially the same planar shape” means that at least outlines of stacked layers partly overlap each other. For example, the case of processing the upper layer and the lower layer with the same mask pattern or mask patterns that are partly the same is included. Note that in some cases, the outlines do not exactly overlap with each other and the upper layer is positioned inward from the lower layer or the upper layer is positioned outward from the lower layer; such cases are also represented by the expression “having substantially the same planar shape”.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in the specification, the description can be changed appropriately depending on the situation.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

### Embodiment 1

In this embodiment, a display apparatus of one embodiment of the present invention, a manufacturing method thereof, and the like will be described with reference to drawings.

One embodiment of the present invention relates to a display apparatus including a transistor. As the transistor, a transistor where a semiconductor layer is provided in an opening formed in an interlayer insulating layer over a substrate is used. With such a structure, a region of the semiconductor layer along a side surface of a first opening can be a channel formation region, and the channel length direction of the transistor can be a direction along the side surface of the opening. Thus, the channel length is not influenced by the performance of a light exposure apparatus used for manufacturing the transistor, and the channel length can have a value smaller than the resolution limit of the light exposure apparatus.

Specifically, in the transistor included in the display apparatus of one embodiment of the present invention, the semiconductor layer is provided in the first opening formed in the interlayer insulating layer over the substrate. A conductive layer in a floating state (an electrically floating state) is provided below the first opening. Over the interlayer insulating layer, a source electrode and a drain electrode that are separated by a second opening including a region overlapping with the first opening are provided. In other words, the source electrode and the drain electrode are provided to face each other with the first opening therebetween in a plan view. A gate insulating layer and a gate electrode are provided over the semiconductor layer. In the transistor having the structure, the region of the semiconductor layer along the side surface of the first opening can be the channel formation region.

In this specification and the like, an opening includes a groove, a slit, and the like in some cases. In this specification and the like, a transistor can be referred to as a semiconductor device. A circuit, a device, and the like each including a transistor may be referred to as a semiconductor device. One embodiment of the present invention is not limited to a display apparatus, and a semiconductor device is also one embodiment of the present invention.

### <Structure Example 1 of Display Apparatus>

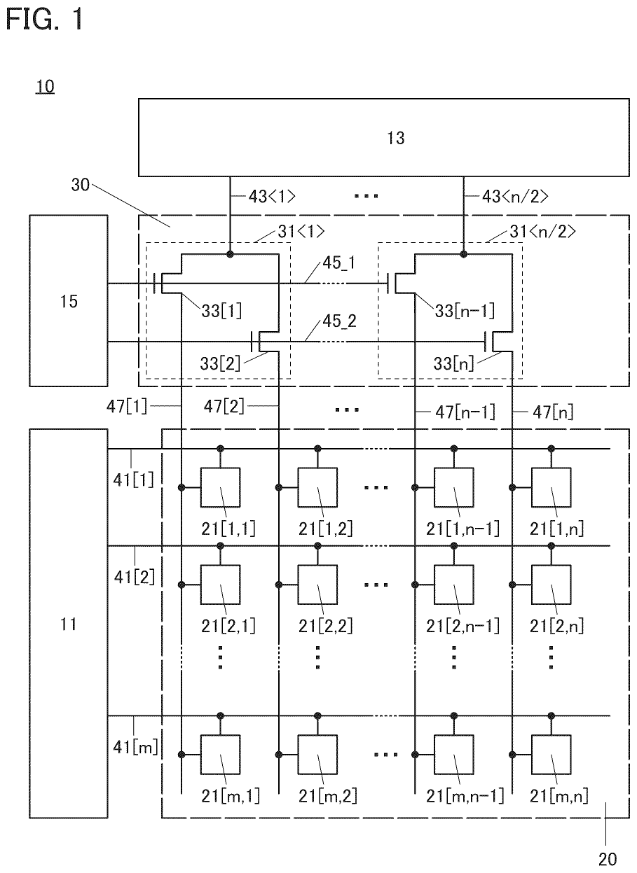

FIG. 1 is a block diagram illustrating a structure example of a display apparatus 10 that is a display apparatus of one embodiment of the present invention. The display apparatus 10 includes a display portion 20, a scan line driver circuit 11, a signal line driver circuit 13, a demultiplexer circuit 31, and a control circuit 15. The display portion 20 includes a plurality of pixels 21 arranged in a matrix of m rows and n columns (m is an integer greater than or equal to 2 and n is an integer greater than or equal to 1).

In this specification and the like, the pixel 21 in an i-th row and a j-th column (i is an integer greater than or equal to 1 and less than or equal to m, and j is an integer greater than or equal to 1 and less than or equal to n) is denoted by a pixel 21[i,j]. For example,[i] is added to a reference numeral representing a wiring electrically connected to the pixel 21 in the i-th row, and [j] is added to a reference numeral representing a wiring electrically connected to the pixel 21 in the j-th column.

The demultiplexer circuit 31 includes a plurality of transistors 33 functioning as switches. FIG. 1 illustrates an example where the demultiplexer circuit 31 includes two transistors 33. The display apparatus 10 includes a plurality of demultiplexer circuits 31, and FIG. 1 illustrates an example where the display apparatus 10 includes n/2 demultiplexer circuits 31. The plurality of demultiplexer circuits 31 are collectively referred to as a demultiplexer circuit group 30.

In this specification and the like, when a plurality of components are denoted by the same reference numerals and in particular need to be distinguished from each other, an identification sign such as “< >”, “_”, or “( )” is sometimes added to the reference numerals. For example, the n/2 demultiplexer circuits 31 are distinguished from one another by being denoted by the demultiplexer circuit 31<1> to a demultiplexer circuit 31<n/2>.

The scan line driver circuit 11 is electrically connected to the pixels 21 through a wiring 41. For example, the pixel 21[i,1] to the pixel 21[i,n] are electrically connected to the scan line driver circuit 11 through a wiring 41[i].

The signal line driver circuit 13 is electrically connected to an input terminal of the demultiplexer circuit 31 through a wiring 43. For example, an input terminal of a demultiplexer circuit 31<k> (here, k is an integer greater than or equal to 1 and less than or equal to n/2) is electrically connected to the signal line driver circuit 13 through a wiring 43<k>.

The control circuit 15 is electrically connected to a selection signal input terminal of the demultiplexer circuit 31 through a wiring 45. For example, the demultiplexer circuit 31<1> to the demultiplexer circuit 31<n/2> are each electrically connected to a wiring 45_1 and a wiring 45_2. That is, the demultiplexer circuit 31 can include a plurality of selection signal input terminals.

An output terminal of the demultiplexer circuit 31 is electrically connected to the pixels 21 through a wiring 47. For example, an output terminal of the demultiplexer circuit 31<k> is electrically connected to the pixel 21[1,2k−1] to the pixel 21[m,2k−1] through a wiring 47[2k−1], and is electrically connected to the pixel 21[1,2k] to the pixel 21[m,2k] through a wiring 47[2k]. That is, the demultiplexer circuit 31 can include a plurality of output terminals.

The demultiplexer circuit 31<k> includes a transistor 33[2k−1] and a transistor 33[2k]. One of a source and a drain of the transistor 33[2k−1] and one of a source and a drain of the transistor 33[2k] are electrically connected to the wiring 43<k>. The other of the source and the drain of the transistor 33[2k−1] is electrically connected to the wiring 47[2k−1], and the other of the source and the drain of the transistor 33[2k] is electrically connected to the wiring 47[2k]. A gate of the transistor 33[2k−1] is electrically connected to the wiring 45_1, and a gate of the transistor 33[2k] is electrically connected to the wiring 45_2.

Thus, the one of the source and the drain of the transistor 33[2k−1] and the one of the source and the drain of the transistor 33[2k] can be the input terminals of the demultiplexer circuit 31<k>. The other of the source and the drain of the transistor 33[2k−1] and the other of the source and the drain of the transistor 33[2k] can be the output terminals of the demultiplexer circuit 31<k>. The gate of the transistor 33[2k−1] and the gate of the transistor 33[2k] can be the selection signal input terminals of the demultiplexer circuit 31<k>.

The pixel 21 includes a display element (also referred to as a display apparatus), an image can be displayed on the display portion 20 with the display element. As the display element, for example, a light-emitting element (also referred to as a light-emitting device) can be used; specifically, an organic EL element can be used.

The scan line driver circuit 11 has a function of selecting the pixel 21 to which image data is to be written. Specifically, the scan line driver circuit 11 can select the pixel 21 to which image data is to be written by outputting a signal to the wiring 41. Here, the scan line driver circuit 11 can output the signals sequentially to a wiring 41[1] to a wiring 41[m], for example. Thus, the signal output from the scan line driver circuit 11 to the wiring 41 is a scan signal, and the wiring 41 can be referred to as a scan line.

The signal line driver circuit 13 has a function of generating image data. The image data is supplied to the demultiplexer circuit 31.

The demultiplexer circuit 31 has a function of outputting the image data generated by the signal line driver circuit 13, from any of the output terminals of the demultiplexer circuit 31. The demultiplexer circuit 31 can determine the output terminal from which the image data is output, in accordance with a selection signal input to the selection signal input terminal of the demultiplexer circuit 31.

The control circuit 15 has a function of generating a selection signal and supplying the selection signal to the demultiplexer circuit 31 to control driving of the demultiplexer circuit 31. For example, the control circuit 15 can generate a first signal and a second signal as selection signals and output the first signal and the second signal to the wiring 45_1 and the wiring 45_2, respectively. Here, for example, when the first signal is a signal that can turn on the transistor 33[2k−1] and the second signal is a signal that can turn off the transistor 33[2k], the demultiplexer circuit 31<k> can output image data to the wiring 47[2k−1]. When the first signal is a signal that can turn off the transistor 33[2k−1] and the second signal is a signal that can turn on the transistor 33[2k], the demultiplexer circuit 31<k> can output image data to the wiring 47[2k].

As described above, in the case where the first signal is a signal that can turn on the transistor 33, for example, the second signal can be a signal that can turn off the transistor 33; alternatively, in the case where the first signal is a signal that can turn off the transistor 33, the second signal can be a signal that can turn on the transistor 33. Thus, the first signal and the second signal can be signals complementary to each other. For example, in the case where the first signal and the second signal are 1-bit digital signals, the second signal can be a low potential in the case of the first signal that is a high potential or the second signal can be a high potential in the case of the first signal that is a low potential.

As described above, the image data generated by the signal line driver circuit 13 is supplied to the pixel 21 through the wiring 43, the demultiplexer circuit 31, and the wiring 47. For example, after the first signal is set to a signal that can turn on the transistor 33, the second signal is set to a signal that can turn on the transistor 33, whereby image data can be written to all the pixels 21 included in the row selected by the scan line driver circuit 11. Here, the image data can be represented as a signal. Thus, the wiring 43 and the wiring 47 can be referred to as signal lines.

Provision of the demultiplexer circuit in the display apparatus can reduce the number of wirings connected to the signal line driver circuit. For example, in the case where the demultiplexer circuit group 30 is not provided in the display apparatus 10, n wirings 43 are connected to the signal line driver circuit 13. By contrast, in the case where the demultiplexer circuit group 30 is provided in the display apparatus 10, the number of wirings 43 electrically connected to the signal line driver circuit 13 can be smaller than n. Accordingly, at the same pixel density of the display portion 20, the density of transistors provided in the signal line driver circuit 13 can be low as compared with the case where the demultiplexer circuit group 30 is not provided. Accordingly, at the same density of transistors provided in the signal line driver circuit 13, the pixel density of the display portion 20 can be increased. Thus, the pixel 21 can be miniaturized and the display apparatus 10 can be a high-resolution display apparatus. When the density of the transistors provided in the signal line driver circuit 13 is increased, the signal line driver circuit 13 can be reduced in size, so that the display apparatus 10 can be a small display apparatus and the display apparatus 10 can be a display apparatus with a narrow bezel.

Although FIG. 1 illustrates an example where the demultiplexer circuit 31 includes two transistors 33, the demultiplexer circuit 31 may include three or more transistors 33, for example. In the case where the demultiplexer circuit 31 includes three transistors 33, for example, the display apparatus 10 can include n/3 demultiplexer circuits 31. In this case, the demultiplexer circuit 31 can include three output terminals and three selection signal input terminals. The demultiplexer circuit 31 may include four or more transistors 33. In this case, the demultiplexer circuit 31 can include four or more output terminals and four or more selection signal input terminals.

For example, in the case where the demultiplexer circuit 31 includes three selection signal input terminals, the first to third signals are input to each selection signal input terminal as selection signals. Then, one of the first to third signals becomes a signal that can turn on the transistors 33, and the other two signals become signals that can turn off the transistors 33. For example, in the case where the first signal is the signal that can turn on the transistors 33, the second signal and the third signal are the signals that can turn off the transistors 33. Then, in the demultiplexer circuit 31, writing is first performed while the first signal is the signal that can turn on only the transistors 33, writing is next performed while the second signal is the signal that can turn on only the transistors 33, and writing is then performed while only the third signal is the signal that can turn on the transistors 33, whereby image data can be written to all the pixels 21 included in a row selected by the scan line driver circuit 11. Similarly, in the case where the demultiplexer circuit 31 includes four or more selection signal input terminals, one of the four or more selection signals is a signal that can turn on the transistors 33 and the others are signals that can turn off the transistors 33.

As the number of transistors 33 included in one demultiplexer circuit 31 increases, the number of wirings 43 electrically connected to the signal line driver circuit 13 can be reduced. Thus, the display apparatus 10 can have a higher resolution, a smaller size, and a narrower bezel.

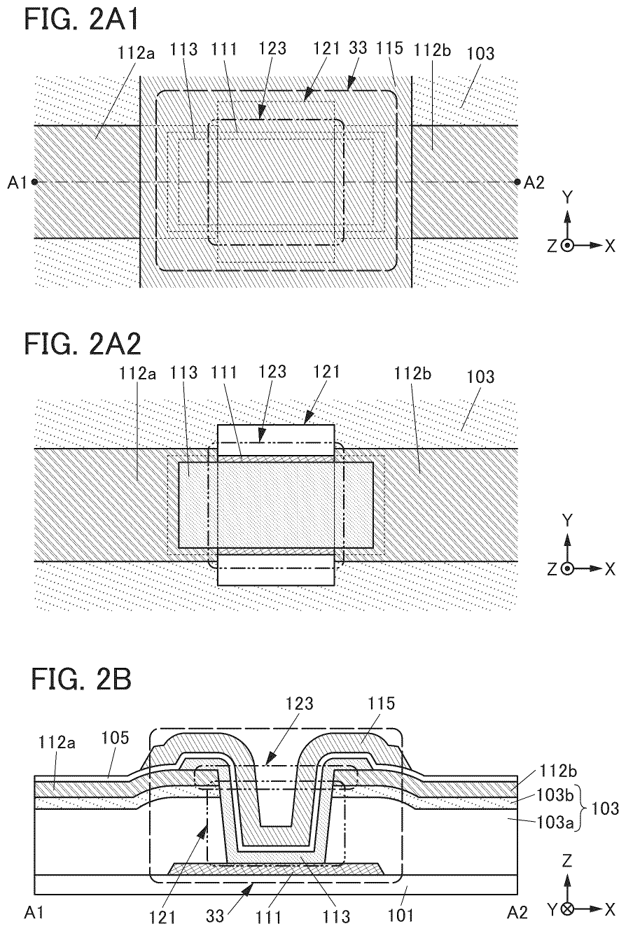

FIG. 2A1 is a plan view illustrating a structure example of the display apparatus of one embodiment of the present invention, specifically, a plan view illustrating the structure of the transistor 33 and its vicinity. FIG. 2B is a cross-sectional view taken along dashed-dotted line A1-A2 in FIG. 2A1.

In this specification and the like, unless otherwise specified, a plan view can be rephrased as a top view in some cases.

The transistor 33 is provided over a substrate 101. The transistor 33 includes a conductive layer 111, a conductive layer 112a, a conductive layer 112b, a semiconductor layer 113, an insulating layer 105, and a conductive layer 115. FIG. 2A1 illustrates an example where the extending direction of the conductive layer 112a and the conductive layer 112b and the extending direction of the conductive layer 115 are orthogonal to each other.

In FIG. 2A1 and FIG. 2B, the extending direction of the conductive layer 112a and the conductive layer 112b is referred to as the X direction, as indicated by coordinate axes. The direction perpendicular to the X direction and parallel to the top surface of the substrate 101, for example, is referred to as the Y direction, and the direction perpendicular the top surface of the substrate 101 is referred to as the Z direction. The definition of the X direction, the Y direction, and the Z direction applies in some drawings and does not apply in other drawings. The X direction, the Y direction, and the Z direction can be perpendicular to each other.

In the description of a plan view in this specification and the like, the X direction may be referred to as the right side or the left side and the Y direction may be referred to as the upper side or the lower side. The right side may be referred to as the X direction, the left side may be referred to as the −X direction, the upper side may be referred to as the Y direction, and the lower side may be referred to as the −Y direction in some cases.

The conductive layer 111 can be an electrode in a floating state. The conductive layer 112a functions as one of a source electrode and a drain electrode of the transistor 33. The conductive layer 112b functions as the other of the source electrode and the drain electrode of the transistor 33. The insulating layer 105 functions as a gate insulating layer of the transistor 33. The conductive layer 115 functions as a gate electrode of the transistor 33.

In this specification and the like, an electrode that can be brought into a floating state is referred to as a floating electrode. The conductive layer 111 functions as a floating electrode.

In the semiconductor layer 113 between the source electrode and the drain electrode, the whole region overlapping with the gate electrode with the gate insulating layer therebetween functions as a channel formation region. In the semiconductor layer 113, a region in contact with the source electrode functions as a source region, and a region in contact with the drain electrode functions as a drain region.

The conductive layer 111 is provided over the substrate 101, an insulating layer 103 is provided over the substrate 101 and the conductive layer 111, and the conductive layer 112a and the conductive layer 112b are provided over the insulating layer 103. The conductive layer 111 is provided between the conductive layer 112a and the conductive layer 112b in a plan view. The insulating layer 103 can have a function of an interlayer insulating layer. The conductive layer 111 includes a region overlapping with the conductive layer 112a with the insulating layer 103 therebetween and a region overlapping with the conductive layer 112b with the insulating layer 103 therebetween. Note that although FIG. 2B and the like illustrate an example where no layer is provided between the substrate 101 and each of the conductive layer 111 and the insulating layer 103, an interlayer insulating layer or the like can be actually provided.

The insulating layer 103 has an opening 121 reaching the conductive layer 111. The conductive layer 112a and the conductive layer 112b are separated by an opening 123 including a region overlapping with the opening 121. In other words, the conductive layer 112a and the conductive layer 112b are provided to face each other with the opening 121 therebetween in a plan view. The opening 123 includes a region overlapping with the conductive layer 111. Here, after a film to be the conductive layer 112a and the conductive layer 112b is formed over the insulating layer 103, the film is processed by a photolithography method and an etching method, for example, whereby the conductive layer 112a and the conductive layer 112b can be formed. The insulating layer 103 is processed after the formation of the conductive layer 112a and the conductive layer 112b, whereby the opening 121 can be formed to include a region overlapping with the opening 123.

Note that the opening 123 and the opening 121 may be formed in the same step or may be formed in different steps. In the case where the opening 123 and the opening 121 are formed in the same step, the opening 123 and the opening 121 can be formed using the same mask pattern. Forming the opening 123 and the opening 121 in different steps means that, for example, the film to be the conductive layer 112a and the conductive layer 112b and the insulating layer 103 are processed under different etching conditions, although the mask pattern of the opening 123 and the mask pattern of the opening 121 are the same. Forming the opening 123 and the opening 121 in different steps means that the opening 123 and the opening 121 are formed using different mask patterns. In the case where the opening 123 and the opening 121 are formed using different mask patterns, for example, a pattern is formed by a photolithography method, the film to be the conductive layer 112a and the conductive layer 112b is processed to form the opening 123, a different pattern is formed by a photolithography method again, and then the insulating layer 103 is processed to form the opening 121.

FIG. 2A1 illustrates the conductive layer 111, the insulating layer 103, the conductive layer 112a, the conductive layer 112b, the semiconductor layer 113, the conductive layer 115, the opening 121, and the opening 123 as components of the transistor 33. Here, FIG. 2A2 is a plan view omitting the conductive layer 115 from the components illustrated in FIG. 2A1. That is, FIG. 2A2 illustrates the conductive layer 111, the insulating layer 103, the conductive layer 112a, the conductive layer 112b, the semiconductor layer 113, the opening 121, and the opening 123.

As illustrated in FIG. 2A2, the conductive layer 111 functioning as a floating electrode can have an island shape. The semiconductor layer 113 can also have an island shape.

FIG. 2A2, FIG. 2B, and the like illustrate an example where an end portion of the conductive layer 112a is aligned or substantially aligned with an end portion of the insulating layer 103 and an end portion of the conductive layer 112b is aligned or substantially aligned with an end portion of the insulating layer 103. FIG. 2A2, FIG. 2B, and the like illustrate an example where end portions of the conductive layer 111 include a region overlapping with the conductive layer 112a and a region overlapping with the conductive layer 112b. FIG. 2A2 illustrates an example where the end portions of the conductive layer 112a and the conductive layer 112b are positioned outward from the end portion of the conductive layer 111 and end portions of the opening 121 are positioned outward from the end portions of the conductive layer 112a and the conductive layer 112b in the Y direction, for example. Furthermore, FIG. 2A2, FIG. 2B, and the like illustrate an example where the whole semiconductor layer 113 overlaps with the conductive layer 111. That is, FIG. 2A2, FIG. 2B, and the like illustrate an example where the end portions of the semiconductor layer 113 are positioned inward from the end portions of the conductive layer 111 in the X direction and the Y direction.

In this specification and the like, the end portion of the conductive layer 112a and the end portion of the conductive layer 112b refer to the end portion of the bottom surface of the conductive layer 112a and the end portion of the bottom surface of the conductive layer 112b, respectively. The bottom surface of the conductive layer 112a and the bottom surface of the conductive layer 112b refer to surfaces on the insulating layer 103 side. The end portions of the opening 123 include a region common to the end portion of the conductive layer 112a and a region common to the end portion of the conductive layer 112b. The end portion of the insulating layer 103 refers to the end portion of the top surface of the insulating layer 103. The top surface of the insulating layer 103 refers to a surface on the conductive layer 112a and the conductive layer 112b side. The end portion of the opening 121 is common to the end portion of the insulating layer 103.

In the case where end portions are aligned or substantially aligned with each other, the end portions can also be said to match or substantially match. In the case where end portions match or substantially match and the case where planar shapes are the same or substantially the same, it can be said that outlines of stacked layers at least partly overlap with each other in a plan view (also referred to as a top view). For example, the case of processing the upper layer and the lower layer using the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match” or the expression “planar shapes are substantially the same”.

The semiconductor layer 113 is provided to cover the opening 121 and the opening 123 and include a region positioned in the opening 121 and the opening 123. The semiconductor layer 113 has a shape along the shapes of the top surface and the side surface of the conductive layer 112a, the top surface and the side surface of the conductive layer 112b, the side surface of the insulating layer 103, and the top surface of the conductive layer 111. The semiconductor layer 113 includes a region in contact with the top surface and the side surface of the conductive layer 112a, the top surface and the side surface of the conductive layer 112b, the side surface of the insulating layer 103, and the top surface of the conductive layer 111.

The semiconductor layer 113 preferably covers the end portion of the conductive layer 112a and the end portion of the conductive layer 112b. FIG. 2A2, FIG. 2B, and the like illustrate a structure where the end portions of the semiconductor layer 113 include a region overlapping with the conductive layer 112a and a region overlapping with the conductive layer 112b. It can be said that the end portions of the semiconductor layer 113 include a region in contact with the top surface of the conductive layer 112a and a region in contact with the top surface of the conductive layer 112b.

Although the semiconductor layer 113 has a single-layer structure in FIG. 2B, for example, one embodiment of the present invention is not limited thereto. The semiconductor layer 113 may have a stacked-layer structure of two or more layers.

The insulating layer 105 functioning as the gate insulating layer of the transistor 33 is provided to cover the opening 121 and the opening 123 and include a region positioned in the opening 121 and the opening 123. The insulating layer 105 is provided over the semiconductor layer 113, the conductive layer 112a, the conductive layer 112b, and the insulating layer 103. The insulating layer 105 can include a region in contact with the top surface and the side surface of the semiconductor layer 113, the top surface and the side surface of the conductive layer 112a, the top surface and the side surface of the conductive layer 112b, and the top surface of the insulating layer 103. The insulating layer 105 has a shape along the shapes of the top surface of the insulating layer 103, the top surface and the side surface of the conductive layer 112a, the top surface and the side surface of the conductive layer 112b, and the top surface and the side surface of the semiconductor layer 113.

The conductive layer 115 functioning as the gate electrode of the transistor 33 can be provided over the insulating layer 105 and can include a region in contact with the top surface of the insulating layer 105. The conductive layer 115 includes a region overlapping with the semiconductor layer 113 with the insulating layer 105 therebetween. The conductive layer 115 has a shape along the shape of the top surface of the insulating layer 105.

As illustrated in FIG. 2B, for example, the conductive layer 115 includes a region overlapping with the semiconductor layer 113 with the insulating layer 105 therebetween in the opening 121 and the opening 123. Moreover, in the example illustrated in FIG. 2B, the conductive layer 115 includes a region overlapping with the conductive layer 111, a region overlapping with the conductive layer 112a, and a region overlapping with the conductive layer 112b, with the insulating layer 105 and the semiconductor layer 113 therebetween.

The conductive layer 115 covers the entire semiconductor layer 113. This enables a gate electric field to be applied to the entire semiconductor layer 113, so that the transistor 33 can have better electrical characteristics; for example, the transistor can have a higher on-state current. FIG. 2A1 and FIG. 2B illustrate an example where the end portion of the conductive layer 115 is positioned outward from the end portion of the conductive layer 111 in the X direction.

The transistor 33 is what is called a top-gate transistor including the gate electrode above the semiconductor layer 113. Furthermore, since the bottom surface of the semiconductor layer 113 includes a region in contact with the source electrode and the drain electrode, the transistor 33 can be referred to as a TGBC (Top Gate Bottom Contact) transistor.

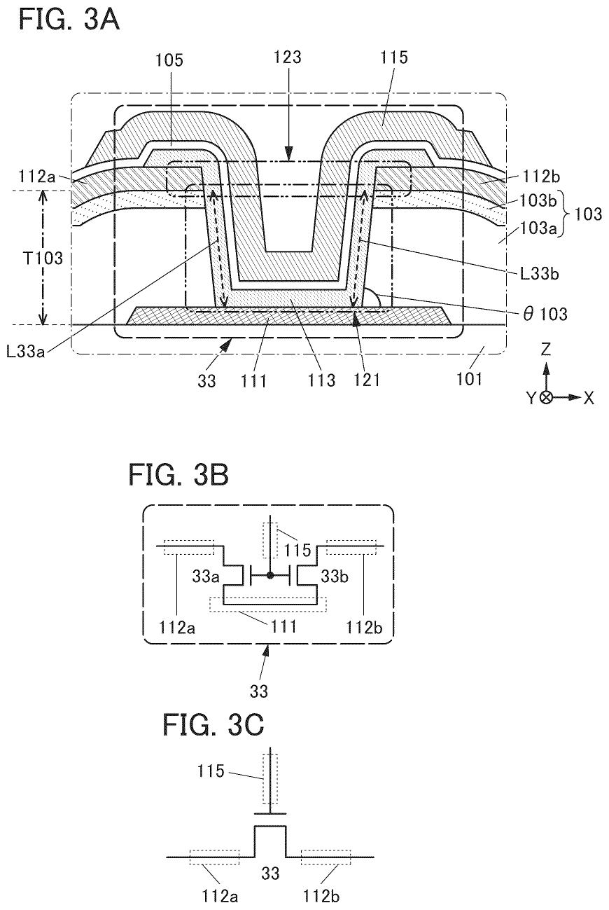

Here, the channel length of the transistor 33 will be described with reference to FIG. 3A. FIG. 3A is an enlarged view of the cross-sectional view in FIG. 2B illustrating the structure example of the transistor 33 and its vicinity.

In the semiconductor layer 113, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 33 is a distance between the source region and the drain region. In FIG. 3A, a length L33a and a length L33b are each indicated by a dashed double-headed arrow. The length L33a is a distance between an end portion of a region where the semiconductor layer 113 and the conductive layer 111 are in contact with each other and an end portion of a region where the semiconductor layer 113 and the conductive layer 112a are in contact with each other when seen from the XZ plane. The length L33b is a distance between an end portion of the region where the semiconductor layer 113 and the conductive layer 111 are in contact with each other and an end portion of a region where the semiconductor layer 113 and the conductive layer 112b are in contact with each other when seen from the XZ plane.

When the conductive layer 111 functioning as a floating electrode is provided between the conductive layer 112a and the conductive layer 112b, a current flowing through the region of the semiconductor layer 113 in contact with the conductive layer 111 and a region in the vicinity thereof can be prevented from being affected by an electric field of the conductive layer 115 functioning as the gate electrode of the transistor 33. Thus, the region of the semiconductor layer 113 in contact with the conductive layer 111 and the region in the vicinity thereof do not function as the channel formation region. This enables the channel length of the transistor 33 to be short as compared with the case where the conductive layer 111 is not provided in the transistor 33. In the example illustrated in FIG. 3A, the sum of the length L33a and the length L33b can be the channel length of the transistor 33. Here, when the end portion of the top surface of the conductive layer 111 is positioned outward from the end portion of the bottom surface of the opening 121 when seen from the XZ plane, the area of the region where the conductive layer 111 and the semiconductor layer 113 are in contact with each other can be favorably increased. Thus, the channel length of the transistor 33 can be favorably shortened. For example, a length only in the direction along the side surface of the insulating layer 103 on the opening 121 side can be the channel length of the transistor 33.

In this specification and the like, the side surface of the insulating layer 103 on the opening 121 side is referred to as the side surface of the opening 121. The side surfaces of the conductive layer 112a and the conductive layer 112b on the opening 123 side are each referred to as the side surface of the opening 123.

The length L33a and the length L33b each correspond to the length of the side surface of the opening 121 when seen from the XZ plane. That is, the length L33a and the length L33b are determined depending on a thickness T103 of the insulating layer 103 and an angle θ103 formed by the side surface of the opening 121 and the formation surface of the insulating layer 103 (here, the top surface of the conductive layer 111), and is not affected by the performance of a light-exposure apparatus used for manufacturing the transistor. Thus, the length L33 can have a value smaller than the resolution limit of the light-exposure apparatus. For example, the length L33 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. In FIG. 3A, the thickness T103 of the insulating layer 103 is indicated by a dashed-dotted double-headed arrow.

The reduction in the channel length of the transistor 33 can increase the on-state current of the transistor 33. Thus, when the transistor 33 included in the demultiplexer circuit 31 has the structure illustrated in FIG. 3A, for example, the demultiplexer circuit 31 can be driven at high speed. Thus, even with a structure where one demultiplexer circuit 31 includes a large number of transistors 33, that is, a structure where one demultiplexer circuit 31 includes a large number of output terminals, the frame frequency of the display apparatus 10 can be ensured. Accordingly, the number of wirings connected to the signal line driver circuit 13 can be favorably reduced. Thus, at the same pixel density of the display portion 20, the densities of transistors provided in the signal line driver circuit 13 can be low as compared with the case where the demultiplexer circuit group 30 is not provided, for example. Thus, at the same density of the transistors provided in the signal line driver circuit 13, the pixel density of the display portion 20 can be increased. Accordingly, the pixel 21 can be miniaturized and the display apparatus 10 can be a high-resolution display apparatus. When the density of transistors provided in the signal line driver circuit 13 is increased, the signal line driver circuit 13 can be reduced in size, so that the display apparatus 10 can be a small display apparatus and a display apparatus with a narrow bezel.

The length L33 can be controlled by adjusting the thickness T103 and the angle θ103 of the insulating layer 103.

The thickness T103 of the insulator 103 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

The side surface of the opening 121 preferably has a tapered shape. The angle θ103 formed by the side surface of the opening 121 and the formation surface of the insulator 103 (here, the top surface of the conductive layer 111) is preferably less than 90°. By reducing the angle θ103, the coverage with a layer (e.g., the semiconductor layer 113) provided over the insulator 103 can be improved. However, reducing the angle θ103 might reduce the contact area between the semiconductor layer 113 and the conductive layer 111 and increase the contact resistance between the semiconductor layer 113 and the conductive layer 111. The angle θ103 is preferably greater than or equal to 45° and less than 90°, further preferably greater than or equal to 50° and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ103 is within the above range, the coverage with the layer (e.g., the semiconductor layer 113) formed over the conductive layer 111 and the insulator 103 can be improved, which can inhibit defects such as step disconnection or a void from being generated in the layer. In addition, the contact resistance between the semiconductor layer 113 and the conductive layer 111 can be reduced.

Although FIG. 3A and the like illustrate the structure where the side surface the opening 121 is linear in the cross-sectional view, one embodiment of the present invention is not limited thereto. In the cross-sectional view, the side surface of the opening 121 may be curved, or the side surface may include both a linear region and a curved region.

Note that the channel width of the transistor 33 can be the length of the semiconductor layer 113 in the Y direction.

In this specification and the like, the length in the Y direction can be referred to as a width in some cases. For example, the length of the conductive layer 111 in the Y direction can be referred to as the width of the conductive layer 111 in some cases. Note that a length in a direction other than the Y direction is sometimes referred to as a width.

FIG. 3B is a circuit diagram illustrating the transistor 33. As illustrated in FIG. 3B, the transistor 33 can be regarded as being composed of a transistor 33a and a transistor 33b. In this case, the conductive layer 111 functions as one of a source electrode and a drain electrode of the transistor 33a and one of a source electrode and a drain electrode of the transistor 33b. The conductive layer 112a functions as the other of the source electrode and the drain electrode of the transistor 33a, and the conductive layer 112b functions as the other of the source electrode and the drain electrode of the transistor 33b. Furthermore, the conductive layer 115 functions as a gate electrode of the transistor 33a and a gate electrode of the transistor 33b.

Thus, the transistor 33 can be regarded as a transistor in which the transistor 33a and the transistor 33b are connected in series through the conductive layer 111. The transistor 33 can be regarded as a multi-gate transistor including two gate electrodes. Here, the length L33a illustrated in FIG. 3A can be the channel length of the transistor 33a, and the length L33b can be the channel length of the transistor 33b.

As illustrated in FIG. 3C, the transistor 33 can be regarded as one transistor in which one of the source electrode and the drain electrode is the conductive layer 112a, the other of the source electrode and the drain electrode is the conductive layer 112b, and the gate electrode is the conductive layer 115.

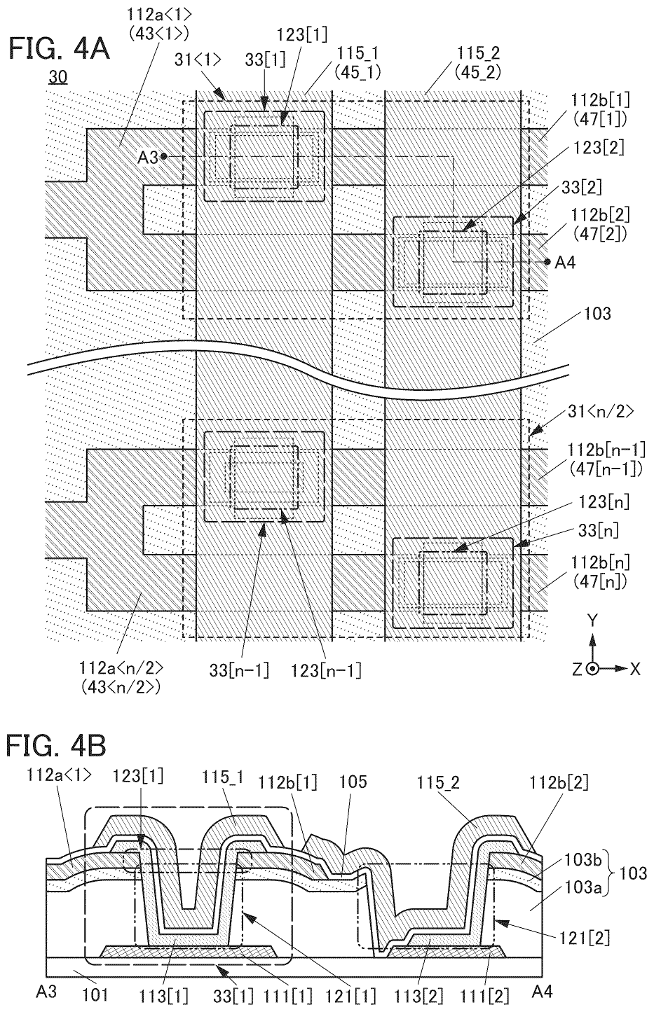

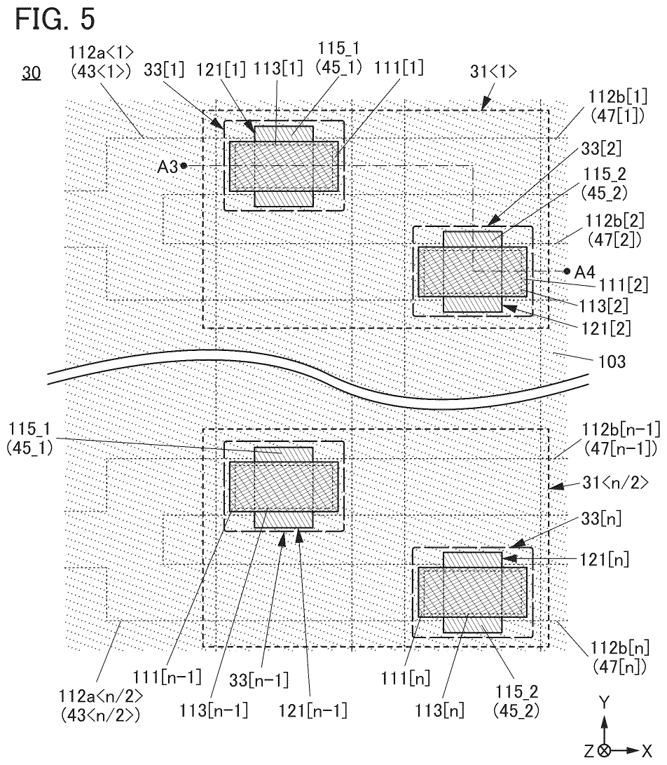

FIG. 4A is a plan view illustrating a structure example of the demultiplexer circuit group 30 illustrated in FIG. 1, and illustrates the demultiplexer circuit 31<1> and the demultiplexer circuit 31<n/2>. FIG. 4B is a cross-sectional view taken along dashed-dotted line A3-A4 in FIG. 4A, for example. FIG. 5 is a plan view seen from the direction opposite to FIG. 4A. In the case where the plan view shown in FIG. 4A is referred to as a top view, the plan view shown in FIG. 5 can be referred to as a bottom view. Note that at least some of the reference numerals representing the components indicated by dotted lines are omitted in FIG. 4A and FIG. 5. The same applies to a plan view illustrating a structure example of another circuit.

FIG. 4A and FIG. 5 illustrate a transistor 33[1], a transistor 33[2], a transistor 33[n−1], and a transistor 33[n]. FIG. 4B illustrates the transistor 33[1].

The transistor 33[1] includes a conductive layer 111[1], a conductive layer 112a<1>, a conductive layer 112b[1], a semiconductor layer 113[1], the insulating layer 105, and a conductive layer 115_1. The transistor 33[2] includes a conductive layer 111[2], a conductive layer 112a<1>, a conductive layer 112b[2], a semiconductor layer 113[2], the insulating layer 105, and a conductive layer 115_2. The transistor 33[n−1] includes a conductive layer 111[n−1], a conductive layer 112a<n/2>, a conductive layer 112b[n−1], a semiconductor layer 113[n−1], the insulating layer 105, and the conductive layer 115_1. The transistor 33[n] includes a conductive layer 111[n], the conductive layer 112a<n/2>, a conductive layer 112b[n], a semiconductor layer 113[n], the insulating layer 105, and the conductive layer 115_2.

In the demultiplexer circuit group 30, the insulating layer 103 is provided over the substrate 101 and the conductive layer 111[1] to the conductive layer 111[n]. The conductive layer 112a<1> to the conductive layer 112a<n/2> and the conductive layer 112b<1> to the conductive layer 112b<n/2> are provided over the insulating layer 103. The insulating layer 103 includes an opening 121[1] reaching the conductive layer 111[1], an opening 121[2] reaching the conductive layer 111[2], an opening 121[n−1] reaching the conductive layer 111[n−1], an opening 121[n] reaching the conductive layer 111[n], and the like.

The conductive layer 112a<1> and the conductive layer 112b[1] are separated by an opening 123[1] including a region overlapping with the opening 121[1]. The conductive layer 112a<1> and the conductive layer 112b[2] are separated by an opening 123[2] including a region overlapping with the opening 121[2]. The conductive layer 112a<n/2> and the conductive layer 112b[n−1] are separated by an opening 123[n−1] including a region overlapping with the opening 121[n−1]. The conductive layer 112a<n/2> and the conductive layer 112b[n] are separated by an opening 123[n] including a region overlapping with the opening 121[n].

The semiconductor layer 113[1] is provided to include regions positioned in the opening 121[1] and the opening 123[1] so as to cover the opening 123[1] and the opening 121[1] that reaches the conductive layer 111[1]. The semiconductor layer 113[2] is provided to include regions positioned in the opening 121[2] and the opening 123[2] so as to cover the opening 123[2] and the opening 121[2] that reaches the conductive layer 111[2]. The semiconductor layer 113[n−1] is provided to include regions positioned in the opening 121[n−1] and the opening 123[n−1] so as to cover the opening 123[n−1] and the opening 121[n−1] that reaches the conductive layer 111[n−1]. The semiconductor layer 113[n] is provided to include regions positioned in the opening 121[n] and the opening 123[n] so as to cover the opening 123[n] and the opening 121[n] that reaches the conductive layer 111[n].

The insulating layer 105 is provided over the semiconductor layer 113[1] to the semiconductor layer 113[n], the conductive layer 112a<1> to the conductive layer 112a<n/2>, and the conductive layer 112b[1] to the conductive layer 112b[n]. The conductive layer 115_1 is provided over the insulating layer 105 to include regions overlapping with the semiconductor layer 113[1], the semiconductor layer 113[n−1], and the like. The conductive layer 115_2 is provided over the insulating layer 105 to include regions overlapping with the semiconductor layer 113[2], the semiconductor layer 113[n], and the like.

The conductive layer 111[1] functions as a floating electrode of the transistor 33[1]. The conductive layer 111[2] functions as a floating electrode of the transistor 33[2]. The conductive layer 111[n−1] functions as a floating electrode of the transistor 33[n−1]. The conductive layer 111[n] functions as a floating electrode of the transistor 33[n].

Furthermore, the conductive layer 112a<1> functions as one of a source electrode and a drain electrode of the transistor 33[1] and one of a source electrode and a drain electrode of the transistor 33[2]. The conductive layer 112a<2> functions as one of a source electrode and a drain electrode of the transistor 33[n−1] and one of a source electrode and a drain electrode of the transistor 33[n]. The conductive layer 112b[1] functions as the other of the source electrode and the drain electrode of the transistor 33[1]. The conductive layer 112b[2] functions as the other of the source electrode and the drain electrode of the transistor 33[2]. The conductive layer 112b[n−1] functions as the other of the source electrode and the drain electrode of the transistor 33[n−1]. The conductive layer 112b[n] functions as the other of the source electrode and the drain electrode of the transistor 33[n].

The conductive layer 115_1 functions as gate electrodes of the transistor 33[1], the transistor 33[n−1], and the like. The conductive layer 115_2 functions as gate electrodes of the transistor 33[2], the transistor 33[n], and the like.

The end portions of the semiconductor layer 113[1] include a region overlapping with the conductive layer 112a<1> and a region overlapping with the conductive layer 112b[1]. The end portions of the semiconductor layer 113[2] include a region overlapping with the conductive layer 112a<1> and a region overlapping with the conductive layer 112b[2]. The end portions of the semiconductor layer 113[n−1] include a region overlapping with the conductive layer 112a<n/2> and a region overlapping with the conductive layer 112b[n−1]. The end portions of the semiconductor layer 113[n] include a region overlapping with the conductive layer 112a<n/2> and a region overlapping with the conductive layer 112b[n].

In the example illustrated in FIG. 5, the conductive layer 111[1] includes a region overlapping with the conductive layer 112a<1> and a region overlapping with the conductive layer 112b[1]. The conductive layer 111[2] includes a region overlapping with the conductive layer 112a<1> and a region overlapping with the conductive layer 112b[2]. The conductive layer 111[n−1] includes a region overlapping with the conductive layer 112a<n/2> and a region overlapping with the conductive layer 112b[n−1]. The conductive layer 111[n] includes a region overlapping with the conductive layer 112a<n/2> and a region overlapping with the conductive layer 112b[n].

The conductive layer 112a<1> to the conductive layer 112a<n/2> function respectively as a wiring 43a<1> to a wiring 43a<n/2> electrically connected to the signal line driver circuit 13. The conductive layer 112b[1] to the conductive layer 112b[n] function respectively as a wiring 47[1] to a wiring 47[n] electrically connected to the pixels 21. The conductive layer 115_1 functions as the wiring 45_1 electrically connected to the control circuit 15, and the conductive layer 115_2 functions as the wiring 45_2 electrically connected to the control circuit 15.

The conductive layer 112a<1> is shared by the transistor 33[1] and the transistor 33[2]. Accordingly, the other of the source and the drain of the transistor 33[1] can be electrically connected to the other of the source and the drain of the transistor 33[2]. The conductive layer 112a<n/2> is shared by the transistor 33[n−1] and the transistor 33[n]. Accordingly, the other of the source and the drain of the transistor 33[n−1] can be electrically connected to the other of the source and the drain of the transistor 33[n].

The conductive layer 115_1 is shared by the transistor 33[1] and the transistor 33[n−1]. Accordingly, the gate of the transistor 33[1] can be electrically connected to the gate of the transistor 33[n−1]. The conductive layer 115_2 is shared by the transistor 33[2] and the transistor 33[n]. Accordingly, the gate of the transistor 33[2] can be electrically connected to the gate of the transistor 33[n].

As illustrated in FIG. 4B, the insulating layer 105 can include a region overlapping with neither the conductive layer 111 nor the semiconductor layer 113 in the opening 121. In this case, the insulating layer 105 can include a region in contact with the side surface of the opening 121.

Components included in the display apparatus of this embodiment will be described below.

### <Components 1 of Display Apparatus>

[Semiconductor Layer 113]

There is no particular limitation on a semiconductor material that can be used for the semiconductor layer 113. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for the semiconductor layer 113, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

Silicon can be used for the semiconductor layer 113. As silicon, single crystal silicon, polycrystalline silicon, microcrystalline silicon, and amorphous silicon can be given. As polycrystalline silicon, low-temperature polysilicon (LTPS) can be given, for example.

A transistor using amorphous silicon in the semiconductor layer 113 can be formed over a large glass substrate, and can be manufactured at low cost. The transistor using polycrystalline silicon in the semiconductor layer 113 has high field-effect mobility and enables high-speed driving. The transistor using microcrystalline silicon in the semiconductor layer 113 has higher field-effect mobility and enables higher speed driving than the transistor using amorphous silicon.

The semiconductor layer 113 preferably includes a metal oxide (also referred to as an oxide semiconductor). Examples of the metal oxide that can be used for the semiconductor layer 113 include indium oxide, gallium oxide, and zinc oxide. The metal oxide preferably contains at least indium (In) or zinc (Zn). The metal oxide preferably contains two or three selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

For the semiconductor layer 113, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO), or the like can be used, for example. Alternatively, indium tin oxide containing silicon or the like can be used.

The element M is preferably one or more kinds selected from gallium, aluminum, yttrium, and tin. In particular, the element M is preferably gallium.

Here, the composition of the metal oxide included in the semiconductor layer 113 greatly affects the electrical characteristics and reliability of the transistor 33.

For example, a metal oxide with a higher indium content enables the transistor to have a higher on-state current.

In the case where an In—Zn oxide is used for the semiconductor layer 113, a metal oxide in which the atomic proportion of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof can be used.

In the case where an In—Sn oxide is used for the semiconductor layer 113, a metal oxide in which the atomic proportion of indium is higher than or equal to that of tin is preferably used. For example, a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof can be used.

In the case where an In—Sn—Zn oxide is used for the semiconductor layer 113, a metal oxide in which the atomic proportion of indium is higher than that of tin can be used. Furthermore, a metal oxide in which the atomic proportion of zinc is higher than that of tin is preferably used. For example, a metal oxide with metal elements in any of the following atomic ratios can be used: In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, and the neighborhood thereof.

In the case where an In—Al—Zn oxide is used for the semiconductor layer 113, a metal oxide in which the atomic proportion of indium is higher than that of aluminum can be used. Furthermore, a metal oxide in which the atomic proportion of zinc is higher than that of aluminum is preferably used. For example, a metal oxide with metal elements in any of the following atomic ratios can be used: In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, and the vicinity thereof.

In the case where an In—Ga—Zn oxide is used for the semiconductor layer 113, a metal oxide in which the atomic proportion of indium in the metal elements is higher than that of gallium can be used. Furthermore, a metal oxide in which the atomic proportion of zinc is higher than that of gallium is preferably used. For example, a metal oxide with metal elements in any of the following atomic ratios can be used for the semiconductor layer 113: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

In the case where an In-M-Zn oxide is used for the semiconductor layer 113, a metal oxide in which the atomic proportion of indium in the metal elements is higher than that of the element M can be used. Furthermore, a metal oxide in which the atomic proportion of zinc is higher than the that of the element M is preferably used. For example, a metal oxide with metal elements in any of the following atomic ratios can be used for the semiconductor layer 113: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the vicinity thereof.

In the case where a plurality of metal elements are contained as the element M, the sum of the atomic proportions of the metal elements can be the atomic proportion of the element M. In the case of In—Ga—Al—Zn oxide in which gallium and aluminum are contained as the element M, for example, the sum of the atomic proportion of gallium and the atomic proportion of aluminum can be the atomic proportion of the element M. The atomic ratio of indium, the element M, and zinc is preferably within the ranges given above.

It is preferable to use a metal oxide in which the proportion of the number of indium atoms to the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet still further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, in the case where an In—Ga—Zn oxide is used for the semiconductor layer 113, the proportion of the number of indium atoms to the total number of the atoms of indium, the element M, and zinc is preferably within the ranges given above.

In this specification and the like, the proportion of the number of indium atoms to the number of atoms of the metal elements contained is sometimes referred to as indium content percentage. The same applies to other metal elements.

A higher indium content percentage in the metal oxide enables the transistor to have a high on-state current. By using such a transistor as a transistor required to have a high on-state current, a display apparatus having excellent electrical characteristics can be provided.

As an analysis method of the composition of a metal oxide, for example, energy dispersive X-ray spectroscopy (EDX), X-ray photoelectron spectroscopy (XPS), inductively coupled plasma-mass spectrometry (ICP-MS), inductively coupled plasma-atomic emission spectroscopy (ICP-AES), or the like can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

Note that a composition in the neighborhood in this specification and the like includes the range of ±30% of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

For the formation of a metal oxide, a sputtering method or an atomic layer deposition (ALD) method can be suitably used. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has a low gallium content percentage in the semiconductor layer 113, the transistor can have high reliability against positive bias application. In other words, the amount of change in the threshold voltage of the transistor in the PBTS test can be small. Meanwhile, with use of a metal oxide that contains gallium, the gallium content percentage is preferably lower than the indium content percentage. Thus, a transistor with high reliability can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where an In—Ga—Zn oxide is used for the semiconductor layer 113, a metal oxide in which the atomic proportion of indium is higher than the atomic proportion of gallium can be used for the semiconductor layer 113. It is further preferable to use a metal oxide in which the atomic proportion of zinc is higher than the atomic proportion of gallium. In other words, a metal oxide in which the atomic ratios of metal elements satisfy In>Ga and Zn>Ga is preferably used for the semiconductor layer 113.

For example, a metal oxide with metal elements in any of the following atomic ratios can be used for the semiconductor layer 113: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

For the semiconductor layer 113, it is preferable to use a metal oxide in which the proportion of the number of indium atoms to the number of atoms of the metal elements contained is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet still further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content percentage in the semiconductor layer enables the transistor to be highly resistant to the PBTS test. Note that oxygen vacancy (V_{O}) is less likely to be generated in the metal oxide when the metal oxide contains gallium.

A metal oxide not containing gallium may be used for the semiconductor layer 113. For example, an In—Zn oxide can be used for the semiconductor layer 113. In this case, when the atomic proportion of indium to the metal elements contained in the metal oxide is increased, the field-effect mobility of the transistor can be increased. By contrast, when the atomic proportion of zinc to the metal elements contained in the metal oxide is increased, the metal oxide has high crystallinity; thus, a change in the electrical characteristics of the transistor can be suppressed and the reliability can be increased. Alternatively, a metal oxide that contains neither gallium nor zinc, such as indium oxide, can be used for the semiconductor layer 113. The use of a metal oxide not containing gallium can make a change in the threshold voltage particularly in the PBTS test extremely small.

For example, an oxide containing indium and zinc can be used for the semiconductor layer 113. At that time, for example, a metal oxide with metal elements in an atomic ratio of In:Zn=2:3, In:Zn=4:1, or the neighborhood thereof can be used.

Although the case of using gallium is described as a typical example, the same applies to the case where the element M is used instead of gallium. In particular, a metal oxide in which the atomic proportion of indium is higher than the atomic proportion of the element M is preferably used for the semiconductor layer 113. Furthermore, a metal oxide in which the atomic proportion of zinc is higher than the atomic proportion of the element M is preferably used.

With use of a metal oxide that has a low content percentage of the element M in the semiconductor layer 113, the transistor can have high reliability against positive bias application. With use of the transistor as a transistor that is required to have high reliability against positive bias application, a highly reliable display apparatus can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content percentage of the element M in the metal oxide enables the transistor to have high reliability against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer 113 is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in any of the following atomic ratios can be used for the semiconductor layer 113: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer 113, in particular, it is preferable to use a metal oxide in which the proportion of the number of atoms of the element M to the number of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic %.

In the case where an In—Ga—Zn oxide is used for the semiconductor layer 113, a metal oxide in which the proportion of the number of indium atoms to the number of atoms of the metal elements contained is lower than or equal to the proportion of the number of gallium atoms can be used. For example, a metal oxide with metal elements in any of the following atomic ratios can be used: In:Ga:Zn=1:1:1, In:Ga:Zn=1:1:1.2, In:Ga:Zn=1:3:2, In:Ga:Zn=1:3:3, In:Ga:Zn=1:3:4, and the neighborhood thereof.

For the semiconductor layer 113, in particular, it is preferable to use a metal oxide in which the proportion of the number of gallium atoms to the number of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, further preferably higher than or equal to 40 atomic % and lower than or equal to 60 atomic %, further preferably higher than or equal to 50 atomic % and lower than or equal to 60 atomic %.

With use of a metal oxide that has a low content percentage of the element M in the semiconductor layer 113, the transistor can have high reliability against light. With use of the transistor as a transistor that is required to have high reliability against light, a highly reliable display apparatus can be provided.

As described above, electrical characteristics and reliability of a transistor depend on the composition of the metal oxide used for the semiconductor layer 113. Thus, by determining the composition of the metal oxide in accordance with the electrical characteristics and reliability required for the transistor, the display apparatus can have both excellent electrical characteristics and high reliability.

The semiconductor layer 113 may have a stacked-layer structure including two or more metal oxide layers. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 113 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 113. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer 113, the density of defect states in the semiconductor layer 113 can be reduced, which enables the display apparatus to have high reliability.

The higher the crystallinity of the metal oxide layer 113 used as the semiconductor layer is, the lower the density of defect states in the semiconductor layer 113 can be. By contrast, the use of a metal oxide layer having low crystallinity enables a transistor to flow a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole formation gas (also referred to as oxygen flow rate ratio) used in formation is higher.

The semiconductor layer 113 may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer 113 may have different compositions.

The thickness of the semiconductor layer 113 is preferably greater than or equal to 3 nm and less than or equal to 100 nm, further preferably greater than or equal to 5 nm and less than or equal to 100 nm, further preferably greater than or equal to 10 nm and less than or equal to 100 nm, further preferably greater than or equal to 10 nm and less than or equal to 70 nm, further preferably greater than or equal to 15 nm and less than or equal to 70 nm, further preferably greater than or equal to 15 nm and less than or equal to 50 nm, further preferably greater than or equal to 20 nm and less than or equal to 50 nm, further preferably greater than or equal to 20 nm and less than or equal to 40 nm, further preferably greater than or equal to 25 nm and less than or equal to 40 nm.

The substrate temperature at the time of forming the semiconductor layer 113 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 113 will be described.

In the case where an oxide semiconductor is used for the semiconductor layer 113, hydrogen contained in the oxide semiconductor reacts with oxygen bonded to a metal atom to be water, and thus sometimes forms oxygen vacancy (V_{O}) in the oxide semiconductor. In some cases, a defect where hydrogen enters oxygen vacancy (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of the transistor. Note that a normally-on transistor refers to a transistor in which current (e.g., current between a drain and a source) flows at a gate voltage of 0 V.

V_{O}H can function as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration on the assumption that the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used as the semiconductor layer 113, the amount of V_{O}H in the semiconductor layer 113 is preferably reduced as much as possible so that the semiconductor layer 113 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill oxygen vacancy (V_{O}). When an oxide semiconductor with sufficiently reduced impurities such as V_{O}H is used for a channel formation region of a transistor, the transistor can have stable electrical characteristics. Supplying oxygen to the oxide semiconductor to fill oxygen vacancy (V_{O}) is sometimes referred to as oxygen adding treatment.

In the case where an oxide semiconductor is used for the semiconductor layer 113, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as off-state current), and charge accumulated in a capacitor that is connected in series with the transistor can be retained for a long period. Furthermore, power consumption of the display apparatus can be reduced with the use of an OS transistor.

To increase the emission luminance of the light-emitting element included in the pixel of the display apparatus, the amount of current fed through the light-emitting element needs to be increased. For that purpose, the source-drain voltage of a driving transistor included in the pixel needs to be increased. Since the OS transistor has higher breakdown voltage between a source and a drain than a transistor including silicon (hereinafter referred to as a Si transistor), high voltage can be applied between the source and the drain of the OS transistor. Accordingly, when an OS transistor is used as the driving transistor included in the pixel, the amount of current flowing through the light-emitting element can be increased, so that the emission luminance of the light-emitting element can be increased.

In the case where transistors are driven in a saturation region, a change in source-drain current relative to a change in gate-source voltage can be smaller in an OS transistor than in a Si transistor. Accordingly, when an OS transistor is used as the driving transistor in the pixel, current flowing between the source and the drain can be set minutely by a change in a gate-source voltage; hence, the amount of current flowing through the light-emitting element can be controlled. Accordingly, the number of gray levels in the pixel can be increased.

Regarding saturation characteristics of current flowing when transistors are driven in the saturation region, even when the source-drain voltage of an OS transistor increases gradually, a more stable current (saturation current) can be fed through the OS transistor than through a Si transistor. Thus, by using an OS transistor as the driving transistor, a stable current can be fed through light-emitting elements even when the current-voltage characteristics of the light-emitting elements vary, for example. In other words, when the OS transistor is driven in the saturation region, the source-drain current hardly changes with an increase in the source-drain voltage; hence, the emission luminance of the light-emitting element can be stable.

As described above, by using an OS transistor as the driving transistor included in the pixel, it is possible to inhibit black-level degradation, increase the luminance, increase the number of gray levels, and suppress variations in light-emitting elements, for example.

### [Insulating Layer 103]

For the insulating layer 103, an inorganic insulating material or an organic insulating material can be used. The insulating layer 103 may have a stacked-layer structure of an inorganic insulating material and an organic insulating material.

For the insulating layer 103, an inorganic insulating material can be suitably used. As the inorganic insulating material, one or more of an oxide, an oxynitride, a nitride oxide, and a nitride can be used. For the insulating layer 103, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The contents of oxygen and nitrogen can be analyzed using secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

The insulating layer 103 may have a stacked-layer structure of two or more layers. FIG. 2B, for example, illustrates a structure where the insulating layer 103 has a stacked-layer structure of an insulating layer 103a and an insulating layer 103b over the insulating layer 103a. For each of the insulating layer 103a and the insulating layer 103b, the above-described material that can be used for the insulating layer 103 can be used. Note that the insulating layer 103a and the insulating layer 103b may be formed using the same material or different materials. Note that the insulating layer 103a may have a stacked-layer structure of two or more layers. The insulating layer 103b may have a stacked-layer structure of two or more layers.

The thickness of the insulating layer 103a can be larger than that of the insulating layer 103b. The film-formation speed of the insulating layer 103a is preferably high. In particular, the film-formation speed of the insulating layer 103a is preferably high in the case where the thickness of the insulating layer 103a is large. By increasing the film-formation speed of the insulating layer 103a, the productivity can be increased. For example, by increasing power at the time of forming the insulating layer 103a, the film-formation speed can be increased.

The stress of the insulating layer 103a is preferably low. When the thickness of the insulating layer 103a is increased, the stress of the insulating layer 103a is increased, so that warpage of the substrate might be caused. By making the stress of the insulating layer 103a low, a problem in the process caused by stress such as warpage of the substrate can be inhibited from arising.

The insulating layer 103b functions as a blocking film that inhibits release of gas from the insulating layer 103a. For the insulating layer 103b, a material that does not easily allow diffusion of gas is preferably used. The insulating layer 103b preferably includes a region having a higher film density than the insulating layer 103a. The insulating layer 103b having a higher film density can have a higher blocking property. A material containing more nitrogen than the insulating layer 103a can be used for the insulating layer 103b. The insulating layer 103b having a higher content of nitrogen can have a higher blocking property.

The insulating layer 103b can be thinner than the insulating layer 103a as long as the insulating layer 103b has a thickness that is sufficient for the function of a blocking film that inhibits release of gas from the insulating layer 103a. The film-formation speed of the insulating layer 103b is preferably lower than that of the insulating layer 103a. Note that when the film formation speed of the insulating layer 103b is made low, the insulating layer 103b can have a higher film density and thus can have a higher blocking property. Similarly, when the substrate temperature at the time of forming the insulating layer 103b is increased, the insulating layer 103b can have a higher film density and thus can have a higher blocking property.

The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Therefore, the transmission electron (TE) image of the insulating layer 103b is a dark-colored (dark) image compared to the insulating layer 103a in some cases. Note that since the insulating layer 103a and the insulating layer 103b have different film densities even when including the same materials, it is sometimes possible to identify the boundary between the insulating layer 103a and the insulating layer 103b by a difference in contrast in a TEM image of a cross section.

The insulating layer 103b may include a region where the hydrogen concentration in the film is lower than that in the insulating layer 103a. The difference in hydrogen concentration between the insulating layer 103a and the insulating layer 103b can be evaluated by secondary ion mass spectrometry (SIMS), for example.

Here, the insulating layer 103 will be described in detail with use of a structure where a metal oxide is used for the semiconductor layer 113 as an example.

In the case where an oxide semiconductor is used for the semiconductor layer 113, an inorganic insulating material can be suitably used for each of the insulating layer 103a and the insulating layer 103b.

An oxide or an oxynitride is preferably used as the insulating layer 103a. A film from which oxygen is released by heating is preferably used as the insulating layer 103a. For the insulating layer 103a, a silicon oxide or a silicon oxynitride can be suitably used, for example.

Oxygen release from the insulating layer 103a enables oxygen supply from the insulating layer 103a to the semiconductor layer 113. The oxygen supply from the insulating layer 103a to the semiconductor layer 113, particularly to the channel formation region of the semiconductor layer 113, reduces oxygen vacancies (V_{O}) and V_{O}H in the semiconductor layer 113, so that the transistor can have favorable electrical characteristics and high reliability. The insulating layer 103a preferably has a high oxygen diffusion coefficient. A high oxygen diffusion coefficient of the insulating layer 103a facilitates diffusion of oxygen in the insulating layer 103a, so that oxygen can be efficiently supplied from the insulating layer 103a to the semiconductor layer 113. Examples of treatment for supplying oxygen to the semiconductor layer 113 include heat treatment in an oxygen-containing atmosphere and plasma treatment in an oxygen-containing atmosphere.

The amount of impurities (e.g., water and hydrogen) released from the insulating layer 103a itself is preferably small. With the insulating layer 103a from which a small amount of impurities is released, diffusion of impurities to the semiconductor layer 113 is inhibited, and the transistor can have favorable electrical characteristics and high reliability.

Silicon oxide or silicon oxynitride by a PECVD method can be suitably used for the insulating layer 103a, for example. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), dinitrogen monoxide (N₂O), nitric oxide (NO), or nitrogen dioxide (NO₂) can be used, for example. Note that by increasing power at the time of forming the insulating layer 103a, the amount of impurities (e.g., water and hydrogen) released from the insulating layer 103a can be reduced.

The insulating layer 103b is preferably less likely to transmit oxygen. The insulating layer 103b functions as a blocking film that inhibits release of oxygen from the insulating layer 103a. Moreover, the insulating layer 103b is preferably less likely to transmit hydrogen. The insulating layer 103b functions as a blocking film that inhibits diffusion of hydrogen into the semiconductor layer 113 from the outside of the transistor through the insulating layer 103. The insulating layer 103b preferably has a high film density. The insulating layer 103b having a higher film density can have a higher blocking property against oxygen and hydrogen. The film density of the insulating layer 103b is preferably higher than that of the insulating layer 103a. In the case where silicon oxide or silicon oxynitride is used for the insulating layer 103a, silicon nitride, silicon nitride oxide, or aluminum oxide can be suitably used for the insulating layer 103b, for example. The insulating layer 103b preferably includes a region containing more nitrogen than the insulating layer 103a, for example. A material containing more nitrogen than the insulating layer 103a can be used for the insulating layer 103b. A nitride or a nitride oxide is preferably used for the insulating layer 103b. For example, silicon nitride or silicon nitride oxide can be suitably used for the insulating layer 103b.

When oxygen contained in the insulating layer 103a is diffused upward from a region of the insulating layer 103a that is not in contact with the semiconductor layer 113 (e.g., the top surface of the insulating layer 103a), the amount of oxygen supplied from the insulating layer 103a to the semiconductor layer 113 might be reduced. Provision of the insulating layer 103b over the insulating layer 103a can inhibit diffusion of oxygen contained in the insulating layer 103a from the region of the insulating layer 103a that is not in contact with the semiconductor layer 113. Accordingly, the amount of oxygen supplied from the insulating layer 103a to the semiconductor layer 113 is increased, whereby oxygen vacancies (V_{O}) and V_{O}H in the semiconductor layer 113 can be reduced. Consequently, the transistor can have favorable electrical characteristics and high reliability.

The conductive layer 112a and the conductive layer 112b are oxidized by oxygen contained in the insulating layer 103a and have high resistance in some cases. When the conductive layer 112a and the conductive layer 112b are oxidized by oxygen contained in the insulating layer 103a, the amount of oxygen supplied from the insulating layer 103a to the semiconductor layer 113 might be reduced. Provision of the insulating layer 103b over the insulating layer 103a can inhibit the conductive layer 112a and the conductive layer 112b from being oxidized and having high resistance. In addition, the amount of oxygen supplied from the insulating layer 103a to the semiconductor layer 113 is increased and oxygen vacancies (V_{O}) and V_{O}H in the semiconductor layer 113 can be reduced, whereby the transistor can have favorable electrical characteristics and high reliability.

Hydrogen diffused in the semiconductor layer 113 reacts with an oxygen atom contained in an oxide semiconductor to be water, and thus sometimes forms oxygen vacancy (V_{O}). Furthermore, V_{O}H is formed and the carrier concentration is increased in some cases. Provision of the insulating layer 103b over the insulating layer 103a can reduce oxygen vacancies (V_{O}) and V_{O}H in the semiconductor layer 113, whereby the transistor can have favorable electrical characteristics and high reliability.

The insulating layer 103b preferably has a thickness that is sufficient for the function of a blocking film against oxygen and hydrogen. When the thickness of the insulating layer 103b is small, the function of a blocking film deteriorates in some cases. Meanwhile, when the thickness of the insulating layer 103b is large, a region of the semiconductor layer 113 in contact with the insulating layer 103a is narrowed and the amount of oxygen supplied from the insulating layer 103a to the semiconductor layer 113 is sometimes reduced. The thickness of the insulating layer 103b may be smaller than that of the insulating layer 103a. The thickness of the insulating layer 103b is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, yet still further preferably larger than or equal to 20 nm and smaller than or equal to 50 nm, yet still further preferably larger than or equal to 20 nm and smaller than or equal to 40 nm. Setting the thickness of the insulating layer 103b in the above range can reduce oxygen vacancies (V_{O}) and V_{O}H in the semiconductor layer 113, particularly in the channel formation region, whereby the transistor can have favorable electrical characteristics and high reliability.

The amount of impurities (e.g., water and hydrogen) released from the insulating layer 103b itself is preferably small. With the insulating layer 103b from which a small amount of impurities is released, diffusion of impurities into the semiconductor layer 113 is inhibited, and the transistor can have favorable electrical characteristics and high reliability.

In the transistor 33, a region of the semiconductor layer 113 in contact with the insulating layer 103 can function as the channel formation region. That is, oxygen is selectively supplied to the channel formation region, so that oxygen vacancies (V_{O}) and V_{O}H can be reduced. Consequently, the transistor can have favorable electrical characteristics and high reliability.

### [Conductive Layer 111, Conductive Layer 112a, Conductive Layer 112b, and Conductive Layer 115]

The conductive layer 111 functioning as a floating electrode, the conductive layer 112a and the conductive layer 112b functioning as the source electrode and the drain electrode, and the conductive layer 115 functioning as the gate electrode can each be formed using one or more of chromium, copper, aluminum, gold, silver, zinc, molybdenum, tantalum, titanium, tungsten, manganese, nickel, iron, cobalt, molybdenum, and niobium; or an alloy containing one or more of the above-described metals as its components. For the conductive layer 111, the conductive layer 112a, the conductive layer 112b, and the conductive layer 115, a conductive material with low resistance that contains one or more of copper, silver, gold, and aluminum can be suitably used. Copper or aluminum is particularly preferable because of its high mass-productivity.

For the conductive layer 111, the conductive layer 112a, the conductive layer 112b, and the conductive layer 115, a metal oxide film (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when oxygen vacancy is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

In addition, each of the conductive layer 111, the conductive layer 112a, the conductive layer 112b, and the conductive layer 115 may have a stacked-layer structure of a conductive film containing the above-described oxide conductor (metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for the conductive layer 111, the conductive layer 112a, the conductive layer 112b, and the conductive layer 115. The use of a Cu—X alloy film can reduce the manufacturing cost because wet etching process can be used in the processing.

Note that the conductive layer 111, the conductive layer 112a, the conductive layer 112b, and the conductive layer 115 may be formed using the same material or different materials.

Here, the conductive layer 111, the conductive layer 112a, and the conductive layer 112b will be described in detail using a structure where a metal oxide is used for the semiconductor layer 113 as an example.

In the case where an oxide semiconductor is used for the semiconductor layer 113, the conductive layer 111, the conductive layer 112a, and the conductive layer 112b are oxidized by oxygen contained in the semiconductor layer 113 and have high resistance in some cases. The conductive layer 111 is oxidized by oxygen contained in the insulating layer 103a and has high resistance in some cases. Moreover, when the conductive layer 111, the conductive layer 112a, and the conductive layer 112b are oxidized by oxygen contained in the semiconductor layer 113, oxygen vacancies (V_{O}) in the semiconductor layer 113 are increased in some cases. When the conductive layer 111 is oxidized by oxygen contained in the insulating layer 103a, the amount of oxygen supplied from the insulating layer 103a to the semiconductor layer 113 is reduced in some cases.

A material that is less likely to be oxidized is preferably used for each of the conductive layer 111, the conductive layer 112a, and the conductive layer 112b. An oxide conductor is preferably used for each of the conductive layer 111, the conductive layer 112a, and the conductive layer 112b. For example, In—Sn oxide (ITO) or In—Sn—Si oxide (ITSO) can be suitably used. For each of the conductive layer 111, the conductive layer 112a, and the conductive layer 112b, a nitride conductor may be used. Examples of the nitride conductor include tantalum nitride and titanium nitride. The conductive layer 111, the conductive layer 112a, and the conductive layer 112b may each have a stacked-layer structure of the above-described materials.

With the use of a material that is less likely to be oxidized for each of the conductive layer 111, the conductive layer 112a, and the conductive layer 112b, these conductive layers can be inhibited from being oxidized by oxygen contained in the semiconductor layer 113 or oxygen contained in the insulating layer 103a and having higher resistance. Furthermore, it is possible to increase the amount of oxygen supplied from the insulating layer 103a to the semiconductor layer 113 while an increase in oxygen vacancies (V_{O}) in the semiconductor layer 113 is suppressed. Accordingly, oxygen vacancies (V_{O}) and V_{O}H in the semiconductor layer 113 can be reduced, whereby the transistor can have favorable electrical characteristics and high reliability. Note that the conductive layer 111, the conductive layer 112a, and the conductive layer 112b may be formed using the same material or different materials.

### [Insulating Layer 105]

The insulating layer 105 functioning as the gate insulating layer preferably has low defect density. With the insulating layer 105 having low defect density, the transistor can have favorable electrical characteristics. In addition, the insulating layer 105 preferably has high withstand voltage. With the insulating layer 105 having high withstand voltage, the transistor can have high reliability.

For the insulating layer 105, one or more of an insulating oxide, an insulating oxynitride, an insulating nitride oxide, and an insulating nitride can be used, for example. For the insulating layer 105, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 105 may be either a single layer or a stacked layer. The insulating layer 105 may have a stacked-layer structure of an oxide and a nitride.

A miniaturized transistor including a thin gate insulating layer may have a large leakage current. When a high dielectric constant material (also referred to as a high-k material) is used for the gate insulating layer, the voltage at the time of driving of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 105 itself is preferably small. With the insulating layer 105 from which a small amount of impurities is released, diffusion of impurities into the semiconductor layer 113 is inhibited, and the transistor can have favorable electrical characteristics and high reliability.

The insulating layer 105 is formed over the semiconductor layer 113, and thus is preferably a film formed under conditions where damage to the semiconductor layer 113 is small. For example, the insulating layer 105 can be formed under conditions where the film formation speed (also referred to as film formation rate) is sufficiently low. For example, when the insulating layer 105 is formed by a plasma CVD method under a low-power condition, damage to the semiconductor layer 113 can be small.

Here, the insulating layer 105 will be described in detail using a structure where a metal oxide is used for the semiconductor layer 113 as an example.

To improve the properties of the interface with the semiconductor layer 113, at least the side of the insulating layer 105 that is in contact with the semiconductor layer 113 is preferably formed using an oxide. For example, one or more of silicon oxide and silicon oxynitride can be suitably used for the insulating layer 105. Moreover, a film from which oxygen is released by heating is preferably used as the insulating layer 105.

Note that the insulating layer 105 may have a stacked-layer structure. The insulating layer 105 can have a stacked-layer structure of the oxide film on a side in contact with the semiconductor layer 113 and a nitride film on the side in contact with the conductive layer 115. For example, one or more of silicon oxide and silicon oxynitride can be suitably used for the oxide film. Silicon nitride can be suitably used for the nitride film.

### [Substrate 101]

Although there is no particular limitation on a material of the substrate 101, for example, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 101. Alternatively, any of these substrates over which a semiconductor element is provided may be used as the substrate 101. A printed circuit board may be used as the substrate 101. Note that the shape of the semiconductor substrate and an insulating substrate may be a circular shape or a shape with corners.

A flexible substrate may be used as the substrate 101, and for example, the transistor 33 may be formed directly on the flexible substrate. Alternatively, a separation layer may be provided between the substrate 101 and the transistor 33 and the like. The separation layer can be used when part or the whole of the display apparatus completed thereover is separated from the substrate 101 and transferred onto another substrate. In that case, for example, the transistor 33 can be transferred onto a substrate having low heat resistance or a flexible substrate as well.

The above is the description of the components.

A structure example of a transistor whose structure is partly different from that in <Structure example 1 of display apparatus> will be described below. Note that description of the same portions as those in <Structure example 1 of display apparatus> is omitted below in some cases. Furthermore, in drawings that are referred to later, the same hatching pattern is applied to portions having functions similar to those in <Structure example 1 of display apparatus>, and the portions are not denoted by reference numerals in some cases.

### <Structure Example 2 of Display Apparatus>

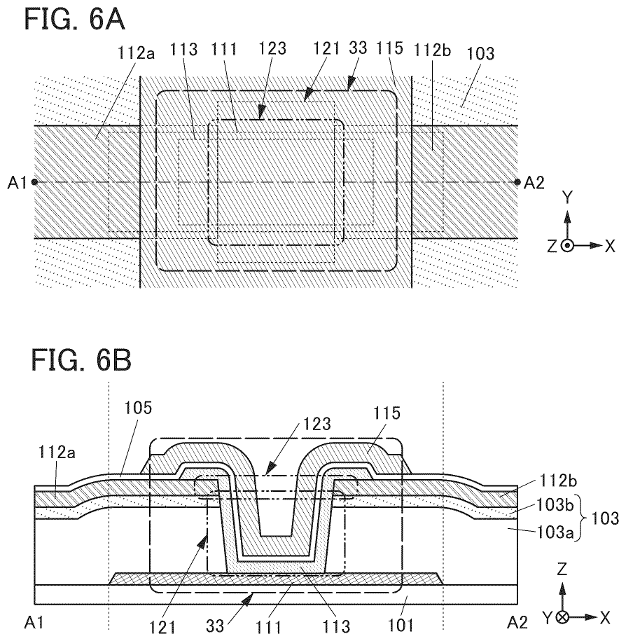

Although FIG. 2A1 and FIG. 2B illustrate an example where the end portion of the conductive layer 111 is positioned outward from the end portion of the semiconductor layer 113 and inward from the end portion of the conductive layer 115 in the X direction, one embodiment of the present invention is not limited thereto. FIG. 6A and FIG. 6B illustrate a variation example of the structure illustrated in FIG. 2A1 and FIG. 2B, in which the end portion of the conductive layer 111 is positioned outward from the end portion of the conductive layer 115 in the X direction. In FIG. 6B, a dotted straight line that extends in the Z direction to be in contact with the end portion of the conductive layer 111 indicates that the end portion of the conductive layer 111 is positioned outward from the end portion of the conductive layer 115.

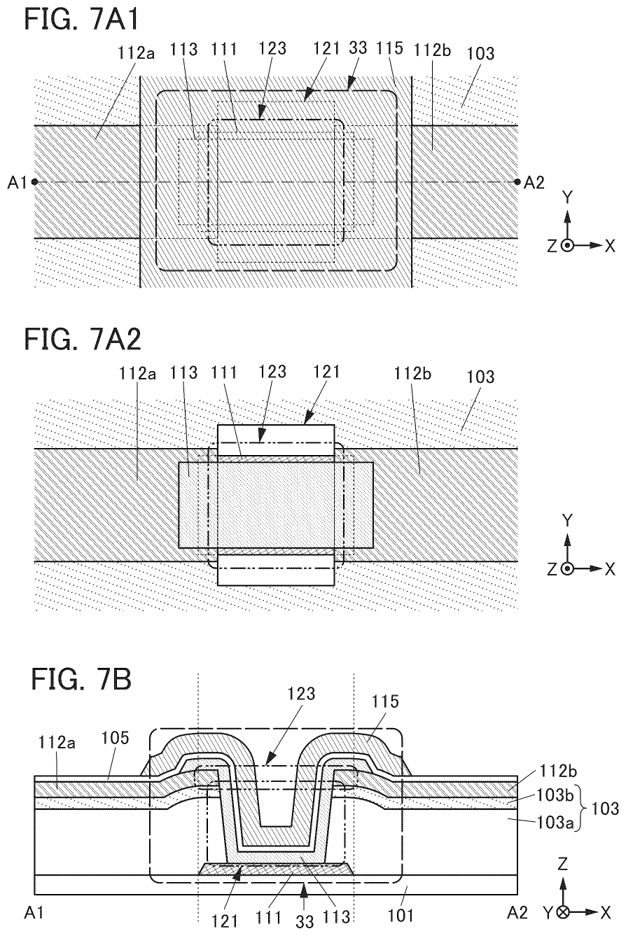

FIG. 7A1 illustrates a variation example of the structure illustrated in FIG. 2A1, and FIG. 7A2 is a plan view omitting the conductive layer 115 from the components illustrated in FIG. 7A1. FIG. 7B is a cross-sectional view taken along dashed-dotted line A1-A2 in FIG. 7A1. FIG. 7A1, FIG. 7A2, and FIG. 7B illustrate an example where in the X direction, the end portion of the conductive layer 111 is positioned inward from the end portion of the semiconductor layer 113 as well as the end portion of the conductive layer 115. In FIG. 7B, a dotted straight line that extends in the Z direction to be in contact with the end portion of the conductive layer 111 indicates that the end portion of the conductive layer 111 is positioned inward from the end portion of the semiconductor layer 113.

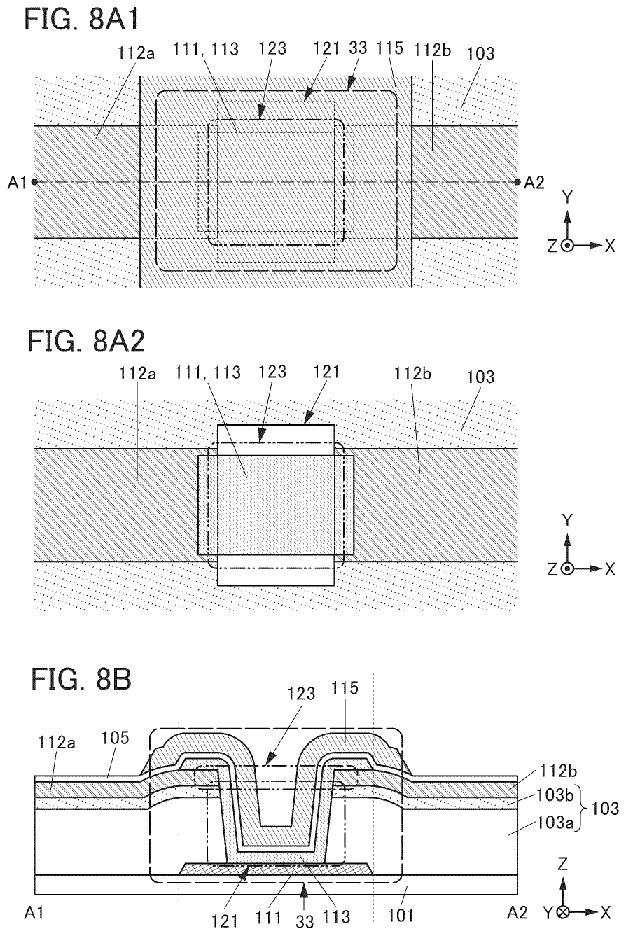

FIG. 8A1 illustrates a variation example of the structure illustrated in FIG. 2A1, and FIG. 8A2 is a plan view omitting the conductive layer 115 from the components illustrated in FIG. 8A1. FIG. 8B is a cross-sectional view taken along dashed-dotted line A1-A2 in FIG. 8A1. FIG. 8A1, FIG. 8A2, and FIG. 8B illustrate an example where the end portion of the conductive layer 111 and the end portion of the semiconductor layer 113 are aligned or substantially aligned with each other. In the example illustrated in FIG. 8B, a dotted straight line that extends in the Z direction to be in contact with the end portion of the bottom surface of the conductive layer 111 indicates that the end portion of the bottom surface of the conductive layer 111 and the end portion of the bottom surface of the semiconductor layer 113 are aligned or substantially aligned with each other. Note that the end portion of the top surface of the conductive layer 111 and the end portion of the top surface of the semiconductor layer 113 may be aligned or substantially aligned with each other. The end portion of the top surface of the conductive layer 111 and the end portion of the bottom surface of the semiconductor layer 113 may be aligned or substantially aligned with each other, or the end portion of the bottom surface of the conductive layer 111 and the end portion of the top surface of the semiconductor layer 113 may be aligned or substantially aligned with each other. Furthermore, for example, in a cross-sectional view, the midpoint of the end portion of the bottom surface and the end portion of the top surface of the conductive layer 111 may be aligned or substantially aligned with the midpoint of the end portion of the bottom surface and the end portion of the top surface of the semiconductor layer 113.

In the transistor 33 illustrated in FIG. 8A1 and FIG. 8B, for example, in the case where the conductive layer 111 and the semiconductor layer 113 are formed by a photolithography method, the conductive layer 111 and the semiconductor layer 113 can be formed using the same mask pattern. Accordingly, a photomask used for forming the conductive layer 111 and a photomask used for forming the semiconductor layer 113 can be the same photomask. Thus, the number of photomasks used for forming the display apparatus 10 can be small as compared with the case where the photomask used for forming the conductive layer 111 and the photomask used for forming the semiconductor layer 113 are different from each other. This can reduce the manufacturing cost of the display apparatus 10 and make the display apparatus 10 inexpensive. Meanwhile, in the case where the photomask used for forming the conductive layer 111 and the photomask used for forming the semiconductor layer 113 are different from each other, the planar shape of the conductive layer 111 and the planar shape of the semiconductor layer 113 can be different from each other. This makes it easy to give desired electrical characteristics to the transistor 33, for example.

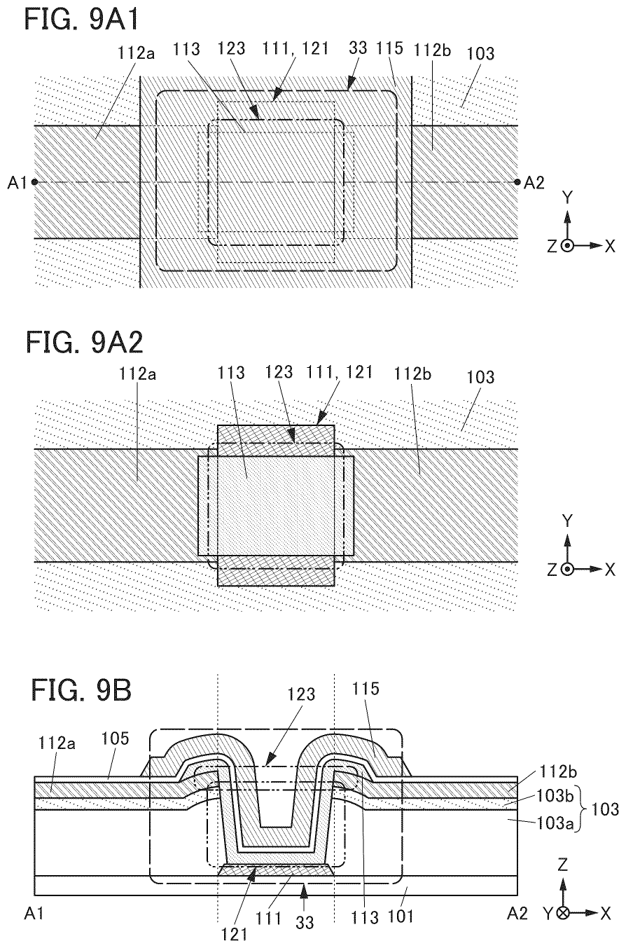

FIG. 9A1 illustrates a variation example of the structure illustrated in FIG. 2A1, and FIG. 9A2 is a plan view omitting the conductive layer 115 from the components illustrated in FIG. 9A1. FIG. 9B is a cross-sectional view taken along dashed-dotted line A1-A2 in FIG. 9A1. FIG. 9A1 and FIG. 9A2 illustrate an example where the end portion of the conductive layer 111 is aligned or substantially aligned with the end portions of the opening 121 and the opening 123. FIG. 9B illustrates an example where the end portion of the conductive layer 111 is aligned or substantially aligned with the end portion of the opening 123. In the example illustrated in FIG. 9B, a dotted straight line that extends in the Z direction to be in contact with the end portion of the bottom surface of the conductive layer 111 indicates that the end portion of the bottom surface of the conductive layer 111 and the end portion of the top surface of the opening 123 are aligned or substantially aligned with each other. Note that the end portion of the bottom surface of the conductive layer 111 and the end portion of the bottom surface of the opening 123 may be aligned or substantially aligned with each other. The end portion of the bottom surface of the conductive layer 111 and the end portion of the bottom surface of the opening 121 may be aligned or substantially aligned with each other. Furthermore, the end portion of the top surface of the conductive layer 111 may be aligned or substantially aligned with the end portion of the top surface of the opening 123, the end portion of the bottom surface of the opening 123, or the end portion of the bottom surface of the opening 121.

In the transistor 33 illustrated in FIG. 9A1 and FIG. 9B, for example, in the case where the conductive layer 111, the opening 121, and the opening 123 are formed by a photolithography method, the conductive layer 111, the opening 121, and the opening 123 can be formed using the same mask pattern. Thus, the number of photomasks used for forming the display apparatus 10 can be small as compared with the case where the photomask used for forming the conductive layer 111 and the photomask used for forming the opening 121 and the opening 123 are different from each other. This can reduce the manufacturing cost of the display apparatus 10 and make the display apparatus 10 inexpensive. Meanwhile, in the case where the photomask used for forming the conductive layer 111 and the photomask used for forming the opening 121 and the opening 123 are different from each other, the planar shape of the conductive layer 111 and the planar shape of the opening 121 can be different from each other. This makes it easy to give desired electrical characteristics to the transistor 33, for example.

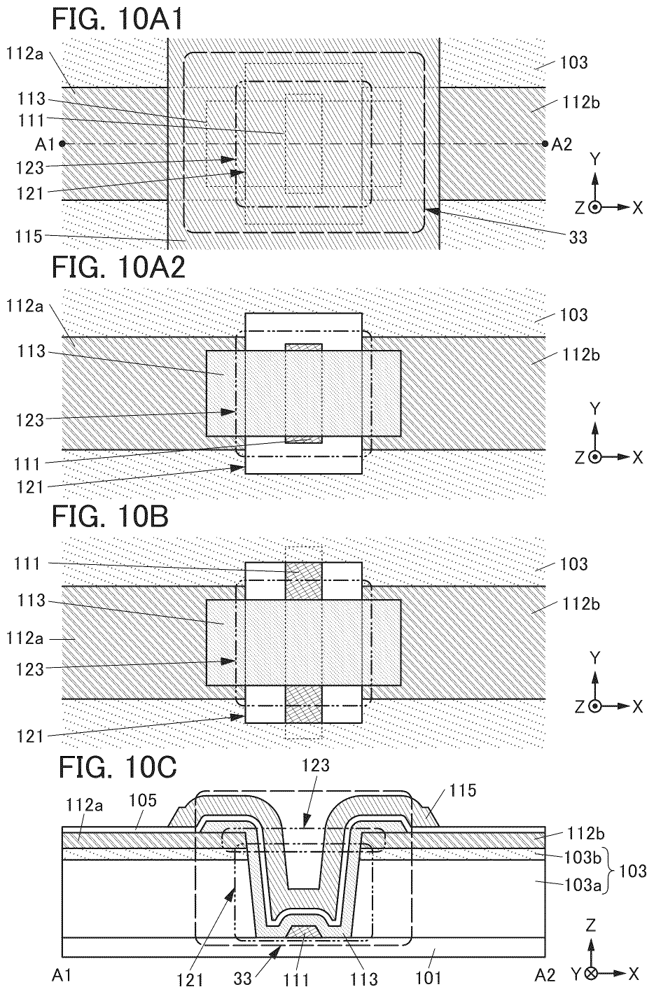

Although FIG. 2A1, FIG. 2A2, and FIG. 2B illustrate the example where the end portion of the conductive layer 111 is positioned outward from the end portion of the bottom surface of the opening 121 in the X direction, one embodiment of the present invention is not limited thereto. FIG. 10A1 illustrates a variation example of the structure illustrated in FIG. 2A1, and FIG. 10A2 is a plan view omitting the conductive layer 115 from the components illustrated in FIG. 10A1. FIG. 10B illustrates a variation example of the structure illustrated in FIG. 10A2, in which the end portion of the conductive layer 111 is positioned outward from the end portion of the opening 121 in the Y direction. FIG. 10C is a cross-sectional view taken along dashed-dotted line A1-A2 in FIG. 10A1. FIG. 10A1, FIG. 10A2, FIG. 10B, and FIG. 10C illustrate examples where the end portion of the conductive layer 111 is positioned inward from the end portion of the bottom surface of the opening 121 in the X direction. In this case, as illustrated in FIG. 10C, the semiconductor layer 113 can cover the end portion of the conductive layer 111 when seen from the XZ plane.

When the transistor included in the display apparatus of one embodiment of the present invention has the structure illustrated in FIG. 10A1 and FIG. 10C, the channel length of the transistor can be long as compared with the case where the transistor has the structure illustrated in FIG. 2A1, FIG. 2A2, FIG. 2B, and the like. Thus, occurrence of a punch-through phenomenon can be inhibited even when a high voltage is applied to the drain of the transistor, for example. Accordingly, the withstand voltage of the transistor can be increased and a high voltage can be applied to the transistor. In the case where the transistor is driven in a saturation region, an increase in drain current due to an increase in drain-source voltage of the transistor can be suppressed. The channel length of the transistor 33 can be controlled by controlling the length of the conductive layer 111 in the X direction. Thus, in the case where the display apparatus of one embodiment of the present invention includes a plurality of transistors each having a structure similar to that illustrated in FIG. 10A1 and FIG. 10C, the transistors can have different channel lengths by changing the length of the conductive layer 111 in the X direction for each transistor. For example, the channel length of a transistor that needs a high on-state current can be made short, and the channel length of a transistor that needs a high withstand voltage can be made long.

In this specification and the like, in the case where a transistor is driven in a saturation region, the transistor is regarded as having stable saturation characteristics when the amount of increase in drain current is small even when the drain-source voltage of the transistor increases.

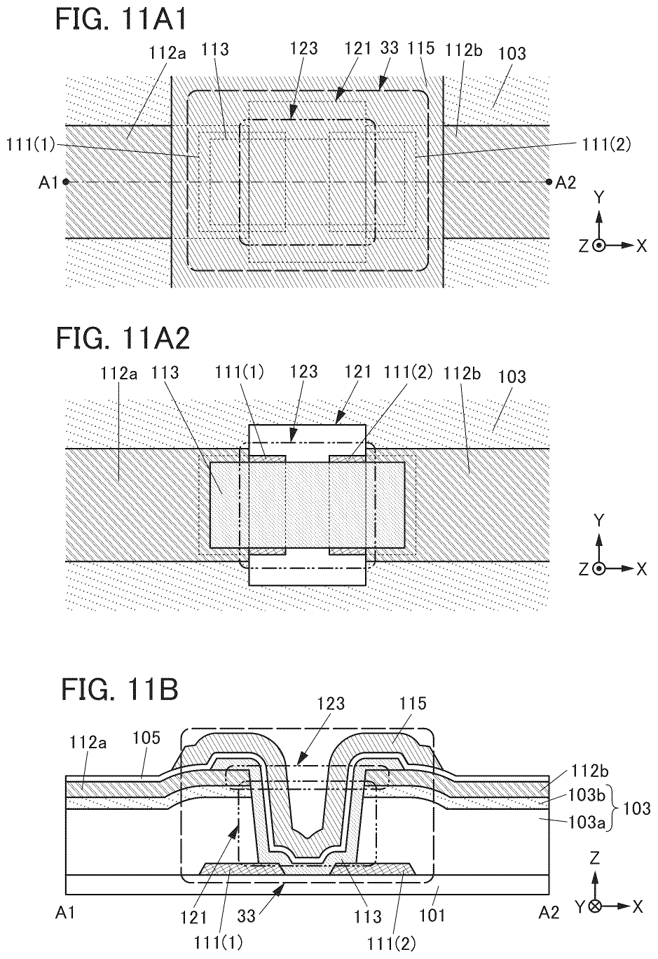

FIG. 11A1 illustrates a variation example of the structure illustrated in FIG. 2A1, and FIG. 11A2 is a plan view omitting the conductive layer 115 from the components illustrated in FIG. 11A1. FIG. 11B is a cross-sectional view taken along dashed-dotted line A1-A2 in FIG. 11A1. FIG. 11A1, FIG. 11A2, and FIG. 11B illustrate an example where the conductive layer 111 is divided into a conductive layer 111(1) and a conductive layer 111(2) in the opening 121. Specifically, in the example illustrated in FIG. 11A1, FIG. 11A2, and FIG. 11B, the conductive layer 111 has an opening in the opening 121, and the conductive layer 111 is divided into the conductive layer 111(1) and the conductive layer 111(2) by the opening. In the structure illustrated in FIG. 11A1, FIG. 11A2, and FIG. 11B, a region of the semiconductor layer 113 between the conductive layer 111(1) and the conductive layer 111(2) functions as the channel formation region of the transistor 33. Note that the conductive layer 111 may be divided into three or more layers.

The shape of the conductive layer 111 described above with reference to FIG. 11A1, FIG. 11A2, and FIG. 11B can be applied to all structures described in this specification and the like.

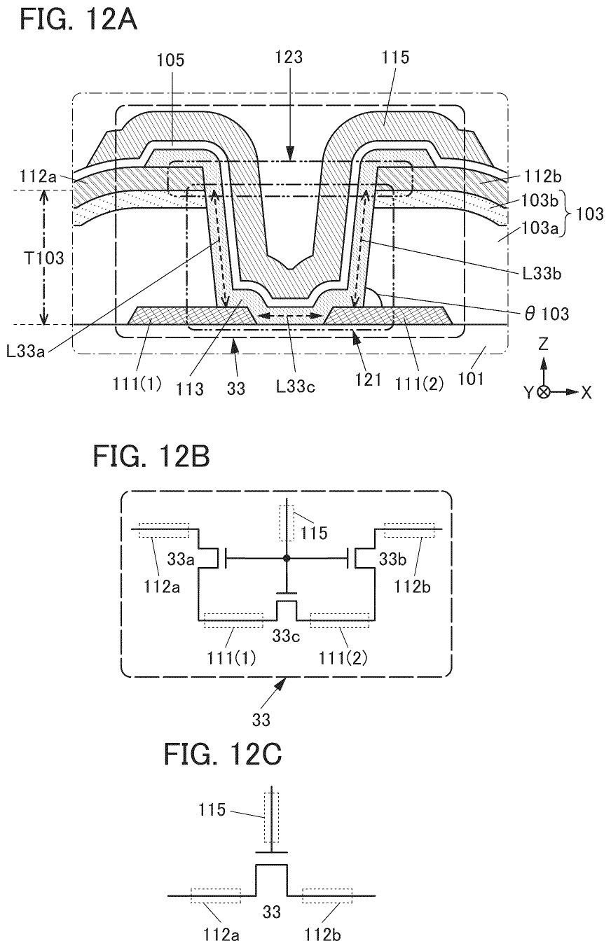

FIG. 12A is an enlarged view of the cross-sectional view in FIG. 11B illustrating the structure example of the transistor 33 and its vicinity, and illustrates a variation example of the structure illustrated in FIG. 3A. In FIG. 12A, the distance between the end portion of the bottom surface of the conductive layer 111(1) on the opening 121 side and the end portion of the bottom surface of the conductive layer 111(2) on the opening 121 side in the semiconductor layer 113 when seen from the XZ plane is referred to as a length L33c indicated by a dashed double-headed arrow. In the example illustrated in FIG. 12A, the sum of the length L33a, the length L33b, and the length L33c can be the channel length of the transistor 33. Thus, the transistor 33 illustrated in FIG. 12A can have a channel length longer than that of the transistor 33 illustrated in FIG. 3A by the length L33c.

Thus, when the transistor included in the display apparatus of one embodiment of the present invention has the structure illustrated in FIG. 11A1, FIG. 11A2, FIG. 11B, and FIG. 12A, the withstand voltage of the transistor can be increased and a high voltage can be applied to the transistor. When the transistor is driven in a saturation region, an increase in drain current due to an increase in drain-source voltage of the transistor can be suppressed. The channel length of the transistor can be controlled by controlling the length in the X direction between the conductive layers 111, which is the length L33c in the example illustrated in FIG. 12A. Thus, in the case where the display apparatus of one embodiment of the present invention includes a plurality of transistors each having a structure similar to that illustrated in FIG. 11A1, FIG. 11A2, FIG. 11B, and FIG. 12A, the transistors can have different channel lengths by changing the length L33c for each transistor. For example, the channel length of a transistor that needs a high on-state current can be made short, and the channel length of a transistor that needs a high withstand voltage can be made long.

FIG. 12B is a circuit diagram illustrating the transistor 33 illustrated in FIG. 11A1, FIG. 11B, and FIG. 12A. As illustrated in FIG. 12B, the transistor 33 can be regarded as having a structure where a transistor 33c is provided between the transistor 33a and a transistor 33b. In this case, the conductive layer 111(1) functions as one of the source electrode and the drain electrode of the transistor 33a and one of a source electrode and a drain electrode of the transistor 33c, and the conductive layer 111(2) functions as one of the source electrode and the drain electrode of the transistor 33b and one of the source electrode and the drain electrode of the transistor 33c. The conductive layer 115 functions as the gate electrode of the transistor 33a, the gate electrode of the transistor 33b, and a gate electrode of the transistor 33c.

Accordingly, the transistor 33 illustrated in FIG. 11A1, FIG. 11B, and FIG. 12A can be regarded as a transistor in which the transistor 33a, the transistor 33b, and the transistor 33c are connected in series through the conductive layer 111(1) and the conductive layer 111(2). The transistor 33 illustrated in FIG. 11A1, FIG. 11B, and FIG. 12A can also be regarded as one multi-gate transistor including three gate electrodes. Here, the length L33a illustrated in FIG. 12A can be the channel length of the transistor 33a, the length L33b can be the channel length of the transistor 33b, and the length L33c can be the channel length of the transistor 33c. In the case where the conductive layer 111 is divided into three or more layers, the transistor 33 can be regarded as a transistor in which four or more transistors are connected in series, or can be regarded as one multi-gate transistor including four or more gate electrodes.

As illustrated in FIG. 12C, the transistor 33 illustrated in FIG. 11A1, FIG. 11B, and FIG. 12A can also be regarded as one transistor in which one of the source electrode and the drain electrode is the conductive layer 112a, the other of the source electrode and the drain electrode is the conductive layer 112b, and the gate electrode is the conductive layer 115.

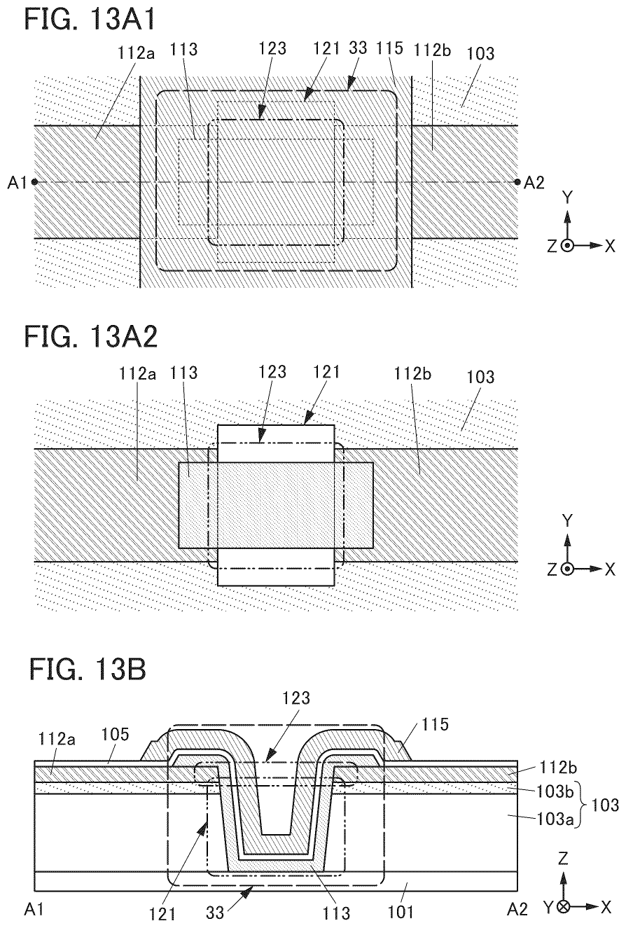

FIG. 13A1 illustrates a variation example of the structure illustrated in FIG. 2A1, and FIG. 13A2 is a plan view omitting the conductive layer 115 from the components illustrated in FIG. 13A1. FIG. 13B is a cross-sectional view taken along dashed-dotted line A1-A2 in FIG. 13A1. FIG. 13A1, FIG. 13A2, and FIG. 13B illustrate an example where the transistor 33 does not include the conductive layer 111 functioning as a floating electrode. When the conductive layer 111 is not formed, the manufacturing process of the transistor 33 can be simplified. Meanwhile, when the conductive layer 111 is formed, the channel length of the transistor 33 can be shortened.

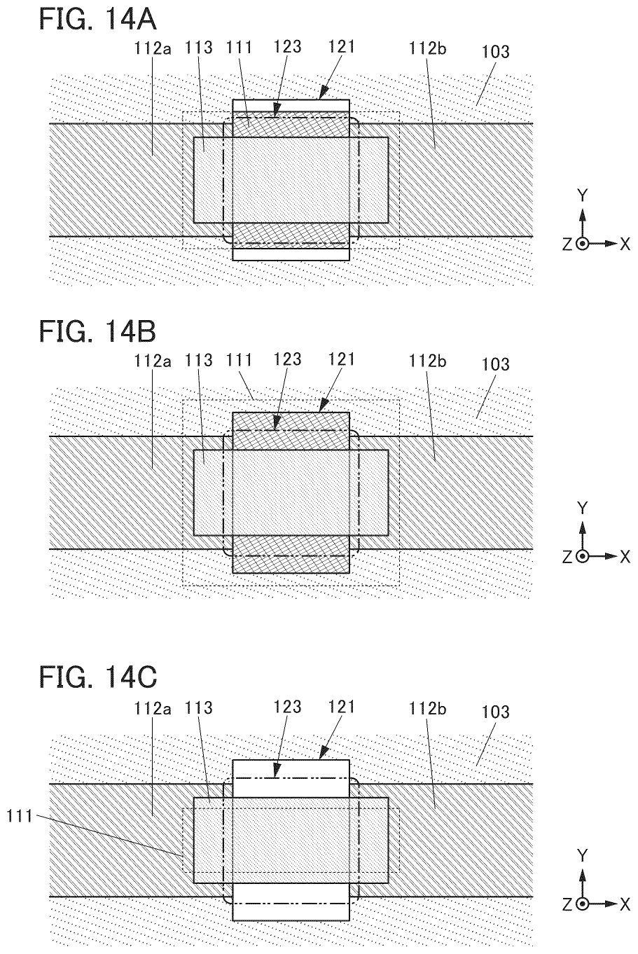

FIG. 14A, FIG. 14B, and FIG. 14C illustrate variation examples of the structure illustrated in FIG. 2A2. FIG. 14A illustrates an example where the end portion of the conductive layer 111 is positioned outward from the end portions of the conductive layer 112a and the conductive layer 112b and inward from the end portion of the opening 121 in the Y direction. FIG. 14B illustrates an example where the end portion of the conductive layer 111 is positioned outward from the end portion of the opening 121 in the Y direction. FIG. 14C illustrates an example where the end portion of the conductive layer 111 is positioned inward from the end portion of the semiconductor layer 113 in the Y direction.

When the length of the conductive layer 111 in the Y direction is increased, the wiring resistance of the conductive layer 111 can be reduced. Meanwhile, when the length of the conductive layer 111 in the Y direction is decreased, the transistor 33 can be miniaturized.

In the example illustrated in FIG. 14B, the whole opening 121 overlaps with the conductive layer 111 in a plan view. Thus, in the case where the opening 121 is formed by removing at least part of the insulating layer 103 by etching, for example, regarding the etching selectivity, only the selectivity of the insulating layer 103 and the conductive layer 111 needs to be considered, and there is no need to consider the selectivity of the insulating layer 103 and a layer other than the conductive layer 111 provided below the insulating layer 103. Thus, the transistor 33 can be easily manufactured.

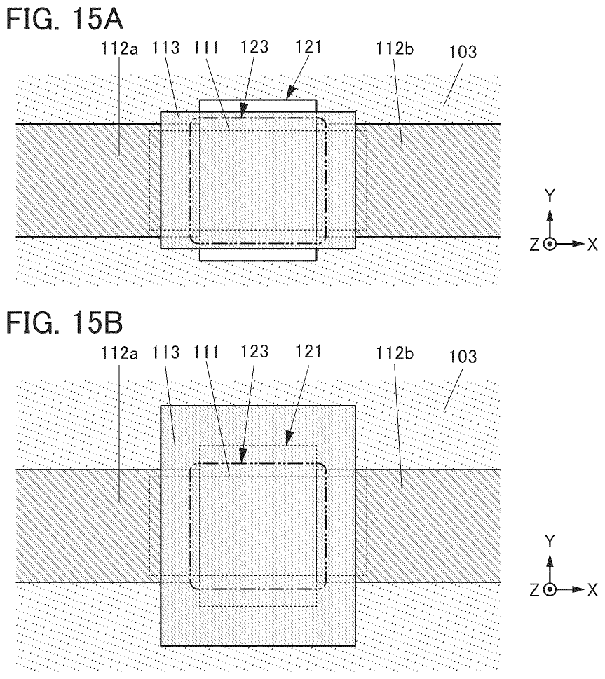

FIG. 15A and FIG. 15B illustrate variation examples of the structure in FIG. 2A2. FIG. 15A illustrates an example where the end portion of the semiconductor layer 113 is positioned outward from the end portions of the conductive layer 112a and the conductive layer 112b and inward from the end portion of the opening 121 in the Y direction. FIG. 15B illustrates an example where the end portion of the semiconductor layer 113 is positioned outward from the end portion of the opening 121 in the Y direction. In the example illustrated in FIG. 15A, the length of the semiconductor layer 113 in the Y direction can be longer than that in the example illustrated in FIG. 2A2. In the example illustrated in FIG. 15B, the length of the semiconductor layer 113 in the Y direction can be further longer than that in the example illustrated in FIG. 15A.

When the length of the semiconductor layer 113 in the Y direction is increased, the channel width of the transistor 33 can be increased. Meanwhile, when the length of the semiconductor layer 113 in the Y direction is decreased, the transistor 33 can be miniaturized. When the length of the semiconductor layer 113 in the Y direction is shorter than the length of the conductive layer 111 in the Y direction, the end portion of the conductive layer 111 can be prevented from being covered with the semiconductor layer 113 as illustrated in FIG. 4B, for example. Thus, generation of a step in the semiconductor layer 113 can be prevented, and for example, occurrence of a step disconnection in the semiconductor layer 113 can be prevented.

As illustrated in FIG. 15B, in the case where the semiconductor layer 113 overlaps with the whole opening 121 in a plan view, the distance between the end portion of the opening 121 and the end portion of the semiconductor layer 113 can be long. Thus, the transistor 33 can be easily manufactured.

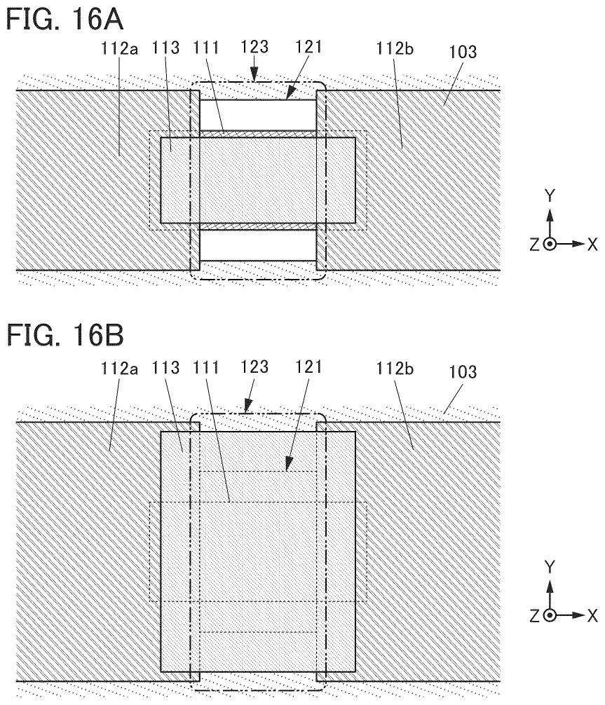

FIG. 16A illustrates a variation example of the structure illustrated in FIG. 2A2, in which the end portions of the conductive layer 112a and the conductive layer 112b are positioned outward from the end portion of the opening 121 in the Y direction. In the example illustrated in FIG. 16A, the wiring resistance of the conductive layer 112a and the conductive layer 112b can be reduced. Meanwhile, in the example illustrated in FIG. 2A2, the transistors 33 can be arranged at high density. The example illustrated in FIG. 16A can be manufactured by, for example, forming the opening 121 and the opening 123 that is provided between the conductive layer 112a and the conductive layer 112b using different mask patterns.

FIG. 16B illustrates a variation example of the structure illustrated in FIG. 16A, in which the semiconductor layer 113 overlaps with the whole opening 121 in a plan view. In the structure illustrated in FIG. 16B, the distance between the end portion of the opening 121 and the end portion of the semiconductor layer 113 can be increased while the channel width of the semiconductor layer 113 is increased from that in the structure illustrated in FIG. 16A. Thus, the transistor 33 can be manufactured easily while the channel width of the semiconductor layer 113 is increased. Meanwhile, in the structure illustrated in FIG. 16A, the transistor 33 can be miniaturized as compared with the structure illustrated in FIG. 16B.

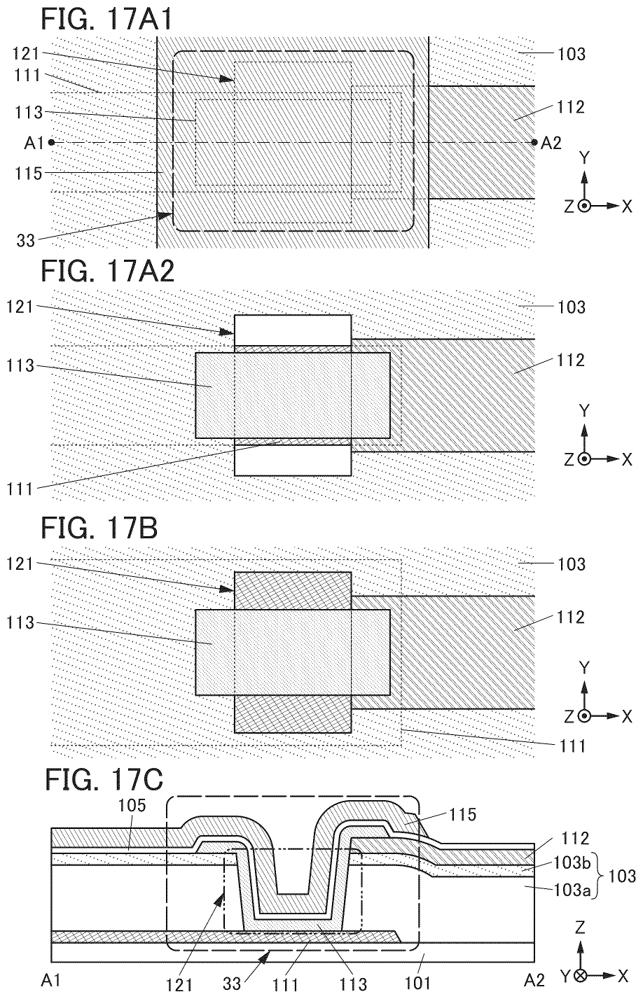

FIG. 17A1 illustrates a variation example of the structure illustrated in FIG. 2A1, and FIG. 17A2 is a plan view omitting the conductive layer 115 from the components illustrated in FIG. 17A1. FIG. 17B illustrates a variation example of the structure illustrated in FIG. 17A2, in which the end portion of the conductive layer 111 is positioned outward from the end portion of the opening 121 in the Y direction. FIG. 17C is a cross-sectional view taken along dashed-dotted line A1-A2 in FIG. 17A1. FIG. 17A1 and FIG. 17C illustrate an example where the transistor 33 does not include one of the conductive layer 112a and the conductive layer 112b and the conductive layer 111 extends in the X direction. In FIG. 17A1, FIG. 17A2, FIG. 17B, FIG. 17C, and the like, the other of the conductive layer 112a and the conductive layer 112b is the conductive layer 112. Specifically, FIG. 17A1 and FIG. 17C illustrate an example where the transistor 33 does not include the conductive layer 112a.

In the transistor 33 illustrated in FIG. 17A1 and FIG. 17C, the conductive layer 111 extends in a direction opposite to the conductive layer 112. For example, FIG. 17C illustrates an example where the conductive layer 112 extends in the X direction from the end portion of the conductive layer 112 and the conductive layer 111 extends in the −X direction from the end portion of the conductive layer 111.

In the transistor 33 illustrated in FIG. 17A1 and FIG. 17C, the conductive layer 111 can be one of the source electrode and the drain electrode, and the conductive layer 112 can be the other of the source electrode and the drain electrode.

Note that the end portion of the semiconductor layer 113 in a region not overlapping with the conductive layer 112 in the X direction may be provided in the opening 121. Specifically, the end portion of the semiconductor layer 113 opposite to the end portion overlapping with the conductive layer 112 in the X direction may be provided in the opening 121.

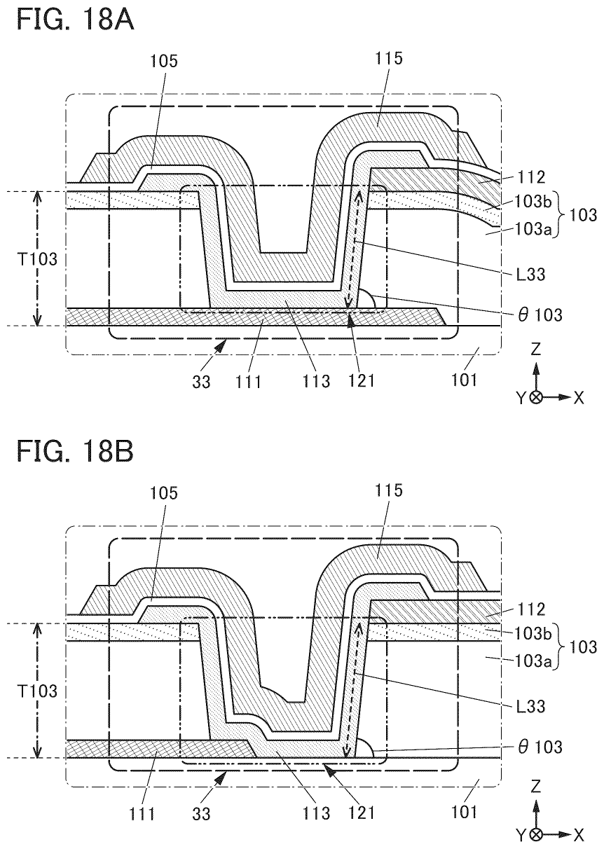

FIG. 18A is an enlarged view of the cross-sectional view in FIG. 17C illustrating the structure example of the transistor 33 and its vicinity, and illustrates a variation example of the structure illustrated in FIG. 3A. The length L33 illustrated in FIG. 18A is the distance between the end portion of the region where the semiconductor layer 113 and the conductive layer 111 are in contact with each other and the end portion of the region where the semiconductor layer 113 and the conductive layer 112 are in contact with each other when seen from the XZ plane. Thus, the length L33 corresponds to the length L33b illustrated in FIG. 3A.

In the example illustrated in FIG. 18A, the length L33 can be the channel length of the transistor 33. Here, as described above, the length L33 corresponds to the length L33b illustrated in FIG. 3A, and in the example illustrated in FIG. 3A, the sum of the length L33a and the length L33b can be the channel length of the transistor 33. Thus, when the transistor 33 has the structure illustrated in FIG. 17A1, FIG. 17C, and FIG. 18A, the channel length of the transistor 33 can be short as compared with the case where the transistor 33 has the structure illustrated in FIG. 2A1, FIG. 2B, FIG. 3A, and the like. Meanwhile, when the transistor 33 has the structure illustrated in FIG. 2A1, FIG. 2B, FIG. 3A, and the like, the shape of the source region and the shape of the drain region can be the same or substantially the same.

FIG. 18B illustrates a variation example of the structure illustrated in FIG. 18A, in which the semiconductor layer 113 covers at least part of the end portion of the conductive layer 111. In the example illustrated in FIG. 18B, the semiconductor layer 113 includes a region not overlapping with the conductive layer 111 in the opening 121. The transistor 33 illustrated in FIG. 18B can have a longer channel length than the transistor 33 illustrated in FIG. 18A by the region.

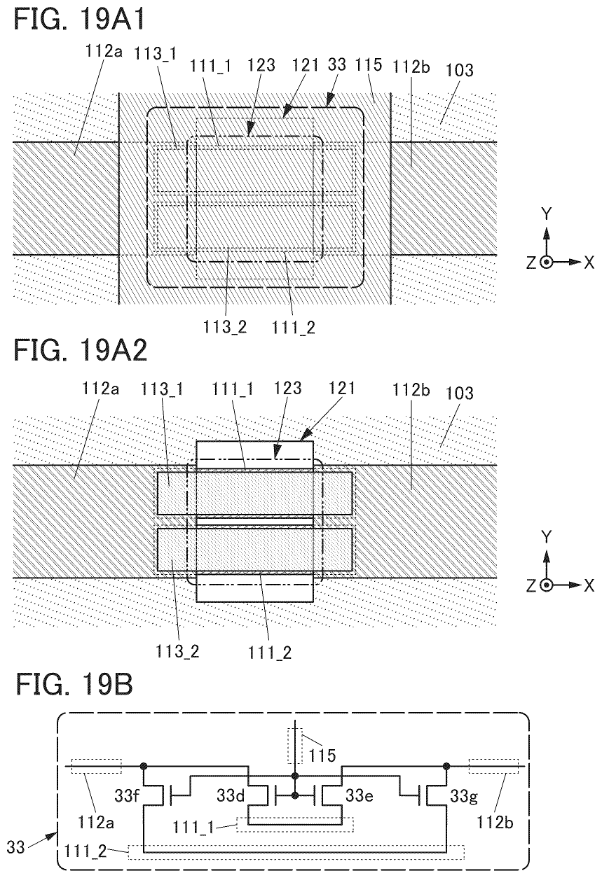

FIG. 19A1 illustrates a variation example of the structure illustrated in FIG. 2A1, and FIG. 19A2 is a plan view omitting the conductive layer 115 from the components illustrated in FIG. 19A1. FIG. 19A1 and FIG. 19A2 illustrate an example where the transistor 33 includes two conductive layers 111 and two semiconductor layers 113. FIG. 19A1 and FIG. 19A2 illustrate an example where the two conductive layers 111 are arranged in the Y direction and the two semiconductor layers 113 are arranged in the Y direction.

In FIG. 19A1 and FIG. 19A2, the two conductive layers 111 are denoted by a conductive layer 111_1 and a conductive layer 111_2 to be distinguished from each other, and the two semiconductor layers 113 are denoted by a semiconductor layer 113_1 and a semiconductor layer 113_2 to be distinguished from each other. The same applies to the other drawings. FIG. 19A1 and FIG. 19A2 illustrate an example where the conductive layer 111_1 and the semiconductor layer 113_1, and the conductive layer 111_2 and the semiconductor layer 113_2 are arranged in the Y direction.

FIG. 19B is a circuit diagram illustrating the transistor 33 illustrated in FIG. 19A1. As illustrated in FIG. 19B, the transistor 33 illustrated in FIG. 19A1 can be regarded as being composed of a transistor 33d, a transistor 33e, a transistor 33f, and a transistor 33g. In this case, the conductive layer 111_1 functions as one of a source electrode and a drain electrode of the transistor 33d and one of a source electrode and a drain electrode of the transistor 33e. The conductive layer 111_2 functions as one of a source electrode and a drain electrode of the transistor 33f and one of a source electrode and a drain electrode of the transistor 33g. The conductive layer 112a functions as the other of the source electrode and the drain electrode of the transistor 33d and the other of the source electrode and the drain electrode of the transistor 33f, and the conductive layer 112b functions as the other of the source electrode and the drain electrode of the transistor 33e and the other of the source electrode and the drain electrode of the transistor 33g. The conductive layer 115 functions as a gate electrode of the transistor 33d, a gate electrode of the transistor 33e, a gate electrode of the transistor 33f, and a gate electrode of the transistor 33g.

Accordingly, the transistor 33 illustrated in FIG. 19A1 and FIG. 19B can be regarded as a transistor where the transistor 33d and the transistor 33e are connected in series through the conductive layer 111_1 and the transistor 33f and the transistor 33g are connected in series through the conductive layer 111_2. The transistor 33 illustrated in FIG. 19A1 and FIG. 19B can be regarded as a transistor in which the transistor 33d and the transistor 33e are connected in parallel and the transistor 33f and the transistor 33g are connected in parallel. Here, the semiconductor layer 113_1 includes a channel formation region of the transistor 33d and a channel formation region of the transistor 33e. The semiconductor layer 113_2 includes a channel formation region of the transistor 33f and a channel formation region of the transistor 33g. Note that the transistor 33 illustrated in FIG. 19A1 and FIG. 19B can also be regarded as one multi-gate transistor including four gate electrodes.

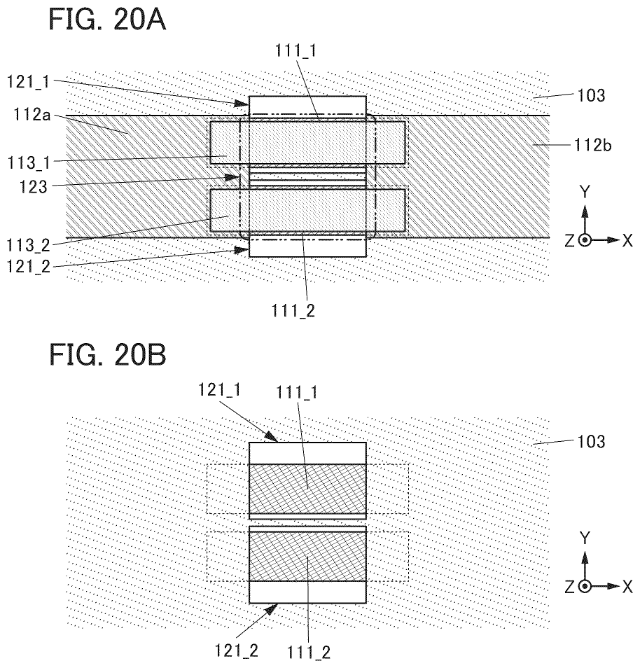

FIG. 20A illustrates a variation example of the structure illustrated in FIG. 19A2, and FIG. 20B is a plan view omitting the semiconductor layer 113_1, the semiconductor layer 113_2, the conductive layer 112a, and the conductive layer 112b from the components illustrated in FIG. 20A. FIG. 20A and FIG. 20B illustrate an example where the opening 121 provided with the conductive layer 111_1 and the semiconductor layer 113_1 is different from the opening 121 provided with the conductive layer 111_2 and the semiconductor layer 113_2.

In FIG. 20A and FIG. 20B, the opening 121 provided with the conductive layer 111_1 and the semiconductor layer 113_1 is referred to as an opening 121_1, and the opening 121 provided with the conductive layer 111_2 and the semiconductor layer 113_2 is referred to as an opening 121_2 so that the two openings 121 are distinguished from each other. The same applies to the other drawings.

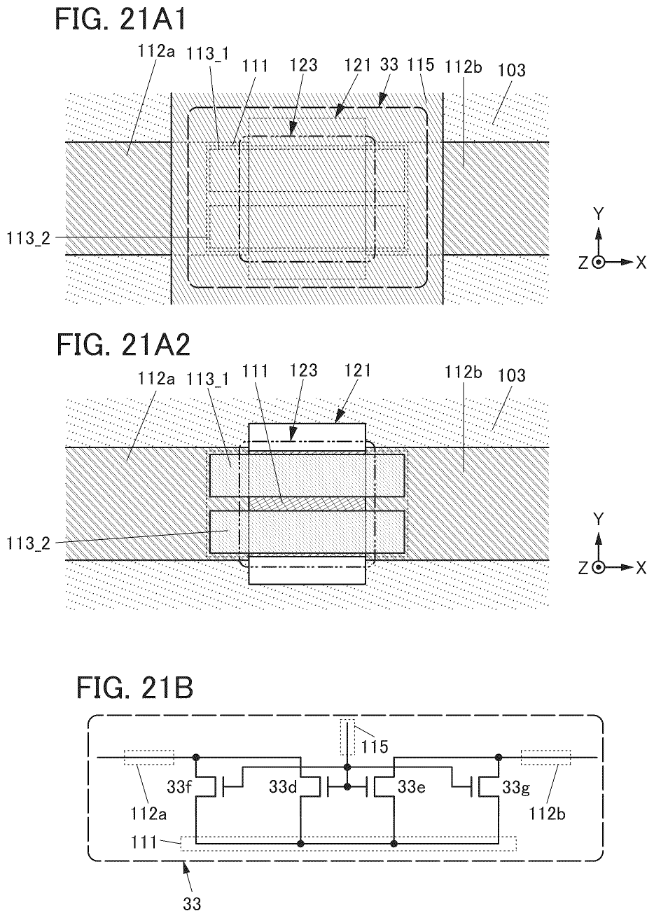

FIG. 21A1 and FIG. 21A2 illustrate a variation example of the structure illustrated in FIG. 19A1 and FIG. 19A2, in which the transistor 33 includes one conductive layer 111. In the example illustrated in FIG. 21A1 and FIG. 21A2, the semiconductor layer 113_1 and the semiconductor layer 113_2 share the one conductive layer 111.

FIG. 21B is a circuit diagram illustrating the transistor 33 illustrated in FIG. 21A1. The structure illustrated in FIG. 21B is different from the structure illustrated in FIG. 19B in that the conductive layer 111 functions as one of the source and the drain of the transistor 33d, one of the source and the drain of the transistor 33e, one of the source and the drain of the transistor 33f, and one of the source and the drain of the transistor 33g.

The transistor 33 illustrated in FIG. 21A1 and FIG. 21B can be regarded as a transistor in which the transistor 33d and the transistor 33f are connected in parallel and the transistor 33e and the transistor 33g are connected in parallel. The transistor 33 illustrated in FIG. 21A1 and FIG. 21B can be regarded as a transistor in which the transistor 33d and the transistor 33f are connected in series with the transistor 33e and the transistor 33g. Note that the transistor 33 illustrated in FIG. 21A1 and FIG. 21B can also be regarded as one multi-gate transistor including four gate electrodes.

The transistor 33 illustrated in FIG. 21A1 and FIG. 21B can also be regarded as one transistor in which one of the source electrode and the drain electrode is the conductive layer 112a, the other of the source electrode and the drain electrode is the conductive layer 112b, and the gate electrode is the conductive layer 115.

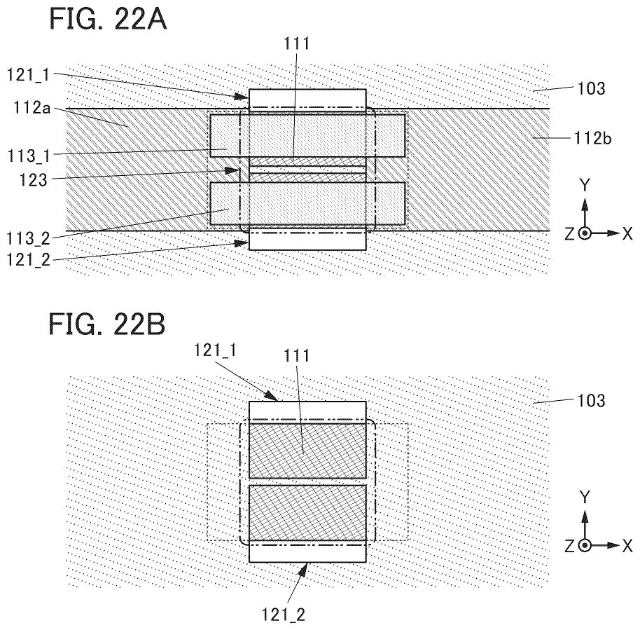

FIG. 22A and FIG. 22B illustrate a variation example of the structure illustrated in FIG. 20A and FIG. 20B, in which the transistor 33 includes one conductive layer 111. In the example illustrated in FIG. 22A and FIG. 22B, the semiconductor layer 113_1 and the semiconductor layer 113_2 share the one conductive layer 111.

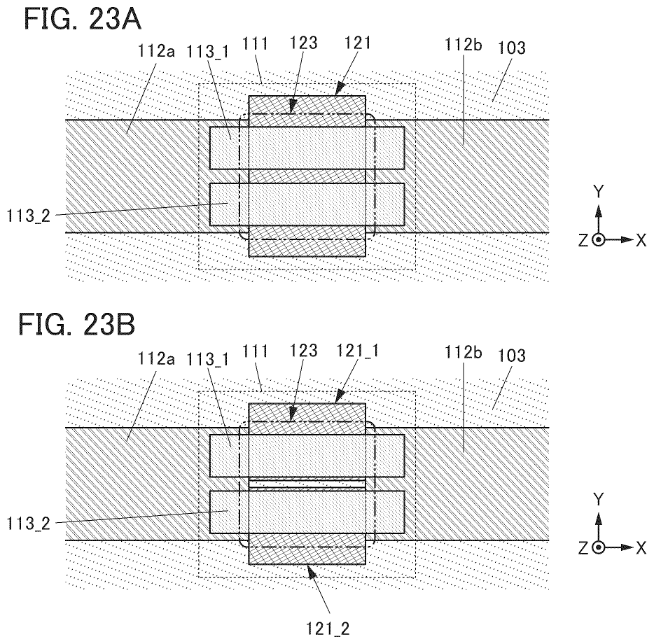

FIG. 23A and FIG. 23B illustrate a variation example of the structure illustrated in FIG. 21A2 and FIG. 22A, in which the end portion of the conductive layer 111 is positioned outward from the end portion of the opening 121 in the Y direction. When the length of the conductive layer 111 in the Y direction is increased, the wiring resistance of the conductive layer 111 can be reduced. Meanwhile, when the length of the conductive layer 111 in the Y direction is decreased, the transistor 33 can be miniaturized.

In the example illustrated in FIG. 23A and FIG. 23B, the whole opening 121 overlaps with the conductive layer 111 in a plan view. Thus, in the case where the opening 121 is formed by removing at least part of the insulating layer 103 by etching, for example, regarding the etching selectivity, only the selectivity of the insulating layer 103 and the conductive layer 111 needs to be considered, and there is no need to consider the selectivity of the insulating layer 103 and a layer other than the conductive layer 111 provided below the insulating layer 103. Thus, the transistor 33 can be easily manufactured.

In the case where the transistor 33 includes two semiconductor layers 113, the area of one semiconductor layer 113 can be small as compared with the case where the transistor 33 includes only one semiconductor layer 113. Accordingly, oxygen is easily supplied to the semiconductor layer 113 in the manufacturing process of the transistor 33 in some cases. Accordingly, oxygen vacancies (V_{O}) and V_{O}H in the semiconductor layer 113 can be reduced in some cases. Thus, the transistor 33 can be inhibited from having normally-on characteristics and the reliability of the transistor 33 can be increased in some cases. Meanwhile, in the case where the transistor 33 includes only one semiconductor layer 113, the channel width of the transistor 33 can be increased while the transistor 33 is miniaturized as compared with the case where the transistor 33 includes two semiconductor layers 113 and the two semiconductor layers 113 are arranged in the Y direction.

Note that the transistor 33 may include three or more semiconductor layers 113. When the number of semiconductor layers 113 included in the transistor 33 is increased, the area of one semiconductor layer 113 can be further reduced. Accordingly, oxygen is further suitably supplied to the semiconductor layer 113 in the manufacturing process of the transistor 33 in some cases, and oxygen vacancies (V_{O}) and V_{O}H in the semiconductor layer 113 can be further suitably reduced in some cases. Accordingly, the transistor 33 can be further suitably inhibited from having normally-on characteristics, and the reliability of the transistor 33 can be further suitably increased in some cases. Here, in the case where the transistor 33 includes three or more semiconductor layers 113, three or more conductive layers 111 can be provided. Alternatively, only one conductive layer 111 can be provided and the conductive layer 111 can be shared by the three or more semiconductor layers 113.

In the case where the transistor included in the display apparatus of one embodiment of the present invention includes two or more semiconductor layers 113 and the two or more semiconductor layers 113 are arranged in the Y direction, the transistors can have different channel widths by changing the number of the semiconductor layers 113 for each transistor. Specifically, the larger the number of semiconductor layers 113 is, the larger the channel width of the transistor can be. Accordingly, even in the case where the transistors have different channel widths, the semiconductor layers 113 can have the same or substantially the same widths. Thus, the transistor can be easily manufactured as compared with the case where the width of the semiconductor layer 113 is changed for each transistor.

In the case where the transistor 33 includes two or more semiconductor layers 113, even when impurities enter one of the semiconductor layers 113 to change the electrical characteristics of the semiconductor layer 113, for example, separation of the conductive layer 111 for each semiconductor layer 113 can suitably inhibit influence of the change in electrical characteristics on the electrical characteristics of the other semiconductor layers 113. Meanwhile, when one conductive layer 111 is shared by the plurality of semiconductor layers 113, the wiring resistance of the conductive layer 111 can be reduced and thus the on-state current of the transistor 33 can be increased.

Note that in the case where the transistor 33 includes two or more semiconductor layers 113, the semiconductor layers 113 preferably have substantially the same area. This can reduce variation in electrical characteristics between the plurality of transistors 33, for example.

In the case where the transistor included in the display apparatus of one embodiment of the present invention includes two or more semiconductor layers 113, all the semiconductor layers 113 may be provided in one opening 121 or different openings 121 may be provided for the semiconductor layers 113, for example. When a plurality of semiconductor layers 113 are provided in the same opening 121, for example, when all the semiconductor layers 113 included in one transistor are provided in one opening 121, the transistor can be miniaturized. Meanwhile, in the case where the plurality of semiconductor layers 113 provided in one transistor are provided in different openings 121 and the two or more semiconductor layers 113 and the openings 121 are arranged in the Y direction, the transistors can have different channel widths by changing the number of the openings 121 for each transistor. Specifically, the larger the number of the openings 121 is, the larger the channel width of the transistor can be. Accordingly, even in the case where the transistors have different channel widths, the openings 121 can have the same or substantially the same widths. Thus, the transistor can be easily manufactured as compared with the case where the width of the opening 121 is changed for each transistor.

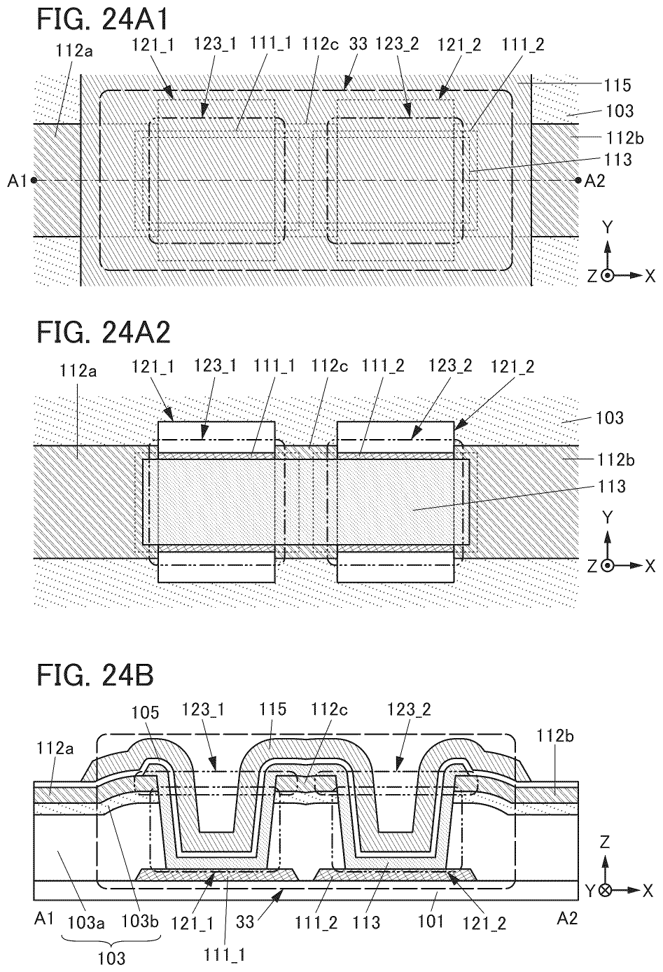

FIG. 24A1 illustrates a variation example of the structure illustrated in FIG. 2A1, and FIG. 24A2 is a plan view omitting the conductive layer 115 from the components illustrated in FIG. 24A1. FIG. 24B is a cross-sectional view taken along dashed-dotted line A1-A2 in FIG. 24A1. FIG. 24A1, FIG. 24A2, and FIG. 24B illustrate an example where two conductive layers 111, two openings 121, and two openings 123 are provided in the transistor 33. FIG. 24A1, FIG. 24A2, and FIG. 24B illustrate an example where the two conductive layers 111 are arranged in the X direction, the two openings 121 are arranged in the X direction, and the two openings 123 are arranged in the X direction.

In FIG. 24A1, FIG. 24A2, and FIG. 24B, the two openings 123 are denoted by an opening 123_1 and an opening 123_2 to be distinguished from each other. The same applies to the other drawings. The opening 123_1 includes a region overlapping with the conductive layer 111_1 and the opening 121_1, and the opening 123_2 includes a region overlapping with the conductive layer 111_2 and the opening 121_2. Here, the transistor 33 illustrated in FIG. 24A1, FIG. 24A2, and FIG. 24B includes a conductive layer 112c in addition to the conductive layer 112a and the conductive layer 112b, and the conductive layer 112c is provided between the conductive layer 112a and the conductive layer 112b. The conductive layer 112a and the conductive layer 112c are separated by the opening 123_1, and the conductive layer 112c and the conductive layer 112b are separated by the opening 123_2.

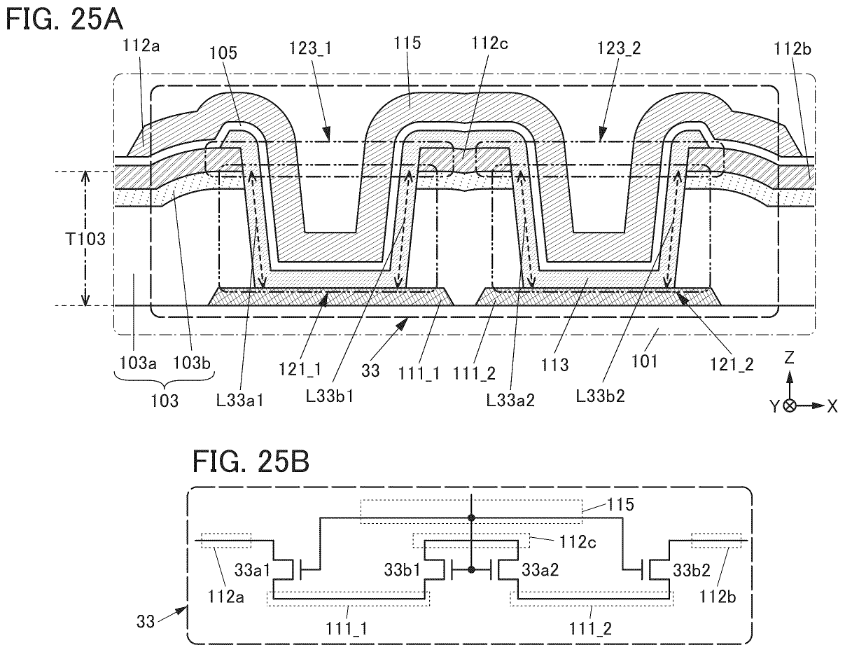

FIG. 25A is an enlarged view of the cross-sectional view in FIG. 24B illustrating the structure example of the transistor 33 and its vicinity, and illustrates a variation example of the structure illustrated in FIG. 3A. In FIG. 25A, the distance between an end portion of a region where the semiconductor layer 113 and the conductive layer 111_1 are in contact with each other and an end portion of a region where the semiconductor layer 113 and the conductive layer 112a are in contact with each other when seen from the XZ plane is referred to as a length L33al. The distance between an end portion of the region where the semiconductor layer 113 and the conductive layer 111_1 are in contact with each other and an end portion of a region where the semiconductor layer 113 and the conductive layer 112c are in contact with each other when seen from the XZ plane is referred to as a length L33b1. The distance between an end portion of a region where the semiconductor layer 113 and the conductive layer 111_2 are in contact with each other and an end portion of the region where the semiconductor layer 113 and the conductive layer 112c are in contact with each other when seen from the XZ plane is referred to as a length L33a2. The distance between an end portion of the region where the semiconductor layer 113 and the conductive layer 111_2 are in contact with each other and an end portion of a region where the semiconductor layer 113 and the conductive layer 112b are in contact with each other when seen from the XZ plane is referred to as a length L33b2. The length L33al, the length L33b1, the length L33a2, and the length L33b2 are each indicated by a dashed double-headed arrow.

The channel length of the transistor 33 illustrated in FIG. 25A can be the sum of the length L33al, the length L33b1, the length L33a2, and the length L33b2. That is, the sum of the four lengths L33 can be the channel length of the transistor 33 illustrated in FIG. 25A. Here, for example, in the transistor 33 illustrated in FIG. 3A, the sum of the two lengths L33 (the length L33a and the length L33b) can be the channel length of the transistor 33. Thus, the transistor 33 illustrated in FIG. 25A can have a longer channel length than the transistor 33 illustrated in FIG. 3A.

As described above, when the transistor included in the display apparatus of one embodiment of the present invention has the structure illustrated in FIG. 24A1, FIG. 24A2, FIG. 24B, and FIG. 25A, the withstand voltage of the transistor can be increased and a high voltage can be applied to the transistor. In the case where the transistor is driven in a saturation region, an increase in drain current due to an increase in drain-source voltage of the transistor can be suppressed.

FIG. 25B is a circuit diagram illustrating the transistor 33 illustrated in FIG. 24A1, FIG. 24B, and FIG. 25A. As illustrated in FIG. 25B, the transistor 33 can be regarded as having a structure where a transistor 33al, a transistor 33b1, a transistor 33a2, and a transistor 33b2 are connected in series. In this case, the conductive layer 111_1 functions as one of a source electrode and a drain electrode of the transistor 33al and one of a source electrode and a drain electrode of the transistor 33b1. The conductive layer 111_2 functions as one of a source electrode and a drain electrode of the transistor 33a2 and one of a source electrode and a drain electrode of the transistor 33b2. The conductive layer 112c functions as the other of the source electrode and the drain electrode of the transistor 33b1 and the other of the source electrode and the drain electrode of the transistor 33a2. The conductive layer 112a functions as the other of the source electrode and the drain electrode of the transistor 33al and the other of the source electrode and the drain electrode of the transistor 33b2. The conductive layer 115 functions as a gate electrode of the transistor 33al, a gate electrode of the transistor 33b1, a gate electrode of the transistor 33a2, and a gate electrode of the transistor 33b2.

The transistor 33 illustrated in FIG. 24A1, FIG. 24B, FIG. 25A, and FIG. 25B can also be regarded as one multi-gate transistor including four gate electrodes. Here, the length L33al illustrated in FIG. 25A can be the channel length of the transistor 33al, the length L33b1 can be the channel length of the transistor 33b1, the length L33a2 can be the channel length of the transistor 33a2, and the length L33b2 can be the channel length of the transistor 33b2.

The transistor 33 illustrated in FIG. 24A1, FIG. 24B, FIG. 25A, and FIG. 25B can also be regarded as a transistor in which one of the source electrode and the drain electrode is the conductive layer 112a, the other of the source electrode and the drain electrode is the conductive layer 112b, and the gate electrode is the conductive layer 115.

Note that the transistor 33 may have a structure where three or more conductive layers 111, three or more openings 121, and three or more openings 123 are provided and arranged in the X direction. Thus, the channel length of the transistor 33 can be further increased as compared with the case where two conductive layers 111, two openings 121, and two openings 123 are provided in the transistor 33 and arranged in the X direction.

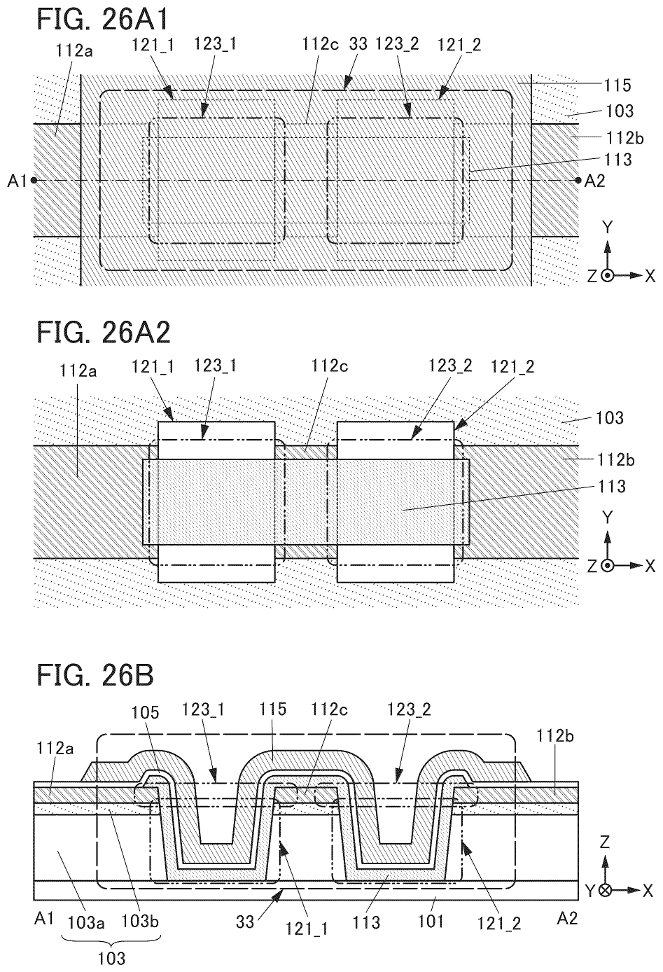

FIG. 26A1, FIG. 26A2, and FIG. 26B illustrate a variation example of the structure illustrated in FIG. 24A1, FIG. 24A2, and FIG. 24B, in which the transistor 33 does not include the conductive layer 111 functioning as a floating electrode. FIG. 26A1, FIG. 26A2, and FIG. 26B illustrate an example where the structure illustrated in FIG. 13A1, FIG. 13A2, and FIG. 13B and the structure illustrated in FIG. 24A1, FIG. 24A2, and FIG. 24B are combined.

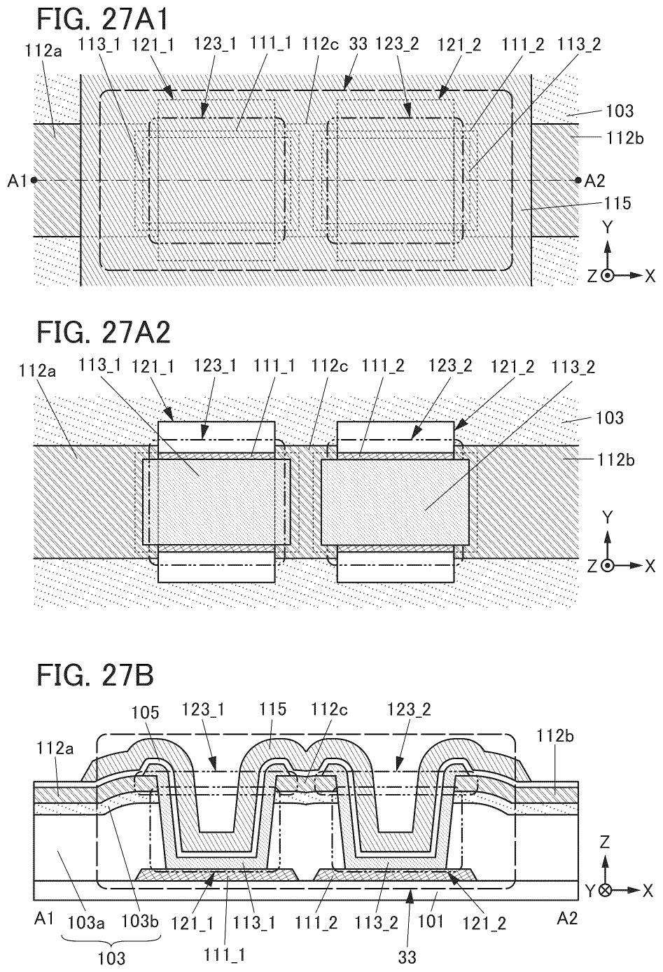

FIG. 27A1 illustrates a variation example of the structure illustrated in FIG. 24A1, and FIG. 27A2 is a plan view omitting the conductive layer 115 from the components illustrated in FIG. 27A1. FIG. 27B is a cross-sectional view taken along dashed-dotted line A1-A2 in FIG. 27A1. FIG. 27A1, FIG. 27A2, and FIG. 27B illustrate an example where the transistor 33 includes two semiconductor layers 113.

In FIG. 27A1, FIG. 27A2, and FIG. 27B, the semiconductor layer 113 including a region positioned in the opening 121_1 and the opening 123_1 is referred to as the semiconductor layer 113_1, and the semiconductor layer 113 including a region positioned in the opening 121_2 and the opening 123_2 is referred to as the semiconductor layer 113_2. The semiconductor layer 113_1 and the semiconductor layer 113_2 can be separated from each other over the conductive layer 112c, for example.

As described above, in the case where the transistor 33 includes two semiconductor layers 113, the area of one semiconductor layer 113 can be small as compared with the case where the transistor 33 includes only one semiconductor layer 113. Accordingly, oxygen is easily supplied to the semiconductor layer 113 in the manufacturing process of the transistor 33 in some cases. Accordingly, oxygen vacancies (V_{O}) and V_{O}H in the semiconductor layer 113 can be reduced in some cases. Thus, the transistor 33 can be inhibited from having normally-on characteristics and the reliability of the transistor 33 can be increased in some cases. Meanwhile, in the case where the transistor 33 includes only one semiconductor layer 113, the transistor 33 can be miniaturized as compared with the case where the transistor 33 includes two semiconductor layers 113.

Note that the transistor 33 may have a structure where three or more conductive layers 111, three or more semiconductor layers 113, three or more openings 121, and three or more openings 123 are provided and arranged in the X direction. Thus, the channel length of the transistor 33 can be further increased as compared with the case where two conductive layers 111, two semiconductor layers 113, two openings 121, and two openings 123 are provided in the transistor 33 and arranged in the X direction.

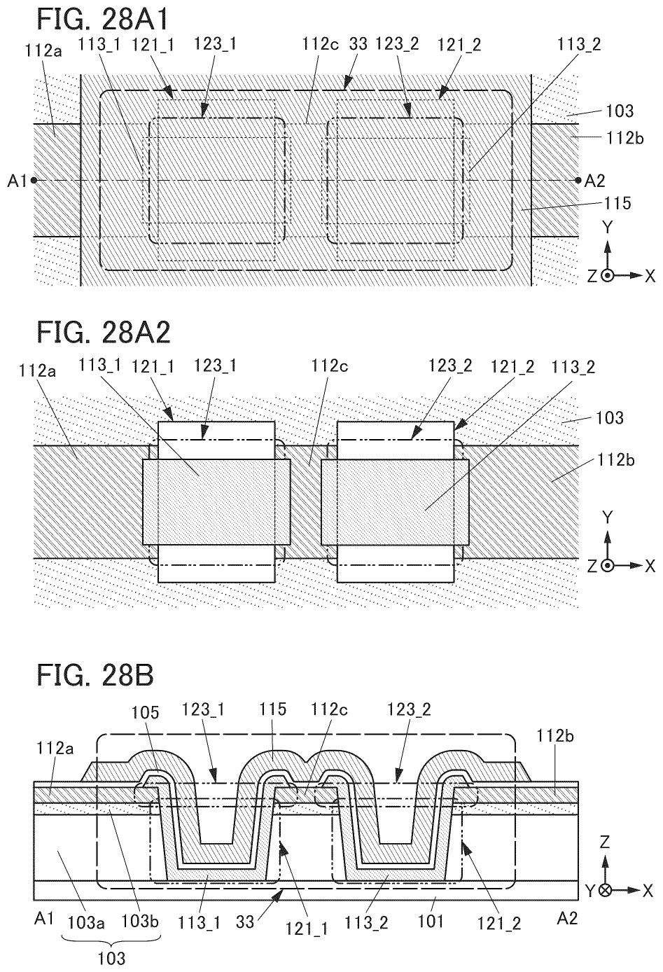

FIG. 28A1, FIG. 28A2, and FIG. 28B illustrate a variation example of the structure illustrated in FIG. 27A1, FIG. 27A2, and FIG. 27B, in which the transistor 33 does not include the conductive layer 111 functioning as a floating electrode. FIG. 28A1, FIG. 28A2, and FIG. 28B illustrate an example where the structure illustrated in FIG. 13A1, FIG. 13A2, and FIG. 13B and the structure illustrated in FIG. 27A1, FIG. 27A2, and FIG. 27B are combined.

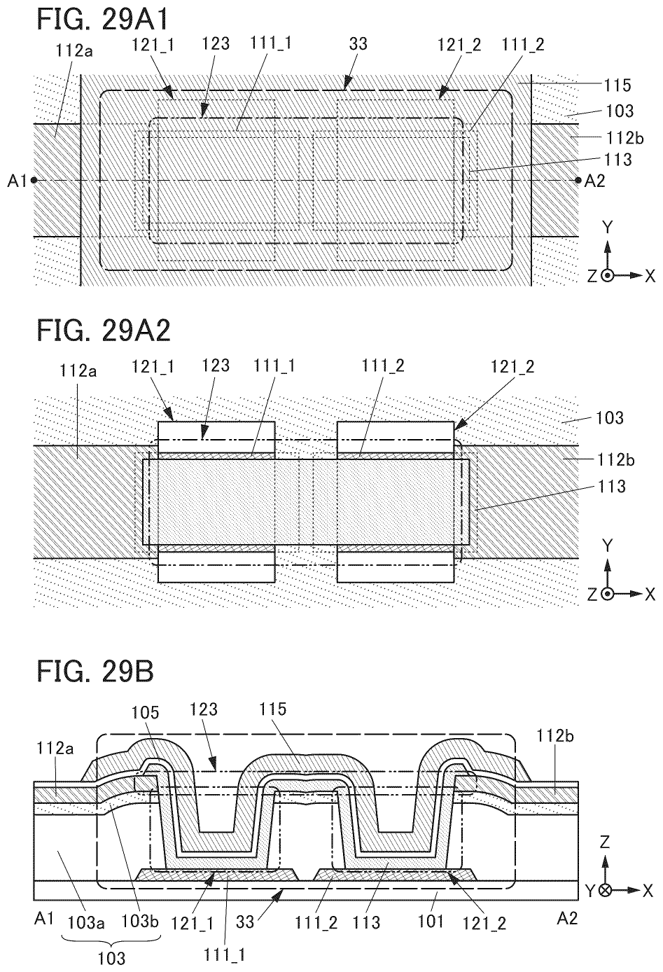

FIG. 29A1 illustrates a variation example of the structure illustrated in FIG. 24A1, and FIG. 29A2 is a plan view omitting the conductive layer 115 from the components illustrated in FIG. 29A1. FIG. 29B is a cross-sectional view taken along dashed-dotted line A1-A2 in FIG. 29A1. FIG. 29A1, FIG. 29A2, and FIG. 29B illustrate an example where the transistor 33 does not include the conductive layer 112c. In FIG. 29A1, FIG. 29A2, and FIG. 29B, one opening 123 is provided between the conductive layer 112a and the conductive layer 112b. As illustrated in FIG. 29A1, FIG. 29A2, and FIG. 29B, the semiconductor layer 113 can include a region in contact with the top surface of the insulating layer 103, specifically, for example, the top surface of the insulating layer 103b, in a region between the opening 121_1 and the opening 121_2 in a plan view.

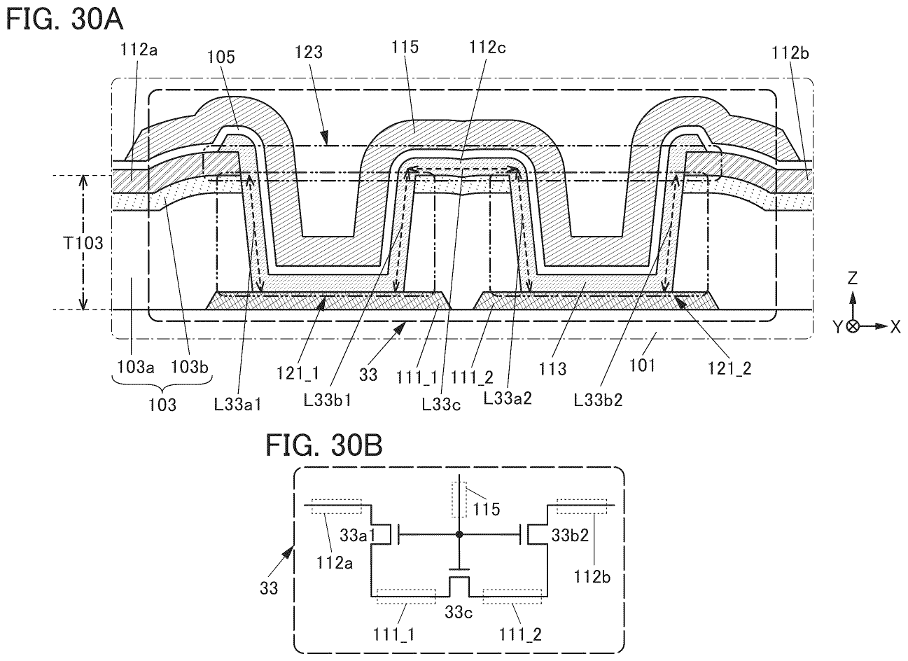

FIG. 30A is an enlarged view of the cross-sectional view in FIG. 29B illustrating the structure example of the transistor 33 and its vicinity, and illustrates a variation example of the structure illustrated in FIG. 25A. In FIG. 30A, the distance between the end portion of the top surface of the opening 121_1 and the end portion of the top surface of the opening 121_2 in the semiconductor layer 113 when seen from the XZ plane is referred to as the length L33c indicated by a dashed double-headed arrow.

In the example illustrated in FIG. 30A, the sum of the length L33al, the length L33b1, the length L33a2, the length L33b2, and the length L33c can be the channel length of the transistor 33. Thus, the transistor 33 illustrated in FIG. 30A can have a channel length longer than that of the transistor 33 illustrated in FIG. 25A by the length L33c.

Here, the channel length of the transistor can be controlled by controlling the length L33c. Thus, in the case where the display apparatus of one embodiment of the present invention includes a plurality of transistors each having a structure similar to that illustrated in FIG. 29A1, FIG. 29A2, FIG. 29B, and FIG. 30A, the transistors can have different channel lengths by changing the length L33c for each transistor. For example, the channel length of a transistor that needs a high on-state current can be made short, and the channel length of a transistor that needs a high withstand voltage can be made long.

FIG. 30B is a circuit diagram illustrating the transistor 33 illustrated in FIG. 29A1, FIG. 29B, and FIG. 30A. FIG. 30B illustrates a variation example of the structure illustrated in FIG. 25B, and can be regarded as a structure where the transistor 33c is provided instead of the transistor 33b1 and the transistor 33a2, and the transistor 33al, the transistor 33c, and the transistor 33b2 are connected in series. In this case, the conductive layer 111_1 functions as one of the source electrode and the drain electrode of the transistor 33al and one of the source electrode and the drain electrode of the transistor 33c. Furthermore, the conductive layer 111_2 functions as the other of the source electrode and the drain electrode of the transistor 33b2 and the other of the source electrode and the drain electrode of the transistor 33c. The conductive layer 115 functions as the gate electrode of the transistor 33al, the gate electrode of the transistor 33b2, and the gate electrode of the transistor 33c.

The transistor 33 illustrated in FIG. 29A1, FIG. 29B, FIG. 30A, and FIG. 30B can also be regarded as one multi-gate transistor including three gate electrodes. Here, the channel length of the transistor 33c can be the sum of the length L33b1, the length L33c, and the length L33a2.

The transistor 33 illustrated in FIG. 29A1, FIG. 29B, FIG. 30A, and FIG. 30B can also be regarded as one transistor where one of the source electrode and the drain electrode is the conductive layer 112a, the other of the source electrode and the drain electrode is the conductive layer 112b, and the gate electrode is the conductive layer 115.

Note that the transistor 33 may have a structure where three or more conductive layers 111 and three or more openings 121 are provided and arranged in the X direction. Thus, the channel length of the transistor 33 can be further increased as compared with the case where two conductive layers 111 and two openings 121 are provided in the transistor 33 and arranged in the X direction.

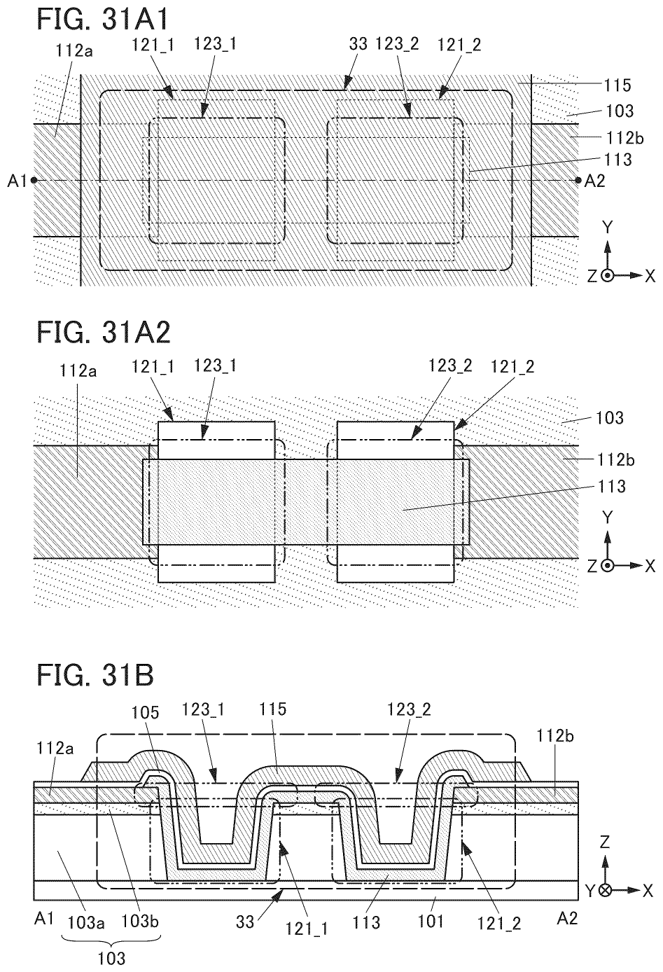

FIG. 31A1, FIG. 31A2, and FIG. 31B illustrate a variation example of the structure illustrated in FIG. 29A1, FIG. 29A2, and FIG. 29B, in which the transistor 33 does not include the conductive layer 111 functioning as a floating electrode. FIG. 31A1, FIG. 31A2, and FIG. 31B illustrate an example where the structure illustrated in FIG. 13A1, FIG. 13A2, and FIG. 13B and the structure illustrated in FIG. 29A1, FIG. 29A2, and FIG. 29B are combined.

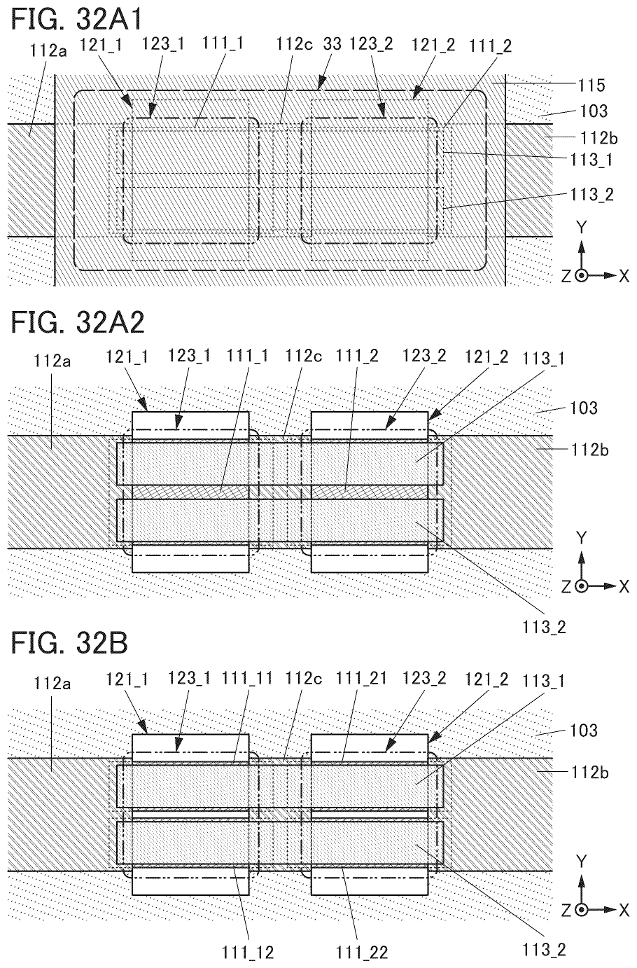

FIG. 32A1 illustrates a variation example of the structure illustrated in FIG. 24A1, and FIG. 32A2 is a plan view omitting the conductive layer 115 from the components illustrated in FIG. 32A1. FIG. 32A1 and FIG. 32A2 illustrate an example where the transistor 33 includes two semiconductor layers 113 and the two semiconductor layers 113 are arranged in the Y direction.

FIG. 32B illustrates a variation example of the structure illustrated in FIG. 32A2, in which the transistor 33 includes four conductive layers 111. FIG. 32B illustrates an example where the conductive layer 111_1 is divided into a conductive layer 111_11 and a conductive layer 111_12, and the conductive layer 111_2 is divided into a conductive layer 111_21 and a conductive layer 111_22. Here, the conductive layer 111_11 and the conductive layer 111_21 each include a region overlapping with the semiconductor layer 113_1, and the conductive layer 111_12 and the conductive layer 111_22 each include a region overlapping with the semiconductor layer 113_2.

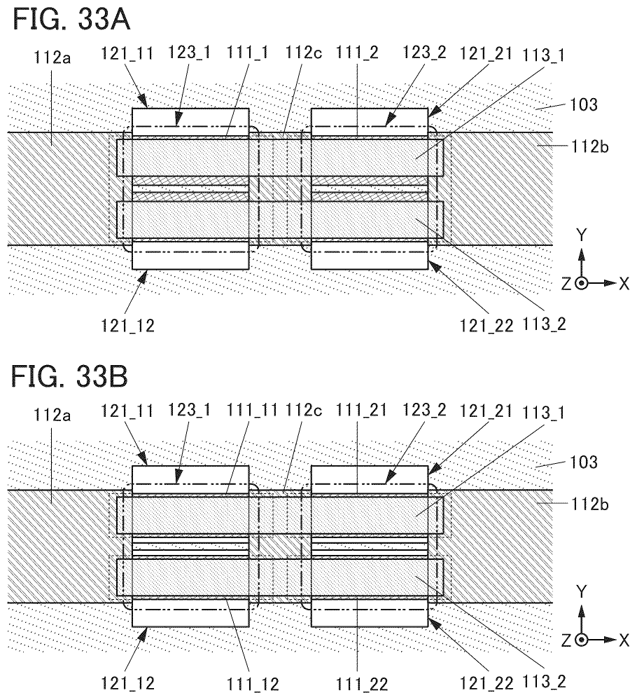

FIG. 33A illustrates a variation example of the structure illustrated in FIG. 32A2, and FIG. 33B illustrates a variation example of the structure illustrated in FIG. 32B. FIG. 33A and FIG. 33B each illustrate an example where the transistor 33 includes four openings 121. In the examples illustrated in FIG. 33A and FIG. 33B, two openings 121 are arranged in the X direction and two openings 121 are arranged in the Y direction. Thus, when the X direction is the row direction and the Y direction is the column direction, the openings 121 are arranged in a matrix of two rows and two columns in one transistor 33. Here, in FIG. 33A and FIG. 33B, the opening 121 in the first row and the first column is referred to as an opening 121_11, the opening 121 in the second row and the first column is referred to as an opening 121_12, the opening 121 in the first row and the second column is referred to as an opening 121_21, and the opening 121 in the second row and the second column is referred to as an opening 121_22. The same applies to the other drawings.

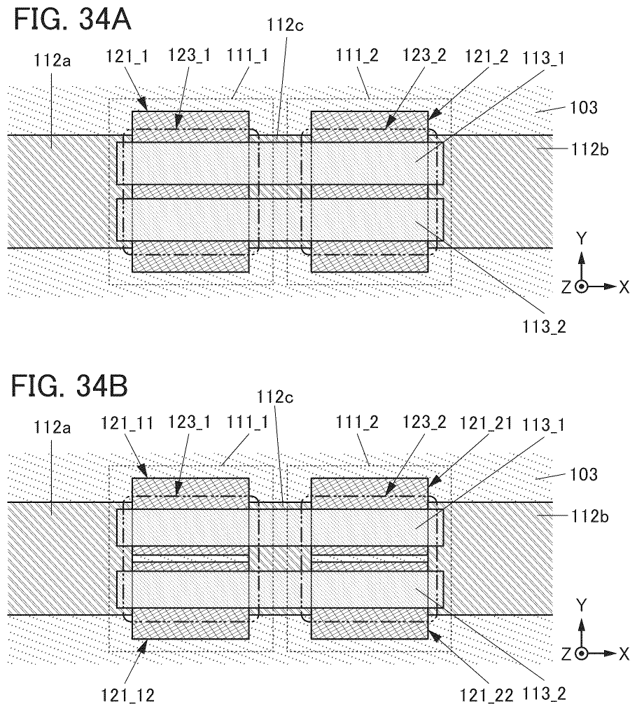

FIG. 34A and FIG. 34B illustrate a variation example of the structure illustrated in FIG. 32A2 and FIG. 33A, in which the end portion of the conductive layer 111 is positioned outward from the end portion of the opening 121 in the Y direction. As described above, when the length of the conductive layer 111 in the Y direction is increased, the wiring resistance of the conductive layer 111 can be reduced. Meanwhile, when the length of the conductive layer 111 in the Y direction is decreased, the transistor 33 can be miniaturized.

In the example illustrated in FIG. 34A and FIG. 34B, the whole opening 121 overlaps with the conductive layer 111 in a plan view. Thus, in the case where the opening 121 is formed by removing at least part of the insulating layer 103 by etching, for example, regarding the etching selectivity, only the selectivity of the insulating layer 103 and the conductive layer 111 needs to be considered, and there is no need to consider the selectivity of the insulating layer 103 and a layer other than the conductive layer 111 provided below the insulating layer 103, as described above. Thus, the transistor 33 can be easily manufactured.

Note that the transistor 33 may have a structure where three or more semiconductor layers 113 are arranged in the Y direction. In this case, one conductive layer 111 may be shared by the three or more semiconductor layers 113, or three or more conductive layers 111 may be arranged in the Y direction. As described above, in the case where two or more semiconductor layers 113 are arranged in the Y direction in the transistor included in the display apparatus of one embodiment of the present invention, the plurality of semiconductor layers 113 arranged in the Y direction may be provided in one opening 121, or different openings 121 may be provided for the semiconductor layers 113.

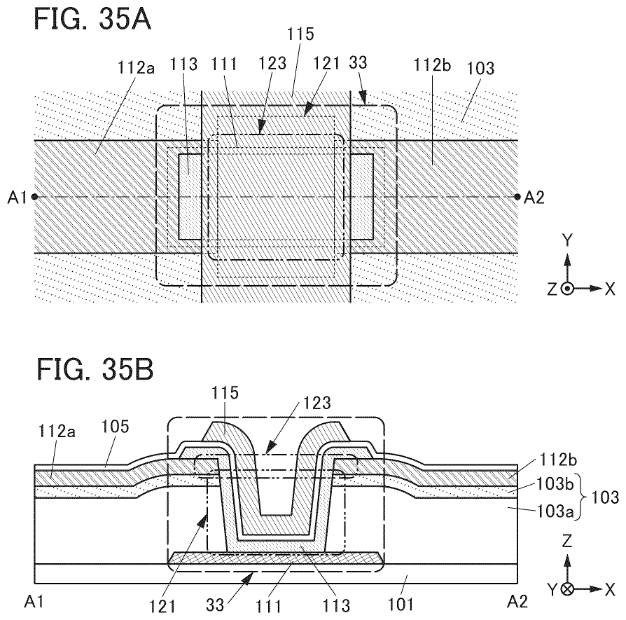

FIG. 35A illustrates a variation example of the structure illustrated in FIG. 2A1, and FIG. 35B is a cross-sectional view taken along dashed-dotted line A1-A2 in FIG. 35A. FIG. 35A and FIG. 35B illustrate an example where in the X direction, the end portion of the conductive layer 115 is positioned inward from the end portion of the semiconductor layer 113, that is, on the opening 123 side. In the example illustrated in FIG. 35A and FIG. 35B, the semiconductor layer 113 includes a region not overlapping with the conductive layer 115. With such a structure, the area of a region where the conductive layer 115 and the conductive layer 112a overlap with each other and the area of a region where the conductive layer 115 and the conductive layer 112b overlap with each other can be reduced. Thus, parasitic capacitance can be reduced.

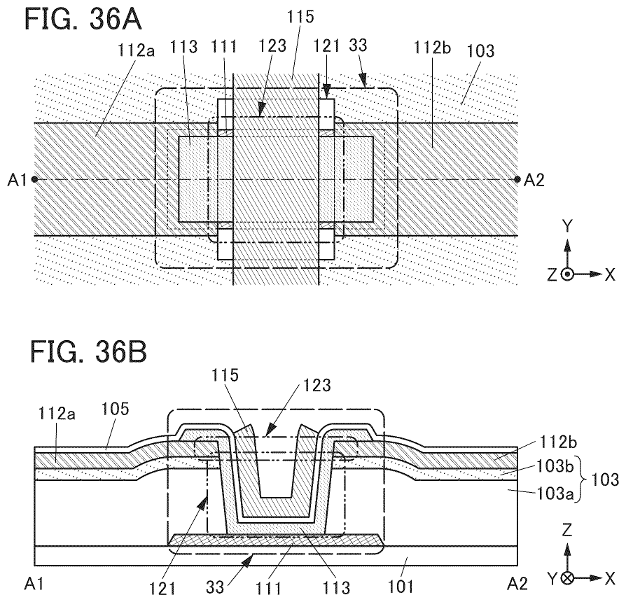

FIG. 36A illustrates a variation example of the structure illustrated in FIG. 35A, and FIG. 36B is a cross-sectional view taken along dashed-dotted line A1-A2 in FIG. 36A. FIG. 36A and FIG. 36B illustrate an example where the end portion of the conductive layer 115 is positioned inward from the end portion of the opening 123 in the X direction. In the example illustrated in FIG. 36A and FIG. 36B, the opening 121 and the opening 123 each include a region not overlapping with the conductive layer 115. With such a structure, the area of the region where the conductive layer 115 and the conductive layer 112a overlap with each other and the area of the region where the conductive layer 115 and the conductive layer 112b overlap with each other can be further reduced. Thus, parasitic capacitance can be further reduced.

The structures illustrated in FIG. 35A, FIG. 35B, FIG. 36A, and FIG. 36B can be combined with any of the structures illustrated in other drawings. In the structures illustrated in the drawings other than FIG. 35A, FIG. 35B, FIG. 36A, and FIG. 36B, the structures illustrated in any two drawings can be combined. Furthermore, a structure combining any three drawings or a structure combining any four or more drawings can be employed.

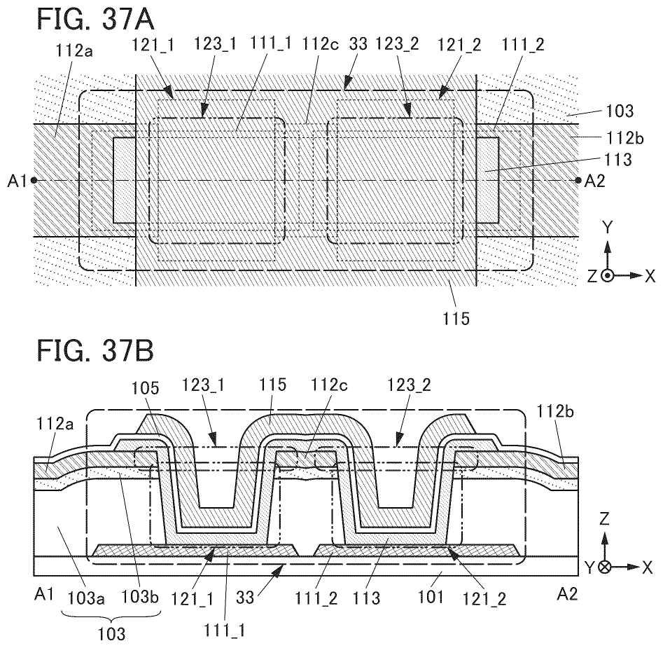

FIG. 37A illustrates a variation example of the structure illustrated in FIG. 24A1, and FIG. 37B is a cross-sectional view taken along dashed-dotted line A1-A2 in FIG. 37A. FIG. 37A and FIG. 37B illustrate an example where in the X direction, the end portion of the conductive layer 115 is positioned inward from the end portion of the semiconductor layer 113, that is, on the opening 123 side. In the example illustrated in FIG. 37A and FIG. 37B, the semiconductor layer 113 includes a region not overlapping with the conductive layer 115. With such a structure, the area of the region where the conductive layer 115 and the conductive layer 112a overlap with each other and the area of the region where the conductive layer 115 and the conductive layer 112b overlap with each other can be reduced. Thus, parasitic capacitance can be reduced.

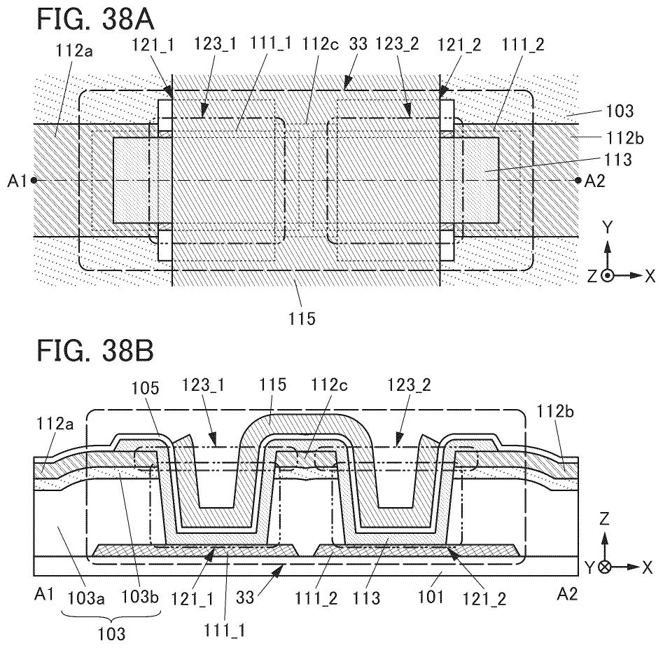

FIG. 38A illustrates a variation example of the structure illustrated in FIG. 37A, and FIG. 38B is a cross-sectional view taken along dashed-dotted line A1-A2 in FIG. 38A. FIG. 38A and FIG. 38B illustrate an example where the end portion of the conductive layer 115 is positioned inward from the end portion of the opening 123 in the X direction; specifically, the end portion of the conductive layer 115 includes a region positioned inward from the end portion of the opening 123_1 and a region positioned inward from the end portion of the opening 123_2. In the example illustrated in FIG. 38A and FIG. 38B, the opening 121 and the opening 123 each include a region not overlapping with the conductive layer 115. With such a structure, the area of the region where the conductive layer 115 and the conductive layer 112a overlap with each other and the area of the region where the conductive layer 115 and the conductive layer 112b overlap with each other can be further reduced. Thus, parasitic capacitance can be further reduced.

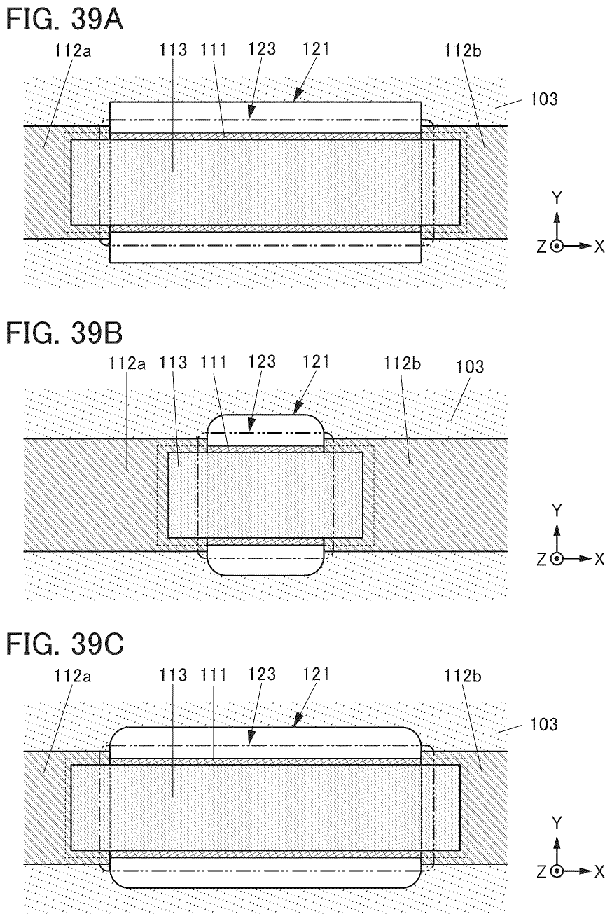

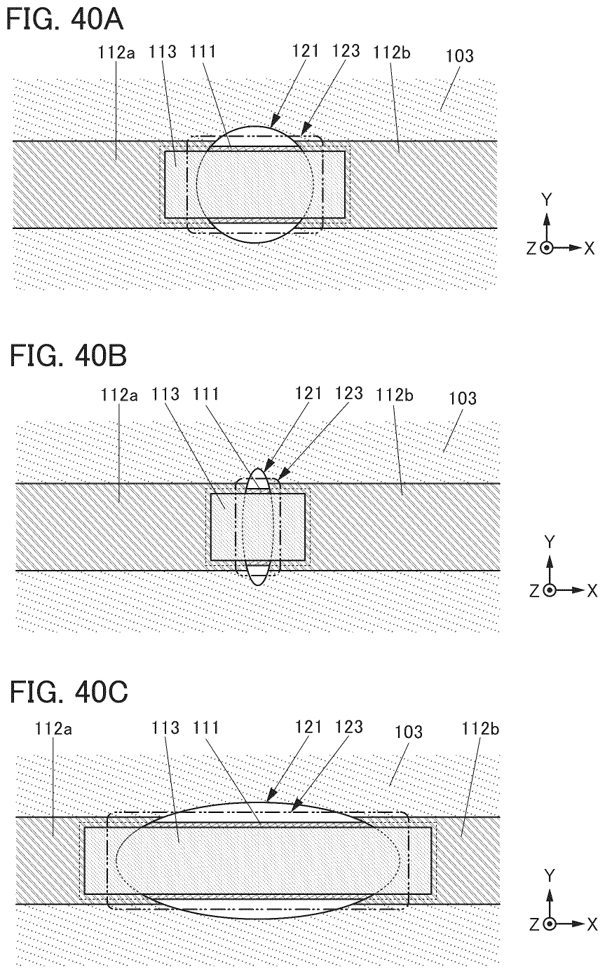

For example, in FIG. 2A2, the planar shape of the opening 121 is a rectangular shape in which the short side extends in the X direction and the long side extends in the Y direction; however, the planar shape of the opening 121 is not limited thereto. FIG. 39A, FIG. 39B, FIG. 39C, FIG. 40A, and FIG. 40B illustrate variation examples of the structure illustrated in FIG. 2A2, in which the planar shape of the opening 121 is different from that in FIG. 2A2.

FIG. 39A illustrates an example where the planar shape of the opening 121 is a rectangular shape in which the long side extends in the X direction and the short side extends in the Y direction. FIG. 39B illustrates an example where the opening 121 illustrated in FIG. 2A2 has rounded corners, for example. FIG. 39C illustrates an example where the opening 121 illustrated in FIG. 39A has rounded corners, for example.

In the case where the planar shape of the opening 121 is a quadrangular shape, by angularizing the corners, the area of the opening 121 in a plan view can be increased as compared with the case where the corners are rounded, while the transistor 33 is miniaturized. Meanwhile, in the case where the corners of the opening 121 are rounded, coverage of the corners of the opening 121 with the layer provided in the opening 121, such as the semiconductor layer 113, the insulating layer 105, or the conductive layer 115, can be increased as compared with the case where the corners of the opening 121 are angularized.

Note that the planar shape of the opening 121 may be a square, a rhombus, or a triangle, or a polygon such as a pentagon. Alternatively, the corners may be rounded. Even when the opening 121 has the above shape, the above description of the planar shape of the opening 121 can be referred to.

FIG. 40A illustrates an example where the planar shape of the opening 121 is a circular shape. When the planar shape of the opening 121 is a circular shape, the processing accuracy at the time of forming the opening 121 can be increased. Meanwhile, when the planar shape of the opening 121 is a rectangular shape, a rectangular shape with rounded corners, or the like, the side surface of the opening 121 includes a region with a flat surface or a substantially flat surface, so that coverage with the layer provided in the opening 121, such as the semiconductor layer 113, the insulating layer 105, or the conductive layer 115, can be increased. Note that in this specification and the like, a circular shape is not necessarily a perfect circular shape.

FIG. 40B illustrates an example where the planar shape of the opening 121 is an elliptical shape in which the major axis extends in the Y direction and the minor axis extends in the X direction. FIG. 40C illustrates an example where the planar shape of the opening 121 is an elliptical shape in which the major axis extends in the X direction and the minor axis extends in the Y direction. Even with the shape illustrated in FIG. 40B or FIG. 40C, the processing accuracy at the time of forming the opening 121 can be sometimes increased as compared with the case where the planar shape of the opening 121 is a rectangular shape, for example.

The above description of the planar shape of the opening 121 can be applied to all structures described in this specification and the like.

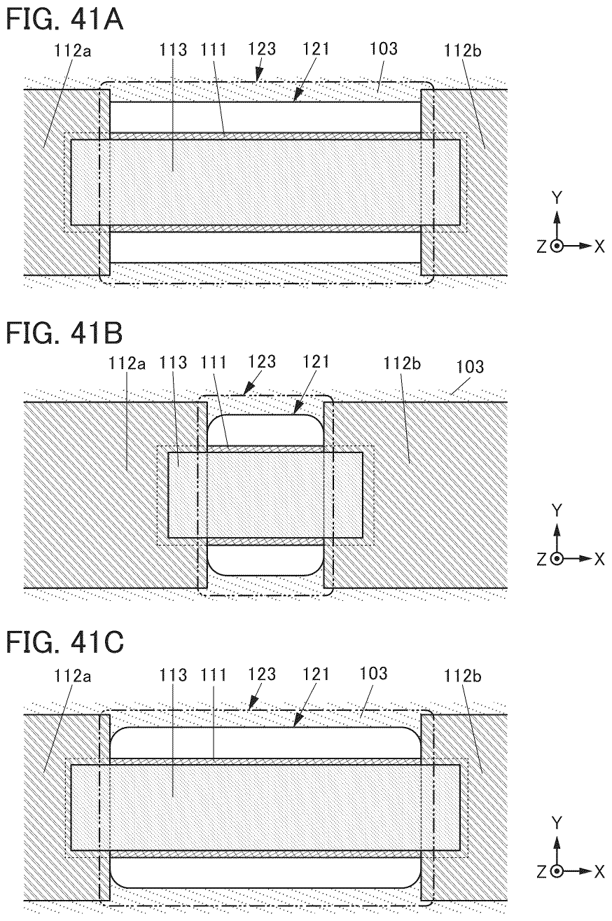

FIG. 41A, FIG. 41B, and FIG. 41C illustrate a variation example of the structure illustrated in FIG. 39A, FIG. 39B, and FIG. 39C, in which the end portions of the conductive layer 112a and the conductive layer 112b are positioned outward from the end portion of the opening 121 in the Y direction. In the example illustrated in FIG. 41A, FIG. 41B, and FIG. 41C, the wiring resistance of the conductive layer 112a and the conductive layer 112b can be reduced. Meanwhile, in the example illustrated in FIG. 39A, FIG. 39B, and FIG. 39C, the transistors 33 can be arranged at high density. The example illustrated in FIG. 41A, FIG. 41B, and FIG. 41C can be manufactured by, for example, forming the opening 121 and the opening 123 that is provided between the conductive layer 112a and the conductive layer 112b using different mask patterns.

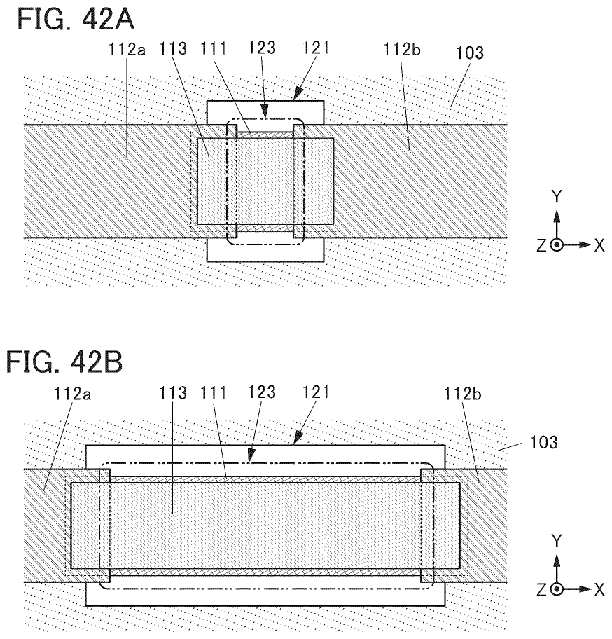

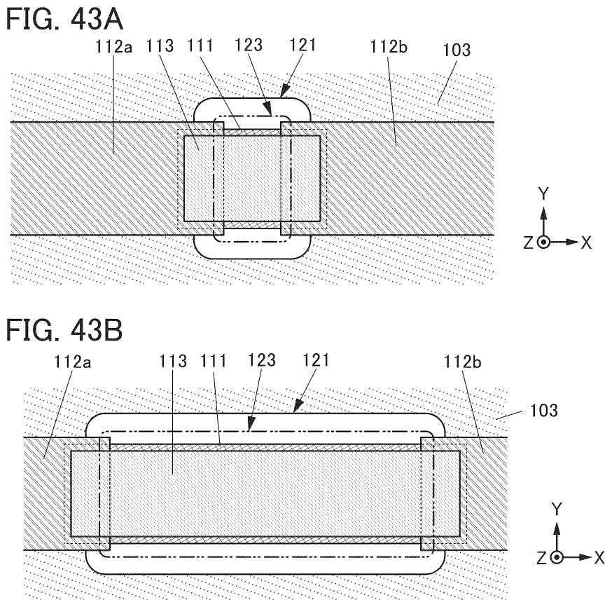

FIG. 2A2, FIG. 39A, FIG. 39B, FIG. 39C, and the like illustrate examples where the opening 121 is in contact with one side of the conductive layer 112a and one side of the conductive layer 112b, specifically, a side of the conductive layer 112a extending in the Y direction and a side of the conductive layer 112b extending in the Y direction in a plan view; however, one embodiment of the present invention is not limited thereto. FIG. 42A, FIG. 42B, FIG. 43A, and FIG. 43B illustrate variation examples of the structures illustrated in FIG. 2A2, FIG. 39A, FIG. 39B, and FIG. 39C, and are different from the structures illustrated in FIG. 2A2, FIG. 39A, FIG. 39B, and FIG. 39C in that the opening 121 includes a region in contact with three sides of the conductive layer 112a and three sides of the conductive layer 112b in a plan view. In the examples illustrated in FIG. 42A, FIG. 42B, FIG. 43A, and FIG. 43B, specifically, the opening 121 is in contact with the side of the conductive layer 112a extending in the Y direction, the side of the conductive layer 112b extending in the Y direction, part of a side of the conductive layer 112a extending in the X direction, and part of a side of the conductive layer 112b extending in the X direction, in a plan view.

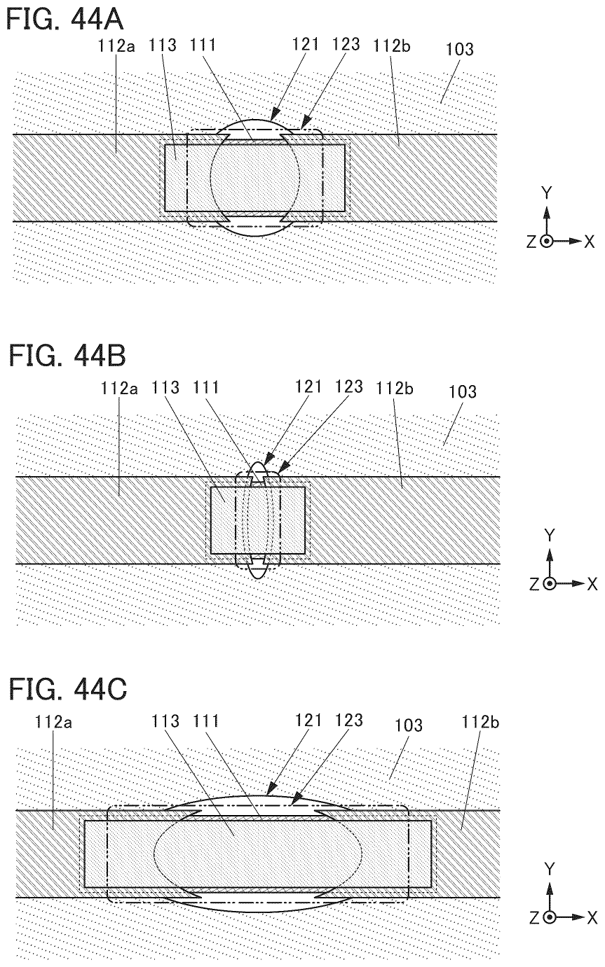

FIG. 44A, FIG. 44B, and FIG. 44C illustrate variation examples of the structures illustrated in FIG. 40A, FIG. 40B, and FIG. 40C, and are different from the structures illustrated in FIG. 40A, FIG. 40B, and FIG. 40C in that the opening 121 is in contact with part of the side of the conductive layer 112a extending in the X direction and part of the side of the conductive layer 112b extending in the X direction, in a plan view.

In the structures illustrated in FIG. 42A, FIG. 42B, FIG. 43A, FIG. 43B, FIG. 44A, FIG. 44B, and FIG. 44C, the range in which the conductive layer 112a and the opening 121 are in contact with each other and the range in which the conductive layer 112b and the opening 121 are in contact with each other can be widened in a plan view. Meanwhile, in the structures illustrated in FIG. 2A2, FIG. 39A, FIG. 39B, FIG. 39C, FIG. 40A, FIG. 40B, FIG. 40C, and the like, the area of the opening 121 in a plan view can be small.

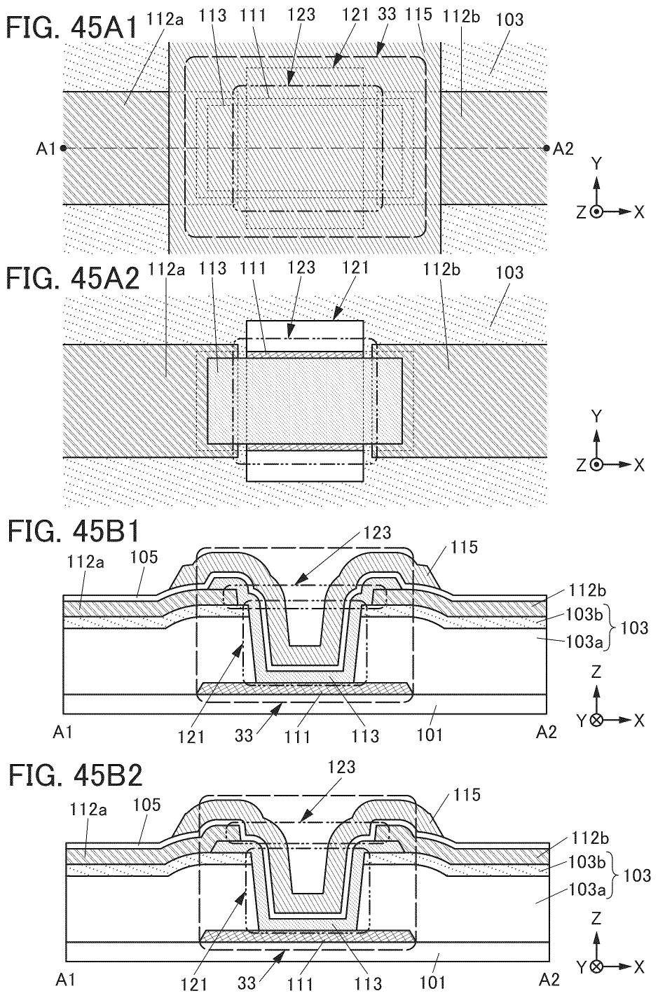

FIG. 45A1 illustrates a variation example of the structure illustrated in FIG. 2A1, and FIG. 45A2 is a plan view omitting the conductive layer 115 from the components illustrated in FIG. 45A1. FIG. 45B1 is a cross-sectional view taken along dashed-dotted line A1-A2 in FIG. 45A1. FIG. 45A1, FIG. 45A2, and FIG. 45B1 illustrate an example where the end portion of the opening 121 is positioned inward from the end portion of the conductive layer 112a and the end portion of the conductive layer 112b in the X direction.

For example, in the case where the opening 121 and the opening 123 that is provided between the conductive layer 112a and the conductive layer 112b are formed in different steps, specifically with different mask patterns, the end portion of the opening 121 is positioned inward from the end portion of the conductive layer 112a and the end portion of the conductive layer 112b in some cases. Even in the case where the opening 121 and the opening 123 are formed in the same step, for example, when the etching rate of a film to be the conductive layer 112a and the conductive layer 112b in the X direction and the Y direction is different from the etching rate of the insulating layer 103 in the X direction and the Y direction, the end portion of the opening 121 is positioned inward from the end portion of the conductive layer 112a and the end portion of the conductive layer 112b in some cases. For example, in the case where the etching rate of the film to be the conductive layer 112a and the conductive layer 112b in the X direction and the Y direction is higher than the etching rate of the insulating layer 103 in the X direction and the Y direction, the end portion of the opening 121 is positioned inward from the end portion of the conductive layer 112a and the end portion of the conductive layer 112b in some cases. Note that the end portion of the opening 121 is positioned outward from the end portion of the conductive layer 112a and the end portion of the conductive layer 112b in some cases.

FIG. 45B2 illustrates a variation example of the structure illustrated in FIG. 45B1, in which the top surface of the semiconductor layer 113 includes a region in contact with the conductive layer 112a and a region in contact with the conductive layer 112b. The structure illustrated in FIG. 45B2 can be formed by, for example, forming the opening 121 in the insulating layer 103, forming the semiconductor layer 113, forming a film to be the conductive layer 112a and the conductive layer 112b, and then forming the opening 123 in the film.

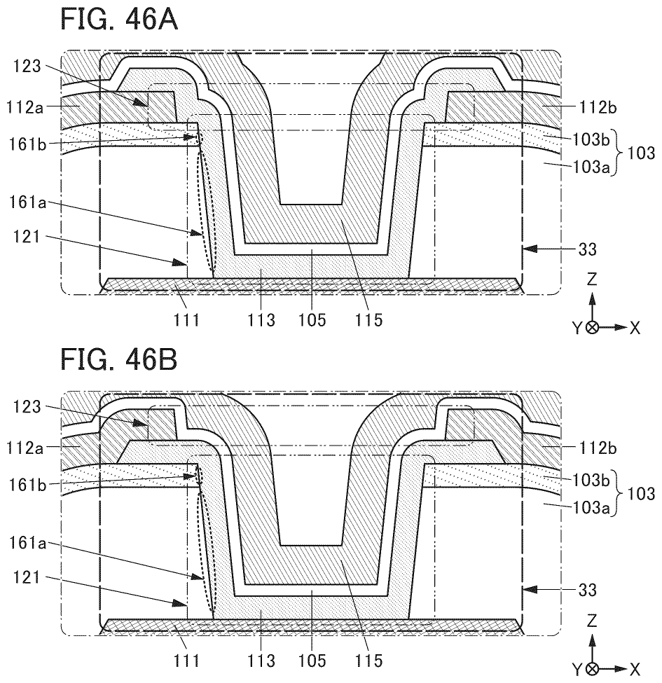

FIG. 46A is an enlarged view illustrating the structure example of the transistor 33 illustrated in FIG. 45B1 and its vicinity, and FIG. 46B is an enlarged view illustrating the structure example of the transistor 33 illustrated in FIG. 45B2 and its vicinity. As illustrated in FIG. 46A and FIG. 46B, the side surface of the insulating layer 103a on the opening 121 side includes a tapered portion 161a and the side surface of the insulating layer 103b on the opening 121 side includes a tapered portion 161b.

As illustrated in FIG. 46A and FIG. 46B, the end portion of the top surface of the insulating layer 103a on the opening 121 side can be the same or substantially the same as the end portion of the bottom surface of the insulating layer 103b on the opening 121 side. Furthermore, the taper angle of the tapered portion 161a can be equal to or substantially equal to the taper angle of the tapered portion 161b. Here, the taper angle of the side surface of the opening 123, that is, the taper angle of the side surface of the conductive layer 112a or the side surface of the conductive layer 112b, may be larger or smaller than the taper angle of the tapered portion 161a or the tapered portion 161b.

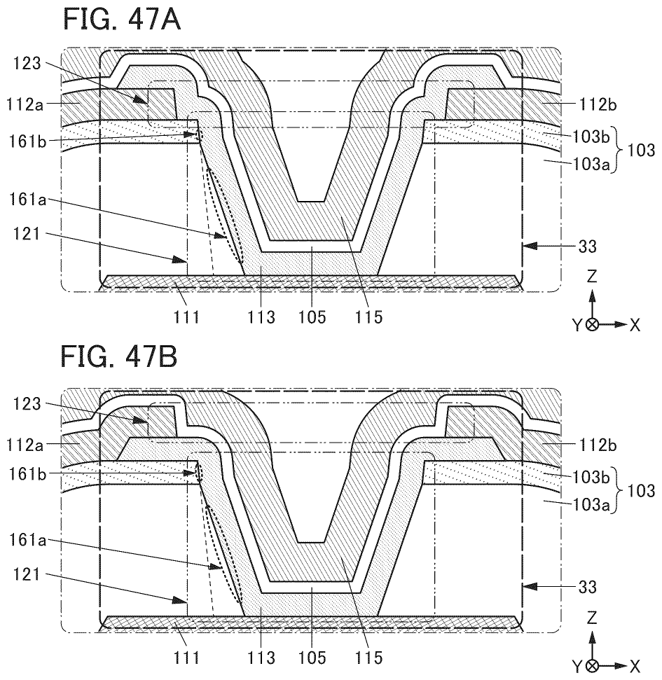

FIG. 47A and FIG. 47B illustrate variation examples of the structures illustrated in FIG. 46A and FIG. 46B, respectively, in which the tapered portion 161a and the tapered portion 161b have different taper angles. In each of FIG. 47A and FIG. 47B, the tapered portion 161b extending to the insulating layer 103a side is indicated by a dashed straight line. For example, in the case where the insulating layer 103a and the insulating layer 103b include different materials and thus the insulating layer 103a and the insulating layer 103b have different processabilities, the tapered portion 161a and the tapered portion 161b have different taper angles in some cases.

FIG. 47A and FIG. 47B illustrate examples where the taper angle of the tapered portion 161a is smaller than the taper angle of the tapered portion 161b. The taper angle of the tapered portion 161a may be larger than the taper angle of the tapered portion 161b. Here, the taper angle of the side surface of the opening 123 may be larger or smaller than the taper angle of the tapered portion 161a and may be larger or smaller than the taper angle of the tapered portion 161b.

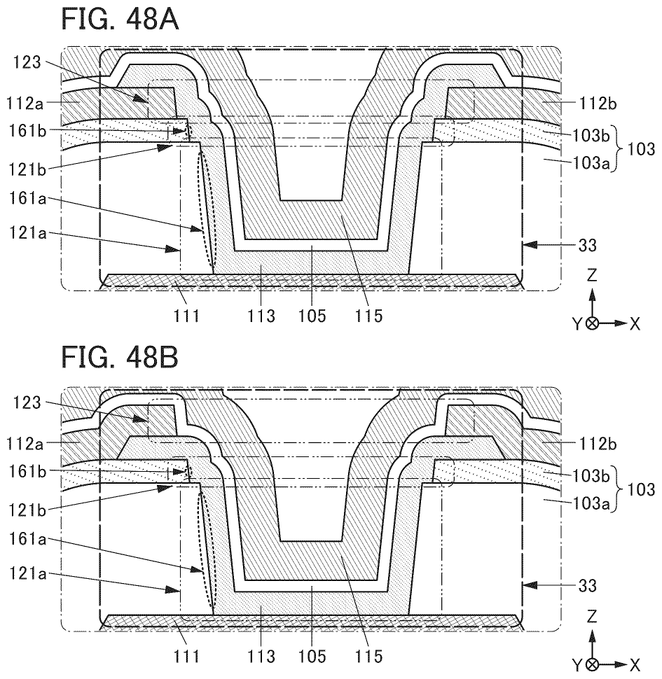

FIG. 48A and FIG. 48B illustrate variation examples of the structures illustrated in FIG. 46A and FIG. 46B, respectively, in which the end portion of the top surface of the insulating layer 103a is not the same as the end portion of the bottom surface of the insulating layer 103b, specifically, an end portion of the insulating layer 103b on the opening 121 side is positioned outward from an end portion of the insulating layer 103a on the opening 121 side. In FIG. 48A and FIG. 48B, the opening 121 provided in the insulating layer 103a is an opening 121a, and the opening 121 provided in the insulating layer 103b is an opening 121b.

For example, in the case where the insulating layer 103a is etched in the X direction at a rate different from a rate at which the insulating layer 103b is etched in the X direction, the end portion of the top surface of the insulating layer 103a is sometimes not the same as the end portion of the bottom surface of the insulating layer 103b. Specifically, in the case where the insulating layer 103b is etched in the X direction at a rate higher than a rate at which the insulating layer 103a is etched in the X direction, any of the structures illustrated in FIG. 48A and FIG. 48B may be formed. Here, the taper angles of the tapered portion 161a and the tapered portion 161b may be equal to, substantially equal to, or different from each other. In addition, the taper angle of the side surface of the opening 123 may be larger or smaller than the taper angle of the tapered portion 161a and may be larger or smaller than the taper angle of the tapered portion 161b. Note that the end portion of the insulating layer 103b on the opening 121 side is positioned outward from the end portion of the insulating layer 103a on the opening 121 side in some cases.

The taper angles of the tapered portion 161a, the tapered portion 161b, and the side surfaces of the conductive layer 112a and the conductive layer 112b, the positional relationship between the insulating layer 103a, the insulating layer 103b, and the end portions of the conductive layer 112a and the conductive layer 112b, and the like described with reference to FIG. 46 to FIG. 48 are applicable to all the structures described in this specification and the like.

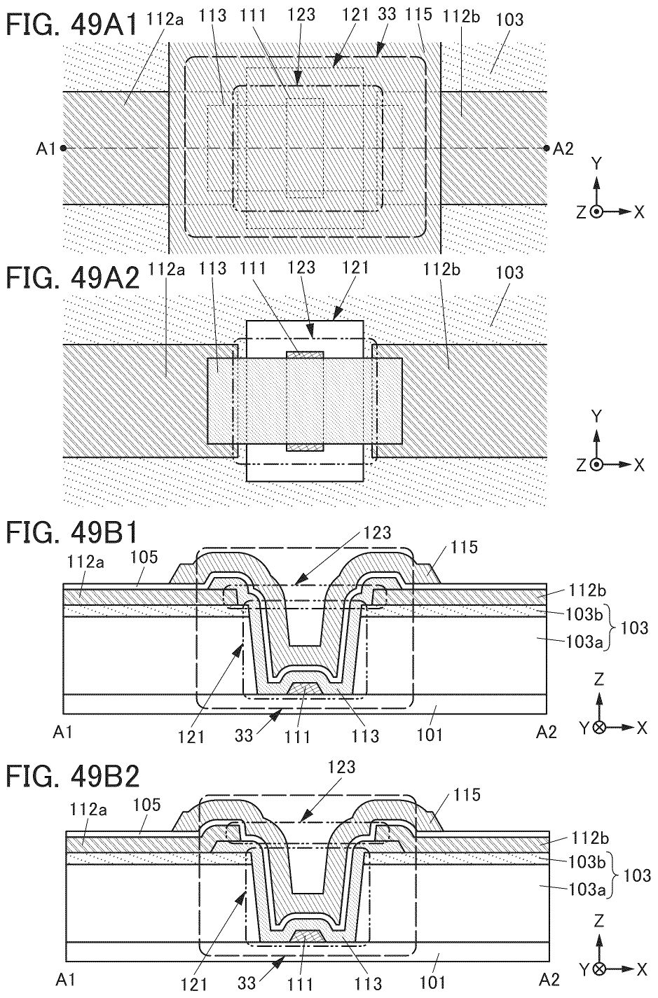

FIG. 49A1, FIG. 49A2, FIG. 49B1, and FIG. 49B2 illustrate variation examples of the structures illustrated in FIG. 45A1, FIG. 45A2, FIG. 45B1, and FIG. 45B2, in which the end portion of the conductive layer 111 is positioned inward from the end portion of the bottom surface of the opening 121 in the X direction. In this case, as illustrated in FIG. 49B1 and FIG. 49B2, the semiconductor layer 113 can cover the end portion of the conductive layer 111.

When the transistor included in the display apparatus of one embodiment of the present invention has the structure illustrated in FIG. 49B1, FIG. 49B2, or the like, the channel length of the transistor can be long as compared with the case where the transistor has the structure illustrated in FIG. 45B1, FIG. 45B2, or the like. Accordingly, the withstand voltage of the transistor can be increased and a high voltage can be applied to the transistor. In the case where the transistor is driven in a saturation region, an increase in drain current due to an increase in drain-source voltage of the transistor can be suppressed. The channel length of the transistor 33 can be controlled by controlling the length of the conductive layer 111 in the X direction. Thus, in the case where the display apparatus of one embodiment of the present invention includes a plurality of transistors each having a structure similar to that illustrated in FIG. 49B1, FIG. 49B2, or the like, the transistors can have different channel lengths by changing the length of the conductive layer 111 in the X direction for each transistor. For example, the channel length of a transistor that needs a high on-state current can be made short, and the channel length of a transistor that needs a high withstand voltage can be made long.

Here, in the case where the transistor 33 has the structure illustrated in FIG. 49B1, the conductive layer 111 can be formed in the same step as the conductive layer 112a and the conductive layer 112b. Specifically, after the opening 121 is formed in the insulating layer 103, for example, a film to be the conductive layer 111, the conductive layer 112a, and the conductive layer 112b is formed and processed by a photolithography method and an etching method, whereby the conductive layer 111, the conductive layer 112a, and the conductive layer 112b illustrated in FIG. 49B1 can be formed. When the conductive layer 111 is formed in the same step as the conductive layer 112a and the conductive layer 112b, the number of manufacturing steps of the transistor 33 can be reduced. Meanwhile, in the case where the conductive layer 111 is formed in a step different from that of forming the conductive layer 112a and the conductive layer 112b, specifically, in the case where the insulating layer 103 is formed after formation of the conductive layer 111 and a film to be the conductive layer 112a and the conductive layer 112b is formed over the insulating layer 103, for example, the film is not formed in the opening 121. Thus, the film to be the conductive layer 112a and the conductive layer 112b can be easily processed and the transistor 33 can be easily manufactured.

Note that two or more kinds of transistors having the structure described in this specification and the like may be provided over the same substrate. For example, the transistor having the structure illustrated in FIG. 2A1 and FIG. 2B and the transistor having the structure illustrated in FIG. 17A1 and FIG. 17C may be provided over the same substrate.

### <Manufacturing Method Example 1 of Display Apparatus>

An example of a method for manufacturing a display apparatus of one embodiment of the present invention will be described below with reference to drawings. Here, a method for manufacturing the display apparatus including the transistor 33 illustrated in FIG. 2A1 and FIG. 2B is described as an example.

Thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma enhanced chemical vapor deposition (PECVD: Plasma Enhanced CVD) method and a thermal CVD method. An example of the thermal CVD method is a metal organic chemical vapor deposition (MOCVD: Metal Organic CVD) method.

The thin films included in the display apparatus (insulating films, semiconductor films, conductive films, and the like) can be formed by a method such as spin coating, dipping, spray coating, ink-jetting, dispensing, screen printing, offset printing, doctor blade coating, slit coating, roll coating, curtain coating, or knife coating in some cases.

The thin films can be processed by, for example, etching of the thin films in accordance with a pattern of a resist mask that has been formed by a photolithography method. Alternatively, a nanoimprinting method, a sandblasting method, a lift-off method, or the like may be used for the processing of the thin films. An island-shaped thin film may be directly formed by a film formation method using a shielding mask such as a metal mask. A photosensitive thin film can be processed by light exposure and development. That is, the photosensitive thin film can be processed by a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) light or X-rays may be used. Instead of the light used for light exposure, an electron beam can be used. It is preferable to use extreme ultraviolet light, X-rays, or an electron beam because extremely minute processing is possible. Note that when light exposure is performed by scanning of a beam such as an electron beam, a photomask is not needed.

For the etching of the thin films, a dry etching method, a wet etching method, or the like can be used.

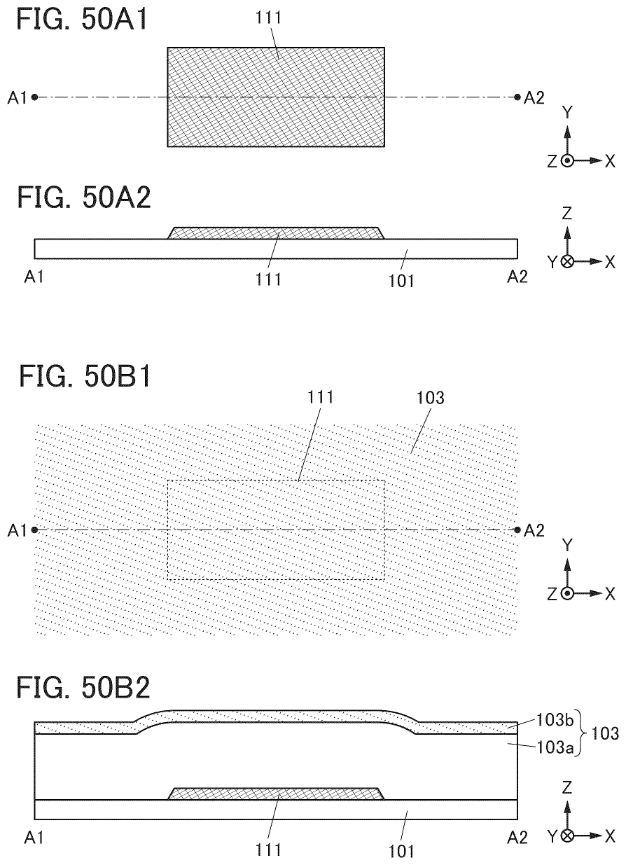

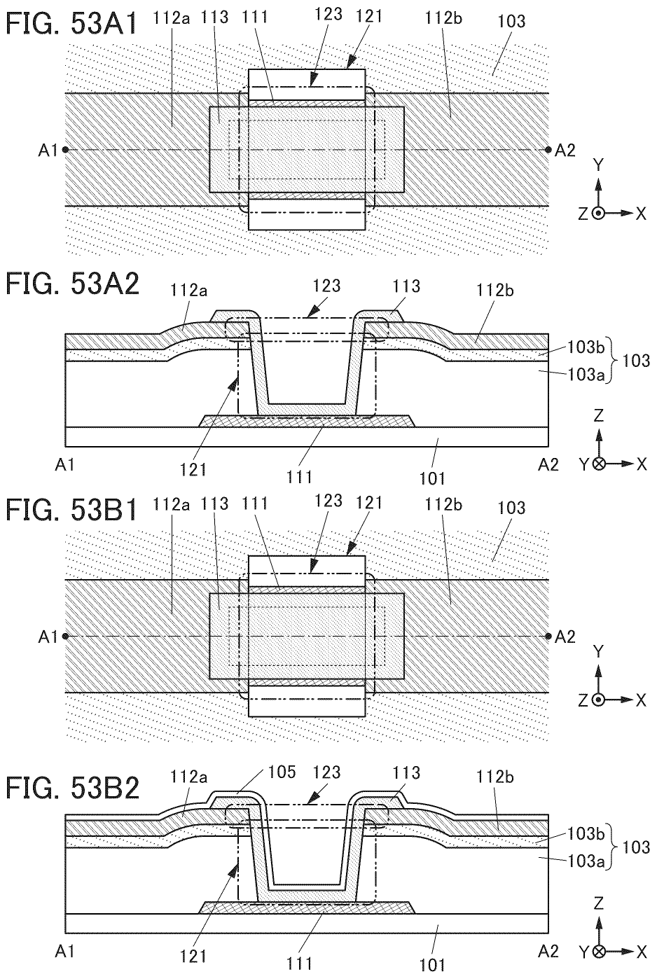

FIG. 50A1 to FIG. 53B2 are diagrams illustrating a method for manufacturing the structure illustrated in FIG. 2A1 and FIG. 2B. In each diagram, A1 and B1 are plan views, and A2 and B2 are cross-sectional views taken along dashed-dotted line A1-A2 in the plan views.

### [Formation of Conductive Layer 111]

A conductive film to be the conductive layer 111 is formed over the substrate 101. A sputtering method can be suitably used for forming the conductive firm, for example. The conductive film is processed after a resist mask is formed over the conductive film by a photolithography step, whereby the island-shaped conductive layer 111 functioning as one of the source electrode and the drain electrode can be formed (FIG. 50A1 and FIG. 50A2). For the processing of the conductive film, one or both of a wet etching method and a dry etching method are used.

[Formation of Insulating Layer 103a and Insulating Layer 103b]

Next, the insulating layer 103a and the insulating layer 103b are formed over the substrate 101 and the conductive layer 111 (FIG. 50B1 and FIG. 50B2). A PECVD method can be suitably used for forming the insulating layer 103a and the insulating layer 103b, for example. It is preferable that the insulating layer 103b be formed in a vacuum successively after the formation of the insulating layer 103a, without exposure of a surface of the insulating layer 103a to the air. The insulating layer 103a and the insulating layer 103b are successively formed, whereby impurities derived from the air can be inhibited from being attached to the surface of the insulating layer 103a. Examples of the impurities include water and organic substances.

The substrate temperature at the time of forming the insulating layer 103a and the insulating layer 103b is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating layer 103a and the insulating layer 103b is in the above range, impurities (e.g., water and hydrogen) released from the insulating layer 103a and the insulating layer 103b can be reduced, which inhibits the diffusion of the impurities into the semiconductor layer 113. Consequently, the transistor can have favorable electrical characteristics and high reliability.

Note that the insulating layer 103a and the insulating layer 103b are formed before the semiconductor layer 113 is formed. Hence, there is no need for concern about release of oxygen from the semiconductor layer 113 due to heat applied at the time of forming the insulating layer 103a and the insulating layer 103b.

Heat treatment may be performed after the insulating layer 103a and the insulating layer 103b are formed. By the heat treatment, water and hydrogen can be released from the surface and inside of the insulating layer 103a and the insulating layer 103b.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the amount of hydrogen, water, or the like contained in the atmosphere is preferably as low as possible. As the atmosphere, a high-purity gas with a dew point of −60° C. or lower, preferably −100° C. or lower is preferably used. With the use of an atmosphere where the amount of hydrogen, water, or the like contained is as low as possible, entry of hydrogen, water, or the like into the insulating layer 103a and the insulating layer 103b can be prevented as much as possible. An oven, a rapid thermal annealing (RTA) apparatus, or the like can be used for the heat treatment. The use of the RTA apparatus can shorten the heat treatment time.

### [Formation of Conductive Film 112F]

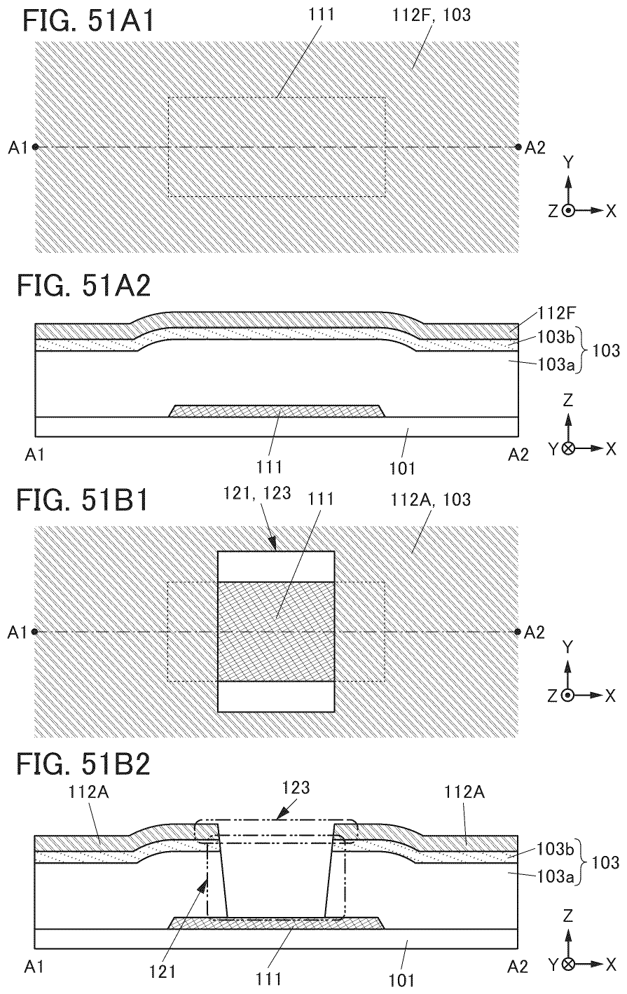

Then, a conductive film 112F to be the conductive layer 112a and the conductive layer 112b is formed over the insulating layer 103b (FIG. 51A1 and FIG. 51A2). For the formation of the conductive film 112F, a sputtering method can be suitably used, for example.

### [Formation of Opening 121 and Opening 123]

Next, at least part of a region of the conductive film 112F that overlaps with the conductive layer 111 is removed, so that a conductive layer 112A including the opening 123 is formed. For the formation of the opening 123, one or both of a wet etching method and a dry etching method can be used. For the formation of the opening 123, a wet etching method can be suitably used, for example.

Next, at least part of a region of the insulating layer 103 (the insulating layer 103a and the insulating layer 103b) that overlaps with the conductive layer 111 is removed. Thus, the opening 121 is formed in the insulating layer 103 (FIG. 51B1 and FIG. 51B2). For the formation of the opening 121, one or both of a wet etching method and a dry etching method can be used. For the formation of the opening 121, a dry etching method can be suitably used, for example.

The opening 121 can be formed using a resist mask used for the formation of the opening 123, for example. Specifically, a resist mask is formed over the conductive film 112F, at least part of the conductive film 112F is removed with use of the resist mask to form the opening 123, and the insulating layer 103 is removed with use of at least part of the resist mask, whereby the opening 121 can be formed. When the width of the opening 123 is made larger than the width of the resist mask by processing, the transistor 33, in which the width of the opening 123 is larger than the width of the opening 121, as illustrated in FIG. 46A, for example, can be fabricated. Here, in the case where the transistor 33 in which the width of the opening 123 is different from the width of the opening 121 is fabricated, for example, the opening 121 may be formed using a resist mask different from the resist mask used to form the opening 123.

[Formation of Conductive Layer 112a and Conductive Layer 112b]

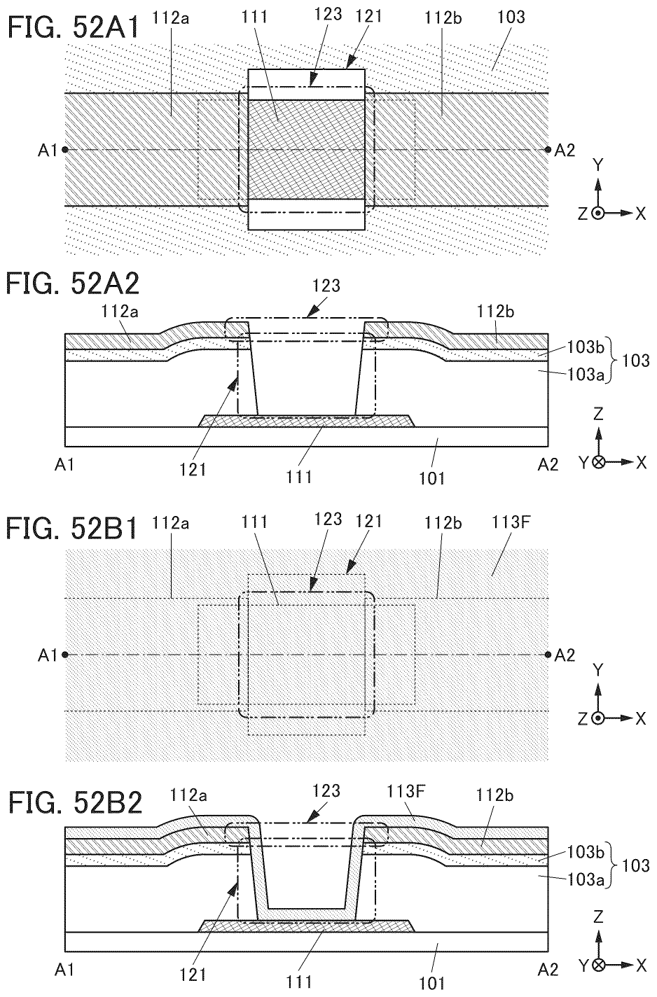

Next, the conductive layer 112A is processed into a desired shape to form the conductive layer 112a and the conductive layer 112b (FIG. 52A1 and FIG. 52A2). For the formation of the conductive layer 112a and the conductive layer 112b, one or both of a wet etching method and a dry etching method can be used. For example, a wet etching method can be suitably used for formation of the conductive layer 112a and the conductive layer 112b.

### [Formation of Semiconductor Layer 113]

Subsequently, a semiconductor film 113F to be the semiconductor layer 113 is formed to cover the opening 121 and the opening 123 (FIG. 52B1 and FIG. 52B2). The semiconductor film 113F can be provided to include a region in contact with the top surface and the side surface of the conductive layer 112a, the top surface and the side surface of the conductive layer 112b, the top surface and the side surface of the insulating layer 103, and the top surface of the conductive layer 111.

The semiconductor film 113F is preferably formed by a sputtering method using a metal oxide target.

The semiconductor film 113F is preferably a dense film with as few defects as possible. The semiconductor film 113F is preferably a highly purified film in which impurities containing the element hydrogen are reduced as much as possible. It is particularly preferable to use a metal oxide film having crystallinity as the semiconductor film 113F.

In forming the semiconductor film 113F, an oxygen gas is preferably used. In the case of using an oxygen gas at the time of forming the semiconductor film 113F, oxygen can be suitably supplied into the insulating layer 103. For example, an oxide is preferably used for the insulating layer 103a, in which case oxygen can be suitably supplied into the insulating layer 103a.

By the supply of oxygen to the insulating layer 103a, oxygen is supplied to the semiconductor layer 113 in a later step, so that oxygen vacancies (V_{O}) and V_{O}H in the semiconductor layer 113 can be reduced.

When the semiconductor film 113F is formed, an inert gas (e.g., a helium gas, an argon gas, or a xenon gas) may be mixed in addition to the oxygen gas. Note that when the proportion of an oxygen gas in the whole deposition gas (an oxygen flow rate ratio) at the time of forming the semiconductor film 113F is higher, the crystallinity of the semiconductor film 113F can be higher and a highly reliable transistor can be achieved. By contrast, when the oxygen flow rate ratio is lower, the crystallinity of the semiconductor film 113F is lower and a transistor with a high on-state current can be obtained.

With the substrate temperature at the time of forming the semiconductor film 113F is higher, the semiconductor film 113F can have higher crystallinity and be denser. By contrast, when the substrate temperature is lower, the semiconductor film 113F can have lower crystallinity and higher electric conductivity.

The substrate temperature at the time of forming the semiconductor film 113F is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the semiconductor film 113F is formed with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 103 and treatment for supplying oxygen into the insulating layer 103 before the formation of the semiconductor film 113F. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 103 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 103. It is preferable that the semiconductor film 113F be formed successively after such treatment, without exposure of the surface of the insulating layer 103 to the air.

Note that in the case where the semiconductor layer 113 has a stacked-layer structure, an upper metal oxide film is preferably formed successively after the formation of a lower metal oxide film without exposure of the surface of the lower metal oxide film to the air.

Next, the semiconductor film 113F is processed into an island shape to form the semiconductor layer 113 (FIG. 53A1 and FIG. 53A2).

For the formation of the semiconductor layer 113, one or both of a wet etching method and a dry etching method can be used. For the formation of the semiconductor layer 113, a wet etching method can be suitably used, for example. At this time, part of the insulating layer 112a and the conductive layer 112b in a region not overlapping with the semiconductor layer 113 is etched and thinned in some cases. In a similar manner, part of the insulating layer 103 in a region overlapping with neither the semiconductor layer 113, the conductive layer 112a, nor the conductive layer 112b is etched and thinned in some cases. For example, in some cases, the insulating layer 103b of the insulating layer 103 is removed by etching and a surface of the insulating layer 103a is exposed. When a material having high etching selectivity with respect to the semiconductor film 113F is used for the insulating layer 103b, a reduction in the thickness of the insulating layer 103b can be inhibited.

Heat treatment is preferably performed after the semiconductor film 113F is formed or after the semiconductor film 113F is processed into the semiconductor layer 113. By the heat treatment, hydrogen or water contained in the semiconductor film 113F or the semiconductor layer 113 or adsorbed on its surface can be removed. Furthermore, the film quality of the semiconductor film 113F or the semiconductor layer 113 is improved (e.g., the number of defects is reduced or crystallinity is increased) by the heat treatment in some cases.

Furthermore, oxygen can be supplied from the insulating layer 103a to the semiconductor film 113F or the semiconductor layer 113 by the heat treatment. In this case, it is further preferable that the heat treatment be performed before the semiconductor film is processed into the semiconductor layer 113. The above description can be referred to for the heat treatment; thus, the detailed description thereof is omitted.

Note that the heat treatment is not necessarily performed. The heat treatment in this step may be omitted, and heat treatment performed in a later step may also serve as the heat treatment in this step. For example, treatment at high temperature in a later step, such as a film formation step, can serve as the heat treatment in some cases.

### [Formation of Insulating Layer 105]

Then, the insulating layer 105 is formed to cover the semiconductor layer 113, the conductive layer 112a, the conductive layer 112b, and the insulating layer 105 (FIG. 53B1 and FIG. 53B2). For the formation of the insulating layer 105, a PECVD method can be favorably used.

In the case of using an oxide semiconductor for the semiconductor layer 113, the insulating layer 105 preferably functions as a barrier film that inhibits diffusion of oxygen. The insulating layer 105 having a function of inhibiting diffusion of oxygen inhibits diffusion of oxygen into the conductive layer 115 formed in a later step from above the insulating layer 105 and thus can inhibit oxidation of the conductive layer 115. Consequently, the transistor can have favorable electrical characteristics and high reliability.

By increasing the temperature at the time of forming the insulating layer 105 functioning as the gate insulating layer, the insulating layer including a small number of defects can be obtained. However, the high temperature at the time of forming the insulating layer 105 sometimes allows release of oxygen from the semiconductor layer 113, which increases oxygen vacancies (V_{O}) and V_{O}H in the semiconductor layer 113 in some cases. The substrate temperature at the time of forming the insulating layer 105 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 105 is in the above range, release of oxygen from the semiconductor layer 113 can be inhibited while the defects in the insulating layer 105 can be reduced. Consequently, the transistor can have favorable electrical characteristics and high reliability.

It is preferable to perform plasma treatment on the surface of the semiconductor layer 113 before the formation of the insulating layer 105. By the plasma treatment, impurities adsorbed onto the surface of the semiconductor layer 113, such as water, can be reduced. Therefore, impurities at the interface between the semiconductor layer 113 and the insulating layer 105 can be reduced, achieving a highly reliable transistor. The plasma treatment is particularly suitable in the case where the surface of the semiconductor layer 113 is exposed to the air after the formation of the semiconductor layer 113 but before the formation of the insulating layer 105. For example, plasma treatment can be performed in an atmosphere containing oxygen, ozone, nitrogen, dinitrogen monoxide, argon, or the like. The plasma treatment and the formation of the insulating layer 105 are preferably performed successively without exposure to the air.

### [Formation of Conductive Layer 115]

Subsequently, a conductive film to be the conductive layer 115 is formed over the insulating layer 105. A sputtering method can be suitably used for forming the conductive firm, for example. After a resist mask is formed over the conductive film by a photolithography process, the conductive film is processed, so that the island-shaped conductive layer 115 functioning as the gate electrode is formed.

Through the above-described steps, the transistor 33 illustrated in FIG. 2A1 and FIG. 2B can be manufactured.

### <Manufacturing Method Example 2 of Display Apparatus>

A manufacturing method of the transistor 33 that is different from the manufacturing method in <Manufacturing method example 1 of display apparatus> described above is described. Note that description of the same portions as the above is omitted and different portions will be described.

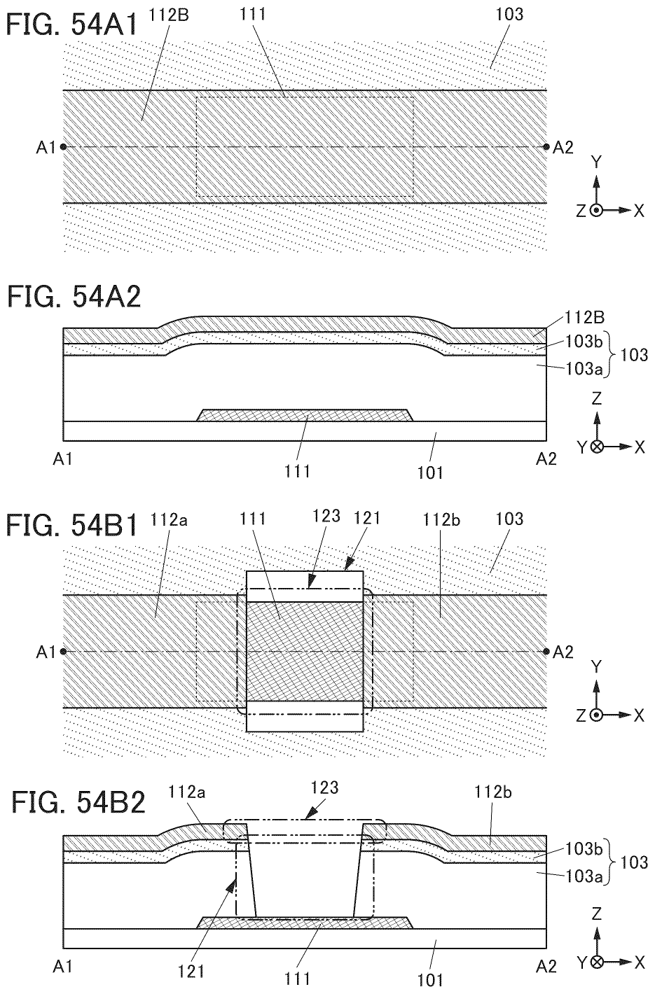

FIG. 54A1, FIG. 54A2, FIG. 54B1, and FIG. 54B2 are diagrams illustrating a method for manufacturing the structure illustrated in FIG. 2A1 and FIG. 2B. FIG. 54A1 and FIG. 54B1 are plan views, and FIG. 54A2 and FIG. 54B2 are cross-sectional views taken along the dashed-dotted line A1-A2 in FIG. 54A1 and FIG. 54B1, respectively.

First, as in <Manufacturing method example 1 of display apparatus>, the steps up to the formation of the conductive film 112F are performed. The description of FIG. 50A1 to FIG. 51A2 can be referred to for the steps up to the formation of the conductive film 112F; thus, the detailed description thereof is omitted.

Next, the conductive film 112F is processed to form a conductive layer 112B (FIG. 54A1 and FIG. 54A2). Here, the opening 123 is not necessarily formed in the conductive layer 112B. For the formation of the conductive layer 112B, one or both of a wet etching method and a dry etching method can be used. For the formation of the conductive layer 112B, a wet etching method can be suitably used, for example.

Next, at least part of a region of the conductive layer 112B that overlaps with the conductive layer 111 is removed, so that the opening 123 is formed in the conductive layer 112B. Thus, the conductive layer 112a and the conductive layer 112b are formed.

Next, at least part of a region of the insulating layer 103 (the insulating layer 103a and the insulating layer 103b) that overlaps with the conductive layer 111 is removed. Thus, the opening 121 is formed in the insulating layer 103 (FIG. 54B1 and FIG. 54B2).

The description in <Manufacturing method example 1 of display apparatus> can be referred to for the formation of the opening 121 and the opening 123; thus, the detailed description thereof is omitted.

Subsequently, the semiconductor film 113F to be the semiconductor layer 113 is formed to cover the opening 121 and the opening 123 (FIG. 52B1 and FIG. 52B2). The above description in <Manufacturing method example 1 of display apparatus> can be referred to for the steps after the formation of the semiconductor film 113F; thus, the detailed description thereof is omitted.

Through the above-described steps, the transistor 33 illustrated in FIG. 2A1 and FIG. 2B can be manufactured.

### <Structure Example 3 of Display Apparatus>

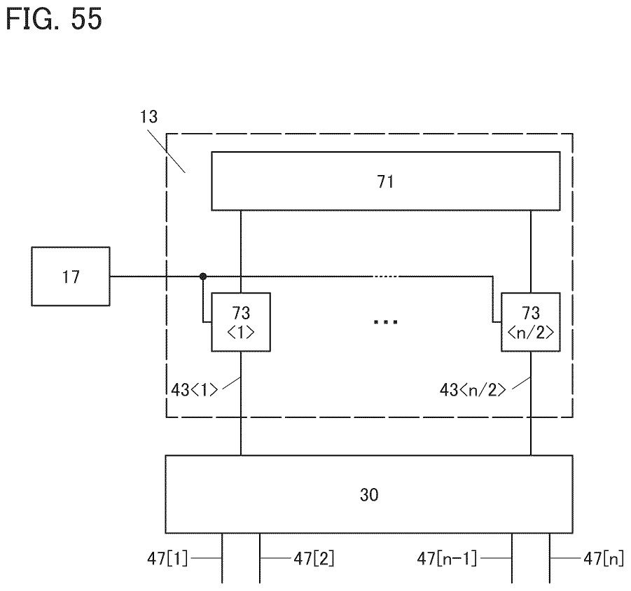

FIG. 55 is a block diagram illustrating a structure example of the signal line driver circuit 13 illustrated in FIG. 1. Note that FIG. 55 also illustrates the demultiplexer circuit group 30 to show the connection relationship.

The signal line driver circuit 13 includes a shift register circuit 71 and a latch circuit 73<1> to a latch circuit 73<n/2>. That is, the signal line driver circuit 13 can include the same number of latch circuits 73 as the demultiplexer circuits 31 provided in the demultiplexer circuit group 30.

The latch circuit 73<1> to the latch circuit 73<n/2> are electrically connected to a circuit 17 provided outside the signal line driver circuit 13. Note that the circuit 17 may be included in the signal line driver circuit 13. The latch circuit 73 is electrically connected to the demultiplexer circuit group 30 through the wiring 43.

The circuit 17 has a function of an interface that receives image data from the outside of the display apparatus 10 illustrated in FIG. 1. Note that the circuit 17 may generate image data.

The image data output from the circuit 17 is supplied to the latch circuit 73<1> to the latch circuit 73<n/2>. The shift register circuit 71 has a function of generating a signal for controlling driving of the latch circuit 73. For example, when a start pulse is supplied to the shift register circuit 71, signals for controlling driving of the latch circuit 73<1> to the latch circuit 73<n/2> are sequentially output.

The latch circuit 73 has a function of retaining or outputting image data output from the circuit 17. Whether the latch circuit 73 retains or outputs image data is determined on the basis of a signal supplied to the latch circuit 73 from the register circuit 71.

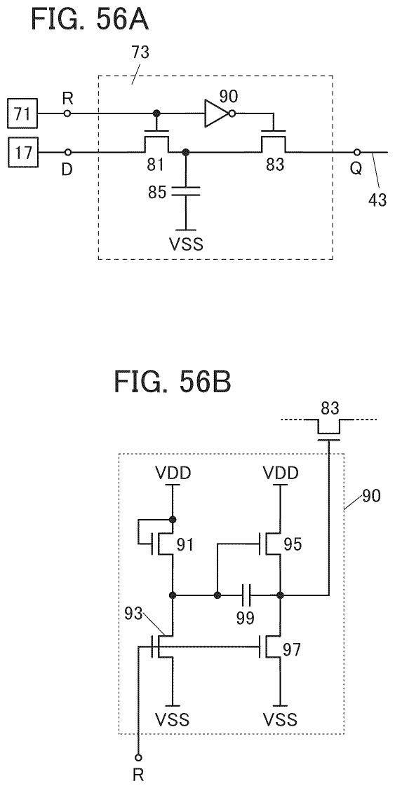

FIG. 56A is a circuit diagram illustrating a structure example of the latch circuit 73. Note that FIG. 56A also illustrates the circuit 17 and the shift register circuit 71 to show the connection relationship.

In this specification and the like, a circuit diagram does not illustrate all the components of a circuit in some cases. For example, the circuit may include a buffer amplifier in addition to the components illustrated in the circuit diagram.

The latch circuit 73 is electrically connected to a terminal R, a terminal D, and a terminal Q. The terminal R is electrically connected to an output terminal of the shift register circuit 71. The terminal D is electrically connected to an output terminal of the circuit 17. The terminal Q is electrically connected to the wiring 43. For the latch circuit 73, the terminal R and the terminal D are input terminals and the terminal Q is an output terminal.

The latch circuit 73 includes a transistor 81, a transistor 83, a capacitor 85, and an inverter circuit 90.

A gate of the transistor 81 and an input terminal of the inverter circuit 90 are electrically connected to the terminal R. One of a source and a drain of the transistor 81 is electrically connected to the terminal D. The other of the source and the drain of the transistor 81 is electrically connected to one of a source and a drain of the transistor 83. One of the source and the drain of the transistor 83 is electrically connected to one electrode of the capacitor 85. The other of the source and the drain of the transistor 83 is electrically connected to the terminal Q. A potential VSS can be supplied to the other electrode of the capacitor 85.

In this specification and the like, the potential VSS can be referred to as a low power supply potential or a low potential. A potential VDD can be referred to as a high power supply potential or a high potential.

As illustrated in FIG. 56A, the on state and the off state of each of the transistor 81 and the transistor 83 are switched in response to a signal input to the terminal R. For example, when a signal corresponding to the logic value “1” is input to the terminal R, the transistor 81 is turned on and the transistor 83 is turned off. As another example, when a signal corresponding to the logic value “0” is input to the terminal R, the transistor 81 is turned off and the transistor 83 is turned on.

When a signal corresponding to the logic value “1” is input to the terminal R, a potential representing image data input from the circuit 17 to the terminal D is retained by the capacitor 85. Thus, image data is retained in the latch circuit 73.

Next, when a signal corresponding to the logic value “0” is input to the terminal R, the transistor 81 is turned off and the transistor 83 is turned on. Accordingly, the potential retained in the capacitor 85 is output from the terminal Q. Thus, the image data is output from the latch circuit 73.

In the above manner, driving of the latch circuit 73 can be controlled by the signal input to the terminal R. As described above, the terminal R is electrically connected to the output terminal of the shift register circuit 71. Thus, the shift register circuit 71 can control driving of the latch circuit 73.

The transistor 81 and the transistor 83 are preferably OS transistors. In particular, a metal oxide containing at least one of indium, the element M (the element M is aluminum, gallium, yttrium, or tin), and zinc in a channel formation region is preferably used for an OS transistor. The use of such an OS transistor as the transistor 81 and the transistor 83 enables the off-state current of the transistor 81 and the transistor 83 to be extremely low. This can inhibit leakage of a potential retained in the capacitor 85. Thus, image data retained in the latch circuit 73 can be analog data. Note that the latch circuit 73 may retain digital data. In this case, the signal line driver circuit 13 includes a digital-analog converter circuit (a D/A converter circuit), converts digital data output from the latch circuit 73 into analog data by the D/A converter circuit, and then the analog data is supplied to the demultiplexer circuit group 30.

Here, the transistor 81 preferably has a structure similar to that applicable to the above-described transistor 33, in which case the transistor 81 can be miniaturized. The transistor 83 may be an OS transistor and may have a structure similar to that applicable to the above-described transistor 33, for example.

FIG. 56B illustrates a structure example of the inverter circuit 90. The inverter circuit 90 includes a transistor 93, a transistor 91, a transistor 97, a transistor 95, and a capacitor 99.

The potential VDD can be supplied to one of a source and a drain of the transistor 91, a gate of the transistor 91, and one of a source and a drain of the transistor 95 in the latch circuit 73. The other of the source and the drain of the transistor 91 is electrically connected to one of a source and a drain of the transistor 93. The one of the source and the drain of the transistor 93 is electrically connected to a gate of the transistor 95. The other of the source and the drain of the transistor 95 is electrically connected to one electrode of the capacitor 99. The gate of the transistor 95 is electrically connected to the other electrode of the capacitor 99. The one electrode of the capacitor 99 is electrically connected to one of a source and a drain of the transistor 97. The one of the source and the drain of the transistor 97 is electrically connected to a gate of the transistor 83. The potentials VSS can be supplied to the other of the source and the drain of the transistor 93 and the other of the source and the drain of the transistor 97. A gate of the transistor 93 and a gate of the transistor 97 are electrically connected to the terminal R.

The transistors included in the latch circuit 73 can be transistors having the same polarity, and can be n-channel transistors, for example. Thus, all the transistors included in the latch circuit 73 can be transistors of the same kind. For example, all the transistors included in the latch circuit 73 can be OS transistors. For example, all the transistors included in the latch circuit 73 can have a structure similar to that applicable to the above-described transistor 33.

When all the transistors included in the latch circuit 73 are transistors of the same kind, all the transistors included in the latch circuit 73 can be manufactured in the same step. Thus, the manufacturing process of the latch circuit 73 can be simplified as compared with the case where the latch circuit 73 includes two or more kinds of transistors. In addition, when all the transistors included in the latch circuit 73 have a structure similar to that applicable to the above-described transistor 33, the latch circuit 73 can be miniaturized.

Note that the transistor included in the latch circuit 73 does not necessarily have a structure similar to that applicable to the above-described transistor 33. For example, at least one of the transistor 81, the transistor 83, the transistor 91, the transistor 93, the transistor 95, and the transistor 97 may have a structure where neither the opening 121 nor the opening 123 is included and specifically may be a planar transistor. Here, in the case where at least one of the transistor 81, the transistor 83, the transistor 91, the transistor 93, the transistor 95, and the transistor 97 has a structure similar to that applicable to the above-described transistor 33, the transistor 33 included in the demultiplexer circuit group 30 may have a structure where neither the opening 121 nor the opening 123 is included, for example.

At least one of the transistor 91, the transistor 93, the transistor 95, and the transistor 97 included in the inverter circuit 90 is not necessarily an OS transistor, and may be a Si transistor, for example. One or both of the transistor 81 and the transistor 83 are also not necessarily OS transistors and may be Si transistors, for example.

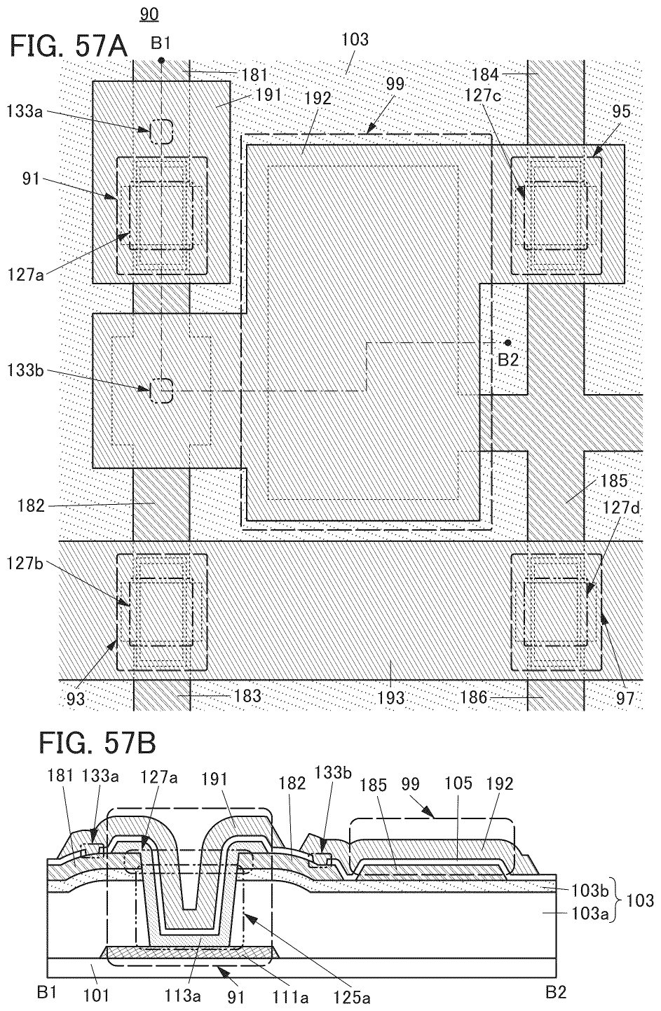

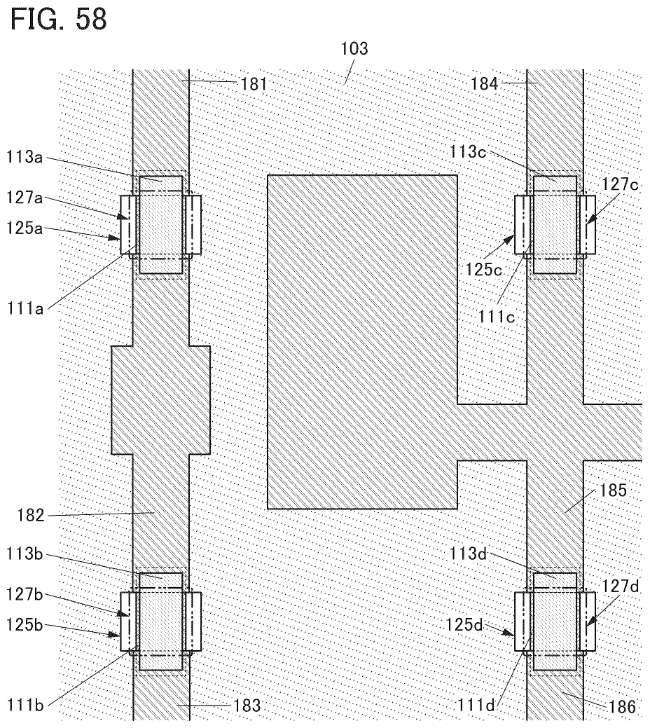

FIG. 57A is a plan view illustrating a structure example of the inverter circuit 90. FIG. 57B is a cross-sectional view taken along dashed-dotted line B1-B2 in FIG. 57A, and illustrates structure examples of the transistor 91 and the capacitor 99. In the example illustrated in FIG. 57A and FIG. 57B, the structures of the transistor 91, the transistor 93, the transistor 95, and the transistor 97 are each similar to the structure of the transistor 33 illustrated in FIG. 2A1 and FIG. 2B. FIG. 58 is a plan view omitting, from the components illustrated in FIG. 57A, a conductive layer functioning as the gate electrode of at least one of the transistor 91, the transistor 93, the transistor 95, and the transistor 97 and a conductive layer that can be formed in the same step as the conductive layer.

The transistor 91 includes a conductive layer 111a, a conductive layer 181, a conductive layer 182, a semiconductor layer 113a, the insulating layer 105, and a conductive layer 191. An opening 125a reaching the conductive layer 111a is provided in the insulating layer 103, and the conductive layer 181 and the conductive layer 182 are separated by an opening 127a. Here, the conductive layer 111a, the conductive layer 181, the conductive layer 182, the semiconductor layer 113a, the conductive layer 191, the opening 125a, and the opening 127a correspond to the conductive layer 111, the conductive layer 112a, the conductive layer 112b, the semiconductor layer 113, the conductive layer 115, the opening 121, and the opening 123 illustrated in FIG. 2A1 and FIG. 2B, respectively.

The transistor 93 includes a conductive layer 111b, the conductive layer 182, a conductive layer 183, a semiconductor layer 113b, the insulating layer 105, and a conductive layer 193. An opening 125b reaching the conductive layer 111b is provided in the insulating layer 103, and the conductive layer 182 and the conductive layer 183 are separated by an opening 127b. Here, the conductive layer 111b, the conductive layer 182, the conductive layer 183, the semiconductor layer 113b, the conductive layer 193, the opening 125b, and the opening 127b correspond to the conductive layer 111, the conductive layer 112a, the conductive layer 112b, the semiconductor layer 113, the conductive layer 115, the opening 121, and the opening 123 illustrated in FIG. 2A1 and FIG. 2B, respectively.

The transistor 95 includes a conductive layer 111c, a conductive layer 184, a conductive layer 185, a semiconductor layer 113c, the insulating layer 105, and the conductive layer 192. An opening 125c reaching the conductive layer 111c is provided in the insulating layer 103, and the conductive layer 184 and the conductive layer 185 are separated by an opening 127c. Here, the conductive layer 111c, the conductive layer 184, the conductive layer 185, the semiconductor layer 113c, the conductive layer 192, the opening 125c, and the opening 127c correspond to the conductive layer 111, the conductive layer 112a, the conductive layer 112b, the semiconductor layer 113, the conductive layer 115, the opening 121, and the opening 123 illustrated in FIG. 2A1 and FIG. 2B, respectively.

The transistor 97 includes a conductive layer 111d, the conductive layer 185, a conductive layer 186, a semiconductor layer 113d, the insulating layer 105, and the conductive layer 193. An opening 125d reaching the conductive layer 111d is provided in the insulating layer 103, and the conductive layer 185 and the conductive layer 186 are separated by an opening 127d. Here, the conductive layer 111d, the conductive layer 185, the conductive layer 186, the semiconductor layer 113d, the conductive layer 193, the opening 125d, and the opening 127d correspond to the conductive layer 111, the conductive layer 112a, the conductive layer 112b, the semiconductor layer 113, the conductive layer 115, the opening 121, and the opening 123 illustrated in FIG. 2A1 and FIG. 2B, respectively.

The capacitor 99 includes the conductive layer 185 over the insulating layer 103, the insulating layer 105 over the conductive layer 185, and the conductive layer 192 that is provided over the insulating layer 105 and includes a region overlapping with the conductive layer 185.

Thus, the conductive layer 181 has a function of one of the source electrode and the drain electrode of the transistor 91. The conductive layer 182 functions as the other of the source electrode and the drain electrode of the transistor 91 and one of the source electrode and the drain electrode of the transistor 93. The conductive layer 183 functions as the other of the source electrode and the drain electrode of the transistor 93. The conductive layer 184 functions as one of the source electrode and the drain electrode of the transistor 95. The conductive layer 185 functions as the other of the source electrode and the drain electrode of the transistor 95, one of the source electrode and the drain electrode of the transistor 97, and one electrode of the capacitor 99. The conductive layer 186 functions as the other of the source electrode and the drain electrode of the transistor 97.

The conductive layer 191 functions as the gate electrode of the transistor 91. The conductive layer 192 functions as the gate electrode of the transistor 95 and the other electrode of the capacitor 99. The conductive layer 193 functions as the gate electrode of the transistor 93 and the gate electrode of the transistor 97. Note that FIG. 58 is a plan view omitting the conductive layer 191, the conductive layer 192, and the conductive layer 193 from the components illustrated in FIG. 57A.

The conductive layer 181 to the conductive layer 186 can contain the same material and can be formed in the same step. The conductive layer 191 to the conductive layer 193 can contain the same material and can be formed in the same step.

In the inverter circuit 90 illustrated in FIG. 57A and FIG. 57B, the insulating layer 105 includes an opening 133a reaching the conductive layer 181 and an opening 133b reaching the conductive layer 182. The conductive layer 191 functioning as the gate electrode of the transistor 91 includes a region in contact with the conductive layer 181 functioning as one of the source electrode and the drain electrode of the transistor 91 in the opening 133a. Thus, the one of the source and the drain of the transistor 91 is electrically connected to the gate of the transistor 91. The conductive layer 192 functioning as the other electrode of the capacitor 99 includes a region in contact with the conductive layer 182 functioning as the other of the source electrode and the drain electrode of the transistor 91 in the opening 133b. Thus, the other of the source and the drain of the transistor 91 is electrically connected to the other electrode of the capacitor 99.

Although the shape of the opening 133a and the shape of the opening 133b are rectangular shapes with rounded corners in FIG. 57A, one embodiment of the present invention is not limited thereto, and the opening 133a and the opening 133b can have a shape similar to the above-described shape that the opening 121 or the opening 123 can have.

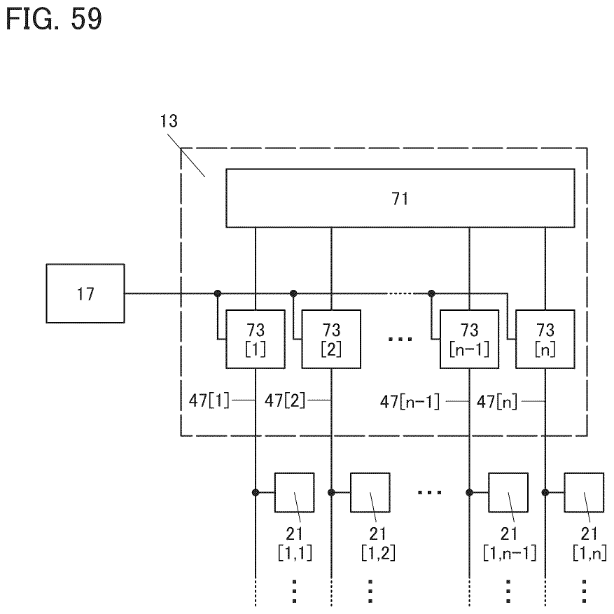

FIG. 59 illustrates a variation example of the structure illustrated in FIG. 55, in which the latch circuit 73 is electrically connected to the pixel 21 through the wiring 47. The display apparatus having the structure illustrated in FIG. 59 is not provided with the demultiplexer circuit group 30. The signal line driver circuit 13 illustrated in FIG. 59 includes the shift register circuit 71 and a latch circuit 73[1] to a latch circuit 73[n]. That is, in the case where the display apparatus is not provided with the demultiplexer circuit group 30, the signal line driver circuit 13 can include the same number of latch circuits 73 as the columns of the pixels 21.

In the case where the display apparatus of one embodiment of the present invention does not include the demultiplexer circuit group 30, the display apparatus of one embodiment of the present invention can be driven at high speed. Thus, the frame frequency of the display apparatus of one embodiment of the present invention can be increased. Furthermore, at the same frame frequency, the power consumption of the display apparatus of one embodiment of the present invention can be reduced.

Note that a transistor provided in a circuit other than the latch circuit 73 included in the signal line driver circuit 13 may have a structure similar to that applicable to the above-described transistor 33. The transistor included in the circuit 17 illustrated in FIG. 55 may have a structure similar to that applicable to the above-described transistor 33. The transistor included in the control circuit 15 illustrated in FIG. 1 may have a structure similar to that applicable to the above-described transistor 33. The transistor included in the scan line driver circuit 11 may have a structure similar to that applicable to the above-described transistor 33. A transistor included in a circuit not illustrated in FIG. 1, such as a protection circuit, may have a structure similar to that applicable to the above-described transistor 33.

### <Structure Example 4 of Display Apparatus>

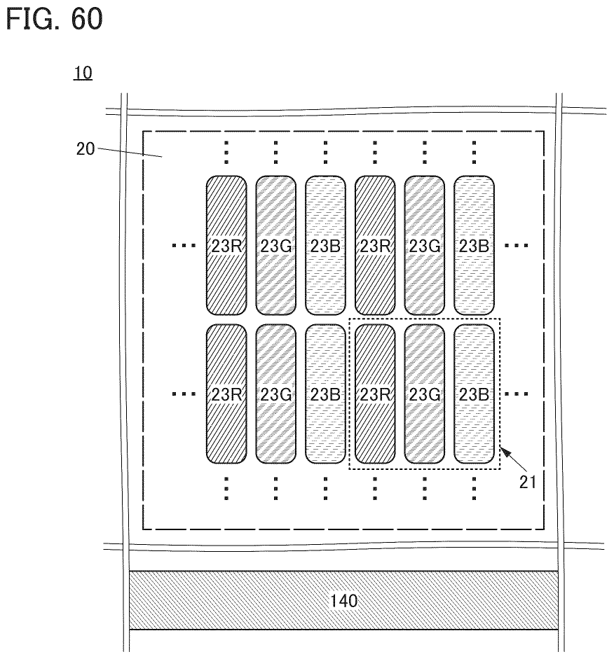

FIG. 60 is a plan view illustrating a structure example of display apparatus 10. As described above, the display apparatus 10 includes the display portion 20, and the pixels 21 are arranged in a matrix in the display portion 20. The pixels 21 each include a plurality of subpixels. FIG. 60 illustrates the pixels 21 in two rows and two columns. As the structure where the pixels 21 each include three subpixels (a subpixel 23R, a subpixel 23G, and a subpixel 23B), the subpixels in two rows and six columns are illustrated. A connection portion 140 is provided outside the display portion 20.

Each of the subpixels includes a display element. Examples of the display element include a light-emitting element and a liquid crystal element (also referred to as a liquid crystal device). As the light-emitting element, an OLED (Organic Light Emitting Diode) or a QLED (Quantum-dot Light Emitting Diode) is preferably used, for example. Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material). An LED such as a micro-LED (Light Emitting Diode) can also be used as the light-emitting element.

The emission color of the light-emitting element can be infrared, red, green, blue, cyan, magenta, yellow, white, or the like. When the light-emitting element has a microcavity structure, the color purity can be increased.

In the following description, a structure where a light-emitting element is used as the display element is given as an example.

The display apparatus of one embodiment of the present invention includes light-emitting elements of different colors, which are separately formed, and can perform full-color display.

Planar shapes of the subpixels illustrated in FIG. 60 correspond to planar shapes of light-emitting regions of the light-emitting elements. Embodiment 2 can be referred to for an example of the planar shape of the subpixel, arrangement of the subpixels, and the like.

The subpixels each include a pixel circuit that controls the light-emitting element. The pixel circuit is not necessarily placed within the range of the subpixel illustrated in FIG. 60 and may be placed outside the subpixel. For example, transistors included in the pixel circuit of the subpixel 23R may be positioned within the range of the subpixel 23G illustrated in FIG. 60, or some or all of the transistors may be positioned outside the range of the subpixel 23R.

Although FIG. 60 illustrates the subpixel 23R, the subpixel 23G, and the subpixel 23B that have the same or substantially the same aperture ratio (also referred to as size or size of a light-emitting region), one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixel 23R, the subpixel 23G, and the subpixel 23B may have the same or substantially the same aperture ratio.

The pixels 21 illustrated in FIG. 60 employ stripe arrangement. The pixel 21 illustrated in FIG. 60 is composed of three subpixels: the subpixel 23R, the subpixel 23G, and the subpixel 23B. The subpixel 23R, the subpixel 23G, and the subpixel 23B emit light of different colors. The subpixel 23R, the subpixel 23G, and the subpixel 23B are subpixels of three colors of red (R), green (G), and blue (B) or subpixels of three colors of yellow (Y), cyan (C), and magenta (M), for example. The number of types of subpixels is not limited to three, and may be four or more. Examples of four subpixels include subpixels of four colors of R, G, B, and white (W), subpixels of four colors of R, G, B, and Y, and subpixels of four types of R, G, B, and infrared light (IR).

Although FIG. 60 illustrates an example where the connection portion 140 is positioned on the lower side of the display portion in the plan view, there is no particular limitation on the position of the connection portion 140. The connection portion 140 is provided in at least one of the upper side, the right side, the left side, and the lower side of the display portion in the plan view, and may be provided to surround the four sides of the display portion. The planar shape of the connection portion 140 is not particularly limited and can be a belt-like shape, an L shape, a U shape, a frame-like shape, or the like. The number of the connection portions 140 can be one or more.

Note that a sensor may be provided in the display portion 20. For example, the display portion 20 may have a function of a fingerprint sensor. For example, the display portion 20 may have a function of an ultrasonic fingerprint sensor.

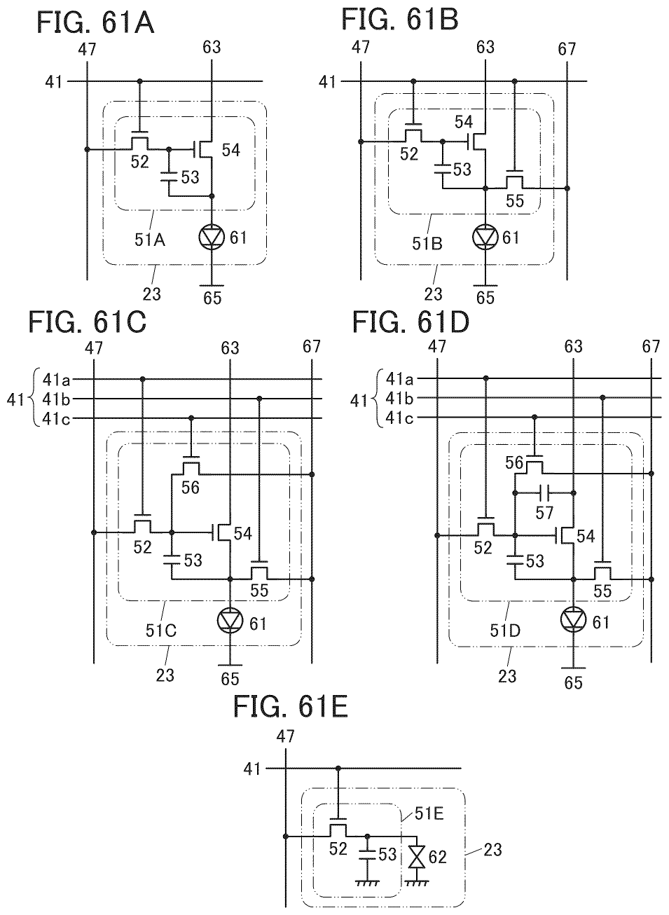

FIG. 61A to FIG. 61E are circuit diagrams illustrating structure examples of the subpixel 23 (e.g., the subpixel 23R, the subpixel 23G, or the subpixel 23B). The subpixel 23 includes a pixel circuit 51 (a pixel circuit 51A, a pixel circuit 51B, a pixel circuit 51C, a pixel circuit 51D, or a pixel circuit 51E) and the display element. FIG. 61A to FIG. 61D each illustrate an example where a light-emitting element 61 is included as the display element, and FIG. 61E illustrates an example where a liquid crystal element 62 is included as the display element.

The pixel circuit 51A illustrated in FIG. 61A is a 2Tr1C-type pixel circuit including a transistor 52, a capacitor 53, and a transistor 54.

In the pixel circuit 51A, one of a source and a drain of the transistor 52 is electrically connected to the wiring 47. The other of the source and the drain of the transistor 52 is electrically connected to a gate of the transistor 54. A gate of the transistor 52 is electrically connected to the wiring 41.

One of a source and a drain of the transistor 54 is electrically connected to a wiring 63. The other of the source and the drain of the transistor 54 is electrically connected to one electrode of the light-emitting element 61. The gate of the transistor 54 is electrically connected to one electrode of the capacitor 53. The one electrode of the light-emitting element 61 is electrically connected to the other electrode of the capacitor 53. The other electrode of the light-emitting element 61 is electrically connected to the wiring 65.

As described above, the wiring 41 functions as a scan line, and the wiring 47 functions as a signal line. The wiring 65 is a wiring supplying a potential for supplying a current to the light-emitting element 61. The transistor 52 has a function of a switch and has a function of controlling the conduction state or the non-conduction state between the wiring 47 and the gate of the transistor 54 on the basis of the potential of the wiring 41. For example, a high power supply potential is supplied to the wiring 63, and a low power supply potential is supplied to the wiring 65. The wiring 63 and the wiring 65 each function as a power supply line.

The transistor 54 has a function of controlling the amount of current flowing through the light-emitting element 61. The capacitor 53 has a function of retaining a gate potential of the transistor 54. The intensity of light emitted by the light-emitting element 61 is controlled in accordance with a potential corresponding to image data supplied to the gate of the transistor 54.

The pixel circuit 51B illustrated in FIG. 61B has a structure where a transistor 55 is added to the pixel circuit 51A. The pixel circuit 51B is a 3Tr1C-type pixel circuit.

One of a source and a drain of the transistor 55 is electrically connected to the one of the source and the drain of the transistor 54, the other electrode of the capacitor 53, and the one electrode of the light-emitting element 61. The other of the source and the drain of the transistor 55 is electrically connected to a wiring 67. A gate of the transistor 55 is electrically connected to the wiring 41.

The transistor 55 has a function of a switch and has a function of controlling the conduction state or the non-conduction state between the wiring 67 and the one of the source and the drain of the transistor 54 on the basis of the potential of the wiring 41. A reference potential is supplied to the wiring 67, for example. Variations in the gate-source voltage of the transistor 54 can be reduced by the reference potential of the wiring 67 supplied through the transistor 55.

The wiring 67 can function as a monitor line for outputting current flowing through the transistor 54 or current flowing through the light-emitting element 61 to the outside. A current output to the wiring 67 can be converted into a voltage by, for example, a source follower circuit and output to the outside. Alternatively, the current can be converted into a digital signal by an A/D converter or the like, and can be output to the outside.

The pixel circuit 51C illustrated in FIG. 61C has a structure where a transistor 56 is added to the pixel circuit 51B. The pixel circuit 51C is a 4Tr1C-type pixel circuit.

One of a source and a drain of the transistor 56 is electrically connected to the one of the source and the drain of the transistor 52, the one electrode of the capacitor 53, and the gate of the transistor 54. The other of the source and the drain of the transistor 56 is electrically connected to the wiring 67.

As the wiring 41, a wiring 41a, a wiring 41b, and a wiring 41c are electrically connected to the pixel circuit 51C. The wiring 41a is electrically connected to the gate of the transistor 52. The wiring 41b is electrically connected to the gate of the transistor 55. The wiring 41c is electrically connected to a gate of the transistor 56. The transistor 56 has a function of a switch and has a function of controlling the conduction state or the non-conduction state between the wiring 67 and the gate of the transistor 54 on the basis of the potential of the wiring 41c.

When the transistor 55 and the transistor 56 are turned on, the source and the gate of the transistor 54 have the same potential, so that the transistor 54 can be brought into a non-conduction state. Thus, current flowing to the light-emitting element 61 can be blocked forcibly. Such a pixel circuit is suitable for the case of using a display method in which a display period and a non-lighting period are alternately provided.

The pixel circuit 51D illustrated in FIG. 61D has a structure where a capacitor 57 is added to the pixel circuit 51C. The pixel circuit 51D is a 4Tr2C-type pixel circuit.

One electrode of the capacitor 57 is electrically connected to the one of the source and the drain of the transistor 52, the one electrode of the capacitor 53, the gate of the transistor 54, and the one of the source and the drain of the transistor 56. The other electrode of the capacitor 57 is electrically connected to the wiring 63.

The pixel circuit 51E illustrated in FIG. 61E is a 1Tr1C-type pixel circuit including the transistor 52 and the capacitor 53.

In the pixel circuit 51E, the one of the source and the drain of the transistor 52 is electrically connected to the one electrode of the capacitor 53 and one electrode of the liquid crystal element 62. The other of the source and the drain of the transistor 52 is electrically connected to the wiring 47. The gate of the transistor 52 is electrically connected to the wiring 41.

In the pixel circuit 51E, the transistor 52 has a function of a switch and has a function of controlling the conduction state or the non-conduction state between the wiring 47 and the one electrode of the liquid crystal element 62 on the basis of the potential of the wiring 41. The capacitor 53 has a function of retaining the potential of the one electrode of the liquid crystal element 62. The alignment state of the liquid crystal element 62 is controlled in accordance with a potential that corresponds to image data and is supplied to the one electrode of the liquid crystal element 62.

As a mode for the liquid crystal element 62, for example, a TN mode, an STN mode, a VA mode, an ASM (Axially Symmetric Aligned Micro-cell) mode, an OCB (Optically Compensated Birefringence) mode, an FLC (Ferroelectric Liquid Crystal) mode, an AFLC (AntiFerroelectric Liquid Crystal) mode, an MVA mode, a PVA (Patterned Vertical Alignment) mode, an IPS mode, an FFS mode, a TBA (Transverse Bend Alignment) mode, or the like may be used. Other examples include an ECB (Electrically Controlled Birefringence) mode, a PDLC (Polymer Dispersed Liquid Crystal) mode, a PNLC (Polymer Network Liquid Crystal) mode, a guest-host mode, and the like. However, the mode is not limited thereto, and a variety of modes can be used.

Note that the liquid crystal element is an element that controls the transmission and non-transmission of light utilizing an optical modulation action of a liquid crystal. The optical modulation action of the liquid crystal is controlled by an electric field applied to the liquid crystal (including a horizontal electric field, a vertical electric field, and an oblique electric field). Examples of the liquid crystal used for the liquid crystal element include a thermotropic liquid crystal, a low-molecular liquid crystal, a high-molecular liquid crystal, a polymer dispersed liquid crystal (PDLC), a ferroelectric liquid crystal, and an anti-ferroelectric liquid crystal. Such a liquid crystal material exhibits a cholesteric phase, a smectic phase, a cubic phase, a chiral nematic phase, an isotropic phase, or the like depending on conditions.

The transistor 52, the transistor 54, the transistor 55, and the transistor 56 preferably have structures similar to that applicable to the above-described transistor 33. In that case, the on-state current of the transistor included in the subpixel 23 can be increased, so that the display apparatus can be driven at high speed.

Note that the transistor 52, the transistor 54, the transistor 55, and the transistor 56 do not necessarily have the structures similar to that applicable to the transistor 33. For example, at least one of the transistor 52, the transistor 54, the transistor 55, and the transistor 56 may have a structure where neither the opening 121 nor the opening 123 is included and specifically may be a planar transistor. Here, in the case where at least one of the transistor 52, the transistor 54, the transistor 55, and the transistor 56 has a structure similar to that applicable to the above-described transistor 33, the transistor 33 included in the demultiplexer circuit group 30 may have a structure where neither the opening 121 nor the opening 123 is included, for example. Alternatively, the display apparatus 10 does not necessarily include the demultiplexer circuit group 30, as illustrated in FIG. 59.

The transistor 52 and the transistor 56 are preferably OS transistors. Since the OS transistor has an extremely low off-state current as described above, charge accumulated in the capacitor 53 electrically connected to one of the source and the drain of the transistor 52 can be retained for a long time. In that case, the frequency of a refresh operation can be low as compared with the case where a transistor with a high off-state current is used as the transistor 52. Thus, power consumption of the display apparatus 10 can be reduced.

The transistor 54 and the transistor 55 may be OS transistors and are not necessarily OS transistors. The transistor 54 and the transistor 55 may be Si transistors, for example. The transistor 52 and the transistor 56 are not necessarily OS transistors and may be Si transistors, for example.

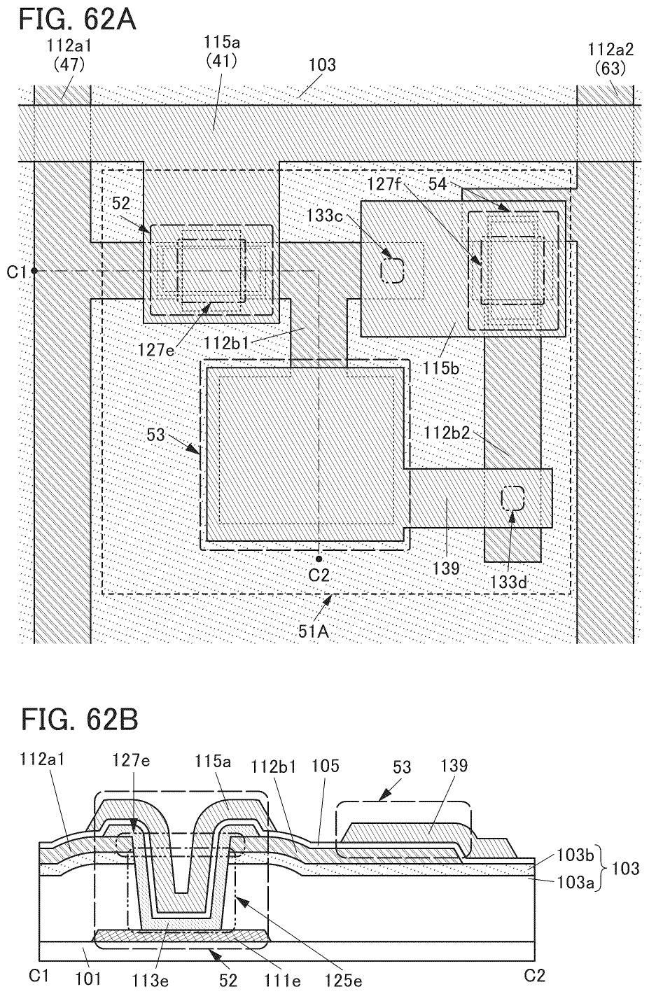

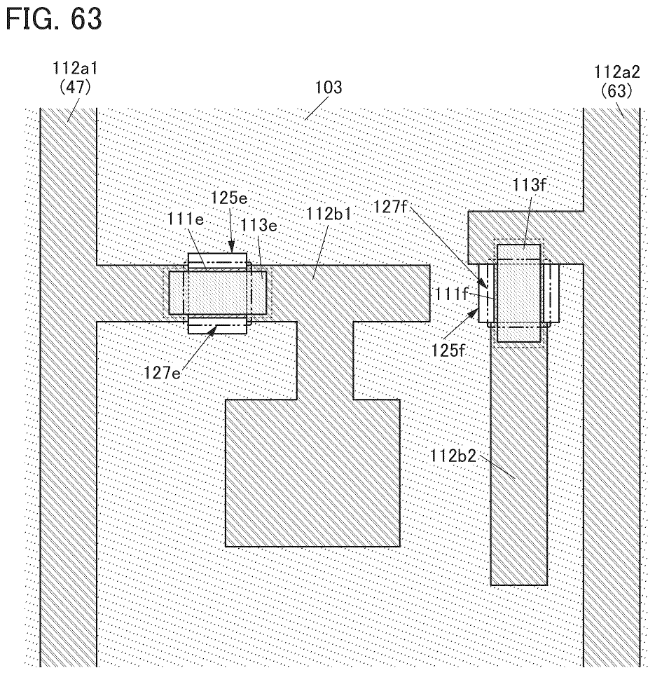

FIG. 62A is a plan view illustrating a structure example of the pixel circuit 51A. FIG. 62B is a cross-sectional view taken along dashed-dotted line C1-C2 in FIG. 62A and illustrates a structure example of the transistor 52, the capacitor 53, and the like. In the example illustrated in FIG. 62A and FIG. 62B, the structure of the transistor 52 and the structure of the transistor 54 are similar to that illustrated in FIG. 2A1 and FIG. 2B. FIG. 63 is a plan view omitting the conductive layer 115 and the conductive layer that can be formed in the same step as the conductive layer 115 from the components illustrated in FIG. 62A.

Here, the conductive layer 111, the conductive layer 112a, the conductive layer 112b, the semiconductor layer 113, and the conductive layer 115 included in the transistor 52 are a conductive layer 111e, a conductive layer 112a1, a conductive layer 112b1, a semiconductor layer 113e, and a conductive layer 115a, respectively. The conductive layer 111, the conductive layer 112a, the conductive layer 112b, the semiconductor layer 113, and the conductive layer 115 included in the transistor 54 are a conductive layer 111f, a conductive layer 112a2, a conductive layer 112b2, a semiconductor layer 113f, and a conductive layer 115b, respectively.

An opening 125e reaching the conductive layer 111e and an opening 125f reaching the conductive layer 111f are provided in the insulating layer 103. The conductive layer 112al and the conductive layer 112b1 are separated by an opening 127e, and the conductive layer 112a2 and the conductive layer 112b2 are separated by an opening 127f. Here, the opening 125e and the opening 125f correspond to the opening 121 illustrated in FIG. 2A1 and FIG. 2B, and the opening 127e and the opening 127f correspond to the opening 123 illustrated in FIG. 2A1 and FIG. 2B.

The capacitor 53 includes the conductive layer 112b1 over the insulating layer 103, the insulating layer 105 over the conductive layer 112b1, and a conductive layer 139 that is provided over the insulating layer 105 and includes a region overlapping with the conductive layer 112b1. The conductive layer 139 can be formed using the same material and be formed in the same step as the conductive layer 115a and the conductive layer 115b.

In the pixel circuit 51A illustrated in FIG. 62A and FIG. 62B, the insulating layer 105 includes an opening 133c reaching the conductive layer 112b1 and an opening 133d reaching the conductive layer 112b2. The conductive layer 115b functioning as the gate electrode of the transistor 54 includes a region in contact with the conductive layer 112b1 functioning as the other of the source electrode and the drain electrode of the transistor 52 and the one electrode of the capacitor 53 in the opening 133c. Thus, the gate of the transistor 54 is electrically connected to the other of the source and the drain of the transistor 52 and the one electrode of the capacitor 53. The conductive layer 112b2 functioning as the other of the source electrode and the drain electrode of the transistor 54 includes a region in contact with the conductive layer 139 functioning as the other electrode of the capacitor 53 in the opening 133d. Thus, the other of the source and the drain of the transistor 54 is electrically connected to the other electrode of the capacitor 53.

Although the shapes of the opening 133c and the opening 133d are rectangular shapes with rounded corners in FIG. 62A, one embodiment of the present invention is not limited thereto, and the opening 133c and the opening 133d can have a shape similar to the above-described shape that the opening 121 or the opening 123 can have.

The conductive layer 112al functions as the wiring 47 functioning as a signal line. The conductive layer 115a functions as the wiring 41 functioning as a scan line. The conductive layer 112a2 functions as the wiring 63 functioning as a power supply line.

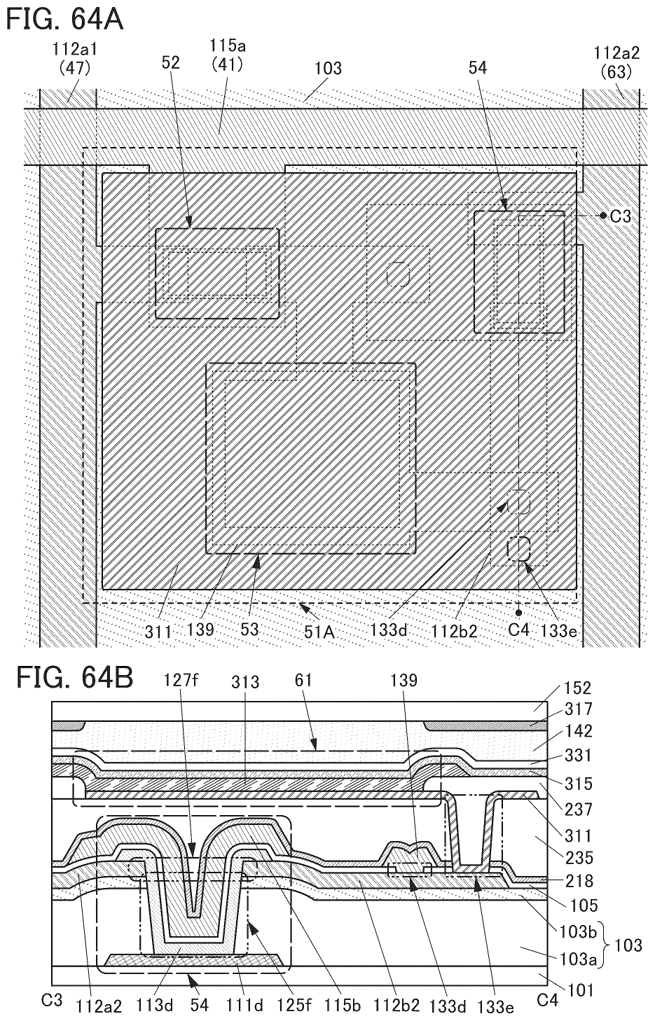

FIG. 64A illustrates a structure example where the pixel electrode 311 of the light-emitting element 61 is added to the plan view in FIG. 62A. FIG. 64B is a cross-sectional view taken along dashed-dotted line C3-C4 in FIG. 64A and illustrates a structure example of the transistor 54, for example. FIG. 64B also illustrates a structure example of layers above the transistor 54, for example. Note that some of the reference numerals illustrated in FIG. 63A are omitted in FIG. 64A and FIG. 64B.

An insulating layer 218 and an insulating layer 235 over the insulating layer 218 are provided to cover the transistor 52, the capacitor 53, and the transistor 54. The light-emitting element 61 is provided over the insulating layer 235, and a protective layer 331 is provided to cover the light-emitting element 61. A substrate 152 is attached onto the protective layer 331 with an adhesive layer 142.

The light-emitting element 61 includes the pixel electrode 311 over the insulating layer 235, an island-shaped layer 313 over the pixel electrode 311, and the common electrode 315 over the island-shaped layer 313. The layer 313 includes at least a light-emitting layer. Note that the layer 313 can be referred to as an EL layer. The common electrode is also referred to as a counter electrode.

The insulating layer 105, the insulating layer 218, and the insulating layer 235 have an opening 133e reaching the conductive layer 112b2. The pixel electrode 311 is provided to cover the opening 133e. The pixel electrode 311 has a shape along the top surface and the side surface of the insulating layer 235, the side surface of the insulating layer 218, the side surface of the insulating layer 105, and the top surface of the conductive layer 112b2. The pixel electrode 311 includes a region in contact with the top surface and the side surface of the insulating layer 235, the side surface of the insulating layer 218, the side surface of the insulating layer 105, and the top surface of the conductive layer 112b2, for example. The pixel electrode 311 can be connected to the conductive layer 112b2 in the opening 133e.

Although the shape of the opening 133e is a rectangular shape with rounded corners in FIG. 64A, one embodiment of the present invention is not limited thereto, and the opening 133e can have a shape similar to the above-described shape that the opening 121 or the opening 123 can have.

An insulating layer 237 can be provided to cover the end portion of the top surface of the pixel electrode 311. The insulating layer 237 functions as a partition (also referred to as a bank or a spacer). Provision of the insulating layer 237 can prevent a contact between the pixel electrode 311 and the common electrode 315 to inhibit a short-circuit in the light-emitting element 61.

A depressed portion is formed in the pixel electrode 311 to cover the opening 133e, and the insulating layer 237 is embedded in the depressed portion. For example, the insulating layer 237 covering the end portion of the top surface of the pixel electrode 311 and the opening 133e is formed, and then the layer 313 can be formed with a fine metal mask (FMM).

A light-blocking layer 317 may be provided on the surface of the substrate 152 on the adhesive layer 142 side. The light-blocking layer 317 can be provided between the adjacent light-emitting elements 61. Provision of the light-blocking layer 317 can prevent color mixture by blocking light emitted from adjacent subpixels 23. Note that a structure without the light-blocking layer 317 may be employed.

Components of the display apparatus illustrated in FIG. 64B will be described below.

### <Components 2 of Display Apparatus>

### [Insulating Layer 218]

The insulating layer 218 is preferably formed using a material through which impurities are not easily diffused. In that case, the insulating layer 218 functions as a blocking film that inhibits the diffusion of impurities from the outside into the transistors. Examples of the impurities include water and hydrogen. With the insulating layer 218, the reliability of the display apparatus can be increased.

The insulating layer 218 can be an insulating layer containing an inorganic material or an insulating layer containing an organic material. For example, an inorganic material such as oxide or nitride can be suitably used for the insulating layer 218. Specifically, one or more of silicon nitride, silicon nitride oxide, silicon oxynitride, aluminum oxide, aluminum oxynitride, aluminum nitride, hafnium oxide, and hafnium aluminate can be used. For example, silicon nitride oxide can be suitably used for the insulating layer 218 because the amount of impurities (such as water and hydrogen) released from the silicon nitride oxide itself is small and a film of silicon nitride oxide can function as a blocking film that inhibits the diffusion of impurities into the transistors from above the transistors. As the organic material, for example, one or more of acrylic resins and polyimide resins can be used. As the organic material, a photosensitive material may be used. A stack including two or more of the above insulating films may also be used. The insulating layer 218 may have a stacked-layer structure of an insulating layer containing an inorganic material and an insulating layer containing an organic material.

### [Insulating Layer 235]

The insulating layer 235 has a function of reducing unevenness caused by the transistor 52, the capacitor 53, the transistor 54, and the like. In this specification and the like, the insulating layer 235 is referred to as a planarization layer in some cases.

An insulating layer containing an organic material can be suitably used as the insulating layer 235. As the organic material, a photosensitive organic resin is preferably used, and for example, a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

The insulating layer 235 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 235 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive material or a negative material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided on the outermost surface of the insulating layer 235 can function as an etching protective layer. This can inhibit a decrease in the planarity of the insulating layer 235, which is caused by etching of part of the insulating layer 235 in the formation of the pixel electrode 311.

The low planarity of the top surface of the insulating layer 235, which is the formation surface of the light-emitting element 61, may cause a defect such as a connection defect due to step disconnection of the common electrode 315 or an increase in wiring resistance due to the locally thinned regions of the common electrode 315 in some cases. In addition, the low planarity of the top surface of the insulating layer 235 may lower the processing accuracy of the layer to be formed over the insulating layer 235 in some cases. Planarizing the top surface of the insulating layer 235 increases the processing accuracy of the light-emitting element 61 provided over the insulating layer 235, whereby a high-resolution display apparatus can be provided. Furthermore, since a connection defect due to step disconnection of the common electrode 315 and an increase in wiring resistance due to the locally thinned regions of the common electrode 315 can be prevented, the display apparatus can have high display quality.

In some cases, the insulating layer 235 is partly removed when the pixel electrode 311 is formed. The insulating layer 235 may have a depressed portion in a region not overlapping with the pixel electrode 311.

### [Insulating Layer 237]

The insulating layer 237 can be an insulating layer containing an inorganic material or an insulating layer containing an organic material. A material that can be used for the insulating layer 218 or a material that can be used for the insulating layer 235 can be used for the insulating layer 237. The insulating layer 237 may have a stacked-layer structure of an insulating layer containing an inorganic material and an insulating layer containing an organic material.

### [Protective Layer 331]

The protective layer 331 may have a single-layer structure or a stacked-layer structure including two or more layers. There is no limitation on the conductivity of the protective layer 331. For the protective layer 331, at least one of an insulating film, a semiconductor film, and a conductive film can be used.

The protective layer 331 includes an inorganic film, which can inhibit oxidation of the common electrode 315 and entry of impurities (e.g., moisture and oxygen) into the light-emitting element. Accordingly, deterioration of the light-emitting element 61 can be inhibited, and the reliability of the display apparatus can be increased.

As the protective layer 331, an inorganic insulating film such as an oxide insulating film, a nitride insulating film, an oxynitride insulating film, or a nitride oxide insulating film can be used, for example. In particular, the protective layer 331 preferably includes a nitride insulating film or a nitride oxide insulating film, and further preferably includes a nitride insulating film.

As the protective layer 331, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 315. The inorganic film may further contain nitrogen.

When light emitted from the light-emitting element is extracted through the protective layer 331, the protective layer 331 preferably has a high visible-light-transmitting property. For example, ITO, IGZO, and aluminum oxide are preferable because they are inorganic materials having a high visible-light-transmitting property.

The protective layer 331 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 331 may include an organic film. For example, the protective layer 331 may include both an organic film and an inorganic film.

The protective layer 331 may have a stacked structure of two layers which are formed by different film formation methods. Specifically, the first layer of the protective layer 331 may be formed by an ALD method, and the second layer of the protective layer 331 may be formed by a sputtering method.

### [Substrate 152]

For the substrate 152, glass, quartz, ceramic, sapphire, a resin, a metal, an alloy, a semiconductor, or the like can be used. For the substrate on the side from which light from the light-emitting element is extracted, a material that transmits the light is used. When a flexible material is used for the substrate 152, the flexibility of the display apparatus can be increased. Furthermore, a polarizing plate may be used as the substrate 152. Alternatively, an attachment film or a base film may be used as the substrate 152.

For the substrate 152, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 152.

In the case where a film used as the substrate absorbs water, the shape of the display apparatus might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

A variety of optical members can be provided on the outer surface of the substrate 152. Examples of the optical members include a polarizing plate (e.g., a circularly polarizing plate), a retardation plate, a light diffusion layer (such as a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 152. For example, a glass layer or a silica layer (SiOₓ layer) is preferably provided as the surface protective layer to inhibit the surface contamination and generation of a scratch. The surface protective layer may be formed using DLC (diamond-like carbon), aluminum oxide (AlOₓ), a polyester-based material, a polycarbonate-based material, or the like. Note that the surface protective layer is preferably formed using a material having a high visible light transmittance. The surface protective layer is preferably formed using a material with high hardness.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

### [Adhesive Layer 142]

For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

### [Light-Blocking Layer 317]

Examples of a material that can be used for the light-blocking layer 317 include carbon black, an oxide semiconductor, and a composite oxide containing a solid solution of a plurality of oxide semiconductors. Stacked films containing the material of the coloring layer can also be used for the light-blocking layer. For example, a stacked-layer structure of a film containing a material used for a coloring layer that transmits light of a certain color and a film containing a material used for a coloring layer that transmits light of another color can be employed.

### <Memory Cell>

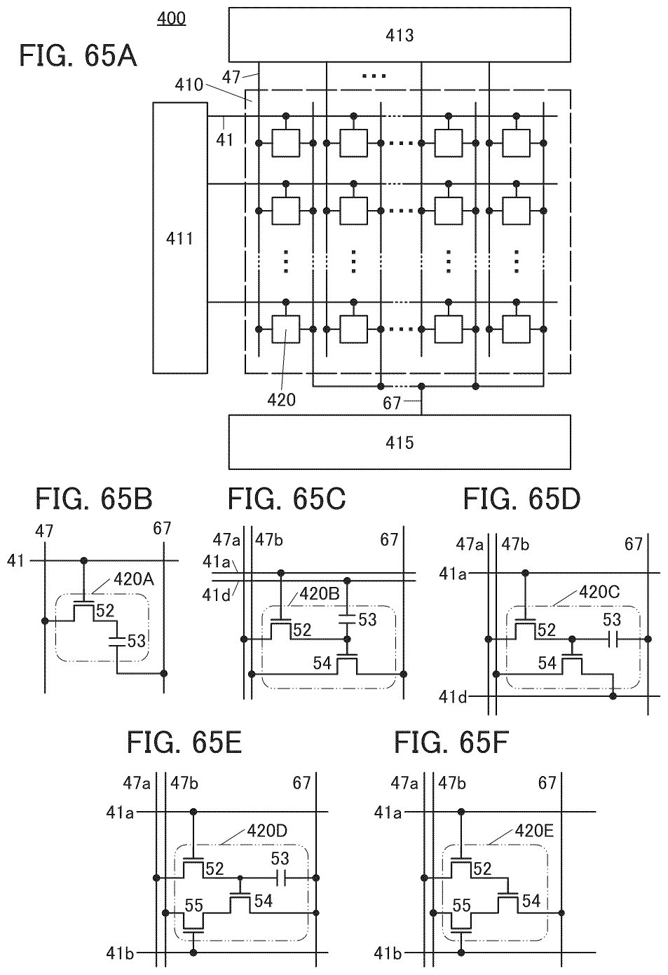

One embodiment of the present invention is applicable to not only a display apparatus but also a memory device. FIG. 65A is a block diagram illustrating a structure example of a memory device 400 to which one embodiment of the present invention can be applied. The memory device 400 includes a memory portion 410, a word line driver circuit 411, a bit line driver circuit 413, and a power supply circuit 415. The memory portion 410 includes a plurality of memory cells 420 arranged in a matrix. Note that the power supply circuit 415 may be provided outside the memory device 400.

The word line driver circuit 411 is electrically connected to the memory cells 420 through the wirings 41. As in the display apparatus 10 illustrated in FIG. 1, for example, the wiring 41 extends in the row direction of the matrix, for example. In the memory device 400, the wiring 41 functions as a word line.

The bit line driver circuit 413 is electrically connected to the memory cells 420 through the wirings 47. As in the display apparatus 10 illustrated in FIG. 1, for example, the wiring 47 extends in the column direction of the matrix, for example. In the memory device 400, the wiring 41 functions as a bit line.

The power supply circuit 415 is electrically connected to the memory cells 420 through the wiring 67. For example, all the memory cells 420 can be electrically connected to the power supply circuit 415 through the same wiring 67. The wiring 67 functions as a power supply line.

The word line driver circuit 411 has a function of selecting, row by row, the memory cells 420 to which data is to be written. The word line driver circuit 411 has a function of selecting, row by row, the memory cells 420 from which data is to be read. Specifically, by outputting a signal to the wiring 41, the word line driver circuit 411 can select the memory cell 420 to which data is to be written or the memory cell 420 from which data is to be read.

The bit line driver circuit 413 has a function of writing data through the wiring 47 to the memory cell 420 selected by the word line driver circuit 411. The bit line driver circuit 413 has a function of reading data retained in the memory cell 420 by amplifying data output from the memory cell 420 to the wiring 47 and outputting the amplified data to, for example, the outside of the memory device 400. Furthermore, the bit line driver circuit 413 has a function of precharging the wiring 47 before data is read from the memory cell 420.

The power supply circuit 415 has a function of generating a power supply potential and supplying it to the wiring 67. The power supply circuit 415 has a function of generating, for example, a high potential or a low potential and supplying it to the wiring 67.

FIG. 65B, FIG. 65C, FIG. 65D, FIG. 65E, and FIG. 65F are circuit diagrams illustrating structure examples of the memory cell 420. Here, the memory cells 420 illustrated in FIG. 65B, FIG. 65C, FIG. 65D, FIG. 65E, and FIG. 65F are a memory cell 420A, a memory cell 420B, a memory cell 420C, a memory cell 420D, and a memory cell 420E, respectively.

The memory cell 420A includes the transistor 52 and the capacitor 53. In other words, the memory cell 420A is a 1Tr1C-type memory cell.

In the memory cell 420A, one of the source and the drain of the transistor 52 is electrically connected to the wiring 47. The other of the source and the drain of the transistor 52 is electrically connected to the one electrode of the capacitor 53. The gate of the transistor 52 is electrically connected to the wiring 41. The other electrode of the capacitor 53 is electrically connected to the wiring 67.

In the memory cell 420A, when the transistor 52 is turned on, data is written to the memory cell 420A through the wiring 47, and when the transistor 52 is turned off, the written data is retained. When the transistor 52 is turned on, the data retained in the memory cell 420A can be output to the wiring 47, so that the data can be read by the bit line driver circuit 413.

The memory cell 420B includes the transistor 52, the transistor 54, and the capacitor 53. In other words, the memory cell 420B is a 2Tr1C-type memory cell.

To the memory cell 420B, the wiring 41a and a wiring 41d are electrically connected as the wiring 41 and a wiring 47a and a wiring 47b are electrically connected as the wiring 47. Specifically, one of the source and the drain of the transistor 52 is electrically connected to the wiring 47a. The other of the source and the drain of the transistor 52 is electrically connected to one electrode of the capacitor 53. The one electrode of the capacitor 53 is electrically connected to the gate of the transistor 54. The gate of the transistor 52 is electrically connected to the wiring 41a. The other electrode of the capacitor 53 is electrically connected to the wiring 41d. One of the source and the drain of the transistor 54 is electrically connected to the wiring 47b. The other of the source and the drain of the transistor 54 is electrically connected to the wiring 67.

In the memory cell 420B, when the transistor 52 is turned on, data is written to the memory cell 420B through the wiring 47a, and when the transistor 52 is turned off, the written data is retained. Thus, in the memory cell 420B, the wiring 41a can be referred to as a write word line and the wiring 47a can be referred to as a write bit line. By controlling the potential of the wiring 41d, the gate potential of the transistor 54 can be changed by capacitive coupling and the potential of the wiring 47b can be a potential corresponding to data retained in the memory cell 420B. Thus, the bit line driver circuit 413 can read the data retained in the memory cell 420B. Accordingly, in the memory cell 420B, the wiring 41d can be referred to as a read word line and the wiring 47b can be referred to as a read bit line.

The memory cell 420C is a variation example of the memory cell 420B, in which the other of the source and the drain of the transistor 54 is electrically connected to the wiring 41d and the other electrode of the capacitor 53 is electrically connected to the wiring 67. In the memory cell 420C, the word line driver circuit 411 controls the potential of the other of the source and the drain of the transistor 54, whereby data retained in the memory cell 420C can be output to the wiring 47b.

The memory cell 420D is a variation example of the memory cell 420C and is different from the memory cell 420C in including the transistor 55. The memory cell 420D is a 3Tr1C-type memory cell.

To the memory cell 420D, the wiring 41a and the wiring 41b are electrically connected as the wiring 41. Specifically, the gate of the transistor 55 is electrically connected to the wiring 41b. One of the source and the drain of the transistor 54 is electrically connected to one of the source and the drain of the transistor 55. The other of the source and the drain of the transistor 54 is electrically connected to the wiring 67. The other of the source and the drain of the transistor 55 is electrically connected to the wiring 47b.

The transistor 55 has a function of a switch and has a function of controlling the conduction state or the non-conduction state between the wiring 47b and the one of the source and the drain of the transistor 54 on the basis of the potential of the wiring 41b. When the transistor 55 is turned on, the potential of the wiring 47b can be a potential corresponding to data retained in the memory cell 420D. Thus, the bit line driver circuit 413 can read the data retained in the memory cell 420D. Accordingly, in the memory cell 420D, the wiring 41b can be referred to as a read word line.

The memory cell 420E is a variation example of the memory cell 420D and is different from the memory cell 420D in not including the capacitor 53. In the memory cell 420E, the wiring 67 is electrically connected to the other of the source and the drain of the transistor 54.

In the case where parasitic capacitance such as the gate capacitance of the transistor 54 is sufficiently high, for example, data can be retained in the memory cell even without the capacitor 53.

An OS transistor is preferably used as the transistor 52 included in each of the memory cell 420A to the memory cell 420E. As described above, an OS transistor has a significantly low off-state current. Thus, by using an OS transistor as the transistor 52, charge accumulated in the capacitor 53 can be retained for a long period. In addition, the gate potential of the transistor 54 can be retained for a long period. Accordingly, data written to the memory cell 420 can be retained for a long period and therefore the frequency of the refresh operation (rewriting data to the memory cell 420) can be reduced. Thus, the power consumption of the memory device 400 can be reduced.

An OS transistor is preferably used as each of the transistor 54 and the transistor 55 as well. As described above, an OS transistor has higher field-effect mobility than a transistor including amorphous silicon, for example. Thus, by using an OS transistor as each of the transistor 52 to the transistor 55, the memory device 400 can be driven at high speed.

The memory cell 420A can be referred to as a DOSRAM (registered trademark). The DOSRAM is an abbreviation for a “Dynamic Oxide Semiconductor Random Access Memory”. The DOSRAM is a RAM including a 1Tr1C-type memory cell. The DOSRAM is a DRAM formed using an OS transistor and is a memory that temporarily stores information transmitted from the outside. The DOSRAM is a memory utilizing a low off-state current of an OS transistor.

The memory cell 420B to the memory cell 420E can each be referred to as a NOSRAM (registered trademark). The NOSRAM is an abbreviation for “Nonvolatile Oxide Semiconductor Random Access Memory (RAM)”. The NOSRAM is capable of reading retained data without destruction (non-destructive reading). Thus, the NOSRAM is suitable for product-sum operation in which only data reading operation is repeated many times.

The plurality of structure examples described in this embodiment can be combined with each other as appropriate. This embodiment can be combined with the other embodiments as appropriate.

### Embodiment 2

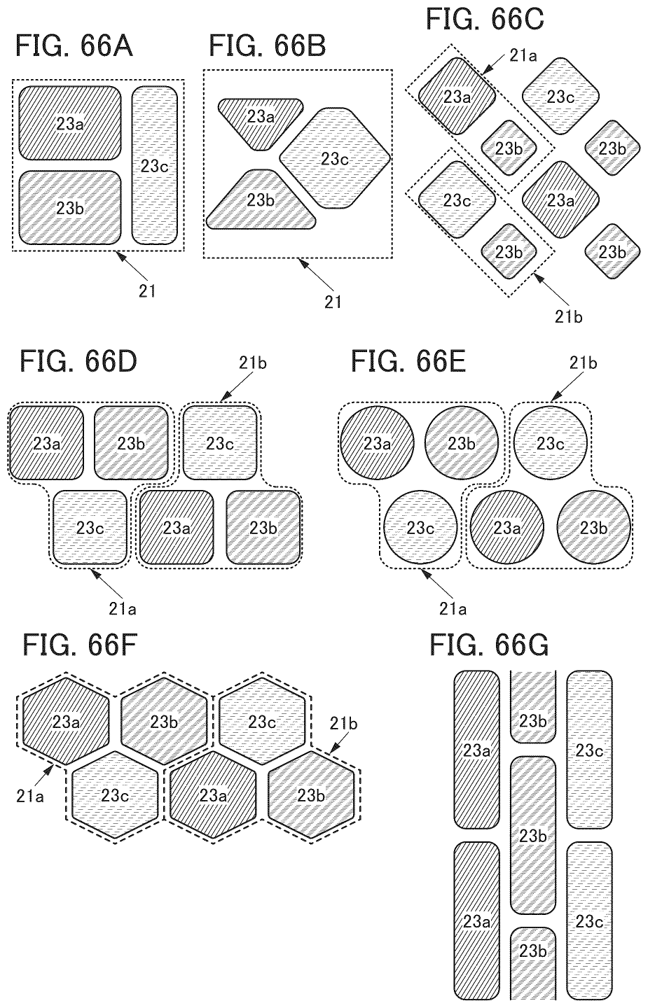

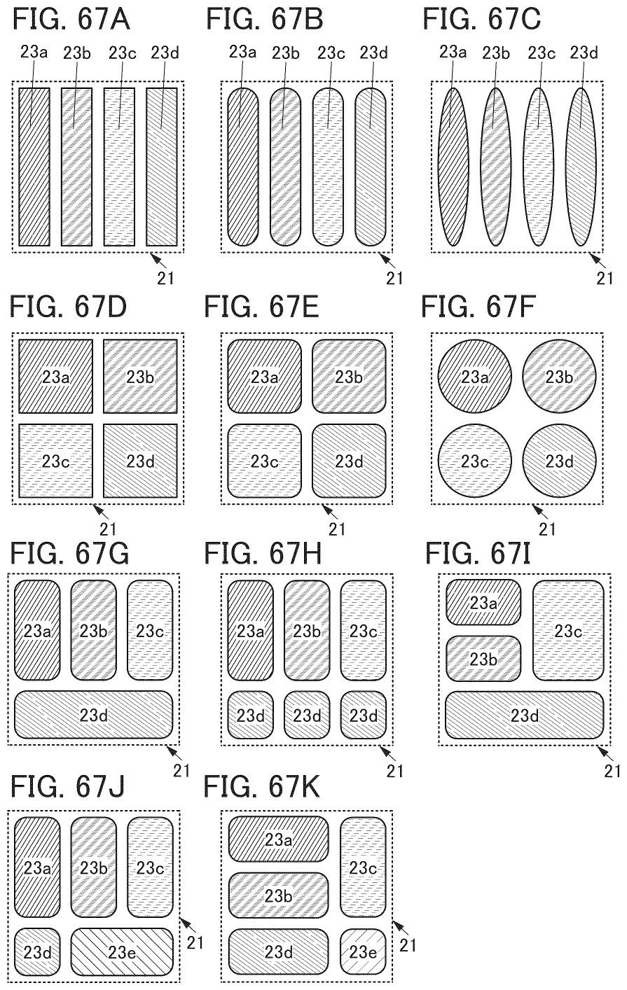

In this embodiment, a display apparatus of one embodiment of the present invention will be described with reference to FIG. 66 and FIG. 67.

In this embodiment, pixel layouts different from that in FIG. 60 will be mainly described. There is no particular limitation on the arrangement of subpixels, and a variety of methods can be employed. Examples of the arrangement of the subpixels include stripe arrangement, S-stripe arrangement, matrix arrangement, delta arrangement, Bayer arrangement, and PenTile arrangement.

The planar shape of a subpixel illustrated in a diagram in this embodiment corresponds to the planar shape of a light-emitting region (or light-receiving region).

Examples of the planar shape of the subpixel include polygons such as a triangle, a tetragon (including a rectangle and a square), and a pentagon; polygons with rounded corners; an ellipse; and a circle.

The circuit layout for forming the subpixel is not limited to being within the range of the subpixel illustrated in a diagram, and may be placed outside the subpixel.

The pixel 21 illustrated in FIG. 66A employs S stripe arrangement. The pixel 21 illustrated in FIG. 66A is composed of three kinds of subpixels: a subpixel 23a, a subpixel 23b, and a subpixel 23c.

The pixel 21 illustrated in FIG. 66B includes the subpixel 23a and the subpixel 23b whose planar surfaces have a rough trapezoidal or rough triangle shape with rounded corners and the subpixel 23c whose planar surface has a rough tetragonal or rough hexagonal shape with rounded corners. The subpixel 23b has a larger light-emitting area than the subpixel 23a. In this manner, the shapes and sizes of the subpixels can be determined independently. For example, the size of a subpixel including a light-emitting element with higher reliability can be smaller.

A pixel 21a and a pixel 21b illustrated in FIG. 66C employ PenTile arrangement. FIG. 66C illustrates an example where the pixel 21a including the subpixel 23a and the subpixel 23b and the pixel 21b including the subpixel 23b and the subpixel 23c are alternately arranged.

The pixel 21a and the pixel 21b illustrated in FIG. 66D to FIG. 66F employ delta arrangement. The pixel 21a includes two subpixels (the subpixel 23a and the subpixel 23b) in the upper row (first row) and one pixel (the subpixel 23c) in the lower row (second row). The pixel 21b includes one pixel (the subpixel 23c) in the upper row (first row) and two subpixels (the subpixel 23a and the subpixel 23b) in the lower row (second row).

FIG. 66D illustrates an example where each subpixel has a rough tetragonal planar shape with rounded corners, FIG. 66E illustrates an example where each subpixel has a circular planar shape, and FIG. 66F illustrates an example where each subpixel has a rough hexagonal planar shape with rounded corners.

In FIG. 66F, each subpixel is placed inside one of the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 23a, three subpixels 23b and three subpixels 23c are provided so that these subpixels are alternately arranged to surround the subpixel 23a.

FIG. 66G illustrates an example where subpixels of different colors are arranged in a zigzag manner. Specifically, the positions of the top sides of two subpixels arranged in the column direction (e.g., the subpixel 23a and the subpixel 23b or the subpixel 23b and the subpixel 23c) are not aligned in a plan view.

For example, in each pixel illustrated in FIG. 66A to FIG. 66G, it is preferable that the subpixel 23a be a subpixel R emitting red light, the subpixel 23b be a subpixel G emitting green light, and the subpixel 23c be a subpixel B emitting blue light. Note that the structure of the subpixels is not limited to this, and the colors and arrangement order of the subpixels can be determined as appropriate. For example, the subpixel 23b may be the subpixel R emitting red light and the subpixel 23a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the planar surface of a subpixel may have a polygonal shape with rounded corners, an elliptical shape, a circular shape, or the like.

To obtain a desired planar shape of the subpixel, a technique of correcting a mask pattern in advance so that a transferred pattern matches with a design pattern (an optical proximity correction (OPC) technique) may be used. Specifically, with the OPC technique, a pattern for correction is added to a corner portion of a figure on a mask pattern, for example.

As illustrated in FIG. 67A to FIG. 67I, the pixel can include four types of subpixels.

The pixels 21 illustrated in FIG. 67A to FIG. 67C employ stripe arrangement.

FIG. 67A illustrates an example where each subpixel has a rectangular planar shape, FIG. 67B illustrates an example where each subpixel has a planar shape formed by combining two half circles and a rectangle, and FIG. 67C illustrates an example where each subpixel has an elliptical planar shape.

The pixels 21 illustrated in FIG. 67D to FIG. 67F employ matrix arrangement.

FIG. 67D illustrates an example where each subpixel has a square planar shape, FIG. 67E illustrates an example where each subpixel has a substantially square planar shape with rounded corners, and FIG. 67F illustrates an example where each subpixel has a circular planar shape.

FIG. 67G and FIG. 67H each illustrate an example where one pixel 21 is composed of two rows and three columns.

The pixel 21 illustrated in FIG. 67G includes three subpixels (the subpixel 23a, the subpixel 23b, and the subpixel 23c) in the upper row (first row) and one pixel (the subpixel 23d) in the lower row (second row). In other words, the pixel 21 includes the subpixel 23a in the left column (first column), the subpixel 23b in the center column (second column), the subpixel 23c in the right column (third column), and the subpixel 23d across these three columns.

The pixel 21 illustrated in FIG. 67H includes three subpixels (the subpixel 23a, the subpixel 23b, and the subpixel 23c) in the upper row (first row) and three subpixels 23d in the lower row (second row). In other words, the pixel 21 includes the subpixel 23a and the subpixel 23d in the left column (first column), the subpixel 23b and the subpixel 23d in the center column (second column), and the subpixel 23c and the subpixel 23d in the right column (third column). Matching the positions of the subpixels in the upper row and the lower row as illustrated in FIG. 67H enables efficient removal of dust that would be produced in the manufacturing process, for example. Thus, a display apparatus with high display quality can be provided.

FIG. 67I illustrates an example where one pixel 21 is composed of three rows and two columns.

The pixel 21 illustrated in FIG. 67I includes the subpixel 23a in the upper row (first row), the subpixel 23b in the center row (second row), the subpixel 23c across the first and second rows, and one pixel (the subpixel 23d) in the lower row (third row). In other words, the pixel 21 includes the subpixel 23a and the subpixel 23b in the left column (first column), the subpixel 23c in the right column (second column), and the subpixel 23d across these two columns.

The pixels 21 illustrated in FIG. 67A to FIG. 67I are each composed of four subpixels: the subpixel 23a, the subpixel 23b, the subpixel 23c, and the subpixel 23d.

The subpixel 23a, the subpixel 23b, the subpixel 23c, and the subpixel 23d can include light-emitting elements emitting light of different colors. The subpixel 23a, the subpixel 23b, the subpixel 23c, and the subpixel 23d are subpixels of four colors of R, G, B, and white (W), subpixels of four colors of R, G, B, and Y, or subpixels of R, G, B, and infrared light (IR).

In the pixel 21 illustrated in FIG. 67A to FIG. 67I, it is preferable that the subpixel 23a be the subpixel R emitting red light, the subpixel 23b be the subpixel G emitting green light, the subpixel 23c be the subpixel B emitting blue light, and the subpixel 23d be any of a pixel W emitting white light, a pixel Y emitting yellow light, and a subpixel IR emitting near-infrared light, for example. In the case of such a structure, stripe arrangement is employed as the layout of R, G, and B in the pixels 21 illustrated in FIG. 67G and FIG. 67H, leading to higher display quality. In the pixel 21 illustrated in FIG. 67I, what is called S stripe arrangement is employed as the layout of R, G, and B, leading to higher display quality.

The pixel 21 may include a subpixel including a light-receiving element.

In the pixels 21 illustrated in FIG. 67A to FIG. 67I, any one of the subpixel 23a to the subpixel 23d may be a subpixel including a light-receiving element.

In the pixels 21 illustrated in FIG. 67A to FIG. 67I, for example, it is preferable that the subpixel 23a be the subpixel R emitting red light, the subpixel 23b be the subpixel G emitting green light, the subpixel 23c be the subpixel B emitting blue light, and the subpixel 23d be a subpixel S including a light-receiving element. In the case of such a structure, stripe arrangement is employed as the layout of R, G, and B in the pixels 21 illustrated in FIG. 67G and FIG. 67H, leading to higher display quality. In the pixel 21 illustrated in FIG. 67I, what is called S stripe arrangement is employed as the layout of R, G, and B, leading to higher display quality.

There is no particular limitation on the wavelength of light detected by the subpixel S including a light-receiving element. The subpixel S can have a structure where one or both of visible light and infrared light are detected.

As illustrated in FIG. 67J and FIG. 67K, the pixel can include five types of subpixels.

FIG. 67J illustrates an example where one pixel 21 is composed of two rows and three columns.

The pixel 21 illustrated in FIG. 67J includes three subpixels (the subpixel 23a, the subpixel 23b, and the subpixel 23c) in the upper row (first row) and two subpixels (the subpixel 23d and a subpixel 23e) in the lower row (second row). In other words, the pixel 21 includes the subpixel 23a and the subpixel 23d in the left column (first column), the subpixel 23b in the center column (second column), the subpixel 23c in the right column (third column), and the subpixel 23e across the second column and the third column.

FIG. 67K illustrates an example where one pixel 21 is composed of three rows and two columns.

The pixel 21 illustrated in FIG. 67K includes the subpixel 23a in the upper row (first row), the subpixel 23b in the center row (second row), the subpixel 23c across the first row and the second row, and two subpixels (the subpixel 23d and the subpixel 23e) in the lower row (third row). In other words, the pixel 21 includes the subpixel 23a, the subpixel 23b, and the subpixel 23d in the left column (first column), and the subpixel 23c and the subpixel 23e in the right column (second column).

In the pixels 21 illustrated in FIG. 67J and FIG. 67K, it is preferable that the subpixel 23a be the subpixel R emitting red light, the subpixel 23b be the subpixel G emitting green light, and the subpixel 23c be the subpixel B emitting blue light, for example. In the case of such a structure, stripe arrangement is employed as the layout of R, G, and B in the pixel 21 illustrated in FIG. 67J, leading to higher display quality. In addition, what is called S stripe arrangement is employed as the layout of R, G, and B in the pixel 21 illustrated in FIG. 67K, leading to higher display quality.

In the pixel 21 illustrated in FIG. 67J and FIG. 67K, for example, it is preferable to use the subpixel S including a light-receiving element as at least one of the subpixel 23d and the subpixel 23e. In the case where light-receiving elements are used in both the subpixel 23d and the subpixel 23e, the light-receiving elements may have different structures. For example, the wavelength ranges of detected light may be different at least partly. Specifically, one of the subpixel 23d and the subpixel 23e may include a light-receiving element mainly detecting visible light and the other may include a light-receiving element mainly detecting infrared light.

In the pixel 21 illustrated in FIG. 67J and FIG. 67K, for example, it is preferable that the subpixel S including a light-receiving element be used as one of the subpixel 23d and the subpixel 23e and a pixel including a light-emitting element that can be used as a light source be used as the other. For example, it is preferable that one of the subpixel 23d and the subpixel 23e be the subpixel IR emitting infrared light and the other be the subpixel S including a light-receiving element detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting element can employ any of a variety of layouts in the display apparatus of one embodiment of the present invention. The display apparatus of one embodiment of the present invention can have a structure where the pixel includes both a light-emitting element and a light-receiving element. Also in this case, any of a variety of layouts can be employed.

The plurality of structure examples described in this embodiment can be combined with each other as appropriate. This embodiment can be combined with the other embodiments as appropriate.

### Embodiment 3

In this embodiment, display apparatuses of one embodiment of the present invention will be described.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices that can be worn on a head, such as a VR device like a head-mounted display (HMD) and a glasses-type AR device.

### [Display Apparatus 10A]

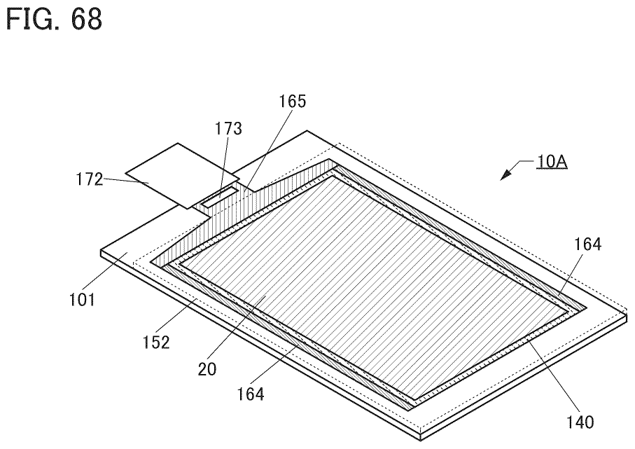

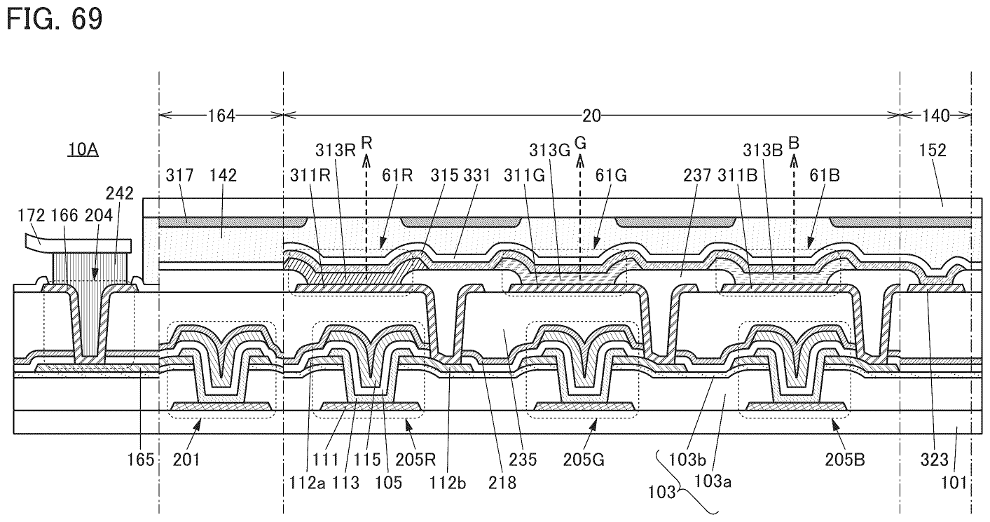

FIG. 68 is a perspective view illustrating a structure example of a display apparatus 10A and FIG. 69 is a cross-sectional view illustrating the structure example of the display apparatus 10A. The structure of the display apparatus 10 described in Embodiment 1 can be applied to the display apparatus 10A.

In the display apparatus 10A, the substrate 152 and the substrate 101 are bonded to each other. In FIG. 68, the substrate 152 is denoted by a dashed line.

The display apparatus 10A includes the display portion 20, the connection portion 140, a circuit 164, a wiring 165, and the like. FIG. 68 illustrates an example where an IC 173 and an FPC 172 are mounted on the display apparatus 10A. Thus, the structure illustrated in FIG. 68 can be regarded as a display module including the display apparatus 10A, the IC (integrated circuit), and the FPC.

In this specification and the like a display apparatus in which a substrate is equipped with a connector such as an FPC or mounted with an IC is referred to as a display module.

The connection portion 140 is provided outside the display portion 20. The connection portion 140 can be provided along one or more sides of the display portion 20. The number of the connection portions 140 can be one or more. FIG. 68 illustrates an example where the connection portion 140 is provided to surround the four sides of the display portion. A common electrode of a light-emitting element is electrically connected to a conductive layer in the connection portion 140, so that a potential can be supplied to the common electrode through the conductive layer.

The circuit 164 can include at least one of the scan line driver circuit 11, the signal line driver circuit 13, the control circuit 15, and the demultiplexer circuit 31 illustrated in FIG. 1 in Embodiment 1.

The wiring 165 has a function of supplying a signal and power to the display portion 20 and the circuit 164. The signal and the power are input to the wiring 165 from the outside through the FPC 172 or input to the wiring 165 from the IC 173.

FIG. 68 illustrates an example where the IC 173 is provided over the substrate 101 by a COG (Chip On Glass) method, a COF (Chip On Film) method, or the like. The IC 173 can include at least one of the scan line driver circuit 11, the signal line driver circuit 13, the control circuit 15, and the demultiplexer circuit 31 illustrated in FIG. 1 in Embodiment 1. Note that the display apparatus 10A and the display module are not necessarily provided with an IC. The IC may be mounted on the FPC by a COF method, for example.

FIG. 69 illustrates an example of cross sections of part of a region including the FPC 172, part of the circuit 164, part of the display portion 20, part of the connection portion 140, and part of a region including an end portion of the display apparatus 10A.

The display apparatus 10A illustrated in FIG. 69 includes a transistor 201, a transistor 205R, a transistor 205G, a transistor 205B, a light-emitting element 61R, a light-emitting element 61G, a light-emitting element 61B, and the like between the substrate 101 and the substrate 152. The light-emitting element 61R, the light-emitting element 61G, and the light-emitting element 61B can have a structure similar to that of the light-emitting element 61 illustrated in FIG. 64B in Embodiment 1. Here, the pixel electrode 311 and the layer 313 included in the light-emitting element 61R are referred to as a pixel electrode 311R and a layer 313R, respectively. The pixel electrode 311 and the layer 313 included in the light-emitting element 61G are referred to as a pixel electrode 311G and a layer 313G, respectively. Furthermore, the pixel electrode 311 and the layer 313 included in the light-emitting element 61B are referred to as a pixel electrode 311B and a layer 313B, respectively. The common electrode 315 is provided over the layer 313R, the layer 313G, and the layer 313B. The common electrode 315 is shared by the light-emitting element 61R, the light-emitting element 61G, and the light-emitting element 61B. In the example in FIG. 69, the conductive layer 112b of the transistor 205R is electrically connected to the pixel electrode 311R, the conductive layer 112b of the transistor 205G is electrically connected to the pixel electrode 311G, and the conductive layer 112b of the transistor 205B is electrically connected to the pixel electrode 311B.

In this specification and the like, matters common to the transistor 205R, the transistor 205G, and the transistor 205B are sometimes described using the term “transistor 205” without any letter of the alphabet distinguishing these transistors. As for other components that are distinguished from each other using letters of the alphabet, matters common to the components are sometimes described using reference numerals without the letters of the alphabet.

The insulating layer 237 is provided to cover the end portion of the top surface of each of the pixel electrode 311R, the pixel electrode 311G, and the pixel electrode 311B. The pixel electrode 311R, the pixel electrode 311G, and the pixel electrode 311B are provided with depressed portions so as to cover the opening in the insulating layer 103, the insulating layer 105, the insulating layer 218, and the insulating layer 235. The insulating layer 237 is embedded in the depressed portions.

Although FIG. 69 illustrates a plurality of cross sections of the insulating layer 237, the insulating layers 237 is one continuous layer when the display apparatus 10A is seen from above. In other words, the display apparatus 10A can have a structure including one insulating layer 237. Note that the display apparatus 10A may include a plurality of insulating layers 237 that are separated from each other.

The layer 313R, the layer 313G, and the layer 313B each include at least a light-emitting layer. The layer 313R includes a light-emitting layer emitting red light, the layer 313G includes a light-emitting layer emitting green light, and the layer 313B includes a light-emitting layer emitting blue light. In other words, the layer 313R contains a light-emitting substance emitting red light, the layer 313G contains a light-emitting substance emitting green light, and the layer 313B contains a light-emitting substance emitting blue light. For example, the light-emitting element 61R can emit red light, the light-emitting element 61G can emit green light, and the light-emitting element 61B can emit blue light.

The layer 313R, the layer 313G, and the layer 313B may each include one or more of a hole-injection layer, a hole-transport layer, a hole-blocking layer, a charge-generation layer, an electron-blocking layer, an electron-transport layer, and an electron-injection layer.

For example, the layer 313R, the layer 313G, and the layer 313B may each include a hole-injection layer, a hole-transport layer, a light-emitting layer, an electron-transport layer, and an electron-injection layer in this order. In addition, an electron-blocking layer may be provided between the hole-transport layer and the light-emitting layer. In addition, a hole-blocking layer may be provided between the electron-transport layer and the light-emitting layer.

The layer 313R, the layer 313G, and the layer 313B may each include an electron-injection layer, an electron-transport layer, a light-emitting layer, a hole-transport layer, and a hole-injection layer in this order, for example. In addition, a hole-blocking layer may be provided between the electron-transport layer and the light-emitting layer. In addition, an electron-blocking layer may be provided between the hole-transport layer and the light-emitting layer.

For each of the light-emitting element 61R, the light-emitting element 61G, and the light-emitting element 61B, a single structure (a structure including only one light-emitting unit) or a tandem structure (a structure including a plurality of light-emitting units) may be employed. The light-emitting unit includes at least one light-emitting layer.

In the case where the light-emitting element 61R, the light-emitting element 61G, and the light-emitting element 61B have a tandem structure, preferably, the layer 313R includes a plurality of light-emitting units that emit red light, the layer 313G includes a plurality of light-emitting units that emit green light, and the layer 313B includes a plurality of light-emitting units that emit blue light. A charge-generation layer is preferably provided between the light-emitting units. In the case where the light-emitting element 61R, the light-emitting element 61G, and the light-emitting element 61B have a tandem structure, the layer 313R, the layer 313G, and the layer 313B can each include a first light-emitting unit, a charge-generation layer over the first light-emitting unit, and a second light-emitting unit over the charge-generation layer, for example.

The layer 313R, the layer 313G, and the layer 313B can each be formed by a vacuum evaporation method using a fine metal mask, for example. In the vacuum evaporation method using a fine metal mask, deposition is performed in an area wider than an opening of the fine metal mask in many cases. Thus, the layer 313R, the layer 313G, and the layer 313B can be formed in the area wider than the opening of the fine metal mask. The end portions of the layer 313R, the layer 313G, and the layer 313B each have a tapered shape. The layer 313R, the layer 313G, and the layer 313B may also be provided over the insulating layer 237. Note that a sputtering method using a fine metal mask or an inkjet method may be used to form the layer 313R, the layer 313G, and the layer 313B.

The protective layer 331 is provided over the light-emitting element 61R, the light-emitting element 61G, and the light-emitting element 61B. The protective layer 331 and the substrate 152 are bonded to each other with the adhesive layer 142. The substrate 152 is provided with the light-blocking layer 317. A solid sealing structure, a hollow sealing structure, or the like can be employed to seal the light-emitting elements. In FIG. 69, a solid sealing structure is employed in which a space between the substrate 152 and the substrate 101 is filled with the adhesive layer 142. Alternatively, a hollow sealing structure where the space is filled with an inert gas (e.g., nitrogen or argon) may be employed. In that case, the adhesive layer 142 may be provided not to overlap with the light-emitting elements. The space may be filled with a resin different from that of the frame-like adhesive layer 142.

The protective layer 331 is provided at least in the display portion 20, and preferably provided to cover the entire display portion 20. The protective layer 331 is preferably provided to cover not only the display portion 20 but also the connection portion 140 and the circuit 164. It is also preferable that the protective layer 331 be provided to extend to the end portion of the display apparatus 10A.

A connection portion 204 is provided in a region of the substrate 101 not overlapping with the substrate 152. In the connection portion 204, the wiring 165 is electrically connected to the FPC 172 through a conductive layer 166 and a connection layer 242. The conductive layer 166 can be formed in the same step as the pixel electrode 311R, the pixel electrode 311G, and the pixel electrode 311B. On the top surface of the connection portion 204, the conductive layer 166 is exposed. Thus, the connection portion 204 and the FPC 172 can be electrically connected to each other through the connection layer 242.

The connection portion 204 includes a portion not provided with the protective layer 331 so that the FPC 172 and the conductive layer 166 can be electrically connected to each other. For example, the protective layer 331 is formed over the entire surface of the display apparatus 10A and then a region of the protective layer 331 overlapping with the conductive layer 166 is removed, so that the conductive layer 166 can be exposed.

A stacked-layer structure of at least one organic layer and a conductive layer may be provided over the conductive layer 166, and the protective layer 331 may be provided over the stacked-layer structure. Then, a separation trigger (a portion that can be a trigger of separation) may be formed in the stacked-layer structure using a laser or a sharp cutter (e.g., a needle or a utility knife) to selectively remove the stacked-layer structure and the protective layer 331 thereover, so that the conductive layer 166 may be exposed. For example, the protective layer 331 can be selectively removed when an adhesive roller is pressed to the substrate 101 and then moved relatively while being rolled. Alternatively, an adhesive tape may be attached to the substrate 101 and then peeled. Since the adhesion between the organic layer and the conductive layer or between the organic layers is low, separation occurs at the interface between the organic layer and the conductive layer or in the organic layer. Thus, a region of the protective layer 331 overlapping with the conductive layer 166 can be selectively removed. For example, when the organic layer remains over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 313B, the layer 313G, or the layer 313R, for example. The organic layer may be formed at the time of forming the layer 313B, the layer 313G, or the layer 313R, or may be provided separately. The conductive layer can be formed using the same step and the same material as the common electrode 315. An ITO film is preferably formed as the common electrode 315 and the conductive layer, for example. Note that in the case where a stacked-layer structure is employed for the common electrode 315, at least one of the layers included in the common electrode 315 is provided as the conductive layer.

The top surface of the conductive layer 166 may be covered with a mask so that the protective layer 331 cannot be provided over the conductive layer 166. As the mask, a metal mask (an area metal mask) or a tape or a film having adhesiveness or attachability may be used. The protective layer 331 is formed while the mask is placed and then the mask is removed, whereby the conductive layer 166 can be kept exposed even after the protective layer 331 is formed.

With such a method, a region not provided with the protective layer 331 can be formed in the connection portion 204, and the conductive layer 166 and the FPC 172 can be electrically connected to each other through the connection layer 242 in the region.

A conductive layer 323 is provided over the insulating layer 235 in the connection portion 140. An end portion of the conductive layer 323 is covered with the insulating layer 237. The common electrode 315 is provided over the conductive layer 323; for example, the connection portion 140 includes a region where the conductive layer 323 is in contact with the common electrode 315. The common electrode 315 is electrically connected to the conductive layer 323 provided in the connection portion 140. As the conductive layer 323, a conductive layer formed using the same material and the same step as the pixel electrode 311R, the pixel electrode 311G, and the pixel electrode 311B is preferably used. Preferably, none of the layer 313R, the layer 313G, and the layer 313B are provided over the conductive layer 323.

The display apparatus 10A has a top-emission structure. Light emitted by the light-emitting element is emitted to the substrate 152 side. Thus, for the substrate 152, a material having a high visible-light-transmitting property is preferably used. In contrast, there is no limitation on the light-transmitting property of a material used for the substrate 101.

For the common electrode 315, a material having a high visible-light-transmitting property is used. A material that reflects visible light is preferably used for each of the pixel electrode 311R, the pixel electrode 311G, and the pixel electrode 311B.

The transistor 201 and the transistor 205 are formed over the substrate 101. These transistors can be manufactured using the same material through the same process. Each of the transistor 201 and the transistor 205 can suitably employ a structure similar to that of the transistor 33 described in Embodiment 1. The transistor 201 can be used as the transistor 33 illustrated in FIG. 1 in Embodiment 1, for example. Besides, the transistor 201 can be used as the transistor included in the signal line driver circuit 13 illustrated in FIG. 1 in Embodiment 1, for example. The transistor 201 can be used as the transistor included in the scan line driver circuit 11 illustrated in FIG. 1 in Embodiment 1, for example. The transistor 201 can be used as the transistor included in the control circuit 15 illustrated in FIG. 1 in Embodiment 1, for example.

The transistor included in the circuit 164 and the transistor included in the display portion 20 may have the same structure or different structures. The same structure or two or more kinds of structures may be employed for a plurality of transistors included in the circuit 164. Similarly, the same structure or two or more kinds of structures may be employed for a plurality of transistors included in the display portion 20.

All of the transistors included in the display portion 20 may be OS transistors or all of the transistors included in the display portion 20 may be Si transistors. Alternatively, some of the transistors included in the display portion 20 may be OS transistors and the others may be Si transistors.

For example, when both an LTPS transistor and an OS transistor are used in the display portion 20, the display apparatus can have low power consumption and high driving capability. In addition, a structure where the LTPS transistor and the OS transistor are combined is referred to as LTPO in some cases. Note that as a further preferable example, a structure is given in which an OS transistor is used as a transistor functioning as a switch for controlling electrical continuity and discontinuity between wirings and an LTPS transistor is used as a transistor controlling current.

For example, one of the transistors included in the display portion 20 functions as a transistor for controlling current flowing through the light-emitting element and can also be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

By contrast, another transistor included in the display portion 20 functions as a switch for controlling selection and non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

The light-blocking layer 317 is preferably provided on the surface of the substrate 152 on the substrate 101 side. The light-blocking layer 317 can be provided between adjacent light-emitting elements, in the connection portion 140, and in the circuit 164, for example. A variety of optical members can be provided on the outer surface of the substrate 152.

As the connection layer 242, an anisotropic conductive film (ACF), an anisotropic conductive paste (ACP), or the like can be used.

### [Display Apparatus 10B]

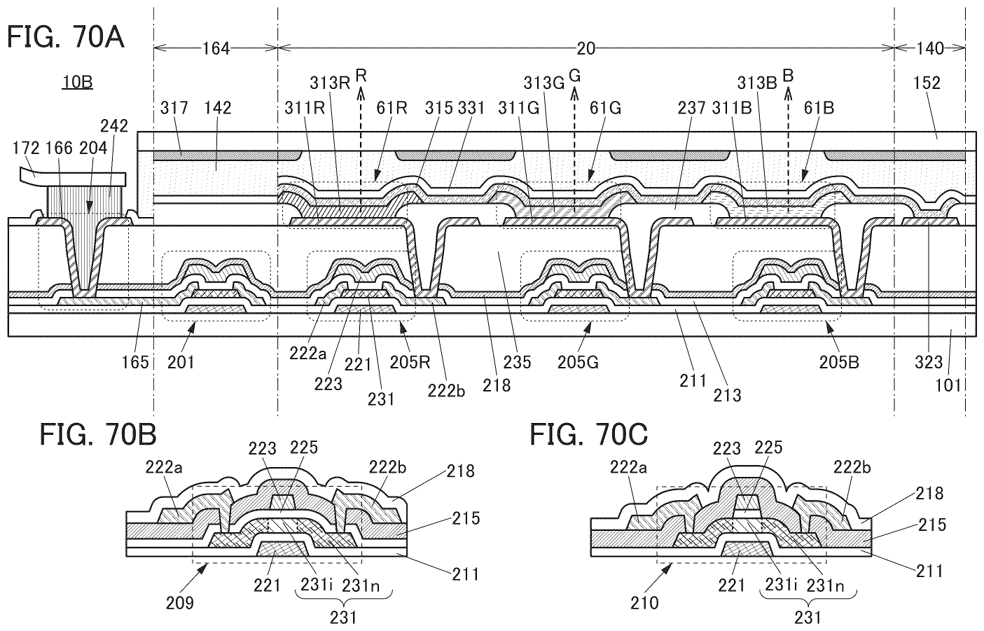

FIG. 70A is a cross-sectional view illustrating a structure example of a display apparatus 10B. The display apparatus 10B is a variation example of the display apparatus 10A and is different from the display apparatus 10A in the structures of the transistor 201, the transistor 205R, the transistor 205G, and the transistor 205B, for example.

Each of the transistor 201 and the transistor 205 included in the display apparatus 10B includes a conductive layer 221 functioning as a gate, an insulating layer 211 functioning as a first gate insulating layer, a conductive layer 222a and a conductive layer 222b functioning as a source and a drain, a semiconductor layer 231, an insulating layer 213 functioning as a second gate insulating layer, and a conductive layer 223 functioning as a second gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231. In the example illustrated in FIG. 70A, the conductive layer 222b of the transistor 205R is electrically connected to the pixel electrode 311R, the conductive layer 222b of the transistor 205G is electrically connected to the pixel electrode 311G, and the conductive layer 222b of the transistor 205B is electrically connected to the pixel electrode 311B.

For the conductive layer 221, for example, a material similar to the material that can be used for the conductive layer 111 can be used. For the conductive layer 222a and the conductive layer 222b, a material similar to the material that can be used for the conductive layer 112a and the conductive layer 112b can be used. For the conductive layer 223, a material similar to the material that can be used for the conductive layer 115 can be used. For the insulating layer 211 and the insulating layer 213, a material similar to the material that can be used for the insulating layer 103a or a material similar to the material that can be used for the insulating layer 103b can be used.

For the semiconductor layer 231, a material similar to the material that can be used for the semiconductor layer 113 can be used. Here, the transistor 201 and the transistor 205 can have improved field-effect mobility by including LTPS in the semiconductor layers 231, for example. Thus, the display apparatus 10B can be driven at high speed.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The transistor 201 and the transistor 205 employ a structure where the semiconductor layer where a channel is formed is provided between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

The transistor 201 illustrated in FIG. 70A can be used as the transistor included in the signal line driver circuit 13 illustrated in FIG. 1 in Embodiment 1, for example. The transistor 201 illustrated in FIG. 70A can be used as the transistor included in the scan line driver circuit 11 illustrated in FIG. 1 in Embodiment 1, for example. The transistor 201 illustrated in FIG. 70A can be used as the transistor included in the control circuit 15 illustrated in FIG. 1 in Embodiment 1, for example.

FIG. 70B and FIG. 70C illustrate other structure examples of transistors.

Each of a transistor 209 and a transistor 210 includes the conductive layer 221 functioning as a gate, the insulating layer 211 functioning as a first gate insulating layer, the semiconductor layer 231 including a channel formation region 231i and a pair of low-resistance regions 231n, the conductive layer 222a electrically connected to one of the pair of low-resistance regions 231n, the conductive layer 222b electrically connected to the other of the pair of low-resistance regions 231n, an insulating layer 225 functioning as a second gate insulating layer, the conductive layer 223 functioning as a gate, and an insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, the insulating layer 218 covering the transistor may be provided.

FIG. 70B illustrates an example of the transistor 209 in which the insulating layer 225 covers the top surface and the side surface of the semiconductor layer 231. The conductive layer 222a and the conductive layer 222b are electrically connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 70C, the insulating layer 225 overlaps with the channel formation region 231i of the semiconductor layer 231 and does not overlap with the low-resistance regions 231n. The structure illustrated in FIG. 70C can be formed by processing the insulating layer 225 using the conductive layer 223 as a mask, for example. In FIG. 70C, the insulating layer 215 is provided to cover the insulating layer 225 and the conductive layer 223, and the conductive layer 222a and the conductive layer 222b are electrically connected to the low-resistance regions 231n through the openings in the insulating layer 215.

### [Display Apparatus 10C]

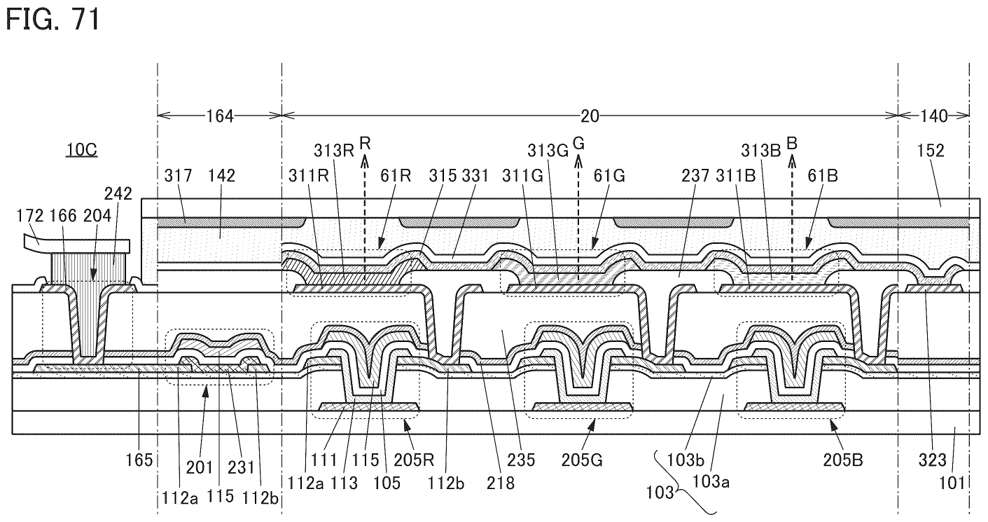

FIG. 71 is a cross-sectional view illustrating a structure example of a display apparatus 10C. The display apparatus 10C is a variation example of the display apparatus 10A and is different from the display apparatus 10A in the structure of the transistor 201, for example.

The transistor 201 included in the display apparatus 10C includes the conductive layer 112a and the conductive layer 112b over the insulating layer 103, the semiconductor layer 231 over the conductive layer 112a, the conductive layer 112b, and the insulating layer 103, the insulating layer 105 over the semiconductor layer 231, the conductive layer 112a, and the conductive layer 112b, and the conductive layer 115 over the insulating layer 105 including a region overlapping with the semiconductor layer 231.

The conductive layer 112a and the conductive layer 112b include the same material as the conductive layer 112a and the conductive layer 112b of the transistor 205 and can be formed in the same step as the conductive layer 112a and the conductive layer 112b. The conductive layer 112a functions as one of a source electrode and a drain electrode of the transistor 201, and the conductive layer 112b functions as the other of the source electrode and the drain electrode of the transistor 201.

For the semiconductor layer 231, silicon can be used; for example, LTPS can be used. The transistor 201 can have improved field-effect mobility by including LTPS in the semiconductor layer 231. Thus, the circuit 164 including the transistor 201 can be driven at high speed. Note that the semiconductor layer 231 may include the same material as the semiconductor layer 113; for example, the semiconductor layer 231 may include a metal oxide.

The transistor 201 illustrated in FIG. 71 can be used as the transistor included in the signal line driver circuit 13 illustrated in FIG. 1 in Embodiment 1, for example. The transistor 201 illustrated in FIG. 71 can be used as the transistor included in the scan line driver circuit 11 illustrated in FIG. 1 in Embodiment 1, for example. The transistor 201 illustrated in FIG. 71 can be used as the transistor included in the control circuit 15 illustrated in FIG. 1 in Embodiment 1, for example. Note that the transistor 201 illustrated in FIG. 71 may be used as the transistor 33 illustrated in FIG. 1 in Embodiment 1.

In the display apparatus 10C, the components included in the transistor 201 and the components included in the transistor 205 can be formed in the same step. Thus, the number of steps for manufacturing the display apparatus can be smaller than that in the case where the components included in the transistor 201 and the components included in the transistor 205 are formed in different steps. Thus, the manufacturing method of the display apparatus can be simplified. Note that when the semiconductor layer 231 includes the same material as the semiconductor layer 113, the semiconductor layer 231 and the semiconductor layer 113 of the transistor 205, for example, can be formed in the same step.

The structure of the transistor 201 included in the display apparatus 10C can be applied to the transistor 201 and the transistor 205 included in the display apparatus 10B. In this case, the semiconductor layer of the transistor 201 and the semiconductor layer of the transistor 205 may be formed in different steps. Accordingly, the semiconductor layer of the transistor 201 and the semiconductor layer of the transistor 205 can include different materials.

### [Display Apparatus 10D]

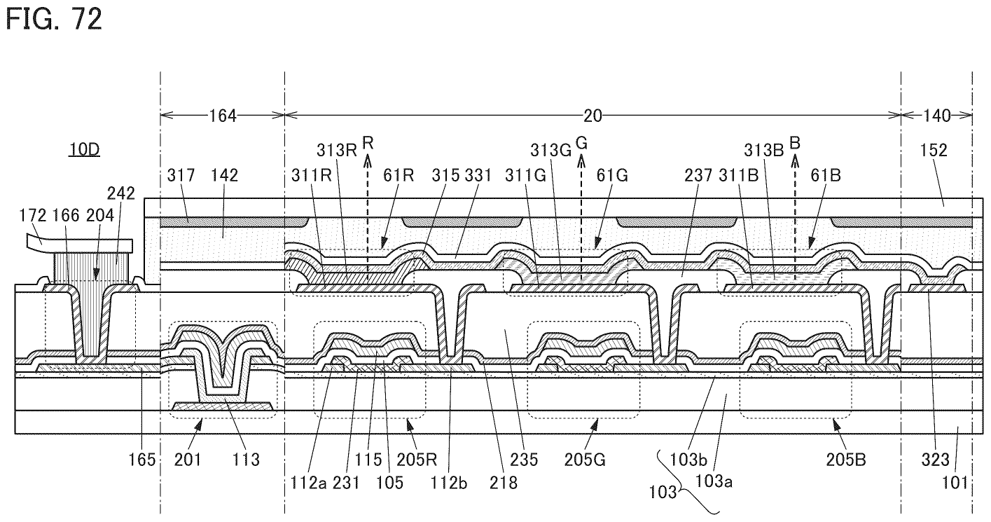

FIG. 72 is a cross-sectional view illustrating a structure example of a display apparatus 10D. The display apparatus 10D is a variation example of the display apparatus 10A and is different from the display apparatus 10A in the structure of the transistor 205, for example.

The transistor 205 included in the display apparatus 10D includes the conductive layer 112a and the conductive layer 112b over the insulating layer 103, the semiconductor layer 231 over the conductive layer 112a, the conductive layer 112b, and the insulating layer 103, the insulating layer 105 over the semiconductor layer 231, the conductive layer 112a, and the conductive layer 112b, and the conductive layer 115 over the insulating layer 105 including a region overlapping with the semiconductor layer 231.

The conductive layer 112a and the conductive layer 112b include the same material as the conductive layer 112a and the conductive layer 112b of the transistor 201 and can be formed in the same step as the conductive layer 112a and the conductive layer 112b. The conductive layer 112a functions as one of the source electrode and the drain electrode of the transistor 201, and the conductive layer 112b functions as the other of the source electrode and the drain electrode of the transistor 201. For the semiconductor layer 231, a material similar to the material that can be used for the semiconductor layer 231 provided in the display apparatus 10C can be used.

The transistor 201 illustrated in FIG. 72 can be used as the transistor included in the signal line driver circuit 13, for example, in addition to the transistor 33 illustrated in FIG. 1 in Embodiment 1. The transistor 201 illustrated in FIG. 72 can be used as the transistor included in the scan line driver circuit 11 illustrated in FIG. 1 in Embodiment 1, for example. The transistor 201 illustrated in FIG. 72 can be used as the transistor included in the control circuit 15 illustrated in FIG. 1 in Embodiment 1, for example.

In the display apparatus 10D, the components included in the transistor 205 and the components included in the transistor 201 can be formed in the same step. Thus, the number of steps for manufacturing the display apparatus can be smaller than that in the case where the components included in the transistor 205 and the components included in the transistor 201 are formed in different steps. Thus, the manufacturing method of the display apparatus can be simplified. Note that when the semiconductor layer 231 includes the same material as the semiconductor layer 113, the semiconductor layer 231 and the semiconductor layer 113 of the transistor 201, for example, can be formed in the same step.

### [Display Apparatus 10E]

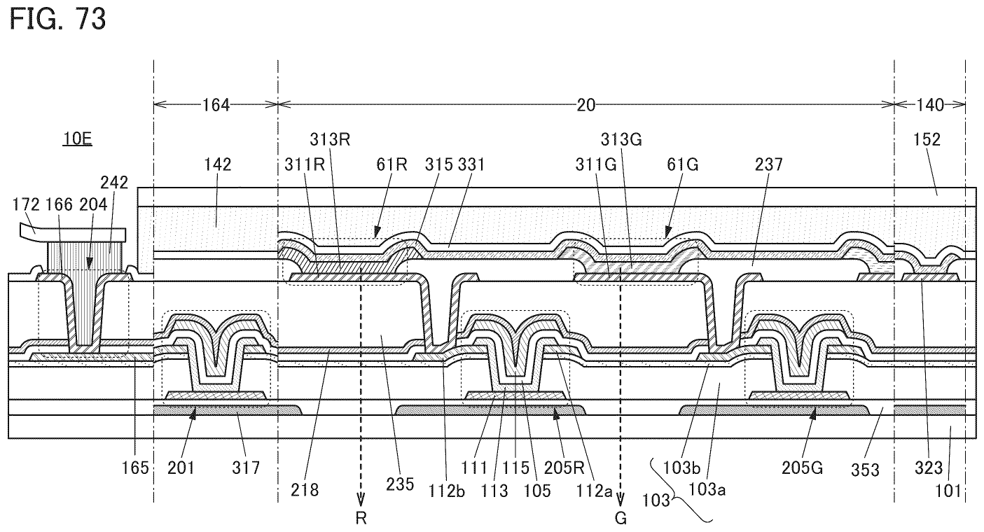

FIG. 73 is a cross-sectional view illustrating a structure example of a display apparatus 10E. The display apparatus 10E is a variation example of the display apparatus 10A and is different from the display apparatus 10A in having a bottom-emission structure, for example.

In the display apparatus 10E, light emitted from the light-emitting element 61 is emitted to the substrate 101 side. For the substrate 101, a material having a high visible-light-transmitting property is preferably used. By contrast, there is no limitation on the light-transmitting property of a material used for the substrate 152.

The light-blocking layer 317 is preferably formed between the substrate 101 and the transistor 201 and between the substrate 101 and the transistor 205. FIG. 73 illustrates an example where the light-blocking layer 317 is provided over the substrate 101, an insulating layer 353 is provided over the light-blocking layer 317, and the transistor 201, the transistor 205, and the like are provided over the insulating layer 353.

A material having a high visible-light-transmitting property is used for each of the pixel electrode 311R, the pixel electrode 311G, and the pixel electrode 311B. A material reflecting visible light is preferably used for the common electrode 315.

The structure of the display apparatus 10E can also be applied to the display apparatus 10B and the display apparatus 10C. Specifically, the display apparatus 10B and the display apparatus 10C can have a bottom-emission structure. When a material having a high visible-light-transmitting property is used for both the pixel electrode 311 and the common electrode 315, the display apparatus 10A to the display apparatus 10E can have a dual-emission structure. In the dual-emission display apparatus 10, a material having a high visible-light-transmitting property is preferably used for both the substrate 101 and the substrate 152.

### [Display Apparatus 10F]

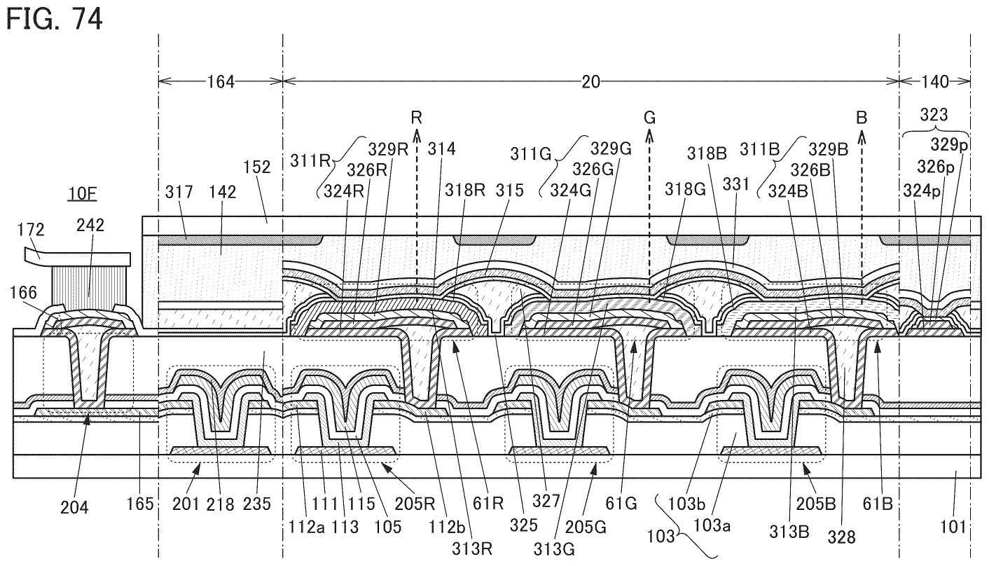

FIG. 74 is a cross-sectional view illustrating a structure example of a display apparatus 10F. The display apparatus 10F is a variation example of the display apparatus 10A and is different from the display apparatus 10A in the structures of the light-emitting element 61R, the light-emitting element 61G, and the light-emitting element 61B, for example. In addition, the display apparatus 10F is different from the display apparatus 10A in that the insulating layer 237 is not provided, the layer 313 covers the top surface and the side surface of the pixel electrode 311, and an insulating layer 325, an insulating layer 327, and a common layer 314 are provided.

The display apparatus 10F is different from the display apparatus 10A mainly in the structures of the pixel electrode 311R, the pixel electrode 311G, the pixel electrode 311B, and the conductive layer 323 and in including a layer 328.

As illustrated in FIG. 74, the pixel electrode 311 included in the light-emitting element 61 has a stacked-layer structure including a conductive layer 324, a conductive layer 326 over the conductive layer 324, and a conductive layer 329 over the conductive layer 326. Here, the conductive layer 324, the conductive layer 326, and the conductive layer 329 included in the pixel electrode 311R are referred to as a conductive layer 324R, a conductive layer 326R, and a conductive layer 329R, respectively. The conductive layer 324, the conductive layer 326, and the conductive layer 329 included in the pixel electrode 311G are referred to as a conductive layer 324G, a conductive layer 326G, and a conductive layer 329G, respectively. The conductive layer 324, the conductive layer 326, and the conductive layer 329 included in the pixel electrode 311B are referred to as a conductive layer 324B, a conductive layer 326B, and a conductive layer 329B, respectively.

The conductive layer 324 is electrically connected to the conductive layer 112b included in the transistor 205 through the opening provided in the insulating layer 105, the insulating layer 218, and the insulating layer 235.

An end portion of the conductive layer 326 is positioned inward from an end portion of the conductive layer 324 and an end portion of the conductive layer 329. In other words, the end portion of the conductive layer 326 is positioned over the conductive layer 324, and the top surface and the side surface of the conductive layer 326 are covered with the conductive layer 329.

For the conductive layer 324, no particular limitations are imposed on the properties of transmitting and reflecting visible light. As the conductive layer 324, a conductive layer having a visible-light-transmitting property or a conductive layer having a visible-light-reflecting property can be used. As the conductive layer having a visible-light-transmitting property, an oxide conductive layer can be used, for example. Specifically, In—Si—Sn oxide (also referred to as ITSO) can be suitably used for the conductive layer 324. Examples of the conductive layer having a visible-light-reflecting property include metal such as aluminum, titanium, chromium, nickel, copper, yttrium, zirconium, silver, tin, zinc, silver, platinum, gold, molybdenum, tantalum, and tungsten, and an alloy containing the metal as its main component (e.g., an alloy of silver, palladium, and copper (APC: Ag—Pd—Cu)). The conductive layer 324 may have a stacked-layer structure of a conductive layer having a visible-light-transmitting property and a conductive layer having visible-light-reflecting property over the conductive layer. For the conductive layer 324, a material with high adhesion to the formation surface of the conductive layer 324 (here, the insulating layer 235) is preferably used. Accordingly, film separation of the conductive layer 324 can be inhibited.

As the conductive layer 326, a conductive layer having a visible-light-reflecting property can be used. The conductive layer 326 may have a stacked-layer structure of a conductive layer having a visible-light-transmitting property and a conductive layer having a visible-light-reflecting property over the conductive layer. For the conductive layer 326, a material that can be used for the conductive layer 324 can be used. Specifically, a stacked-layer structure of In—Si—Sn oxide (ITSO) and an alloy of silver, palladium, and copper (APC) over the In—Si—Sn oxide (ITSO) can be suitably used for the conductive layer 326.

For the conductive layer 329, a material that can be used for the conductive layer 324 can be used. As the conductive layer 329, a conductive layer having a visible-light-transmitting property can be used. Specifically, In—Si—Sn oxide (ITSO) can be used for the conductive layer 329.

In the case where a material that is easily oxidized is used for the conductive layer 326, a material that is not easily oxidized is used for the conductive layer 329 and the conductive layer 326 is covered with the conductive layer 329, whereby oxidation of the conductive layer 326 can be inhibited. In addition, precipitation of a metal component included in the conductive layer 326 can be inhibited. For example, in the case where a material containing silver is used for the conductive layer 326, In—Si—Sn oxide (ITSO) can be suitably used for the conductive layer 329. Thus, oxidation of the conductive layer 326 can be inhibited, and precipitation of silver can be inhibited.

For example, the conductive layer 323 can have a stacked-layer structure of a conductive layer 324p, a conductive layer 326p over the conductive layer 324p, and a conductive layer 329p over the conductive layer 326p. The conductive layer 324p can be formed in the same step as the conductive layer 324R, the conductive layer 324G, and the conductive layer 324B. The conductive layer 326p can be formed in the same step as the conductive layer 326R, the conductive layer 326G, and the conductive layer 326B. The conductive layer 329p can be formed in the same step as the conductive layer 329R, the conductive layer 329G, and the conductive layer 329B.

FIG. 74 illustrates an example where the thickness of the conductive layer 329p is different from the thicknesses of the conductive layer 329R, the conductive layer 329G, and the conductive layer 329B. The thicknesses of the conductive layer 329p, the conductive layer 329R, the conductive layer 329G, and the conductive layer 329B may be different depending on the resistivities of materials used for these layers. In the case of making the thicknesses different, the conductive layer 329p may be formed in a step different from a step of forming the conductive layer 329R, the conductive layer 329G, and the conductive layer 329B. Alternatively, some formation steps may be common between the conductive layer 329p and the conductive layer 329R, the conductive layer 329G, and the conductive layer 329B.

Depressed portions are formed in the conductive layer 324R, the conductive layer 324G, and the conductive layer 324B so as to cover the openings provided in the insulating layer 105, the insulating layer 218, and the insulating layer 235. The layer 328 is embedded in each of the depressed portions.

The layer 328 has a planarization function for the depressed portions of the conductive layer 324R, the conductive layer 324G, and the conductive layer 324B. The conductive layer 326R, the conductive layer 326G, and the conductive layer 326B electrically connected to the conductive layer 324R, the conductive layer 324G, and the conductive layer 324B, respectively, are provided over the conductive layer 324R, the conductive layer 324G, the conductive layer 324B, and the layer 328. Thus, regions overlapping with the depressed portions of the conductive layer 324R, the conductive layer 324G, and the conductive layer 324B can also function as the light-emitting regions, increasing the aperture ratio of the pixels.

The layer 328 may be an insulating layer or a conductive layer. Any of a variety of inorganic insulating materials, organic insulating materials, and conductive materials can be used for the layer 328 as appropriate. Specifically, the layer 328 is preferably formed using an insulating material and is particularly preferably formed using an organic insulating material. The layer 328 can be formed using an organic insulating material usable for the insulating layer 327, for example.

In the case where the layer 328 is a conductive layer, the layer 328 can function as part of a pixel electrode.

The layer 328 included in the display apparatus 10F can also be used for the display apparatus 10A to the display apparatus 10E. For example, instead of the insulating layer 237, the layer 328 can be embedded in at least part of the depressed portions in the pixel electrode 311R, the pixel electrode 311G, and the pixel electrode 311B.

FIG. 74 illustrates an example where an end portion of the layer 313 is positioned outward from an end portion of the pixel electrode 311. The layer 313 is formed to cover the end portion of the pixel electrode 311. Such a structure enables the entire top surface of the pixel electrode 311 to be a light-emitting region, and the aperture ratio can be increased as compared with the structure where the end portion of the island-shaped layer 313 is positioned inward from the end portion of the pixel electrode 311. Covering the side surface of the pixel electrode 311 with the layer 313 can inhibit contact between the pixel electrode 311 and the common electrode 315, thereby inhibiting a short circuit of the light-emitting element 61.

The insulating layer 237 is not provided between the pixel electrode 311 and the layer 313. Thus, the distance between adjacent light-emitting elements 61 can be shortened. Accordingly, the display apparatus 10F can have high resolution or high definition. In addition, a mask for forming the insulating layer is not needed, which leads to a reduction in manufacturing cost of the display apparatus.

The layer 313 can be formed by a photolithography method and an etching method, for example. Specifically, a film to be the layer 313 is formed across a plurality of pixel electrodes 311 that have been formed for respective subpixels. Next, a mask layer is formed over the film to be the layer 313, and a resist mask is formed over the mask layer by a photolithography method. After that, the mask layer and the film to be the layer 313 are processed by an etching method, for example, and the resist mask is removed. A mask layer having a two-layer structure of a first mask layer and a second mask layer over the first mask layer is used, for example. In this case, a resist mask is formed over the second mask layer and the second mask layer is processed. Then, the resist mask is removed. After that, the first mask layer and the film to be the layer 313 are processed using the second mask layer as a hard mask, for example. In this manner, one island-shaped layer 313 is formed for every pixel electrode 311. Thus, the layer 313 can be divided into island-shaped layers 313 for respective subpixels. By performing a series of steps from the formation of the film to be the layer 313 to the processing of the film three times, for example, the layer 313R, the layer 313G, and the layer 313B can be separately formed.

When the island-shaped layer 313 is formed without using a fine metal mask, the formed layer 313 can have a minute size. Providing the island-shaped layer 313 for each light-emitting element 61 can inhibit a leakage current between the adjacent light-emitting elements 61. This can prevent crosstalk due to unintended light emission, so that a display apparatus with extremely high contrast can be achieved. Specifically, a display apparatus having high current efficiency at low luminance can be achieved.

In this specification and the like, a device fabricated using a metal mask or an FMM is sometimes referred to as a device having an MM (metal mask) structure. In this specification and the like, a device fabricated without using a metal mask or an FMM is sometimes referred to as a device having an MML (metal maskless) structure.

In the case where the island-shaped layer 313 is formed without using a fine metal mask, a surface of the layer 313 is exposed in the manufacturing process of the display apparatus. The layer 313R, the layer 313G, and the layer 313B each preferably include a carrier-transport layer over a light-emitting layer. Alternatively, the layer 313R, the layer 313G, and the layer 313B each preferably include a carrier-blocking layer over the light-emitting layer. Alternatively, the layer 313R, the layer 313G, and the layer 313B each preferably include a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. As a result, the reliability of the light-emitting element 61 can be improved.

In the case where the light-emitting element 61 has a tandem structure where, for example, the layer 313 includes a first light-emitting unit, a charge-generation layer over the first light-emitting unit, and a second light-emitting unit over the charge-generation layer, a surface of the second light-emitting unit is exposed in the manufacturing process of the display apparatus. The second light-emitting unit preferably includes a carrier-transport layer over a light-emitting layer. Alternatively, the second light-emitting unit preferably includes a carrier-blocking layer over the light-emitting layer. Alternatively, the second light-emitting unit preferably includes a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. As a result, the reliability of the light-emitting element 61 can be improved. Note that in the case where three or more light-emitting units are provided, the uppermost light-emitting unit preferably includes one or both of a carrier-transport layer and a carrier-blocking layer over the light-emitting layer.

The upper temperature limits of the compounds contained in the layer 313R, the layer 313G, and the layer 313B are each preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition points (Tg) of these compounds are each preferably higher than or equal to 100° C. and lower than or equal to 180° C., further preferably higher than or equal to 120° C. and lower than or equal to 180° C., still further preferably higher than or equal to 140° C. and lower than or equal to 180° C. This inhibits a reduction in light emission efficiency and a decrease in lifetime which are due to damage to the layer 313R, the layer 313G, and the layer 313B by heat applied in a process.

In a region between adjacent light-emitting elements 61, the insulating layer 325 and the insulating layer 327 over the insulating layer 325 are provided. Although FIG. 74 illustrates a plurality of cross sections of the insulating layer 325 and the insulating layer 327, the insulating layer 325 and the insulating layer 327 are each one continuous layer when the display apparatus 10F is seen from above. In other words, the display apparatus 10F can have a structure including one insulating layer 325 and one insulating layer 327, for example. Note that the display apparatus 10F may include a plurality of insulating layers 325 that are separated from each other, and may include a plurality of insulating layers 327 that are separated from each other.

The insulating layer 325 preferably includes regions in contact with the side surfaces of the layer 313R, the layer 313G, and the layer 313B. The insulating layer 325 includes regions in contact with the layer 313R, the layer 313G, and the layer 313B, whereby film separation of the layer 313R, the layer 313G, and the layer 313B can be prevented. When the insulating layer 325 is closely attached to the layer 313R, the layer 313G, or the layer 313B, the effect of fixing or bonding the adjacent layers 313 and the like by the insulating layer 325 is obtained. As a result, the reliability of the light-emitting element 61 can be improved. In addition, the yield of the light-emitting element 61 can be increased.

The insulating layer 325 can be an insulating layer including an inorganic material. As the insulating layer 325, an inorganic insulating film such as an oxide insulating film, a nitride insulating film, an oxynitride insulating film, or a nitride oxide insulating film can be used, for example. The insulating layer 325 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the layer 313 in etching and has a function of protecting the layer 313.

The insulating layer 325 preferably has a function of a barrier insulating layer against at least one of water and oxygen. Alternatively, the insulating layer 325 preferably has a function of inhibiting diffusion of at least one of water and oxygen. Alternatively, the insulating layer 325 preferably has a function of capturing or fixing (also referred to as gettering) at least one of water and oxygen. Note that in this specification and the like, a barrier insulating layer refers to an insulating layer having a barrier property. A barrier property in this specification and the like means a function of inhibiting diffusion of a particular substance (also referred to as low permeability).

When the insulating layer 325 has a function of a barrier insulating layer or a gettering function, entry of impurities (typically, at least one of water and oxygen) that might diffuse into the light-emitting element from the outside can be inhibited. With this structure, a highly reliable light-emitting element and a highly reliable display apparatus can be provided.

The insulating layer 327 is provided over the insulating layer 325 to fill a depressed portion formed on the insulating layer 325. The insulating layer 327 can be configured to overlap with the side surface and part of the top surface of each of the layer 313R, the layer 313G, and the layer 313B with the insulating layer 325 therebetween. The insulating layer 327 preferably covers at least part of the side surface of the insulating layer 325. The insulating layer 325 and the insulating layer 327 can fill a gap between the adjacent island-shaped layers, whereby unevenness of the formation surface of the layers, e.g., the common electrode 315, to be provided over the island-shaped layers can be reduced and the coverage with the layers can be improved. This can inhibit a connection defect due to the step disconnection. In addition, an increase in wiring resistance, which is caused by local thinning of the common electrode 315 due to the step, can be inhibited. The top surface of the insulating layer 327 preferably has a shape with higher flatness; however, it may have a projecting portion, a convex surface, a concave surface, or a depressed portion.

An insulating layer containing an organic material can be suitably used for the insulating layer 327. As the organic material, a photosensitive organic resin is preferably used, and for example, a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

A mask layer 318R is positioned over the layer 313R included in the light-emitting element 61R, a mask layer 318G is positioned over the layer 313G included in the light-emitting element 61G, and a mask layer 318B is positioned over the layer 313B included in the light-emitting element 61B. The mask layer 318 is provided to surround the light-emitting region. In other words, the mask layer 318 has an opening in a portion overlapping with the light-emitting region. The mask layer 318R is a remaining part of a mask layer provided over the layer 313R at the time of forming the layer 313R. In a similar manner, the mask layer 318G is a remaining part of the mask layer provided at the time of forming the layer 313G, and the mask layer 318B is a remaining part of the mask layer provided at the time of forming the layer 313B. Thus, the mask layer used to protect the layer 313 in manufacture of the display apparatus may partly remain in the display apparatus of one embodiment of the present invention.

Although the mask layer 318 has a single-layer structure in FIG. 74, the mask layer 318 may have a stacked-layer structure. For example, the mask layer 318 may have a two-layer structure or a stacked-layer structure of three or more layers. After the formation of the film to be the layer 313, a first mask layer and a second mask layer over the first mask layer are formed as mask layers in some cases. After that, the layer 313R, the layer 313G, and the layer 313B are formed using the mask layers, the second mask layer is removed, and then an opening reaching the layer 313 is formed in the first mask layer in some cases. In that case, the mask layer 318 remaining in the display apparatus 10F has a single-layer structure. In other words, the mask layer 318 may include a smaller number of layers than the mask layer formed in the manufacturing process of the display apparatus 10F.

In the display apparatus 10F, the common layer 314 is provided over the layer 313R, the layer 313G, the layer 313B, and the insulating layer 327 and the common electrode 315 is provided over the common layer 314. Like the common electrode 315, the common layer 314 is shared by the light-emitting element 61R, the light-emitting element 61G, and the light-emitting element 61B. In the case where the light-emitting element 61 includes the common layer 314, the layer 313 and the common layer 314 can be collectively referred to as an EL layer. Note that the common layer 314 is not necessarily included in the EL layer.

The common layer 314 includes an electron-injection layer or a hole-injection layer, for example. Alternatively, the common layer 314 may include a stack of an electron-transport layer and an electron-injection layer, or may include a stack of a hole-transport layer and a hole-injection layer. Here, a structure can be employed where the layer included in the common layer 314 is not included in the layer 313. For example, when the common layer 314 includes an electron-injection layer, the layer 313 does not necessarily include an electron-injection layer. When the common layer 314 includes a hole-injection layer, the layer 313 does not necessarily include a hole-injection layer.

In the case where the common layer 314 is provided in the display apparatus, the common electrode 315 can be formed successively after the formation of the common layer 314, without interposing a step of etching or the like. For example, after the common layer 314 is formed in a vacuum, the common electrode 315 can be formed in a vacuum without exposing the substrate 101 to the air. In other words, the common layer 314 and the common electrode 315 can be successively formed in a vacuum. Accordingly, the lower surface of the common electrode 315 can be a clean surface, as compared with the case where the common layer 314 is not provided in the display apparatus. Thus, in the case where the surface of the layer 313 is exposed to the air after the formation of the layer 313, the common layer 314 is preferably provided in the display apparatus.

In the example in FIG. 74, the common layer 314 is not provided in the connection portion 140. For example, by using a mask for specifying a deposition area (also referred to as an area mask or a rough metal mask to distinguish from a fine metal mask), the common layer 314 and the common electrode 315 can be formed in different regions.

Here, in the case where the wiring resistance of the common layer 314 in the thickness direction is low enough to be negligible, electrical continuity between the conductive layer 323 and the common electrode 315 can be maintained even when the common layer 314 is provided between the conductive layer 323 and the common electrode 315. When the common layer 314 is provided not only in the display portion 20 but also in the connection portion 140, the common layer 314 can be formed, for example, without using a metal mask such as an area mask. Thus, the manufacturing process of the display apparatus 10F can be simplified.

Although the display apparatus 10F in FIG. 74 has a top-emission structure, the display apparatus 10F may have a bottom-emission structure or a dual-emission structure.

The structure of the display apparatus 10F is also applicable to the display apparatus 10A to the display apparatus 10E. Specifically, the display apparatus 10A to the display apparatus 10E can employ at least one of the structure of the light-emitting elements 61, absence of the insulating layer 237, covering the top surface and the side surface of the pixel electrode 311 with the layer 313, inclusion of the insulating layer 325, inclusion of the insulating layer 327, and inclusion of the common layer 314.

### [Display Apparatus 10G]

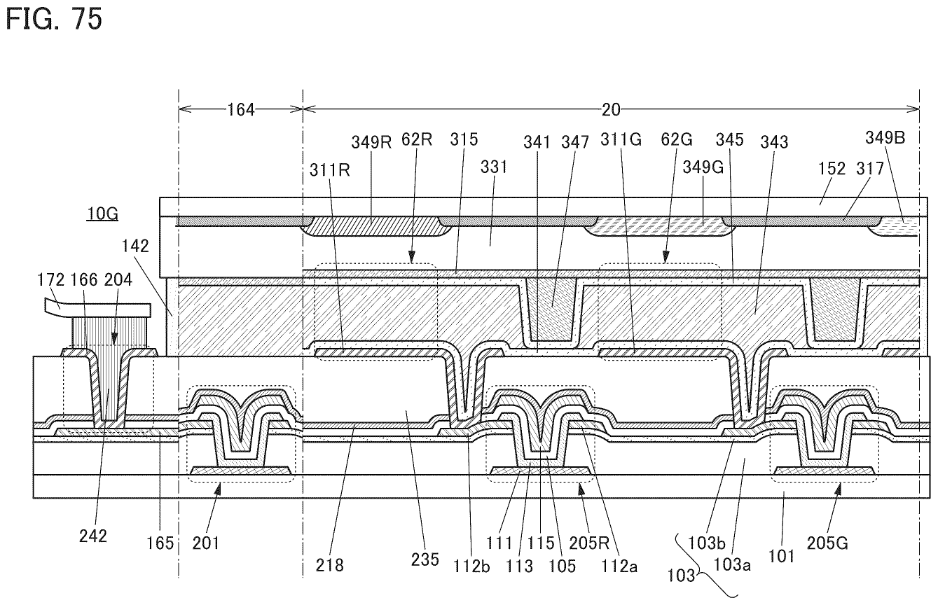

FIG. 75 is a cross-sectional view illustrating a structure example of a display apparatus 10G. The display apparatus 10G is a variation example of the display apparatus 10E and is different from the display apparatus 10E in that the liquid crystal element 62 is included as a display element. FIG. 75 illustrates a liquid crystal element 62R and a liquid crystal element 62G as the liquid crystal elements 62.

The liquid crystal element 62 includes the pixel electrode 311 and the common electrode 315, and a liquid crystal layer 343 is provided between the pixel electrode 311 and the common electrode 315. In FIG. 75, the pixel electrode 311 included in the liquid crystal element 62R is referred to as the pixel electrode 311R, and the pixel electrode 311 included in the liquid crystal element 62G is referred to as the pixel electrode 311G. An insulating layer 341 is provided between the pixel electrode 311 and the liquid crystal layer 343, and an insulating layer 345 is provided between the liquid crystal layer 343 and the common electrode 315. The insulating layer 341 and the insulating layer 345 each have a function of an alignment film.

A spacer 347 is provided between the liquid crystal elements 62. The spacer 347 is a columnar spacer obtained by selectively etching an insulating layer and is provided to control the distance (cell gap) between the pixel electrode 311 and the common electrode 315. Note that the spacer 347 may be a spherical spacer.

On the surface of the substrate 152 on the substrate 101 side, the light-blocking layer 317, a coloring layer 349R, a coloring layer 349G, a coloring layer 349B, the protective layer 331, the common electrode 315, the spacer 347, and the insulating layer 345 are provided in this order. The coloring layer 349R, the coloring layer 349G, and the coloring layer 349B are provided in regions of the display portion 20 where the light-blocking layers 317 are not provided. Note that the protective layer 331 can function as a planarization layer. An end portion of the coloring layer 349R, an end portion of the coloring layer 349G, and an end portion of the coloring layer 349B each overlap with an end portion of the light-blocking layer 317. The insulating layer 235 and the protective layer 331 are bonded to each other with the adhesive layer 142.

The coloring layer 349R includes a region overlapping with the liquid crystal element 62R, and has a transmittance of red light higher than that of light of other colors, for example. Thus, light emitted from the liquid crystal element 62R is extracted as red light to the outside of the display apparatus 10G. The coloring layer 349G includes a region overlapping with the liquid crystal element 62G, and has a transmittance of green light higher than that of light of other colors, for example. Thus, light emitted from the liquid crystal element 62G is extracted as green light to the outside of the display apparatus 10G. Furthermore, the coloring layer 349B includes a region overlapping with the liquid crystal element 62 that is not illustrated in FIG. 75, and has a transmittance of blue light higher than that of light of other colors, for example. Thus, light emitted from the liquid crystal element 62 including a region overlapping with the coloring layer 349B is extracted as blue light to the outside of the display apparatus 10G. In this manner, the display apparatus 10G can perform full-color display.

Examples of a material that can be used for the coloring layer 349 include a metal material, a resin material, and a resin material containing a pigment or dye. The coloring layer can be formed by an inkjet method, for example.

Although FIG. 75 illustrates an example of a display apparatus including a liquid crystal element with a vertical electric field mode, one embodiment of the present invention is not limited thereto and may be a display apparatus including a liquid crystal element with a horizontal electric field mode, for example. In the case of employing a horizontal electric field mode, a liquid crystal exhibiting a blue phase for which an alignment film is not used may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which a chiral material is mixed at 5 weight % or more is used for the liquid crystal layer 343 in order to improve the temperature range. The liquid crystal composition that contains the liquid crystal exhibiting a blue phase and the chiral material has a short response time and exhibits optical isotropy. In addition, the liquid crystal composition that contains the liquid crystal exhibiting a blue phase and the chiral material does not need alignment treatment and has small viewing angle dependence. Since an alignment film is not necessarily provided, rubbing treatment is unnecessary. Accordingly, electrostatic breakdown caused by the rubbing treatment can be prevented, and defects or damage of the display apparatus in the manufacturing process can be reduced.

The transistor 201 and the transistor 205 included in the display apparatus 10G are not limited to having the structures illustrated in FIG. 75, and can have any of the structures illustrated in FIG. 70A, FIG. 70B, FIG. 70C, FIG. 71, and FIG. 72.

The plurality of structure examples described in this embodiment can be combined with each other as appropriate. This embodiment can be combined with the other embodiments as appropriate.

### Embodiment 4

In this embodiment, a light-emitting element that can be used in the display apparatus of one embodiment of the present invention will be described.

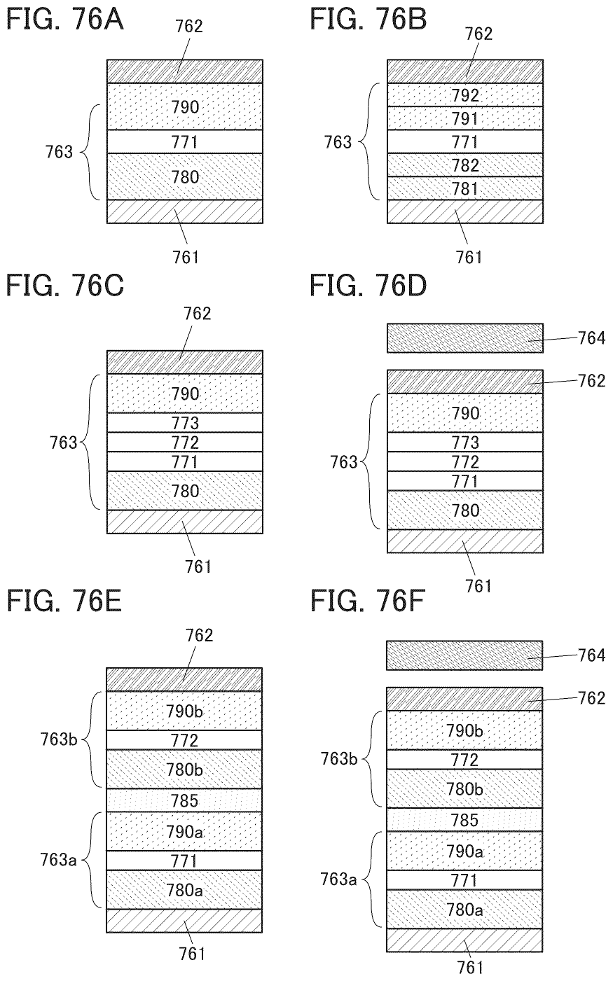

As illustrated in FIG. 76A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 76A is referred to as a single structure in this specification.

FIG. 76B is a variation example of the EL layer 763 included in the light-emitting element illustrated in FIG. 76A. Specifically, the light-emitting element illustrated in FIG. 76B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures where a plurality of light-emitting layers (the light-emitting layers 771, 772, and 773) are provided between the layer 780 and the layer 790 as illustrated in FIG. 76C and FIG. 76D are other variations of the single structure. Although FIG. 76C and FIG. 76D illustrate the examples where three light-emitting layers are included, the light-emitting layer in the light-emitting element with a single structure may include two or four or more light-emitting layers. In addition, the light-emitting element with a single structure may include a buffer layer between two light-emitting layers. A carrier-transport layer (a hole-transport layer or an electron-transport layer) can be used as the buffer layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 76E and FIG. 76F is referred to as a tandem structure in this specification. Note that a tandem structure may be referred to as a stack structure. The tandem structure enables a light-emitting element capable of high-luminance light emission. Furthermore, the tandem structure can reduce the amount of current needed for obtaining the same luminance as compared with a single structure, and thus can improve the reliability.

Note that FIG. 76D and FIG. 76F illustrate examples where the display apparatus includes a layer 764 overlapping with the light-emitting element. FIG. 76D illustrates an example where the layer 764 overlaps with the light-emitting element illustrated in FIG. 76C, and FIG. 76F illustrates an example where the layer 764 overlaps with the light-emitting element illustrated in FIG. 76E. In FIG. 76D and FIG. 76F, a conductive film transmitting visible light is used for the upper electrode 762 to extract light to the upper electrode 762 side.

One or both of a color conversion layer and a color filter (a coloring layer) can be used as the layer 764.

In FIG. 76C and FIG. 76D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting element can be extracted. In a subpixel that emits red light and a subpixel that emits green light, by providing a color conversion layer as the layer 764 illustrated in FIG. 76D, blue light emitted from the light-emitting element can be converted into light with a longer wavelength, and red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the desired color can be absorbed by the coloring layer, and color purity of light emitted from a subpixel can be improved.

In FIG. 76C and FIG. 76D, light-emitting substances that emit light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element having a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 76D. When white light passes through the color filter, light of a desired color can be obtained.

In the case where the light-emitting element with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting element with a single structure includes two light-emitting layers, the light-emitting element preferably includes a light-emitting layer containing a light-emitting substance that emits blue (B) light and a light-emitting layer containing a light-emitting substance that emits yellow (Y) light. Such a structure may be referred to as a BY single structure.

The light-emitting element emitting white light preferably contains two or more kinds of light-emitting substances. To obtain white light emission, two or more light-emitting substances are selected such that their emission colors are complementary colors. For example, when an emission color of a first light-emitting layer and an emission color of a second light-emitting layer are complementary colors, the light-emitting element can be configured to emit white light as a whole. The same applies to a light-emitting element including three or more light-emitting layers.

Also in FIG. 76C and FIG. 76D, the layer 780 and the layer 790 may each independently have a stacked-layer structure of two or more layers as illustrated in FIG. 76B.

In FIG. 76E and FIG. 76F, light-emitting substances that emit light of the same color, or moreover, the same light-emitting substance may be used for the light-emitting layer 771 and the light-emitting layer 772. For example, in light-emitting elements included in subpixels emitting light of different colors, a light-emitting substance that emits blue light may be used for each of the light-emitting layer 771 and the light-emitting layer 772. In a subpixel that emits blue light, blue light emitted from the light-emitting element can be extracted. In the subpixel that emits red light and the subpixel that emits green light, by providing a color conversion layer as the layer 764 illustrated in FIG. 76F, blue light emitted from the light-emitting element can be converted into light with a longer wavelength, and red light or green light can be extracted. As the layer 764, both a color conversion layer and a coloring layer are preferably used.

In the case where the light-emitting element having the structure illustrated in FIG. 76E or FIG. 76F is used for the subpixels emitting different colors, the subpixels may use different light-emitting substances. Specifically, in the light-emitting element included in the subpixel that emits red light, a light-emitting substance that emits red light may be used for each of the light-emitting layer 771 and the light-emitting layer 772. Similarly, in the light-emitting element included in the subpixel that emits green light, a light-emitting substance that emits green light may be used for each of the light-emitting layer 771 and the light-emitting layer 772. In the light-emitting element included in the subpixel that emits blue light, a light-emitting substance that emits blue light may be used for each of the light-emitting layer 771 and the light-emitting layer 772. A display apparatus with such a structure includes a light-emitting element with a tandem structure and can be regarded as having an SBS structure. Thus, the display apparatus can have both the advantage of a tandem structure and the advantage of an SBS structure. Accordingly, a light-emitting element capable of high-luminance light emission and having high reliability can be achieved.

In FIG. 76E and FIG. 76F, light-emitting substances emitting light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 76F. When white light passes through the color filter, light of a desired color can be obtained.

Although FIG. 76E and FIG. 76F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 76E and FIG. 76F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 76E and FIG. 76F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting element with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

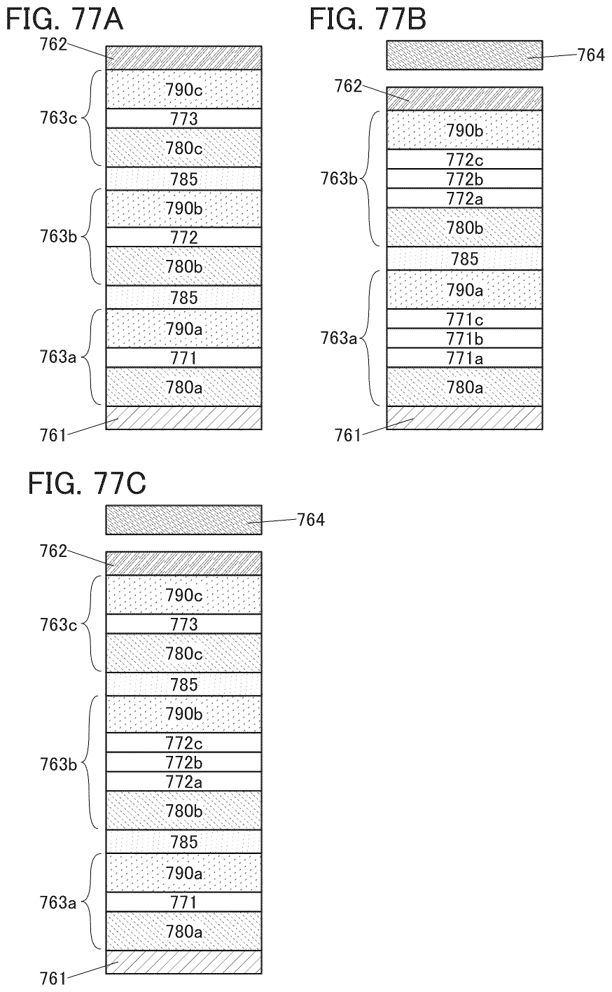

Structures illustrated in FIG. 77A to FIG. 77C can be given as examples of the light-emitting element with a tandem structure.

FIG. 77A illustrates a structure including three light-emitting units. In FIG. 77A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 77A, the light-emitting layer 771, the light-emitting layer 772, and the light-emitting layer preferably can contain light-emitting substances that emit light of the same color. Specifically, the light-emitting layer 771, the light-emitting layer 772, and the light-emitting layer 773 can each contain a red (R) light-emitting substance (a so-called three-unit tandem structure of R\R\R); the light-emitting layer 771, the light-emitting layer 772, and the light-emitting layer 773 can each contain a green (G) light-emitting substance (a so-called three-unit tandem structure of G\G\G); or the light-emitting layer 771, the light-emitting layer 772, and the light-emitting layer 773 can each contain a blue (B) light-emitting substance (a so-called three-unit tandem structure of B\B\B). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 77A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structures of the light-emitting substances that emit light of the same color are not limited to the above structures. For example, a light-emitting element with a tandem structure may be employed where light-emitting units each including a plurality of light-emitting layers are stacked as illustrated in FIG. 77B. FIG. 77B illustrates a structure where two light-emitting units (the light-emitting unit 763a and the light-emitting unit 763b) are connected in series through the charge-generation layers 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 77B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 77B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

In the case of a light-emitting element with a tandem structure, any of the following structures may be employed, for example: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

As illustrated in FIG. 77C, a light-emitting unit including one light-emitting layer and a light-emitting unit including a plurality of light-emitting layers may be used in combination.

Specifically, in the structure illustrated in FIG. 77C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 77C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting element will be described.

A conductive film transmitting visible light is used for the electrode through which light is extracted, which is either the lower electrode 761 or the upper electrode 762. A conductive film reflecting visible light is preferably used for the electrode through which light is not extracted. In the case where a display apparatus includes a light-emitting element emitting infrared light, it is preferable that a conductive film transmitting visible light and infrared light be used for the electrode through which light is extracted and that a conductive film reflecting visible light and infrared light be used for the electrode through which light is not extracted.

A conductive film transmitting visible light may be used also for an electrode through which light is not extracted. In this case, this electrode is preferably provided between the reflective layer and the EL layer 763. In other words, light emitted from the EL layer 763 may be reflected by the reflective layer to be extracted from the display apparatus.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (APC). Other example of the material include elements belonging to Group 1 and Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting element preferably employs a microcavity structure. Therefore, one of the pair of electrodes of the light-emitting element preferably includes an electrode having properties of transmitting and reflecting visible light (transflective electrode), and the other preferably includes an electrode having a property of reflecting visible light (reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting element. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting element includes at least the light-emitting layer. In addition, the light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting element, and an inorganic compound may also be included. Each layer included in the light-emitting element can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property that can be used for the hole-transport layer and will be described later. As the electron-transport material, it is possible to use a material with a high electron-transport property that can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting element can be achieved at the same time.

The hole-injection layer is a layer injecting holes from an anode to the hole-transport layer and a layer containing a material with a high hole-injection property. Examples of a material with a high hole-injection property include an aromatic amine compound and a composite material containing a hole-transport material and an acceptor material (electron-accepting material).

As the hole-transport material, it is possible to use a material with a high hole-transport property that can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material containing a hole-transport material and the above-described oxide of a metal belonging to Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property such as a π-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

The hole-blocking layer is provided in contact with the light-emitting layer. The hole-blocking layer is a layer having an electron-transport property and containing a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can be also used.

The difference between the lowest unoccupied molecular orbital (LUMO) level of the material with a high electron-injection property and the work function value of the material used for the cathode is preferably small (specifically, less than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the LUMO level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c] phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in drive voltage.

The plurality of structure examples described in this embodiment can be combined with each other as appropriate. This embodiment can be combined with the other embodiments as appropriate.

### Embodiment 5

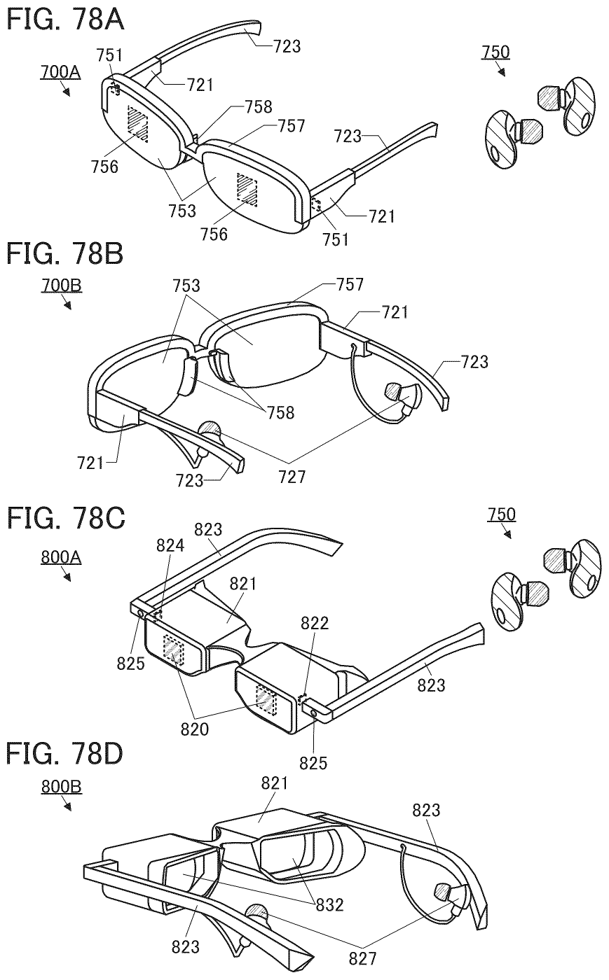

In this embodiment, electronic devices of one embodiment of the present invention will be described with reference to FIG. 78 to FIG. 80.

Electronic devices of this embodiment each include the display apparatus of one embodiment of the present invention in a display portion. Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The resolution of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

Examples of a wearable device that can be worn on a head are described with reference to FIG. 78A to FIG. 78D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 78A and an electronic device 700B illustrated in FIG. 78B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a picture signal, for example, can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 78C and an electronic device 800B illustrated in FIG. 78D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 78C illustrates an example where the wearing portion 823 has a shape like a temple (also referred to as a joint or the like) of glasses, for example; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable supplying a video signal from a video output device, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 78A has a function of transmitting information to the earphones 750 with the wireless communication function. As another example, the electronic device 800A illustrated in FIG. 78C has a function of transmitting information to the earphones 750 with the wireless communication function.

The electronic device may include an earphone portion. The electronic device 700B illustrated in FIG. 78B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 78D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

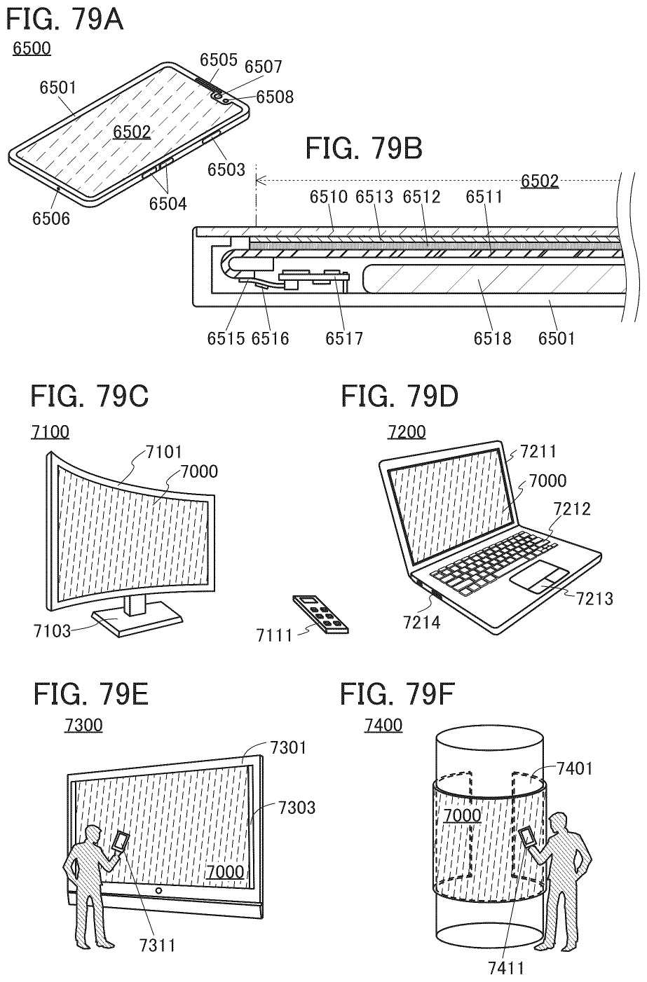

An electronic device 6500 illustrated in FIG. 79A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 79B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. Thus, an extremely lightweight electronic device can be obtained. Since the display panel 6511 is extremely thin, the battery 6518 with high capacity can be mounted while an increase in the thickness of the electronic device is suppressed. Moreover, part of the display panel 6511 is folded back so that a connection portion with the FPC 6515 is provided on the back side of the pixel portion, whereby an electronic device with a narrow bezel can be obtained.

FIG. 79C illustrates an example of a television device. In a television device 7100, a display portion 7000 is incorporated in a housing 7101. Here, a structure where the housing 7101 is supported by a stand 7103 is illustrated.

The display apparatus of one embodiment of the present invention can be used in the display portion 7000.

Operation of the television device 7100 illustrated in FIG. 79C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 79D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000.

FIG. 79E and FIG. 79F illustrate examples of digital signage.

Digital signage 7300 illustrated in FIG. 79E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 79F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 79E and FIG. 79F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 79E and FIG. 79F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

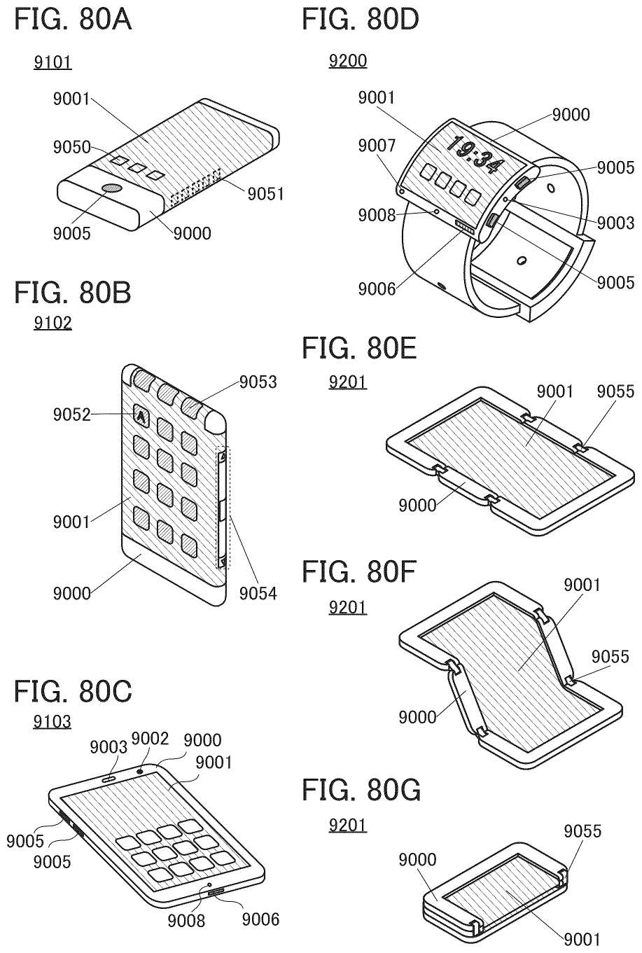

Electronic devices illustrated in FIG. 80A to FIG. 80G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 80A to FIG. 80G are described in detail below.

FIG. 80A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 80A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 80B is a perspective view illustrating a portable information terminal 9102. The portable information terminal 9102 has a function of displaying information on three or more surfaces of the display portion 9001. Here, an example where information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 80C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 80D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 80E to FIG. 80G are perspective views illustrating a foldable portable information terminal 9201. FIG. 80E is a perspective view of an opened state of the portable information terminal 9201, FIG. 80G is a perspective view of a folded state thereof, and FIG. 80F is a perspective view of a state in the middle of change from one of FIG. 80E and FIG. 80G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The plurality of structure examples described in this embodiment can be combined with each other as appropriate. This embodiment can be combined with the other embodiments as appropriate.

### REFERENCE NUMERALS

10A: display apparatus, 10B: display apparatus, 10C: display apparatus, 10D: display apparatus, 10E: display apparatus, 10F: display apparatus, 10G: display apparatus, 10: display apparatus, 11: scan line driver circuit, 13: signal line driver circuit, 15: control circuit, 17: circuit, 20: display portion, 21a: pixel, 21b: pixel, 21: pixel, 23a: subpixel, 23B: subpixel, 23b: subpixel, 23c: subpixel, 23d: subpixel, 23e: subpixel, 23G: subpixel, 23R: subpixel, 23: subpixel, 30: demultiplexer circuit group, 31: demultiplexer circuit, 33a: transistor, 33b: transistor, 33c: transistor, 33d: transistor, 33e: transistor, 33f: transistor, 33g: transistor, 33: transistor, 41a: wiring, 41b: wiring, 41c: wiring, 41d: wiring, 41: wiring, 43: wiring, 45: wiring, 47a: wiring, 47b: wiring, 47: wiring, 51A: pixel circuit, 51B: pixel circuit, 51C: pixel circuit, 51D: pixel circuit, 51E: pixel circuit, 51: pixel circuit, 52: transistor, 53: capacitor, 54: transistor, 55: transistor, 56: transistor, 57: capacitor, 61B: light-emitting element, 61G: light-emitting element, 61R: light-emitting element, 61: light-emitting element, 62G: liquid crystal element, 62R: liquid crystal element, 62: liquid crystal element, 63: wiring, 65: wiring, 67: wiring, 71: shift register circuit, 73: latch circuit, 81: transistor, 83: transistor, 85: capacitor, 90: inverter circuit, 91: transistor, 93: transistor, 95: transistor, 97: transistor, 99: capacitor, 101: substrate, 103a: insulating layer, 103b: insulating layer, 103: insulating layer, 105: insulating layer, 111a: conductive layer, 111b: conductive layer, 111c: conductive layer, 111d: conductive layer, 111e: conductive layer, 111f: conductive layer, 111: conductive layer, 112A: conductive layer, 112a: conductive layer, 112B: conductive layer, 112b: conductive layer, 112c: conductive layer, 112F: conductive film, 112: conductive layer, 113a: semiconductor layer, 113b: semiconductor layer, 113c: semiconductor layer, 113d: semiconductor layer, 113e: semiconductor layer, 113f: semiconductor layer, 113F: semiconductor film, 113: semiconductor layer, 115a: conductive layer, 115b: conductive layer, 115: conductive layer, 121a: opening, 121b: opening, 121: opening, 123: opening, 125a: opening, 125b: opening, 125c: opening, 125d: opening, 125e: opening, 125f: opening, 127a: opening, 127b: opening, 127c: opening, 127d: opening, 127e: opening, 127f: opening, 133a: opening, 133b: opening, 133c: opening, 133d: opening, 133e: opening, 139: conductive layer, 140: connection portion, 142: adhesive layer, 152: substrate, 161a: tapered portion, 161b: tapered portion, 164: circuit, 165: wiring, 166: conductive layer, 172: FPC, 173: IC, 181: conductive layer, 182: conductive layer, 183: conductive layer, 184: conductive layer, 185: conductive layer, 186: conductive layer, 191: conductive layer, 192: conductive layer, 193: conductive layer, 201: transistor, 204: connection portion, 205B: transistor, 205G: transistor, 205R: transistor, 205: transistor, 209: transistor, 210: transistor, 211: insulating layer, 213: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 235: insulating layer, 237: insulating layer, 242: connection layer, 311B: pixel electrode, 311G: pixel electrode, 311R: pixel electrode, 311: pixel electrode, 313B: layer, 313G: layer, 313R: layer, 313: layer, 314: common layer, 315: common electrode, 317: light-blocking layer, 318B: mask layer, 318G: mask layer, 318R: mask layer, 318: mask layer, 323: conductive layer, 324B: conductive layer, 324G: conductive layer, 324p: conductive layer, 324R: conductive layer, 324: conductive layer, 325: insulating layer, 326B: conductive layer, 326G: conductive layer, 326p: conductive layer, 326R: conductive layer, 326: conductive layer, 327: insulating layer, 328: layer, 329B: conductive layer, 329G: conductive layer, 329p: conductive layer, 329R: conductive layer, 329: conductive layer, 331: protective layer, 341: insulating layer, 343: liquid crystal layer, 345: insulating layer, 347: spacer, 349B: coloring layer, 349G: coloring layer, 349R: coloring layer, 349: coloring layer, 353: insulating layer, 400: memory device, 410: memory portion, 411: word line driver circuit, 413: bit line driver circuit, 415: power supply circuit, 420A: memory cell, 420B: memory cell, 420C: memory cell, 420D: memory cell, 420E: memory cell, 420: memory cell, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor; and
a first insulating layer,
wherein the transistor comprises:
a first conductive layer;
a second conductive layer;
a third conductive layer;
a fourth conductive layer;
a semiconductor layer; and
a second insulating layer,
wherein the first insulating layer is over the first conductive layer,
wherein the second conductive layer and the third conductive layer are over the first insulating layer,
wherein the first insulating layer comprises an opening reaching the first conductive layer,
wherein the second conductive layer and the third conductive layer face each other with the opening therebetween in a plan view,
wherein the semiconductor layer comprises a region in contact with the first conductive layer, a region in contact with the second conductive layer, a region in contact with the third conductive layer, and a region positioned in the opening,
wherein the second insulating layer is over the semiconductor layer, comprising a region positioned in the opening, and
wherein the fourth conductive layer is over the second insulating layer, comprising a region positioned in the opening.

2. The semiconductor device according to claim 1,
wherein the first conductive layer is in a floating state,
wherein the second conductive layer serves as one of a source electrode and a drain electrode of the transistor,
wherein the third conductive layer serves as the other of the source electrode and the drain electrode of the transistor, and
wherein the fourth conductive layer serves as a gate electrode of the transistor.

3. The semiconductor device according to claim 1,
wherein an end portion of the semiconductor layer comprises a region overlapping with the second conductive layer and a region overlapping with the third conductive layer, and
wherein the first conductive layer comprises a region overlapping with the second conductive layer and a region overlapping with the third conductive layer.

4. (canceled)

5. The semiconductor device according to claim 1,
wherein the semiconductor layer comprises a metal oxide,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

6. (canceled)

7. A display apparatus comprising:
a signal line driver circuit;
a first transistor;
a first insulating layer; and
a first pixel,
wherein the first transistor comprises:
a first conductive layer;
a second conductive layer;
a third conductive layer;
a fourth conductive layer;
a first semiconductor layer; and
a second insulating layer,
wherein the first insulating layer is over the first conductive layer,
wherein the second conductive layer and the third conductive layer are over the first insulating layer,
wherein the first insulating layer comprises a first opening reaching the first conductive layer,
wherein the second conductive layer and the third conductive layer face each other with the first opening therebetween in a plan view,
wherein the first semiconductor layer comprises a region in contact with the first conductive layer, a region in contact with the second conductive layer, a region in contact with the third conductive layer, and a region positioned in the first opening,
wherein the second insulating layer is over the first semiconductor layer, comprising a region positioned in the first opening,
wherein the fourth conductive layer is over the second insulating layer, comprising a region positioned in the first opening,
wherein the second conductive layer is electrically connected to the signal line driver circuit, and
wherein the third conductive layer is electrically connected to the first pixel.

8. The display apparatus according to claim 7,
wherein the first conductive layer is in a floating state, and
wherein the fourth conductive layer serves as a gate electrode of the first transistor.

9. The display apparatus according to claim 7,
wherein an end portion of the first semiconductor layer comprises a region overlapping with the second conductive layer and a region overlapping with the third conductive layer.

10. The display apparatus according to claim 7,
wherein the first conductive layer comprises a region overlapping with the second conductive layer and a region overlapping with the third conductive layer.

11. The display apparatus according to claim 7,
wherein the first semiconductor layer comprises a metal oxide.

12. The display apparatus according to claim 11,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

13-19. (canceled)

20. A semiconductor device comprising:
a transistor; and
a first insulating layer,
wherein the transistor comprises:
a first conductive layer;
a second conductive layer;
a third conductive layer;
a semiconductor layer; and
a second insulating layer,
wherein the first insulating layer comprises a first opening,
wherein the semiconductor layer comprises a region positioned in the first opening,
wherein a top surface of the semiconductor layer comprises a region in contact with the first conductive layer and a region in contact with the second conductive layer,
wherein the first conductive layer and the second conductive layer face each other with the first opening therebetween in a plan view,
wherein the second insulating layer is over the semiconductor layer, comprising a region positioned in the first opening, and
wherein the third conductive layer is over the second insulating layer, comprising a region positioned in the first opening.

21-23. (canceled)

24. The display apparatus according to claim 7, further comprising:
a second transistor; and
a second pixel,
wherein the second transistor comprises:
the second conductive layer;
a fifth conductive layer;
a sixth conductive layer;
a seventh conductive layer;
a second semiconductor layer; and
the second insulating layer,
wherein the first insulating layer is over the first conductive layer and the fifth conductive layer,
wherein the second conductive layer, the third conductive layer, and the sixth conductive layer are over the first insulating layer,
wherein the first insulating layer comprises the first opening reaching the first conductive layer and a second opening reaching the fifth conductive layer,
wherein the second conductive layer and the sixth conductive layer face each other with the second opening therebetween in the plan view,
wherein the second semiconductor layer comprises a region in contact with the second conductive layer, a region in contact with the fifth conductive layer, a region in contact with the sixth conductive layer, and a region positioned in the second opening,
wherein the second insulating layer is over the first semiconductor layer and the second semiconductor layer, comprising a region positioned in the first opening and a region positioned in the second opening,
wherein the seventh conductive layer is over the second insulating layer, comprising a region positioned in the second opening, and
wherein the sixth conductive layer is electrically connected to the second pixel.

25. The display apparatus according to claim 24,
wherein the first conductive layer and the fifth conductive layer are each in a floating state,
wherein the fourth conductive layer serves as a gate electrode of the first transistor, and
wherein the seventh conductive layer serves as a gate electrode of the second transistor.

26. The display apparatus according to claim 24,
wherein an end portion of the first semiconductor layer comprises a region overlapping with the second conductive layer and a region overlapping with the third conductive layer, and
wherein an end portion of the second semiconductor layer comprises a region overlapping with the second conductive layer and a region overlapping with the sixth conductive layer.

27. The display apparatus according to claim 24,
wherein the first conductive layer comprises a region overlapping with the second conductive layer and a region overlapping with the third conductive layer, and
wherein the fifth conductive layer comprises a region overlapping with the second conductive layer and a region overlapping with the sixth conductive layer.

28. The display apparatus according to claim 24,
wherein the first semiconductor layer and the second semiconductor layer each comprise a metal oxide,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

29. The display apparatus according to claim 24, further comprising a control circuit,
wherein the control circuit is configured to generate a first signal and to output the first signal to the fourth conductive layer,
wherein the control circuit is configured to generate a second signal and to output the second signal to the seventh conductive layer, and
wherein the first signal and the second signal are complementary signals.

30. The semiconductor device according to claim 20,
wherein the transistor further comprises a fourth conductive layer,
wherein the first insulating layer comprises the first opening and a second opening,
wherein the semiconductor layer comprises a region positioned in the first opening and a region positioned in the second opening,
wherein the semiconductor layer comprises a region in contact with the first conductive layer, a region in contact with the second conductive layer, and a region in contact with the third conductive layer,
wherein the second conductive layer and the third conductive layer face each other with the second opening therebetween in the plan view,
wherein the second insulating layer is over the semiconductor layer, comprising a region positioned in the first opening and a region positioned in the second opening, and
wherein the fourth conductive layer is over the second insulating layer, comprising a region positioned in the first opening and a region positioned in the second opening.

31. The semiconductor device according to claim 20,
wherein the first insulating layer comprises the first opening and a second opening,
wherein the semiconductor layer comprises a region positioned in the first opening and a region positioned in the second opening,
wherein the semiconductor layer comprises a region in contact with the first conductive layer and a region in contact with the second conductive layer,
wherein the first conductive layer and the second conductive layer face each other with the first opening and the second opening therebetween in the plan view,
wherein the second insulating layer is over the semiconductor layer, comprising a region positioned in the first opening and a region positioned in the second opening, and
wherein the third conductive layer is over the second insulating layer, comprising a region positioned in the first opening and a region positioned in the second opening.

32. The semiconductor device according to claim 31,
wherein the semiconductor layer comprises a region in contact with a top surface of the first insulating layer in a region between the first opening and the second opening in the plan view.
